(19) United States
(12) Patent Application Publication
(10) Pub. No.: US 2024/0045418 A1
(43) Pub. Date: Feb. 8, 2024

(54) PREDICTIVE MAINTENANCE RECOMMENDATION THROUGH COMPONENT CONDITION DATA MONITORING

(71) Applicant: MELLANOX TECHNOLOGIES, LTD., Yokneam (IL)

(72) Inventors: Siddha Ganju, Santa Clara, CA (US); Elad Mentovich, Tel aviv (IL); Dimitrios Kalavrouziotis, Papagos (GR); Paraskevas Bakopoulos, Argiroupoli (GR); Dimitrios Syrivelis, Volos (GR); Nikolaos Argyris, Zografou (GR); Yoram Zer, Megido (IL); Maoz Menachem Nagler, Moshavb Sde Yaakov (IL); Holger Prüsse Orup, Lejre (DK); Finn Leif Kraemer, Naerum (DK)

(21) Appl. No.: 17/887,642

(22) Filed: Aug. 15, 2022

(30) Foreign Application Priority Data
Aug. 1, 2022 (GR) 20220100625

(51) Int. Cl. G05B 23/02; G01R 31/08

(52) U.S. Cl. CPC G05B 23/0283; G01R 31/088; G05B 23/0254; G05B 23/0216; G05B 2223/02

(57) ABSTRACT

Apparatuses, systems, and techniques to monitor health data from components and predict needs for maintenance. In at least one embodiment, monitoring health data of cables having one or more known characteristics ands analyzing the health data to determine the health metrics of the one or more cable to generate profiles of the cables used to predict future health metrics of the cables and related cables sharing known characteristics.

### CROSS-REFERENCES TO RELATED APPLICATION

The present disclosure claims priority to Greek Application 20220100625, filed on Aug. 1, 2022, the disclosure of which is incorporated herein by reference in its entirety for all intents and purposes.

### TECHNICAL FIELD

At least one embodiment pertains to a condition monitoring system, as may be used with data transfer components. In at least one embodiment, such a monitoring system can be used in an environment such as a datacenter containing one or more racks of computing servers.

### BACKGROUND

Data centers typically contain many racks of servers which are cabled together. Adding patch panels to the racks can ease installation and improve cabling management. However, transceiver-to-transceiver cable links will be split into multiple cable segments, and in the event of a link failure, locating the failing cable segment and maintaining the cables may be difficult. An availability of up-to-date physical condition data related to the cables make it difficult to detect or predict failures and determine required maintenance.

### BRIEF DESCRIPTION OF DRAWINGS

FIG. 1 is a schematic diagram of an example of a schematic diagram of a data transmission system, according to at least one embodiment;

FIG. 2 illustrates a flow chart of an example of a process for component maintenance prediction, according to at least one embodiment;

FIG. 3A illustrates inference and/or training logic, according to at least one embodiment;

FIG. 3B illustrates inference and/or training logic, according to at least one embodiment;

FIG. 4 illustrates training and deployment of a neural network, according to at least one embodiment;

FIG. 5 illustrates an example data center system, according to at least one embodiment;

FIG. 6 is a block diagram illustrating a computer system, according to at least one embodiment;

FIG. 7 is a block diagram illustrating a computer system, according to at least one embodiment;

FIG. 8 illustrates a computer system, according to at least one embodiment;

FIG. 9 illustrates a computer system, according to at least one embodiment;

FIG. 10A illustrates a computer system, according to at least one embodiment;

FIG. 10B illustrates a computer system, according to at least one embodiment;

FIG. 10C illustrates a computer system, according to at least one embodiment;

FIG. 10D illustrates a computer system, according to at least one embodiment;

FIGS. 10E and 10F illustrate a shared programming model, according to at least one embodiment;

FIG. 11 illustrates exemplary integrated circuits and associated graphics processors, according to at least one embodiment;

FIGS. 12A-12B illustrate exemplary integrated circuits and associated graphics processors, according to at least one embodiment;

FIGS. 13A-13B illustrate additional exemplary graphics processor logic according to at least one embodiment;

FIG. 14 illustrates a computer system, according to at least one embodiment;

FIG. 15A illustrates a parallel processor, according to at least one embodiment;

FIG. 15B illustrates a partition unit, according to at least one embodiment;

FIG. 15C illustrates a processing cluster, according to at least one embodiment;

FIG. 15D illustrates a graphics multiprocessor, according to at least one embodiment;

FIG. 16 illustrates a multi-graphics processing unit (GPU) system, according to at least one embodiment;

FIG. 17 illustrates a graphics processor, according to at least one embodiment;

FIG. 18 is a block diagram illustrating a processor micro-architecture for a processor, according to at least one embodiment;

FIG. 19 illustrates a deep learning application processor, according to at least one embodiment;

FIG. 20 is a block diagram illustrating an example neuromorphic processor, according to at least one embodiment;

FIG. 21 illustrates at least portions of a graphics processor, according to one or more embodiments;

FIG. 22 illustrates at least portions of a graphics processor, according to one or more embodiments;

FIG. 23 illustrates at least portions of a graphics processor, according to one or more embodiments;

FIG. 24 is a block diagram of a graphics processing engine of a graphics processor in accordance with at least one embodiment;

FIG. 25 is a block diagram of at least portions of a graphics processor core, according to at least one embodiment;

FIGS. 26A-26B illustrate thread execution logic including an array of processing elements of a graphics processor core according to at least one embodiment;

FIG. 27 illustrates a parallel processing unit (“PPU”), according to at least one embodiment;

FIG. 28 illustrates a general processing cluster (“GPC”), according to at least one embodiment;

FIG. 29 illustrates a memory partition unit of a parallel processing unit (“PPU”), according to at least one embodiment;

FIG. 30 illustrates a streaming multi-processor, according to at least one embodiment.

FIG. 31 is an example data flow diagram for an advanced computing pipeline, in accordance with at least one embodiment;

FIG. 32 is a system diagram for an example system for training, adapting, instantiating and deploying machine learning models in an advanced computing pipeline, in accordance with at least one embodiment;

FIG. 33 includes an example illustration of an advanced computing pipeline 3210A for processing imaging data, in accordance with at least one embodiment;

FIG. 34A includes an example data flow diagram of a virtual instrument supporting an ultrasound device, in accordance with at least one embodiment;

FIG. 34B includes an example data flow diagram of a virtual instrument supporting an CT scanner, in accordance with at least one embodiment;

FIG. 35A illustrates a data flow diagram for a process to train a machine learning model, in accordance with at least one embodiment; and

FIG. 35B is an example illustration of a client-server architecture to enhance annotation tools with pre-trained annotation models, in accordance with at least one embodiment.

### DETAILED DESCRIPTION

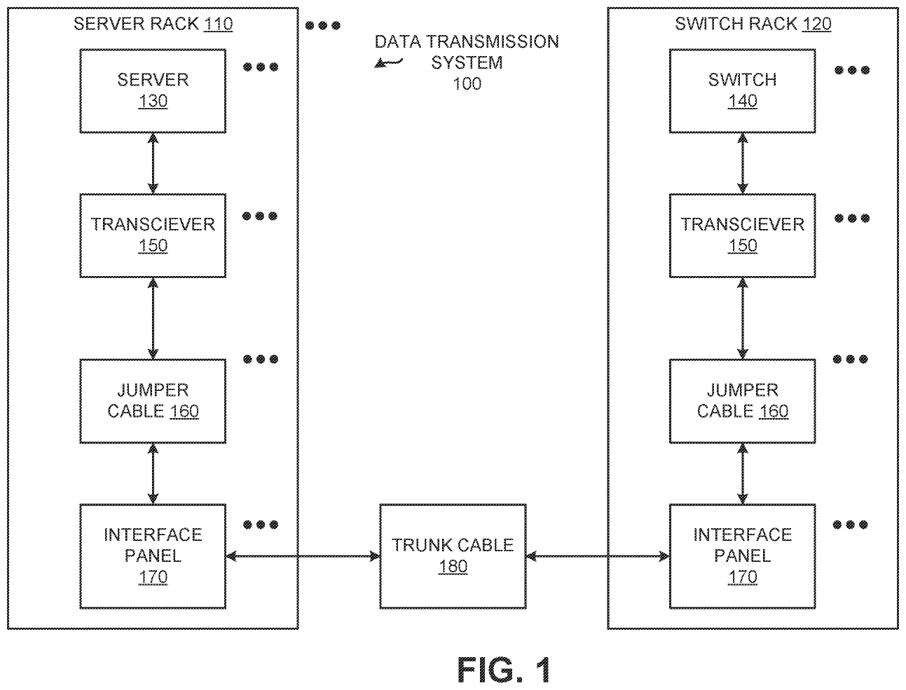

FIG. 1 illustrates an example of a data transmission system 100 which may include a variety of computing devices and control systems. In at least one embodiment a data transmission system 100 may be installed in a data center or a Performance Optimized Datacenter (POD), which includes any number of server racks 110, pods, or other groupings of resources, which may also include various switches or other networking components, such as one or more switch racks 120. Server racks 110 and switch racks 120 can be connected directly by any number of jumper cables 160. Each server 130 or switch 140 in a rack can be coupled with a corresponding transceiver 150. A transceiver 150 can be an optical transceiver, used in high-bandwidth data communications applications, having an electrical interface on a side that connects inside a system and an optical interface on a side that connects outside a system through a fiber optic cable. In at least one embodiment, transceivers 150 are connected to servers with multi-fiber push on (MPO) jumper cables 160, or any other suitable cable. Server 130 transceivers 150 can be connected to switch 140 transceivers 150 only with jumper cables 160 to directly connect a transceiver 150.

In at least one embodiment, data transmission system 100 includes interface panels 170, also known as patch panels, to break a link between server racks 110 and switch rack 120 into individual segments. In at least one example, a fiber jumper cable 160 leads from a transceiver 150 of server 130 to a point inside a server rack 110 and does not leave a server rack 110. A fiber jumper cable 160 can lead from a server transceiver 150 to an interface panel 170. Each individual wire from a transceiver 150 inside a server rack 110 can lead to an interface panel 170. Jumper cables 160 can be aggregated into more dense cables, and trunk cables 180 can be used to connect interface panel 170 of a server rack 110 to an interface panel 170 of a switch rack 120. A switch rack 120 can include a reverse configuration to link an interface panel 170 of a switch rack 120 to a transceiver 150 of a switch rack 120. A fiber cable link between server racks 110 and a switch rack 120 can be split into segments. Various server racks 110 may be preinstalled with fiber cable and can be disconnected from a POD at any time without disconnecting cables from each transceiver 150, but only disconnecting trunk cables 180 from interface panels 170 without disconnecting cabling within a rack. In at least one embodiment racks are pre-wired unit which eases installation.

Installation of interface panels may prevent identifying a failure if a link drops without any further information. Installation of an interface panel may require that any failure related to fiber cables also prevents identifying a location of a failure if a link drops without any further information. Installation of an interface panel may also interrupt a single fiber jumper cable going from one transceiver another and now includes any number of segments which should be monitored. In at least one embodiment, an approach can involve monitoring a link to either identify or predict a failure at a position in a link by, for example, cross-correlating several kinds of data to identify any number of failure mechanisms. When a trunk cable fails, specific health data monitored from components of a link can be identified by monitoring data. In at least one embodiment when a MPO jumper cable fails, specific health data monitored from components of a link can be identified by monitoring data as well.

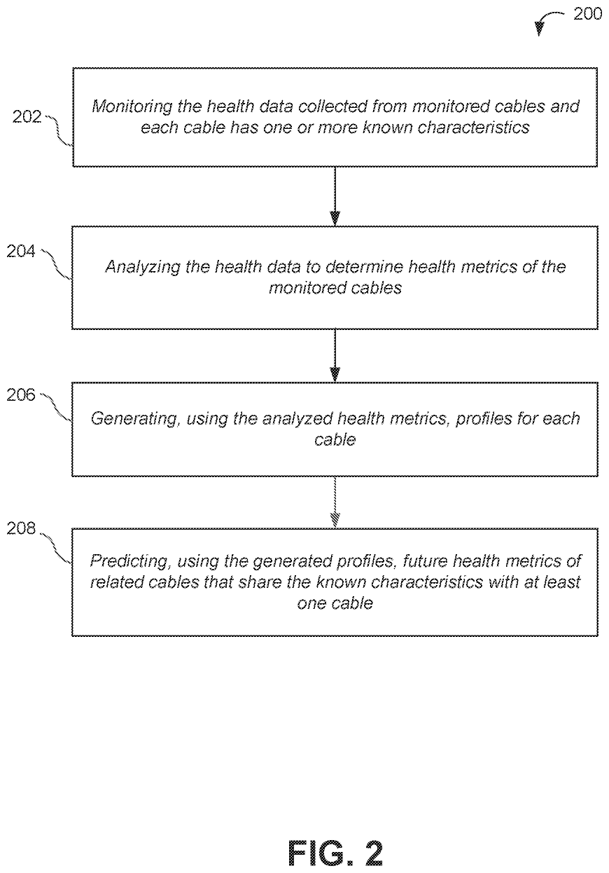

FIG. 2 illustrates example of a process 200 for component maintenance prediction. This example process includes monitoring health data collected from any number of monitored cables and each cable has any number of known characteristics 202. Health data is then analyzed to determine health metrics of monitored cables 204. Profiles for individual cables are generated using analyzed health metrics 206. This process can then predict future health metrics of related cables that share known characteristics with at least one individual cable using individual cable generated profiles 208.

In at least one embodiment, a system used to perform such a process for monitoring health data can acquire health data of those components of a data transmission system in order to develop a logical profile and cross-correlate between collected data in order to identify a fault and a fault location. Cross correlating of monitored data can be used to locate a component that has provided data with an anomaly. In at least one embodiment, physical co-location or related spatial information of wires, cables, or components can be added to the information for cluster formation, in addition to manufacturing information, machine information and health information. Acquiring health data to develop a logical profile of each relevant component can enable or allow a predictive analysis and proactive maintenance. When a fault or related anomaly is identified, recommendations or instructions can be provided to repair or replace a component. Such an approach to monitoring and analyzing can reduce maintenance time and down time. One example approach can be based on machine learning and fuzzy logic to operate a monitoring and predictive function on a large scale which can encapsulate an entire data center.

In any system which include a high number of components or cables it is possible to improve traceability to determine which component or cable is failing, which component should be repaired, or what other action should be taken. When a monitored system includes a large number of components, many components may be similar in terms of their profile or their performance. Using this knowledge of shared characteristics between some components, similar cable behavior can be predicted. For example, if one cable fails, it can be determined that other similar cables may also fail. It can be determined from collected and monitored health data which component have failed, and which components require replacement. If data is needed to be collected from a specific cable, it can be determined which other similar cables should have data collected from as well. In at least one embodiment, components may be monitored to determine their performance metrics in order to understand if any components can perform at higher levels than others. For example, if certain components are determined to be better suited for maximum performance, a recommendation may be provided to schedule workflow requiring higher performance to those components. In another example, if certain components are determined to be provide consistent but lower than average performance, a recommendation may be provided to schedule workflow requiring lower performance to those components or replace those components with components that can perform at higher levels.

In at least one embodiment, component health can be monitored over time to continue to develop logical profiles, which describe conditions of cable over time. Clusters can be formed from component logical profiles in order to generate predictions and recommendations. One example approach can cluster similar groups of components and monitor activity individually and as a group to draw conclusions. During such a monitoring process, a large amount of data can be collected from components and which data is monitored largely depends on metrics that are being collected. Logical clusters of components can be used which generally define how components are structured and what other components are similar. As more health data is received about components, component positions inside clusters may move over time and trigger an identification of an anomaly. Is moving from a centroid to an outer region of a cluster, an indication of an anomaly may be triggered. Monitoring components and identifying requirements of components and actions to be taken can be automated. When monitoring determines an anomaly with a component in a particular cluster, other components in a single cluster can be indicated as possibly exhibiting identical behavior. This may reduce time to detect a failure or even proactively predict a failure.

Any number and type of clustering algorithms can be used to input health data of components and develop clusters using collected data. In at least one embodiment information can be input constantly over extended periods of time or continuously while components are in use. Over time clusters will exhibit unique traits. For example, cables from one vendor may have similar performance or in another example, cables sharing an operating environment may have identical performance. Such information can be used to develop future maintenance activities and predictive analytics. Any number of metrics can be used to group components, including physical characteristic, vendor data, shared location, and physical characteristics.

In at least one embodiment metrics of physical characteristic of components may be read from transceivers of a system, and this data can be collected. Physical characteristics can be cross-correlated and used to identify a position of any possible fault. For example, transmitted optical power and laser IV data, including laser bias and voltage, can be read from a transceiver and used for cross-correlation. Received power or received signal strength indication (RSSI) can be constantly monitored to identify whether a link experiences an issue that causes optical loss or a related issue. Pre-forward error correction (FEC) bit error rate (BER) and respective bit error histograms can indicate performance of a link. For example, pre-FEC BER begins degradation could be caused by a problem in several areas, including a link, a transmitter, or a receiver and degradation past a certain threshold will affect performance of system.

If certain functions of a transceiver analog front end (AFE), also known as receiver side, such as amplification or continuous time linear equalize (CTLE) settings, change due to constant adaptation of a device, then an fault is likely in a link. If amplification must be increased gradually, then a loss in power is likely. Equalization depth, decision feedback equalizer (DFE) coefficients may be able to be read. DFE coefficients can be monitored to identify whether a link requires heavy equalization. In at least one embodiment, if a link is transitioning from light equalization to heavy equalization, health of a link is degrading. Temperature may be important to monitor for indications of condition due to temperature drift in a system. Signal-to-noise ratio (SNR) and eye-opening-monitor are related to quality of received signal. SNR and eye-opening-monitor are metrics on eye quality itself. Any number and types of metrics of physical characteristics of components may be monitored. Different transceivers will be able to provide different metrics. In at least one embodiment a system can identify a transceiver and adapt to accept a corresponding set of specifications.

It may be possible to more efficiently determine a nature and location of a detected anomaly based on failure scenarios with known metric conditions. A possible failure scenario exists when a connector is improperly mated, and collected data indicates this expected cross-correlation. Such a failure may occur after a maintenance event and correspond to an abrupt change in metrics where current status of a link will not equate to pre-maintenance status. Identifying a failed connector can be narrowed down based on a number of failing fiber cores since different connectors can have different numbers of fibers. Trunk cables might have many fibers and if many fibers are down then a large connector to a trunk is likely problematic. Where these characteristics are identified, an improperly mated connector can be identified more efficiently as a failure scenario.

A possible failure scenario exists when dirt enters a connector, and collected data indicates this expected cross-correlation. Such a failure may occur after a maintenance event, and may correspond to an abrupt change in metrics where current status of a link will not equate to pre-maintenance status. A number of affected fibers can indicate a location of affected fibers. Certain connectors may be known to be less prone to dirt related failures, whereas other connectors are known to be more sensitive. Where these characteristics are identified, a contaminated connector can be identified more efficiently as a failure scenario.

A possible failure scenario exists when a fiber is bent, and collected data indicates this expected cross-correlation. Such a failure may occur after a maintenance event. Identifying a failed connector can be narrowed down based on a number of failing fiber cores since different connectors can have different numbers of fibers. SNR and optical eye may be lower than expected. A link will be operational immediately prior to failure where a link will be active and then stop working abruptly. Where these characteristics are identified, a bent fiber can be identified more efficiently as a failure scenario.

Another possible failure scenario exists when a transceiver is failing, and collected data indicates this expected cross-correlation. Such a failure may occur at any time and is not necessarily related to a timing of maintenance. Transceiver failure can happen when a system is running, and such a failure may not be abrupt and a gradual change in metrics is identifiable over an extended period. Such a failure may be evidenced by a loss of power of gradual wear out of a laser and a sudden link drop. Where these characteristics are identified, a failing transceiver can be identified more efficiently as a failure scenario.

Another possible failure scenario exists when a link close to a loss budget limit, and collected data indicates this expected cross-correlation. Such a failure may occur during initial setup of a data center or other similar system. During an initial setup, or initialization, data can be collected and then links close to a loss budget limit can be identified as have increased chance of failing because those links will be more sensitive to any kind of failure. Where these characteristics are identified, a link close to a loss budget limit can be identified more efficiently as a failure scenario.

A possible failure scenario exists when a link is over a loss budget limit or Rx power too high, and collected data indicates this expected cross-correlation. Such a failure may occur during system initialization of a data center or other similar system. In contrast to previous example, links over a loss budget limit may be identified. A wrong connection may be made, and a reach specification passed. Such a failure may occur with ER and ZR transceivers and can suggest a longer fiber should be used. Where these characteristics are identified, a link is over a loss budget limit or Rx power too high can be identified more efficiently as a failure scenario.

False positive link failures can exist since during monitoring it is possible to identify when a component appears to be failing but is not. A false positive example may include a low-quality active optic cable (AOC), which can be indicated by unsupported BER and or link flapping. If transceiver re-insertion correcting an error indicates a likely port FW related issue. Components with temperature drifts greater than three degrees Celsius per minute should be checked, since high temperature drifts indicate that it is not a specific cable issue. In case of low numbers of failing cable, cable quality likely should be inspected.

A false positive example may relate to an inoperable transceiver laser. Such a false positive failure may occur when work by a laser is first started, in contrast to a failure after a laser has started working. It is possible that a port FW did not turn on laser power and a recommendation can be given to turn laser power on manually. Host firmware can be inspected to determine condition.

Monitoring and predictive analysis of lasers may not only involve collecting data from transceivers, but may also be applicable to data center with co-packaged optic slides or any other kind of data center deployment that requires optics. A system to monitor and provide predictive maintenance can be applied to any suitable system. Monitoring and providing predictive maintenance is scalable for any size system, including from one or more components to multiple data center. This may be applied to related applications outside of a data center, stacks, and other data transmission systems. Any system that includes many wires or components or where locating and maintaining wires are time consuming may be applicable. An electrical grid, newsrooms, security systems, electric automobiles, warehouses, systems in remote areas such as an oil rig, a manufacturing plant and related examples would benefit from this system.

Since a large amount of data is potentially to be collected and monitored, data can be used to track a history of data and trends which can be used to improve an understanding trends in a data center or in data center portions. Because some data centers may be very large and are divided into multiple rooms, it is possible to monitor trends separately across different locations of a data center. Trends can be monitored and compared for different vendors of optical fiber or other components. For example, multiple vendors may provide similar product by recording events related to examples of products over a long time period it can be determined if cross-correlation exists between vendors and performance. Histograms can be used to improve monitoring.

Artificial intelligence and machine learning techniques can be used when data does not provide obvious solutions or more precise information is sought. Artificial intelligence and machine learning techniques may also be used to monitor and predict on a large scale. A visualization can be incorporated to visualize clusters using any suitable program. Visualization can be used to identify which components belong together in a cluster. 3D visualizations can be utilized to move around clusters and identify interactions of components or metrics, using any suitable tool such as a tensor flow projector tool. Incorporating a visualization with interpretability tests can ensure that a human is able to review and interpret results for a human-in-the-loop component to complement any automated systems.

### Inference and Training Logic

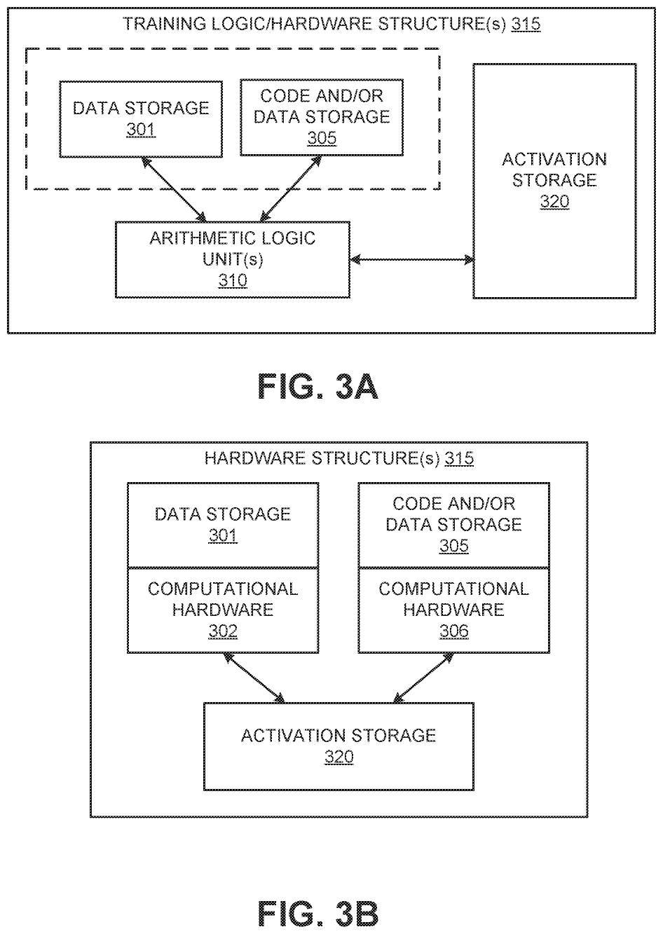

FIG. 3A illustrates inference and/or training logic 315 used to perform inferencing and/or training operations associated with one or more embodiments. Details regarding inference and/or training logic 315 are provided below in conjunction with FIGS. 3A and/or 3B.

In at least one embodiment, inference and/or training logic 315 may include, without limitation, code and/or data storage 301 to store forward and/or output weight and/or input/output data, and/or other parameters to configure neurons or layers of a neural network trained and/or used for inferencing in aspects of one or more embodiments. In at least one embodiment, training logic 315 may include, or be coupled to code and/or data storage 301 to store graph code or other software to control timing and/or order, in which weight and/or other parameter information is to be loaded to configure, logic, including integer and/or floating point units (collectively, arithmetic logic units (ALUs)). In at least one embodiment, code, such as graph code, loads weight or other parameter information into processor ALUs based on an architecture of a neural network to which such code corresponds. In at least one embodiment, code and/or data storage 301 stores weight parameters and/or input/output data of each layer of a neural network trained or used in conjunction with one or more embodiments during forward propagation of input/output data and/or weight parameters during training and/or inferencing using aspects of one or more embodiments. In at least one embodiment, any portion of code and/or data storage 301 may be included with other on-chip or off-chip data storage, including a processor's L1, L2, or L3 cache or system memory.

In at least one embodiment, any portion of code and/or data storage 301 may be internal or external to one or more processors or other hardware logic devices or circuits. In at least one embodiment, code and/or code and/or data storage 301 may be cache memory, dynamic randomly addressable memory (“DRAM”), static randomly addressable memory (“SRAM”), non-volatile memory (e.g., flash memory), or other storage. In at least one embodiment, a choice of whether code and/or code and/or data storage 301 is internal or external to a processor, for example, or comprising DRAM, SRAM, flash or some other storage type may depend on available storage on-chip versus off-chip, latency requirements of training and/or inferencing functions being performed, batch size of data used in inferencing and/or training of a neural network, or some combination of these factors.

In at least one embodiment, inference and/or training logic 315 may include, without limitation, a code and/or data storage 305 to store backward and/or output weight and/or input/output data corresponding to neurons or layers of a neural network trained and/or used for inferencing in aspects of one or more embodiments. In at least one embodiment, code and/or data storage 305 stores weight parameters and/or input/output data of each layer of a neural network trained or used in conjunction with one or more embodiments during backward propagation of input/output data and/or weight parameters during training and/or inferencing using aspects of one or more embodiments. In at least one embodiment, training logic 315 may include, or be coupled to code and/or data storage 305 to store graph code or other software to control timing and/or order, in which weight and/or other parameter information is to be loaded to configure, logic, including integer and/or floating point units (collectively, arithmetic logic units (ALUs)).

In at least one embodiment, code, such as graph code, causes the loading of weight or other parameter information into processor ALUs based on an architecture of a neural network to which such code corresponds. In at least one embodiment, any portion of code and/or data storage 305 may be included with other on-chip or off-chip data storage, including a processor's L1, L2, or L3 cache or system memory. In at least one embodiment, any portion of code and/or data storage 305 may be internal or external to one or more processors or other hardware logic devices or circuits. In at least one embodiment, code and/or data storage 305 may be cache memory, DRAM, SRAM, non-volatile memory (e.g., flash memory), or other storage. In at least one embodiment, a choice of whether code and/or data storage 305 is internal or external to a processor, for example, or comprising DRAM, SRAM, flash memory or some other storage type may depend on available storage on-chip versus off-chip, latency requirements of training and/or inferencing functions being performed, batch size of data used in inferencing and/or training of a neural network, or some combination of these factors.

In at least one embodiment, code and/or data storage 301 and code and/or data storage 305 may be separate storage structures. In at least one embodiment, code and/or data storage 301 and code and/or data storage 305 may be a combined storage structure. In at least one embodiment, code and/or data storage 301 and code and/or data storage 305 may be partially combined and partially separate. In at least one embodiment, any portion of code and/or data storage 301 and code and/or data storage 305 may be included with other on-chip or off-chip data storage, including a processor's L1, L2, or L3 cache or system memory.

In at least one embodiment, inference and/or training logic 315 may include, without limitation, one or more arithmetic logic unit(s) (“ALU(s)”) 310, including integer and/or floating point units, to perform logical and/or mathematical operations based, at least in part on, or indicated by, training and/or inference code (e.g., graph code), a result of which may produce activations (e.g., output values from layers or neurons within a neural network) stored in an activation storage 320 that are functions of input/output and/or weight parameter data stored in code and/or data storage 301 and/or code and/or data storage 305. In at least one embodiment, activations stored in activation storage 320 are generated according to linear algebraic and or matrix-based mathematics performed by ALU(s) 310 in response to performing instructions or other code, wherein weight values stored in code and/or data storage 305 and/or data storage 301 are used as operands along with other values, such as bias values, gradient information, momentum values, or other parameters or hyperparameters, any or all of which may be stored in code and/or data storage 305 or code and/or data storage 301 or another storage on or off-chip.

In at least one embodiment, ALU(s) 310 are included within one or more processors or other hardware logic devices or circuits, whereas in another embodiment, ALU(s) 310 may be external to a processor or other hardware logic device or circuit that uses them (e.g., a co-processor). In at least one embodiment, ALUs 310 may be included within a processor's execution units or otherwise within a bank of ALUs accessible by a processor's execution units either within same processor or distributed between different processors of different types (e.g., central processing units, graphics processing units, fixed function units, etc.). In at least one embodiment, code and/or data storage 301, code and/or data storage 305, and activation storage 320 may share a processor or other hardware logic device or circuit, whereas in another embodiment, they may be in different processors or other hardware logic devices or circuits, or some combination of same and different processors or other hardware logic devices or circuits. In at least one embodiment, any portion of activation storage 320 may be included with other on-chip or off-chip data storage, including a processor's L1, L2, or L3 cache or system memory. Furthermore, inferencing and/or training code may be stored with other code accessible to a processor or other hardware logic or circuit and fetched and/or processed using a processor's fetch, decode, scheduling, execution, retirement and/or other logical circuits.

In at least one embodiment, activation storage 320 may be cache memory, DRAM, SRAM, non-volatile memory (e.g., flash memory), or other storage. In at least one embodiment, activation storage 320 may be completely or partially within or external to one or more processors or other logical circuits. In at least one embodiment, a choice of whether activation storage 320 is internal or external to a processor, for example, or comprising DRAM, SRAM, flash memory or some other storage type may depend on available storage on-chip versus off-chip, latency requirements of training and/or inferencing functions being performed, batch size of data used in inferencing and/or training of a neural network, or some combination of these factors.

In at least one embodiment, inference and/or training logic 315 illustrated in FIG. 3A may be used in conjunction with an application-specific integrated circuit (“ASIC”), such as a TensorFlow® Processing Unit from Google, an inference processing unit (IPU) from Graphcore™, or a Nervana® (e.g., “Lake Crest”) processor from Intel Corp. In at least one embodiment, inference and/or training logic 315 illustrated in FIG. 3A may be used in conjunction with central processing unit (“CPU”) hardware, graphics processing unit (“GPU”) hardware or other hardware, such as field programmable gate arrays (“FPGAs”).

FIG. 3B illustrates inference and/or training logic 315, according to at least one embodiment. In at least one embodiment, inference and/or training logic 315 may include, without limitation, hardware logic in which computational resources are dedicated or otherwise exclusively used in conjunction with weight values or other information corresponding to one or more layers of neurons within a neural network. In at least one embodiment, inference and/or training logic 315 illustrated in FIG. 3B may be used in conjunction with an application-specific integrated circuit (ASIC), such as TensorFlow® Processing Unit from Google, an inference processing unit (IPU) from Graphcore™, or a Nervana® (e.g., “Lake Crest”) processor from Intel Corp. In at least one embodiment, inference and/or training logic 315 illustrated in FIG. 3B may be used in conjunction with central processing unit (CPU) hardware, graphics processing unit (GPU) hardware or other hardware, such as field programmable gate arrays (FPGAs). In at least one embodiment, inference and/or training logic 315 includes, without limitation, code and/or data storage 301 and code and/or data storage 305, which may be used to store code (e.g., graph code), weight values and/or other information, including bias values, gradient information, momentum values, and/or other parameter or hyperparameter information. In at least one embodiment illustrated in FIG. 3B, each of code and/or data storage 301 and code and/or data storage 305 is associated with a dedicated computational resource, such as computational hardware 302 and computational hardware 306, respectively. In at least one embodiment, each of computational hardware 302 and computational hardware 306 comprises one or more ALUs that perform mathematical functions, such as linear algebraic functions, only on information stored in code and/or data storage 301 and code and/or data storage 305, respectively, result of which is stored in activation storage 320.

In at least one embodiment, each of code and/or data storage 301 and 305 and corresponding computational hardware 302 and 306, respectively, correspond to different layers of a neural network, such that resulting activation from one storage/computational pair 301/302 of code and/or data storage 301 and computational hardware 302 is provided as an input to a next storage/computational pair 305/306 of code and/or data storage 305 and computational hardware 306, in order to mirror a conceptual organization of a neural network. In at least one embodiment, each of storage/computational pairs 301/302 and 305/306 may correspond to more than one neural network layer. In at least one embodiment, additional storage/computation pairs (not shown) subsequent to or in parallel with storage/computation pairs 301/302 and 305/306 may be included in inference and/or training logic 315.

### Neural Network Training and Deployment

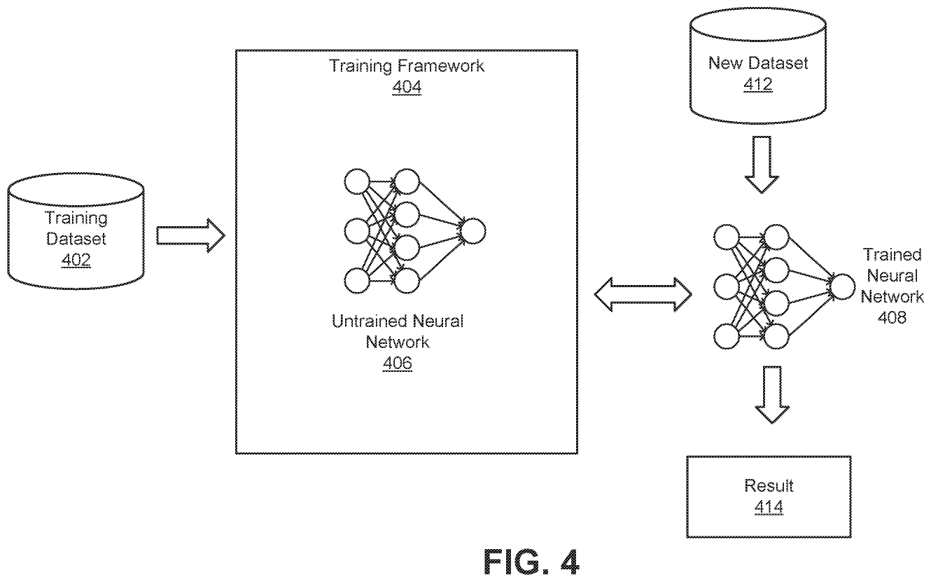

FIG. 4 illustrates training and deployment of a deep neural network, according to at least one embodiment. In at least one embodiment, untrained neural network 406 is trained using a training dataset 402. In at least one embodiment, training framework 404 is a PyTorch framework, whereas in other embodiments, training framework 404 is a TensorFlow, Boost, Caffe, Microsoft Cognitive Toolkit/CNTK, MXNet, Chainer, Keras, Deeplearning4j, or other training framework. In at least one embodiment, training framework 404 trains an untrained neural network 406 and enables it to be trained using processing resources described herein to generate a trained neural network 408. In at least one embodiment, weights may be chosen randomly or by pre-training using a deep belief network. In at least one embodiment, training may be performed in either a supervised, partially supervised, or unsupervised manner.

In at least one embodiment, untrained neural network 406 is trained using supervised learning, wherein training dataset 402 includes an input paired with a desired output for an input, or where training dataset 402 includes input having a known output and an output of neural network 406 is manually graded. In at least one embodiment, untrained neural network 406 is trained in a supervised manner and processes inputs from training dataset 402 and compares resulting outputs against a set of expected or desired outputs. In at least one embodiment, errors are then propagated back through untrained neural network 406. In at least one embodiment, training framework 404 adjusts weights that control untrained neural network 406. In at least one embodiment, training framework 404 includes tools to monitor how well untrained neural network 406 is converging towards a model, such as trained neural network 408, suitable to generating correct answers, such as in result 414, based on input data such as a new dataset 412. In at least one embodiment, training framework 404 trains untrained neural network 406 repeatedly while adjust weights to refine an output of untrained neural network 406 using a loss function and adjustment algorithm, such as stochastic gradient descent. In at least one embodiment, training framework 404 trains untrained neural network 406 until untrained neural network 406 achieves a desired accuracy. In at least one embodiment, trained neural network 408 can then be deployed to implement any number of machine learning operations.

In at least one embodiment, untrained neural network 406 is trained using unsupervised learning, wherein untrained neural network 406 attempts to train itself using unlabeled data. In at least one embodiment, unsupervised learning training dataset 402 will include input data without any associated output data or “ground truth” data. In at least one embodiment, untrained neural network 406 can learn groupings within training dataset 402 and can determine how individual inputs are related to untrained dataset 402. In at least one embodiment, unsupervised training can be used to generate a self-organizing map in trained neural network 408 capable of performing operations useful in reducing dimensionality of new dataset 412. In at least one embodiment, unsupervised training can also be used to perform anomaly detection, which allows identification of data points in new dataset 412 that deviate from normal patterns of new dataset 412.

In at least one embodiment, semi-supervised learning may be used, which is a technique in which in training dataset 402 includes a mix of labeled and unlabeled data. In at least one embodiment, training framework 404 may be used to perform incremental learning, such as through transferred learning techniques. In at least one embodiment, incremental learning enables trained neural network 408 to adapt to new dataset 412 without forgetting knowledge instilled within trained neural network 408 during initial training.

In at least one embodiment, training framework 404 is a framework processed in connection with a software development toolkit such as an OpenVINO (Open Visual Inference and Neural network Optimization) toolkit. In at least one embodiment, an OpenVINO toolkit is a toolkit such as those developed by Intel Corporation of Santa Clara, CA.

In at least one embodiment, OpenVINO is a toolkit for facilitating development of applications, specifically neural network applications, for various tasks and operations, such as human vision emulation, speech recognition, natural language processing, recommendation systems, and/or variations thereof. In at least one embodiment, OpenVINO supports neural networks such as convolutional neural networks (CNNs), recurrent and/or attention-based neural networks, and/or various other neural network models. In at least one embodiment, OpenVINO supports various software libraries such as OpenCV, OpenCL, and/or variations thereof.

In at least one embodiment, OpenVINO supports neural network models for various tasks and operations, such as classification, segmentation, object detection, face recognition, speech recognition, pose estimation (e.g., humans and/or objects), monocular depth estimation, image inpainting, style transfer, action recognition, colorization, and/or variations thereof.

In at least one embodiment, OpenVINO comprises one or more software tools and/or modules for model optimization, also referred to as a model optimizer. In at least one embodiment, a model optimizer is a command line tool that facilitates transitions between training and deployment of neural network models. In at least one embodiment, a model optimizer optimizes neural network models for execution on various devices and/or processing units, such as a GPU, CPU, PPU, GPGPU, and/or variations thereof. In at least one embodiment, a model optimizer generates an internal representation of a model, and optimizes said model to generate an intermediate representation. In at least one embodiment, a model optimizer reduces a number of layers of a model. In at least one embodiment, a model optimizer removes layers of a model that are utilized for training. In at least one embodiment, a model optimizer performs various neural network operations, such as modifying inputs to a model (e.g., resizing inputs to a model), modifying a size of inputs of a model (e.g., modifying a batch size of a model), modifying a model structure (e.g., modifying layers of a model), normalization, standardization, quantization (e.g., converting weights of a model from a first representation, such as floating point, to a second representation, such as integer), and/or variations thereof.

In at least one embodiment, OpenVINO comprises one or more software libraries for inferencing, also referred to as an inference engine. In at least one embodiment, an inference engine is a C++ library, or any suitable programming language library. In at least one embodiment, an inference engine is utilized to infer input data. In at least one embodiment, an inference engine implements various classes to infer input data and generate one or more results. In at least one embodiment, an inference engine implements one or more API functions to process an intermediate representation, set input and/or output formats, and/or execute a model on one or more devices.

In at least one embodiment, OpenVINO provides various abilities for heterogeneous execution of one or more neural network models. In at least one embodiment, heterogeneous execution, or heterogeneous computing, refers to one or more computing processes and/or systems that utilize one or more types of processors and/or cores. In at least one embodiment, OpenVINO provides various software functions to execute a program on one or more devices. In at least one embodiment, OpenVINO provides various software functions to execute a program and/or portions of a program on different devices. In at least one embodiment, OpenVINO provides various software functions to, for example, run a first portion of code on a CPU and a second portion of code on a GPU and/or FPGA. In at least one embodiment, OpenVINO provides various software functions to execute one or more layers of a neural network on one or more devices (e.g., a first set of layers on a first device, such as a GPU, and a second set of layers on a second device, such as a CPU).

In at least one embodiment, OpenVINO includes various functionality similar to functionalities associated with a CUDA programming model, such as various neural network model operations associated with frameworks such as TensorFlow, PyTorch, and/or variations thereof. In at least one embodiment, one or more CUDA programming model operations are performed using OpenVINO. In at least one embodiment, various systems, methods, and/or techniques described herein are implemented using OpenVINO.

### Data Center

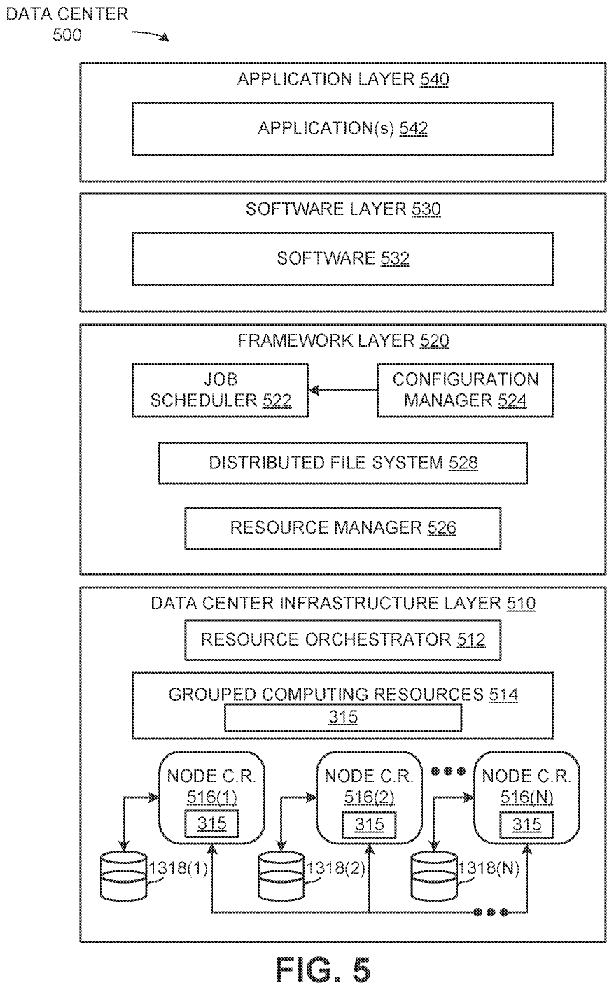

FIG. 5 illustrates an example data center 500, in which at least one embodiment may be used. In at least one embodiment, data center 500 includes a data center infrastructure layer 510, a framework layer 520, a software layer 530 and an application layer 540.

In at least one embodiment, as shown in FIG. 5, data center infrastructure layer 510 may include a resource orchestrator 512, grouped computing resources 514, and node computing resources (“node C.R.s”) 516(1)-516(N), where “N” represents a positive integer (which may be a different integer “N” than used in other figures). In at least one embodiment, node C.R.s 516(1)-516(N) may include, but are not limited to, any number of central processing units (“CPUs”) or other processors (including accelerators, field programmable gate arrays (FPGAs), graphics processors, etc.), memory storage devices 518(1)-518(N) (e.g., dynamic read-only memory, solid state storage or disk drives), network input/output (“NW I/O”) devices, network switches, virtual machines (“VMs”), power modules, and maintenance modules, etc. In at least one embodiment, one or more node C.R.s from among node C.R.s 516(1)-516(N) may be a server having one or more of above-mentioned computing resources.

In at least one embodiment, grouped computing resources 514 may include separate groupings of node C.R.s housed within one or more racks (not shown), or many racks housed in data centers at various geographical locations (also not shown). In at least one embodiment, separate groupings of node C.R.s within grouped computing resources 514 may include grouped compute, network, memory or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, maintenance modules, and network switches, in any combination.

In at least one embodiment, resource orchestrator 512 may configure or otherwise control one or more node C.R.s 516(1)-516(N) and/or grouped computing resources 514. In at least one embodiment, resource orchestrator 512 may include a software design infrastructure (“SDI”) management entity for data center 500. In at least one embodiment, resource orchestrator 312 may include hardware, software or some combination thereof.

In at least one embodiment, as shown in FIG. 5, framework layer 520 includes a job scheduler 522, a configuration manager 524, a resource manager 526 and a distributed file system 528. In at least one embodiment, framework layer 520 may include a framework to support software 532 of software layer 530 and/or one or more application(s) 542 of application layer 540. In at least one embodiment, software 532 or application(s) 542 may respectively include web-based service software or applications, such as those provided by Amazon Web Services, Google Cloud and Microsoft Azure. In at least one embodiment, framework layer 520 may be, but is not limited to, a type of free and open-source software web application framework such as Apache Spark™ (hereinafter “Spark”) that may utilize distributed file system 528 for large-scale data processing (e.g., “big data”). In at least one embodiment, job scheduler 522 may include a Spark driver to facilitate scheduling of workloads supported by various layers of data center 500. In at least one embodiment, configuration manager 524 may be capable of configuring different layers such as software layer 530 and framework layer 520 including Spark and distributed file system 528 for supporting large-scale data processing. In at least one embodiment, resource manager 526 may be capable of managing clustered or grouped computing resources mapped to or allocated for support of distributed file system 528 and job scheduler 522. In at least one embodiment, clustered or grouped computing resources may include grouped computing resources 514 at data center infrastructure layer 510. In at least one embodiment, resource manager 526 may coordinate with resource orchestrator 512 to manage these mapped or allocated computing resources.

In at least one embodiment, software 532 included in software layer 530 may include software used by at least portions of node C.R.s 516(1)-516(N), grouped computing resources 514, and/or distributed file system 528 of framework layer 520. In at least one embodiment, one or more types of software may include, but are not limited to, Internet web page search software, e-mail virus scan software, database software, and streaming video content software.

In at least one embodiment, application(s) 542 included in application layer 540 may include one or more types of applications used by at least portions of node C.R.s 516(1)-516(N), grouped computing resources 514, and/or distributed file system 528 of framework layer 520. In at least one embodiment, one or more types of applications may include, but are not limited to, any number of a genomics application, a cognitive compute, application and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 524, resource manager 526, and resource orchestrator 512 may implement any number and type of self-modifying actions based on any amount and type of data acquired in any technically feasible fashion. In at least one embodiment, self-modifying actions may relieve a data center operator of data center 500 from making possibly bad configuration decisions and possibly avoiding underutilized and/or poor performing portions of a data center.

In at least one embodiment, data center 500 may include tools, services, software or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to data center 500. In at least one embodiment, trained machine learning models corresponding to one or more neural networks may be used to infer or predict information using resources described above with respect to data center 500 by using weight parameters calculated through one or more training techniques described herein.

In at least one embodiment, data center may use CPUs, application-specific integrated circuits (ASICs), GPUs, FPGAs, or other hardware to perform training and/or inferencing using above-described resources. Moreover, one or more software and/or hardware resources described above may be configured as a service to allow users to train or performing inferencing of information, such as image recognition, speech recognition, or other artificial intelligence services.

Inference and/or training logic 315 are used to perform inferencing and/or training operations associated with one or more embodiments. Details regarding inference and/or training logic 315 are provided herein in conjunction with FIGS. 3A and/or 3B. In at least one embodiment, inference and/or training logic 315 may be used in system FIG. 5 for inferencing or predicting operations based, at least in part, on weight parameters calculated using neural network training operations, neural network functions and/or architectures, or neural network use cases described herein.

In at least one embodiment, one or more neural networks of an inference and/or training logic 315 may be used in conjunction with the system of FIG. 5 and may be configured to receive sensor inputs from multiple sensors and may be trained to infer a coolant requirement. In at least one embodiment, an inference and/or training logic 315 may be able to infer this using information from historical maintenance requirements and of historical sensor inputs. In at least one embodiment, an inference and/or training logic 315 may make an inference of a change in a maintenance requirement. In at least one embodiment, sensor inputs may be correlated to classes of different maintenance requirements of each of different sensor inputs. In at least one embodiment, a new sensor input classifying within a class of such different sensor inputs may indicate a maintenance requirement, or a change thereof.

### Computer Systems

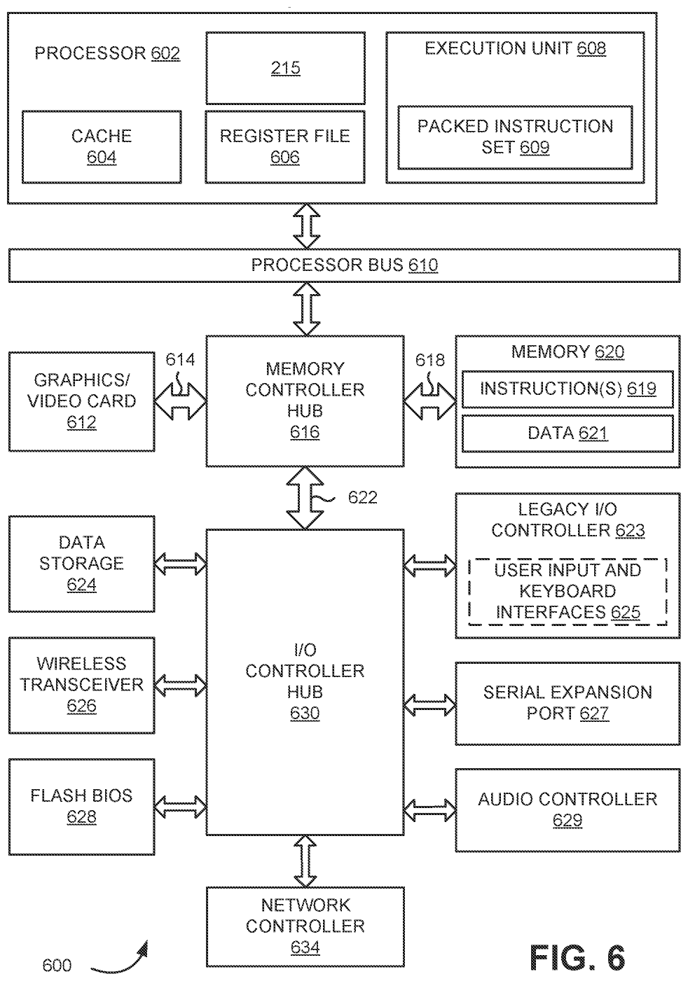

FIG. 6 is a block diagram illustrating an exemplary computer system, which may be a system with interconnected devices and components, a system-on-a-chip (SOC) or some combination thereof formed with a processor that may include execution units to execute an instruction, according to at least one embodiment. In at least one embodiment, a computer system 600 may include, without limitation, a component, such as a processor 602 to employ execution units including logic to perform algorithms for process data, in accordance with present disclosure, such as in embodiment described herein. In at least one embodiment, computer system 600 may include processors, such as PENTIUM® Processor family, Xeon™ Itanium®, XScale™ and/or StrongARM™, Intel® Core™, or Intel® Nervana™ microprocessors available from Intel Corporation of Santa Clara, California, although other systems (including PCs having other microprocessors, engineering workstations, set-top boxes and like) may also be used. In at least one embodiment, computer system 600 may execute a version of WINDOWS operating system available from Microsoft Corporation of Redmond, Wash., although other operating systems (UNIX and Linux, for example), embedded software, and/or graphical user interfaces, may also be used.

Embodiments may be used in other devices such as handheld devices and embedded applications. Some examples of handheld devices include cellular phones, Internet Protocol devices, digital cameras, personal digital assistants (“PDAs”), and handheld PCs. In at least one embodiment, embedded applications may include a microcontroller, a digital signal processor (“DSP”), system on a chip, network computers (“NetPCs”), set-top boxes, network hubs, wide area network (“WAN”) switches, or any other system that may perform one or more instructions in accordance with at least one embodiment.

In at least one embodiment, computer system 600 may include, without limitation, processor 602 that may include, without limitation, one or more execution units 608 to perform machine learning model training and/or inferencing according to techniques described herein. In at least one embodiment, computer system 600 is a single processor desktop or server system, but in another embodiment, computer system 600 may be a multiprocessor system. In at least one embodiment, processor 602 may include, without limitation, a complex instruction set computer (“CISC”) microprocessor, a reduced instruction set computing (“RISC”) microprocessor, a very long instruction word (“VLIW”) microprocessor, a processor implementing a combination of instruction sets, or any other processor device, such as a digital signal processor, for example. In at least one embodiment, processor 602 may be coupled to a processor bus 610 that may transmit data signals between processor 602 and other components in computer system 600.

In at least one embodiment, processor 602 may include, without limitation, a Level 1 (“L1”) internal cache memory (“cache”) 604. In at least one embodiment, processor 602 may have a single internal cache or multiple levels of internal cache. In at least one embodiment, cache memory may reside external to processor 602. Other embodiments may also include a combination of both internal and external caches depending on particular implementation and needs. In at least one embodiment, a register file 606 may store different types of data in various registers including, without limitation, integer registers, floating point registers, status registers, and an instruction pointer register.

In at least one embodiment, execution unit 608, including, without limitation, logic to perform integer and floating point operations, also resides in processor 602. In at least one embodiment, processor 602 may also include a microcode (“ucode”) read only memory (“ROM”) that stores microcode for certain macro instructions. In at least one embodiment, execution unit 608 may include logic to handle a packed instruction set 609. In at least one embodiment, by including packed instruction set 609 in an instruction set of a general-purpose processor, along with associated circuitry to execute instructions, operations used by many multimedia applications may be performed using packed data in processor 602. In at least one embodiment, many multimedia applications may be accelerated and executed more efficiently by using a full width of a processor's data bus for performing operations on packed data, which may eliminate a need to transfer smaller units of data across that processor's data bus to perform one or more operations one data element at a time.

In at least one embodiment, execution unit 608 may also be used in microcontrollers, embedded processors, graphics devices, DSPs, and other types of logic circuits. In at least one embodiment, computer system 600 may include, without limitation, a memory 620. In at least one embodiment, memory 620 may be a Dynamic Random Access Memory (“DRAM”) device, a Static Random Access Memory (“SRAM”) device, a flash memory device, or another memory device. In at least one embodiment, memory 620 may store instruction(s) 619 and/or data 621 represented by data signals that may be executed by processor 602.

In at least one embodiment, a system logic chip may be coupled to processor bus 610 and memory 620. In at least one embodiment, a system logic chip may include, without limitation, a memory controller hub (“MCH”) 616, and processor 602 may communicate with MCH 616 via processor bus 610. In at least one embodiment, MCH 616 may provide a high bandwidth memory path 618 to memory 620 for instruction and data storage and for storage of graphics commands, data and textures. In at least one embodiment, MCH 616 may direct data signals between processor 602, memory 620, and other components in computer system 600 and to bridge data signals between processor bus 610, memory 620, and a system I/O interface 622. In at least one embodiment, a system logic chip may provide a graphics port for coupling to a graphics controller. In at least one embodiment, MCH 616 may be coupled to memory 620 through high bandwidth memory path 618 and a graphics/video card 612 may be coupled to MCH 616 through an Accelerated Graphics Port (“AGP”) interconnect 614.

In at least one embodiment, computer system 600 may use system I/O interface 622 as a proprietary hub interface bus to couple MCH 616 to an I/O controller hub (“ICH”) 630. In at least one embodiment, ICH 630 may provide direct connections to some I/O devices via a local I/O bus. In at least one embodiment, a local I/O bus may include, without limitation, a high-speed I/O bus for connecting peripherals to memory 620, a chipset, and processor 602. Examples may include, without limitation, an audio controller 629, a firmware hub (“flash BIOS”) 628, a wireless transceiver 626, a data storage 624, a legacy I/O controller 623 containing user input and keyboard interfaces 625, a serial expansion port 627, such as a Universal Serial Bus (“USB”) port, and a network controller 634. In at least one embodiment, data storage 624 may comprise a hard disk drive, a floppy disk drive, a CD-ROM device, a flash memory device, or other mass storage device.

In at least one embodiment, FIG. 6 illustrates a system, which includes interconnected hardware devices or “chips”, whereas in other embodiments, FIG. 6 may illustrate an exemplary SoC. In at least one embodiment, devices illustrated in FIG. 6 may be interconnected with proprietary interconnects, standardized interconnects (e.g., PCIe) or some combination thereof. In at least one embodiment, one or more components of computer system 600 are interconnected using compute express link (CXL) interconnects.

Inference and/or training logic 315 are used to perform inferencing and/or training operations associated with one or more embodiments. Details regarding inference and/or training logic 315 are provided herein in conjunction with FIGS. 3A and/or 3B. In at least one embodiment, inference and/or training logic 315 may be used in system FIG. 6 for inferencing or predicting operations based, at least in part, on weight parameters calculated using neural network training operations, neural network functions and/or architectures, or neural network use cases described herein.

In at least one embodiment, one or more neural networks of an inference and/or training logic 315 may be used in conjunction with the system of FIG. 6 and may be configured to receive sensor inputs from multiple sensors and may be trained to infer a coolant requirement. In at least one embodiment, an inference and/or training logic 315 may be able to infer this using information from historical maintenance requirements and of historical sensor inputs. In at least one embodiment, an inference and/or training logic 315 may make an inference of a change in a maintenance requirement. In at least one embodiment, sensor inputs may be correlated to classes of different maintenance requirements of each of different sensor inputs. In at least one embodiment, a new sensor input classifying within a class of such different sensor inputs may indicate a maintenance requirement, or a change thereof.

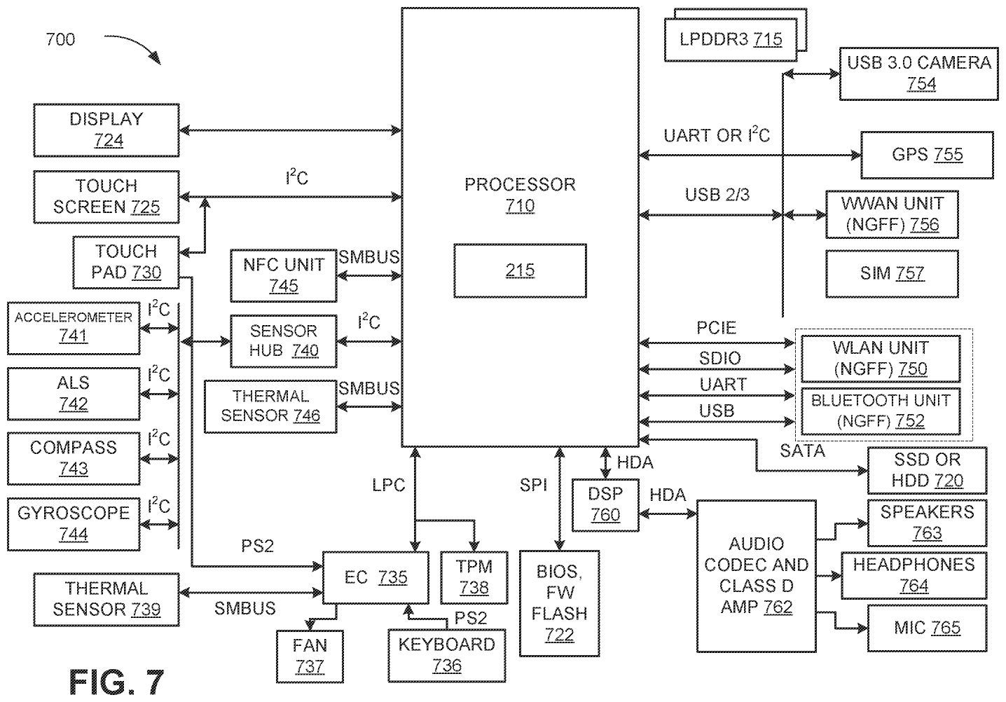

FIG. 7 is a block diagram illustrating an electronic device 700 for utilizing a processor 710, according to at least one embodiment. In at least one embodiment, electronic device 700 may be, for example and without limitation, a notebook, a tower server, a rack server, a blade server, a laptop, a desktop, a tablet, a mobile device, a phone, an embedded computer, or any other suitable electronic device.

In at least one embodiment, electronic device 700 may include, without limitation, processor 710 communicatively coupled to any suitable number or kind of components, peripherals, modules, or devices. In at least one embodiment, processor 710 is coupled using a bus or interface, such as a I²C bus, a System Management Bus (“SMBus”), a Low Pin Count (LPC) bus, a Serial Peripheral Interface (“SPI”), a High Definition Audio (“HDA”) bus, a Serial Advance Technology Attachment (“SATA”) bus, a Universal Serial Bus (“USB”) (versions 1, 2, 3, etc.), or a Universal Asynchronous Receiver/Transmitter (“UART”) bus. In at least one embodiment, FIG. 7 illustrates a system, which includes interconnected hardware devices or “chips”, whereas in other embodiments, FIG. 7 may illustrate an exemplary SoC. In at least one embodiment, devices illustrated in FIG. 7 may be interconnected with proprietary interconnects, standardized interconnects (e.g., PCIe) or some combination thereof. In at least one embodiment, one or more components of FIG. 7 are interconnected using compute express link (CXL) interconnects.

In at least one embodiment, FIG. 7 may include a display 724, a touch screen 725, a touch pad 730, a Near Field Communications unit (“NFC”) 745, a sensor hub 740, a thermal sensor 746, an Express Chipset (“EC”) 735, a Trusted Platform Module (“TPM”) 738, BIOS/firmware/flash memory (“BIOS, FW Flash”) 722, a DSP 760, a drive 720 such as a Solid State Disk (“SSD”) or a Hard Disk Drive (“HDD”), a wireless local area network unit (“WLAN”) 750, a Bluetooth unit 752, a Wireless Wide Area Network unit (“WWAN”) 756, a Global Positioning System (GPS) unit 755, a camera (“USB 3.0 camera”) 754 such as a USB 3.0 camera, and/or a Low Power Double Data Rate (“LPDDR”) memory unit (“LPDDR3”) 715 implemented in, for example, an LPDDR3 standard. These components may each be implemented in any suitable manner.

In at least one embodiment, other components may be communicatively coupled to processor 710 through components described herein. In at least one embodiment, an accelerometer 741, an ambient light sensor (“ALS”) 742, a compass 743, and a gyroscope 744 may be communicatively coupled to sensor hub 740. In at least one embodiment, a thermal sensor 739, a fan 737, a keyboard 736, and touch pad 730 may be communicatively coupled to EC 735. In at least one embodiment, speakers 763, headphones 764, and a microphone (“mic”) 765 may be communicatively coupled to an audio unit (“audio codec and class D amp”) 762, which may in turn be communicatively coupled to DSP 760. In at least one embodiment, audio unit 762 may include, for example and without limitation, an audio coder/decoder (“codec”) and a class D amplifier. In at least one embodiment, a SIM card (“SIM”) 757 may be communicatively coupled to WWAN unit 756. In at least one embodiment, components such as WLAN unit 750 and Bluetooth unit 752, as well as WWAN unit 756 may be implemented in a Next Generation Form Factor (“NGFF”).

Inference and/or training logic 315 are used to perform inferencing and/or training operations associated with one or more embodiments. Details regarding inference and/or training logic 315 are provided herein in conjunction with FIGS. 3A and/or 3B. In at least one embodiment, inference and/or training logic 315 may be used in system FIG. 7 for inferencing or predicting operations based, at least in part, on weight parameters calculated using neural network training operations, neural network functions and/or architectures, or neural network use cases described herein.

In at least one embodiment, one or more neural networks of an inference and/or training logic 315 may be used in conjunction with the system of FIG. 7 and may be configured to receive sensor inputs from multiple sensors and may be trained to infer a coolant requirement. In at least one embodiment, an inference and/or training logic 315 may be able to infer this using information from historical maintenance requirements and of historical sensor inputs. In at least one embodiment, an inference and/or training logic 315 may make an inference of a change in a maintenance requirement. In at least one embodiment, sensor inputs may be correlated to classes of different maintenance requirements of each of different sensor inputs. In at least one embodiment, a new sensor input classifying within a class of such different sensor inputs may indicate a maintenance requirement, or a change thereof.

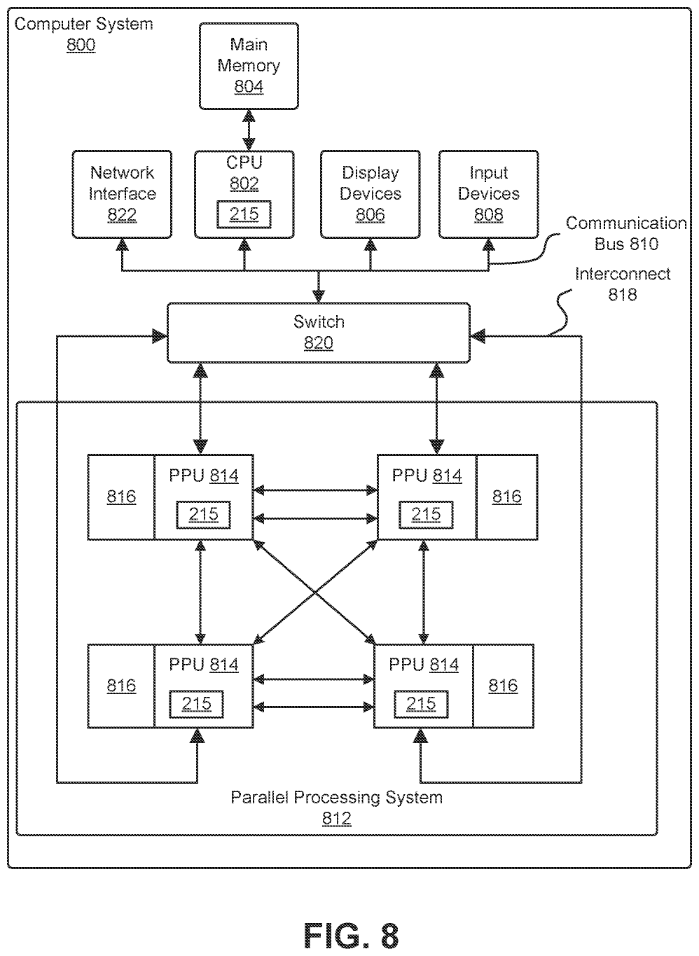

FIG. 8 illustrates a computer system 800, according to at least one embodiment. In at least one embodiment, computer system 800 is configured to implement various processes and methods described throughout this disclosure.

In at least one embodiment, computer system 800 comprises, without limitation, at least one central processing unit (“CPU”) 802 that is connected to a communication bus 810 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 800 includes, without limitation, a main memory 804 and control logic (e.g., implemented as hardware, software, or a combination thereof) and data are stored in main memory 804, which may take form of random access memory (“RAM”). In at least one embodiment, a network interface subsystem (“network interface”) 822 provides an interface to other computing devices and networks for receiving data from and transmitting data to other systems with computer system 800.

In at least one embodiment, computer system 800, in at least one embodiment, includes, without limitation, input devices 808, a parallel processing system 812, and display devices 806 that can be implemented using a conventional cathode ray tube (“CRT”), a liquid crystal display (“LCD”), a light emitting diode (“LED”) display, a plasma display, or other suitable display technologies. In at least one embodiment, user input is received from input devices 808 such as keyboard, mouse, touchpad, microphone, etc. In at least one embodiment, each module described herein can be situated on a single semiconductor platform to form a processing system.

Inference and/or training logic 315 are used to perform inferencing and/or training operations associated with one or more embodiments. Details regarding inference and/or training logic 315 are provided herein in conjunction with FIGS. 3A and/or 3B. In at least one embodiment, inference and/or training logic 315 may be used in system FIG. 8 for inferencing or predicting operations based, at least in part, on weight parameters calculated using neural network training operations, neural network functions and/or architectures, or neural network use cases described herein.

In at least one embodiment, one or more neural networks of an inference and/or training logic 315 may be used in conjunction with the system of FIG. 8 and may be configured to receive sensor inputs from multiple sensors and may be trained to infer a coolant requirement. In at least one embodiment, an inference and/or training logic 315 may be able to infer this using information from historical maintenance requirements and of historical sensor inputs. In at least one embodiment, an inference and/or training logic 315 may make an inference of a change in a maintenance requirement. In at least one embodiment, sensor inputs may be correlated to classes of different maintenance requirements of each of different sensor inputs. In at least one embodiment, a new sensor input classifying within a class of such different sensor inputs may indicate a maintenance requirement, or a change thereof.

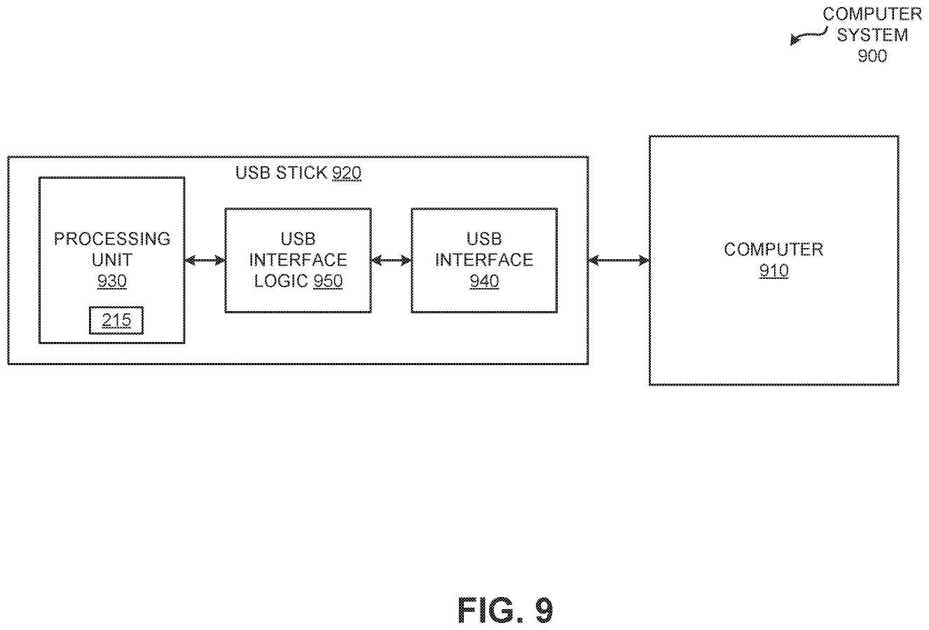

FIG. 9 illustrates a computer system 900, according to at least one embodiment. In at least one embodiment, computer system 900 includes, without limitation, a computer 910 and a USB stick 920. In at least one embodiment, computer 910 may include, without limitation, any number and type of processor(s) (not shown) and a memory (not shown). In at least one embodiment, computer 910 includes, without limitation, a server, a cloud instance, a laptop, and a desktop computer.

In at least one embodiment, USB stick 920 includes, without limitation, a processing unit 930, a USB interface 940, and USB interface logic 950. In at least one embodiment, processing unit 930 may be any instruction execution system, apparatus, or device capable of executing instructions. In at least one embodiment, processing unit 930 may include, without limitation, any number and type of processing cores (not shown). In at least one embodiment, processing unit 930 comprises an application specific integrated circuit (“ASIC”) that is optimized to perform any amount and type of operations associated with machine learning. For instance, in at least one embodiment, processing unit 930 is a tensor processing unit (“TPC”) that is optimized to perform machine learning inference operations. In at least one embodiment, processing unit 930 is a vision processing unit (“VPU”) that is optimized to perform machine vision and machine learning inference operations.

In at least one embodiment, USB interface 940 may be any type of USB connector or USB socket. For instance, in at least one embodiment, USB interface 940 is a USB 3.0 Type-C socket for data and power. In at least one embodiment, USB interface 940 is a USB 3.0 Type-A connector. In at least one embodiment, USB interface logic 950 may include any amount and type of logic that enables processing unit 930 to interface with devices (e.g., computer 910) via USB connector 940.

Inference and/or training logic 315 are used to perform inferencing and/or training operations associated with one or more embodiments. Details regarding inference and/or training logic 315 are provided herein in conjunction with FIGS. 3A and/or 3B. In at least one embodiment, inference and/or training logic 315 may be used in system FIG. 9 for inferencing or predicting operations based, at least in part, on weight parameters calculated using neural network training operations, neural network functions and/or architectures, or neural network use cases described herein.

In at least one embodiment, one or more neural networks of an inference and/or training logic 315 may be used in conjunction with the system of FIG. 9 and may be configured to receive sensor inputs from multiple sensors and may be trained to infer a coolant requirement. In at least one embodiment, an inference and/or training logic 315 may be able to infer this using information from historical maintenance requirements and of historical sensor inputs. In at least one embodiment, an inference and/or training logic 315 may make an inference of a change in a maintenance requirement. In at least one embodiment, sensor inputs may be correlated to classes of different maintenance requirements of each of different sensor inputs. In at least one embodiment, a new sensor input classifying within a class of such different sensor inputs may indicate a maintenance requirement, or a change thereof.

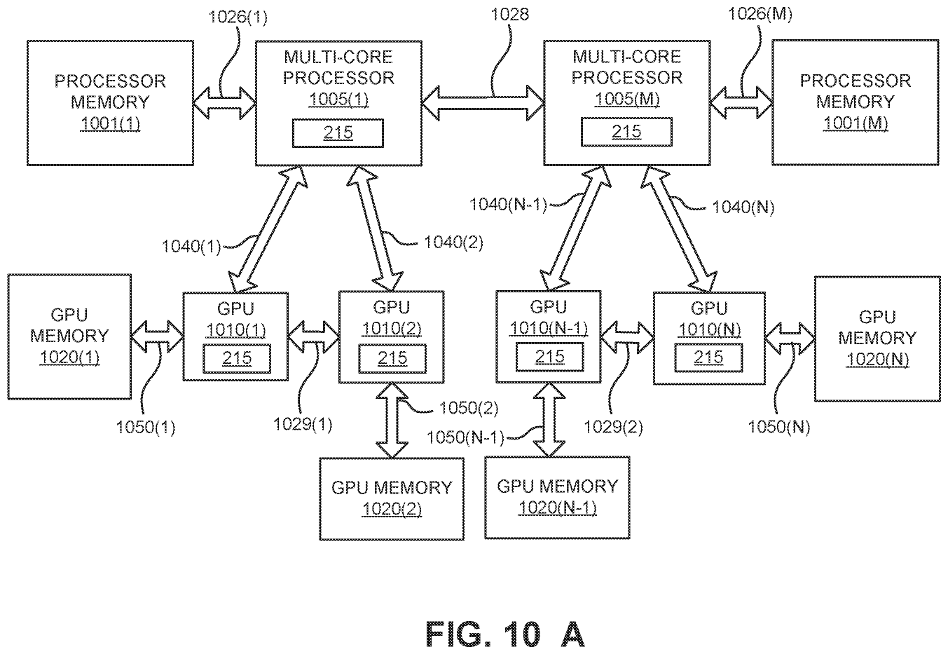

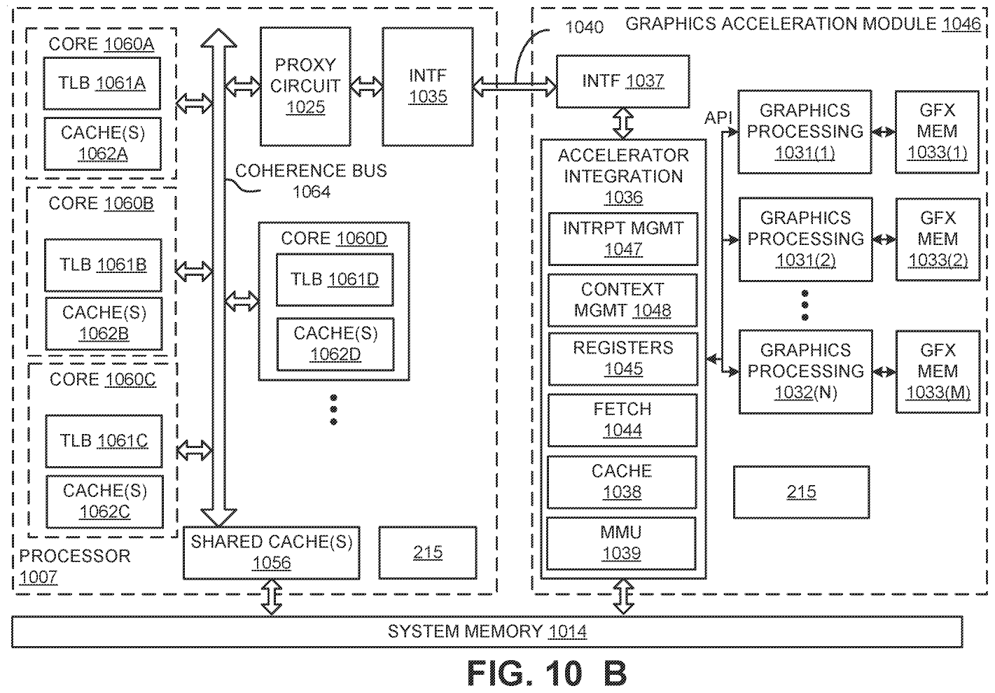

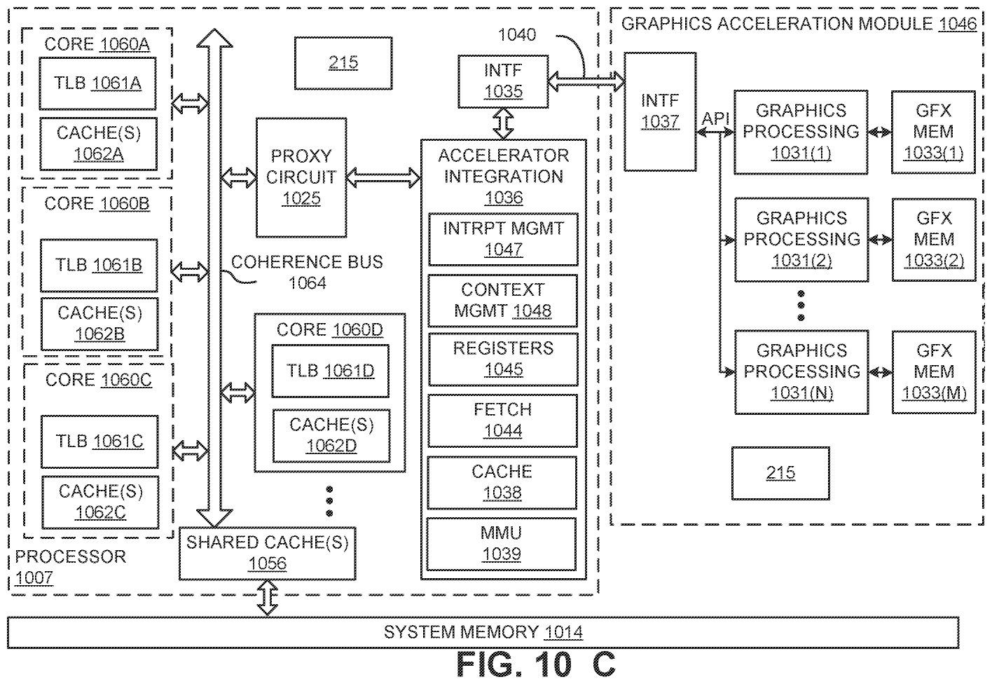

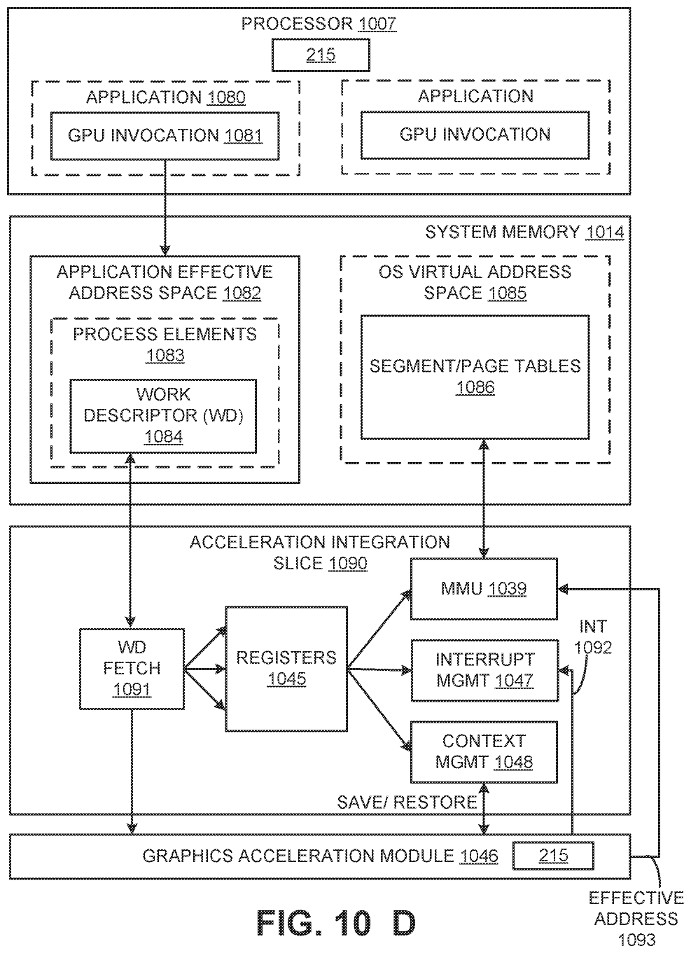

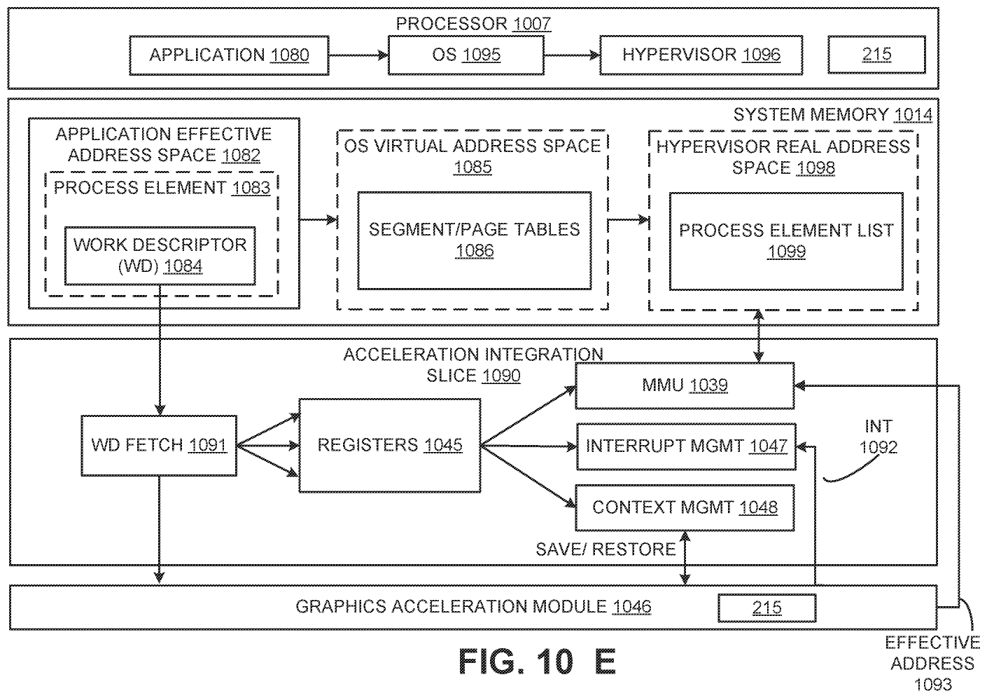

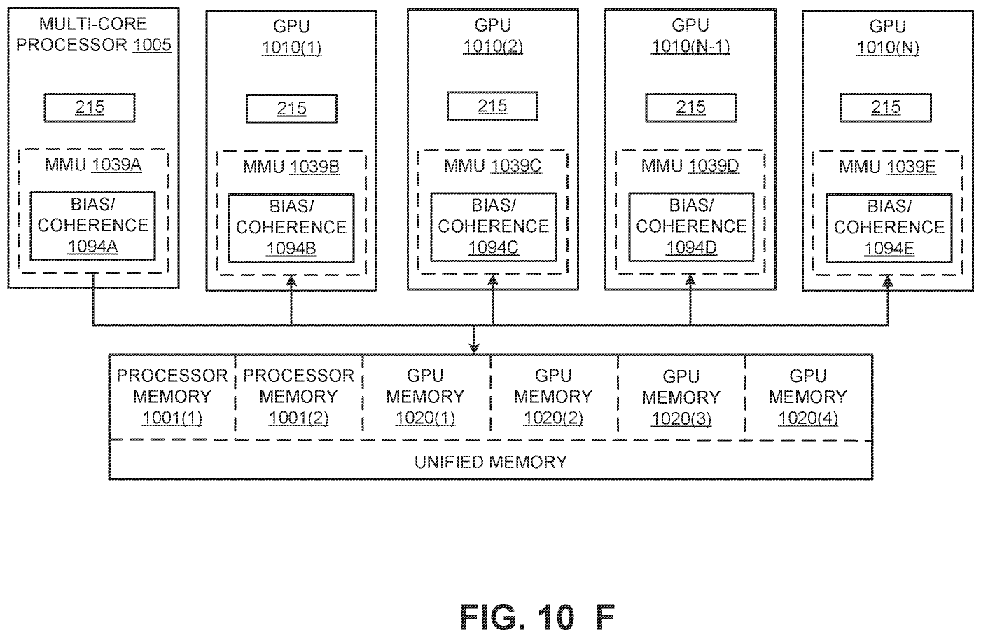

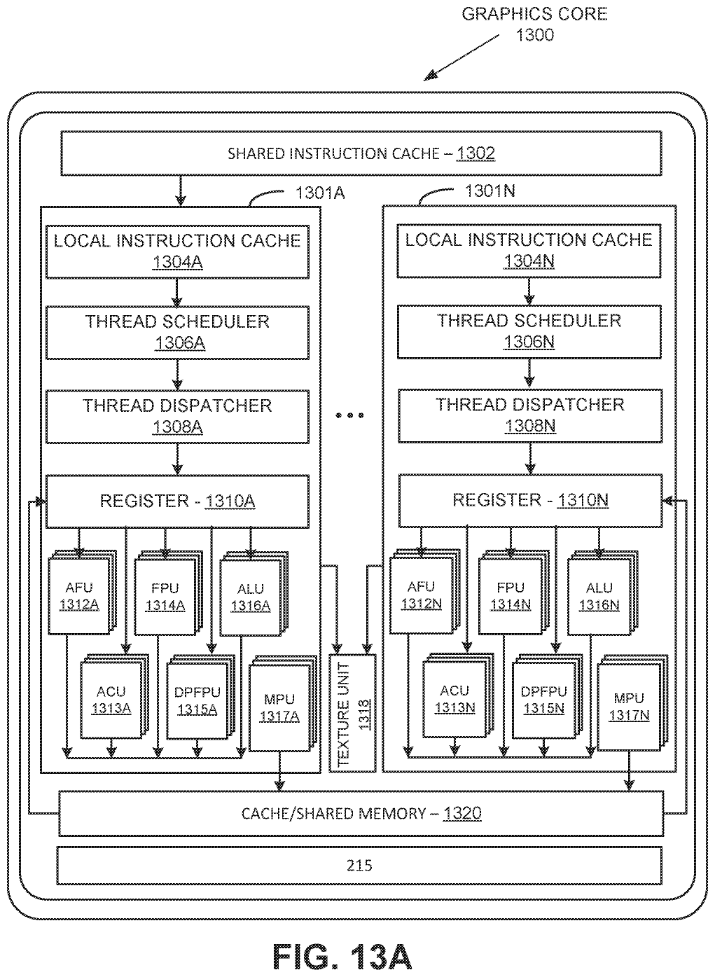

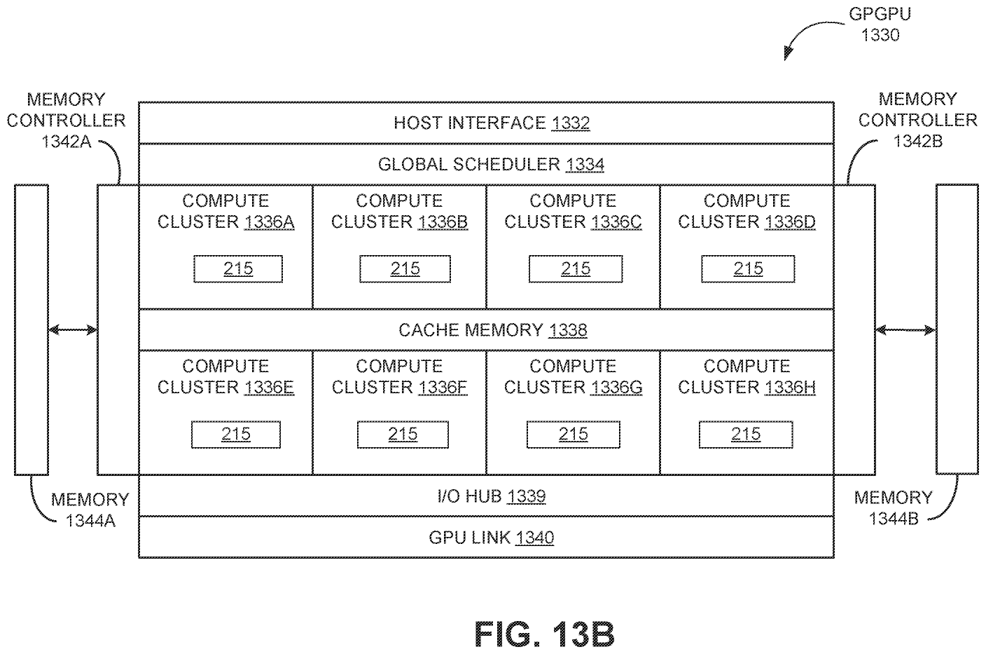

FIG. 10A illustrates an exemplary architecture in which a plurality of GPUs 1010(1)-1010(N) is communicatively coupled to a plurality of multi-core processors 1005(1)-1005(M) over high-speed links 1040(1)-1040(N) (e.g., buses, point-to-point interconnects, etc.). In at least one embodiment, high-speed links 1040(1)-1040(N) support a communication throughput of 4 GB/s, 30 GB/s, 80 GB/s or higher. In at least one embodiment, various interconnect protocols may be used including, but not limited to, PCIe 4.0 or 5.0 and NVLink 2.0. In various figures, “N” and “M” represent positive integers, values of which may be different from figure to figure. In at least one embodiment, one or more GPUs in a plurality of GPUs 1010(1)-1010(N) includes one or more graphics cores (also referred to simply as “cores”) 1300 as disclosed in FIGS. 13A and 13B. In at least one embodiment, one or more graphics cores 1300 may be referred to as streaming multiprocessors (“SMs”), stream processors (“SPs”), stream processing units (“SPUs”), compute units (“CUs”), execution units (“EUs”), and/or slices, where a slice in this context can refer to a portion of processing resources in a processing unit (e.g., 16 cores, a ray tracing unit, a thread director or scheduler).

In addition, and in at least one embodiment, two or more of GPUs 1010 are interconnected over high-speed links 1029(1)-1029(2), which may be implemented using similar or different protocols/links than those used for high-speed links 1040(1)-1040(N). Similarly, two or more of multi-core processors 1005 may be connected over a high-speed link 1028 which may be symmetric multi-processor (SMP) buses operating at 20 GB/s, 30 GB/s, 120 GB/s or higher. Alternatively, all communication between various system components shown in FIG. 10A may be accomplished using similar protocols/links (e.g., over a common interconnection fabric).

In at least one embodiment, each multi-core processor 1005 is communicatively coupled to a processor memory 1001(1)-1001(M), via memory interconnects 1026(1)-1026(M), respectively, and each GPU 1010(1)-1010(N) is communicatively coupled to GPU memory 1020(1)-1020(N) over GPU memory interconnects 1050(1)-1050(N), respectively. In at least one embodiment, memory interconnects 1026 and 1050 may utilize similar or different memory access technologies. By way of example, and not limitation, processor memories 1001(1)-1001(M) and GPU memories 1020 may be volatile memories such as dynamic random access memories (DRAMs) (including stacked DRAMs), Graphics DDR SDRAM (GDDR) (e.g., GDDR5, GDDR6), or High Bandwidth Memory (HBM) and/or may be non-volatile memories such as 3D)(Point or Nano-Ram. In at least one embodiment, some portion of processor memories 1001 may be volatile memory and another portion may be non-volatile memory (e.g., using a two-level memory (2LM) hierarchy).

As described herein, although various multi-core processors 1005 and GPUs 1010 may be physically coupled to a particular memory 1001, 1020, respectively, and/or a unified memory architecture may be implemented in which a virtual system address space (also referred to as “effective address” space) is distributed among various physical memories. For example, processor memories 1001(1)-1001(M) may each comprise 64 GB of system memory address space and GPU memories 1020(1)-1020(N) may each comprise 32 GB of system memory address space resulting in a total of 256 GB addressable memory when M=2 and N=4. Other values for N and M are possible.

FIG. 10B illustrates additional details for an interconnection between a multi-core processor 1007 and a graphics acceleration module 1046 in accordance with one exemplary embodiment. In at least one embodiment, graphics acceleration module 1046 may include one or more GPU chips integrated on a line card which is coupled to processor 1007 via high-speed link 1040 (e.g., a PCIe bus, NVLink, etc.). In at least one embodiment, graphics acceleration module 1046 may alternatively be integrated on a package or chip with processor 1007.

In at least one embodiment, processor 1007 includes a plurality of cores 1060A-1060D (which may be referred to as “execution units”), each with a translation lookaside buffer (“TLB”) 1061A-1061D and one or more caches 1062A-1062D. In at least one embodiment, cores 1060A-1060D may include various other components for executing instructions and processing data that are not illustrated. In at least one embodiment, caches 1062A-1062D may comprise Level 1 (L1) and Level 2 (L2) caches. In addition, one or more shared caches 1056 may be included in caches 1062A-1062D and shared by sets of cores 1060A-1060D. For example, one embodiment of processor 1007 includes 24 cores, each with its own L1 cache, twelve shared L2 caches, and twelve shared L3 caches. In this embodiment, one or more L2 and L3 caches are shared by two adjacent cores. In at least one embodiment, processor 1007 and graphics acceleration module 1046 connect with system memory 1014, which may include processor memories 1001(1)-1001(M) of FIG. 10A.

In at least one embodiment, coherency is maintained for data and instructions stored in various caches 1062A-1062D, 1056 and system memory 1014 via inter-core communication over a coherence bus 1064. In at least one embodiment, for example, each cache may have cache coherency logic/circuitry associated therewith to communicate to over coherence bus 1064 in response to detected reads or writes to particular cache lines. In at least one embodiment, a cache snooping protocol is implemented over coherence bus 1064 to snoop cache accesses.

In at least one embodiment, a proxy circuit 1025 communicatively couples graphics acceleration module 1046 to coherence bus 1064, allowing graphics acceleration module 1046 to participate in a cache coherence protocol as a peer of cores 1060A-1060D. In particular, in at least one embodiment, an interface 1035 provides connectivity to proxy circuit 1025 over high-speed link 1040 and an interface 1037 connects graphics acceleration module 1046 to high-speed link 1040.

In at least one embodiment, an accelerator integration circuit 1036 provides cache management, memory access, context management, and interrupt management services on behalf of a plurality of graphics processing engines 1031(1)-1031(N) of graphics acceleration module 1046. In at least one embodiment, graphics processing engines 1031(1)-1031(N) may each comprise a separate graphics processing unit (GPU). In at least one embodiment, plurality of graphics processing engines 1031(1)-1031(N) of graphics acceleration module 1046 include one or more graphics cores 1300 as discussed in connection with FIGS. 13A and 13B. In at least one embodiment, graphics processing engines 1031(1)-1031(N) alternatively may comprise different types of graphics processing engines within a GPU, such as graphics execution units, media processing engines (e.g., video encoders/decoders), samplers, and blit engines. In at least one embodiment, graphics acceleration module 1046 may be a GPU with a plurality of graphics processing engines 1031(1)-1031(N) or graphics processing engines 1031(1)-1031(N) may be individual GPUs integrated on a common package, line card, or chip.

In at least one embodiment, accelerator integration circuit 1036 includes a memory management unit (MMU) 1039 for performing various memory management functions such as virtual-to-physical memory translations (also referred to as effective-to-real memory translations) and memory access protocols for accessing system memory 1014. In at least one embodiment, MMU 1039 may also include a translation lookaside buffer (TLB) (not shown) for caching virtual/effective to physical/real address translations. In at least one embodiment, a cache 1038 can store commands and data for efficient access by graphics processing engines 1031(1)-1031(N). In at least one embodiment, data stored in cache 1038 and graphics memories 1033(1)-1033(M) is kept coherent with core caches 1062A-1062D, 1056 and system memory 1014, possibly using a fetch unit 1044. As mentioned, this may be accomplished via proxy circuit 1025 on behalf of cache 1038 and memories 1033(1)-1033(M) (e.g., sending updates to cache 1038 related to modifications/accesses of cache lines on processor caches 1062A-1062D, 1056 and receiving updates from cache 1038).

In at least one embodiment, a set of registers 1045 store context data for threads executed by graphics processing engines 1031(1)-1031(N) and a context management circuit 1048 manages thread contexts. For example, context management circuit 1048 may perform save and restore operations to save and restore contexts of various threads during contexts switches (e.g., where a first thread is saved and a second thread is stored so that a second thread can be execute by a graphics processing engine). For example, on a context switch, context management circuit 1048 may store current register values to a designated region in memory (e.g., identified by a context pointer). It may then restore register values when returning to a context. In at least one embodiment, an interrupt management circuit 1047 receives and processes interrupts received from system devices.

In at least one embodiment, virtual/effective addresses from a graphics processing engine 1031 are translated to real/physical addresses in system memory 1014 by MMU 1039. In at least one embodiment, accelerator integration circuit 1036 supports multiple (e.g., 4, 8, 16) graphics accelerator modules 1046 and/or other accelerator devices. In at least one embodiment, graphics accelerator module 1046 may be dedicated to a single application executed on processor 1007 or may be shared between multiple applications. In at least one embodiment, a virtualized graphics execution environment is presented in which resources of graphics processing engines 1031(1)-1031(N) are shared with multiple applications or virtual machines (VMs). In at least one embodiment, resources may be subdivided into “slices” which are allocated to different VMs and/or applications based on processing requirements and priorities associated with VMs and/or applications.

In at least one embodiment, accelerator integration circuit 1036 performs as a bridge to a system for graphics acceleration module 1046 and provides address translation and system memory cache services. In addition, in at least one embodiment, accelerator integration circuit 1036 may provide virtualization facilities for a host processor to manage virtualization of graphics processing engines 1031(1)-1031(N), interrupts, and memory management.

In at least one embodiment, because hardware resources of graphics processing engines 1031(1)-1031(N) are mapped explicitly to a real address space seen by host processor 1007, any host processor can address these resources directly using an effective address value. In at least one embodiment, one function of accelerator integration circuit 1036 is physical separation of graphics processing engines 1031(1)-1031(N) so that they appear to a system as independent units.

In at least one embodiment, one or more graphics memories 1033(1)-1033(M) are coupled to each of graphics processing engines 1031(1)-1031(N), respectively and N=M. In at least one embodiment, graphics memories 1033(1)-1033(M) store instructions and data being processed by each of graphics processing engines 1031(1)-1031(N). In at least one embodiment, graphics memories 1033(1)-1033(M) may be volatile memories such as DRAMs (including stacked DRAMs), GDDR memory (e.g., GDDR5, GDDR6), or HBM, and/or may be non-volatile memories such as 3D)(Point or Nano-Ram.

In at least one embodiment, to reduce data traffic over high-speed link 1040, biasing techniques can be used to ensure that data stored in graphics memories 1033(1)-1033(M) is data that will be used most frequently by graphics processing engines 1031(1)-1031(N) and preferably not used by cores 1060A-1060D (at least not frequently). Similarly, in at least one embodiment, a biasing mechanism attempts to keep data needed by cores (and preferably not graphics processing engines 1031(1)-1031(N)) within caches 1062A-1062D, 1056 and system memory 1014.

FIG. 10C illustrates another exemplary embodiment in which accelerator integration circuit 1036 is integrated within processor 1007. In this embodiment, graphics processing engines 1031(1)-1031(N) communicate directly over high-speed link 1040 to accelerator integration circuit 1036 via interface 1037 and interface 1035 (which, again, may be any form of bus or interface protocol). In at least one embodiment, accelerator integration circuit 1036 may perform similar operations as those described with respect to FIG. 10B, but potentially at a higher throughput given its close proximity to coherence bus 1064 and caches 1062A-1062D, 1056. In at least one embodiment, an accelerator integration circuit supports different programming models including a dedicated-process programming model (no graphics acceleration module virtualization) and shared programming models (with virtualization), which may include programming models which are controlled by accelerator integration circuit 1036 and programming models which are controlled by graphics acceleration module 1046.

In at least one embodiment, graphics processing engines 1031(1)-1031(N) are dedicated to a single application or process under a single operating system. In at least one embodiment, a single application can funnel other application requests to graphics processing engines 1031(1)-1031(N), providing virtualization within a VM/partition.

In at least one embodiment, graphics processing engines 1031(1)-1031(N), may be shared by multiple VM/application partitions. In at least one embodiment, shared models may use a system hypervisor to virtualize graphics processing engines 1031(1)-1031(N) to allow access by each operating system. In at least one embodiment, for single-partition systems without a hypervisor, graphics processing engines 1031(1)-1031(N) are owned by an operating system. In at least one embodiment, an operating system can virtualize graphics processing engines 1031(1)-1031(N) to provide access to each process or application.

In at least one embodiment, graphics acceleration module 1046 or an individual graphics processing engine 1031(1)-1031(N) selects a process element using a process handle. In at least one embodiment, process elements are stored in system memory 1014 and are addressable using an effective address to real address translation technique described herein. In at least one embodiment, a process handle may be an implementation-specific value provided to a host process when registering its context with graphics processing engine 1031(1)-1031(N) (that is, calling system software to add a process element to a process element linked list). In at least one embodiment, a lower 16-bits of a process handle may be an offset of a process element within a process element linked list.

FIG. 10D illustrates an exemplary accelerator integration slice 1090. In at least one embodiment, a “slice” comprises a specified portion of processing resources of accelerator integration circuit 1036. In at least one embodiment, an application is effective address space 1082 within system memory 1014 stores process elements 1083. In at least one embodiment, process elements 1083 are stored in response to GPU invocations 1081 from applications 1080 executed on processor 1007. In at least one embodiment, a process element 1083 contains process state for corresponding application 1080. In at least one embodiment, a work descriptor (WD) 1084 contained in process element 1083 can be a single job requested by an application or may contain a pointer to a queue of jobs. In at least one embodiment, WD 1084 is a pointer to a job request queue in an application's effective address space 1082.

In at least one embodiment, graphics acceleration module 1046 and/or individual graphics processing engines 1031(1)-1031(N) can be shared by all or a subset of processes in a system. In at least one embodiment, an infrastructure for setting up process states and sending a WD 1084 to a graphics acceleration module 1046 to start a job in a virtualized environment may be included.

In at least one embodiment, a dedicated-process programming model is implementation-specific. In at least one embodiment, in this model, a single process owns graphics acceleration module 1046 or an individual graphics processing engine 1031. In at least one embodiment, when graphics acceleration module 1046 is owned by a single process, a hypervisor initializes accelerator integration circuit 1036 for an owning partition and an operating system initializes accelerator integration circuit 1036 for an owning process when graphics acceleration module 1046 is assigned.

In at least one embodiment, in operation, a WD fetch unit 1091 in accelerator integration slice 1090 fetches next WD 1084, which includes an indication of work to be done by one or more graphics processing engines of graphics acceleration module 1046. In at least one embodiment, data from WD 1084 may be stored in registers 1045 and used by MMU 1039, interrupt management circuit 1047 and/or context management circuit 1048 as illustrated. For example, one embodiment of MMU 1039 includes segment/page walk circuitry for accessing segment/page tables 1086 within an OS virtual address space 1085. In at least one embodiment, interrupt management circuit 1047 may process interrupt events 1092 received from graphics acceleration module 1046. In at least one embodiment, when performing graphics operations, an effective address 1093 generated by a graphics processing engine 1031(1)-1031(N) is translated to a real address by MMU 1039.

In at least one embodiment, registers 1045 are duplicated for each graphics processing engine 1031(1)-1031(N) and/or graphics acceleration module 1046 and may be initialized by a hypervisor or an operating system. In at least one embodiment, each of these duplicated registers may be included in an accelerator integration slice 1090. Exemplary registers that may be initialized by a hypervisor are shown in Table 1.

TABLE 1
Hypervisor Initialized Registers

| Register # | Description |
|---|---|
| 1 | Slice Control Register |
| 2 | Real Address (RA) Scheduled Processes Area Pointer |
| 3 | Authority Mask Override Register |
| 4 | Interrupt Vector Table Entry Offset |
| 5 | Interrupt Vector Table Entry Limit |
| 6 | State Register |
| 7 | Logical Partition ID |
| 8 | Real address (RA) Hypervisor Accelerator Utilization |
| | Record Pointer |
| 9 | Storage Description Register |

Exemplary registers that may be initialized by an operating system are shown in Table 2.

TABLE 2
Operating System Initialized Registers

| Register # | Description |
|---|---|
| 1 | Process and Thread Identification |
| 2 | Effective Address (EA) Context Save/Restore Pointer |
| 3 | Virtual Address (VA) Accelerator Utilization Record Pointer |
| 4 | Virtual Address (VA) Storage Segment Table Pointer |
| 5 | Authority Mask |
| 6 | Work descriptor |

In at least one embodiment, each WD 1084 is specific to a particular graphics acceleration module 1046 and/or graphics processing engines 1031(1)-1031(N). In at least one embodiment, it contains all information required by a graphics processing engine 1031(1)-1031(N) to do work, or it can be a pointer to a memory location where an application has set up a command queue of work to be completed.

FIG. 10E illustrates additional details for one exemplary embodiment of a shared model. This embodiment includes a hypervisor real address space 1098 in which a process element list 1099 is stored. In at least one embodiment, hypervisor real address space 1098 is accessible via a hypervisor 1096 which virtualizes graphics acceleration module engines for operating system 1095.

In at least one embodiment, shared programming models allow for all or a subset of processes from all or a subset of partitions in a system to use a graphics acceleration module 1046. In at least one embodiment, there are two programming models where graphics acceleration module 1046 is shared by multiple processes and partitions, namely time-sliced shared and graphics directed shared.

In at least one embodiment, in this model, system hypervisor 1096 owns graphics acceleration module 1046 and makes its function available to all operating systems 1095. In at least one embodiment, for a graphics acceleration module 1046 to support virtualization by system hypervisor 1096, graphics acceleration module 1046 may adhere to certain requirements, such as (1) an application's job request must be autonomous (that is, state does not need to be maintained between jobs), or graphics acceleration module 1046 must provide a context save and restore mechanism, (2) an application's job request is guaranteed by graphics acceleration module 1046 to complete in a specified amount of time, including any translation faults, or graphics acceleration module 1046 provides an ability to preempt processing of a job, and (3) graphics acceleration module 1046 must be guaranteed fairness between processes when operating in a directed shared programming model.

In at least one embodiment, application 1080 is required to make an operating system 1095 system call with a graphics acceleration module type, a work descriptor (WD), an authority mask register (AMR) value, and a context save/restore area pointer (CSRP). In at least one embodiment, graphics acceleration module type describes a targeted acceleration function for a system call. In at least one embodiment, graphics acceleration module type may be a system-specific value. In at least one embodiment, WD is formatted specifically for graphics acceleration module 1046 and can be in a form of a graphics acceleration module 1046 command, an effective address pointer to a user-defined structure, an effective address pointer to a queue of commands, or any other data structure to describe work to be done by graphics acceleration module 1046.

In at least one embodiment, an AMR value is an AMR state to use for a current process. In at least one embodiment, a value passed to an operating system is similar to an application setting an AMR. In at least one embodiment, if accelerator integration circuit 1036 (not shown) and graphics acceleration module 1046 implementations do not support a User Authority Mask Override Register (UAMOR), an operating system may apply a current UAMOR value to an AMR value before passing an AMR in a hypervisor call. In at least one embodiment, hypervisor 1096 may optionally apply a current Authority Mask Override Register (AMOR) value before placing an AMR into process element 1083. In at least one embodiment, CSRP is one of registers 1045 containing an effective address of an area in an application's effective address space 1082 for graphics acceleration module 1046 to save and restore context state. In at least one embodiment, this pointer is optional if no state is required to be saved between jobs or when a job is preempted. In at least one embodiment, context save/restore area may be pinned system memory.

Upon receiving a system call, operating system 1095 may verify that application 1080 has registered and been given authority to use graphics acceleration module 1046. In at least one embodiment, operating system 1095 then calls hypervisor 1096 with information shown in Table 3.

TABLE 3
OS to Hypervisor Call Parameters

| Parameter # | Description |
|---|---|
| 1 | A work descriptor (WD) |
| 2 | An Authority Mask Register (AMR) value |
| | (potentially masked) |
| 3 | An effective address (EA) Context Save/Restore |
| | Area Pointer (CSRP) |
| 4 | A process ID (PID) and optional thread ID (TID) |
| 5 | A virtual address (VA) accelerator utilization |
| | record pointer (AURP) |
| 6 | Virtual address of storage segment table pointer (SSTP) |
| 7 | A logical interrupt service number (LISN) |

In at least one embodiment, upon receiving a hypervisor call, hypervisor 1096 verifies that operating system 1095 has registered and been given authority to use graphics acceleration module 1046. In at least one embodiment, hypervisor 1096 then puts process element 1083 into a process element linked list for a corresponding graphics acceleration module 1046 type. In at least one embodiment, a process element may include information shown in Table 4.

TABLE 4
Process Element Information

| Element # | Description |
|---|---|
| 1 | A work descriptor (WD) |
| 2 | An Authority Mask Register (AMR) value |
| | (potentially masked). |
| 3 | An effective address (EA) Context Save/Restore |
| | Area Pointer (CSRP) |
| 4 | A process ID (PID) and optional thread ID (TID) |
| 5 | A virtual address (VA) accelerator utilization |
| | record pointer (AURP) |
| 6 | Virtual address of storage segment table pointer (SSTP) |
| 7 | A logical interrupt service number (LISN) |
| 8 | Interrupt vector table, derived from hypervisor |
| | call parameters |
| 9 | A state register (SR) value |
| 10 | A logical partition ID (LPID) |
| 11 | A real address (RA) hypervisor accelerator |
| | utilization record pointer |
| 12 | Storage Descriptor Register (SDR) |

In at least one embodiment, hypervisor initializes a plurality of accelerator integration slice 1090 registers 1045.

As illustrated in FIG. 10F, in at least one embodiment, a unified memory is used, addressable via a common virtual memory address space used to access physical processor memories 1001(1)-1001(N) and GPU memories 1020(1)-1020(N). In this implementation, operations executed on GPUs 1010(1)-1010(N) utilize a same virtual/effective memory address space to access processor memories 1001(1)-1001(M) and vice versa, thereby simplifying programmability. In at least one embodiment, a first portion of a virtual/effective address space is allocated to processor memory 1001(1), a second portion to second processor memory 1001(N), a third portion to GPU memory 1020(1), and so on. In at least one embodiment, an entire virtual/effective memory space (sometimes referred to as an effective address space) is thereby distributed across each of processor memories 1001 and GPU memories 1020, allowing any processor or GPU to access any physical memory with a virtual address mapped to that memory.

In at least one embodiment, bias/coherence management circuitry 1094A-1094E within one or more of MMUs 1039A-1039E ensures cache coherence between caches of one or more host processors (e.g., 1005) and GPUs 1010 and implements biasing techniques indicating physical memories in which certain types of data should be stored. In at least one embodiment, while multiple instances of bias/coherence management circuitry 1094A-1094E are illustrated in FIG. 10F, bias/coherence circuitry may be implemented within an MMU of one or more host processors 1005 and/or within accelerator integration circuit 1036.

One embodiment allows GPU memories 1020 to be mapped as part of system memory, and accessed using shared virtual memory (SVM) technology, but without suffering performance drawbacks associated with full system cache coherence. In at least one embodiment, an ability for GPU memories 1020 to be accessed as system memory without onerous cache coherence overhead provides a beneficial operating environment for GPU offload. In at least one embodiment, this arrangement allows software of host processor 1005 to setup operands and access computation results, without overhead of tradition I/O DMA data copies. In at least one embodiment, such traditional copies involve driver calls, interrupts and memory mapped I/O (MMIO) accesses that are all inefficient relative to simple memory accesses. In at least one embodiment, an ability to access GPU memories 1020 without cache coherence overheads can be critical to execution time of an offloaded computation. In at least one embodiment, in cases with substantial streaming write memory traffic, for example, cache coherence overhead can significantly reduce an effective write bandwidth seen by a GPU 1010. In at least one embodiment, efficiency of operand setup, efficiency of results access, and efficiency of GPU computation may play a role in determining effectiveness of a GPU offload.

In at least one embodiment, selection of GPU bias and host processor bias is driven by a bias tracker data structure. In at least one embodiment, a bias table may be used, for example, which may be a page-granular structure (e.g., controlled at a granularity of a memory page) that includes 1 or 2 bits per GPU-attached memory page. In at least one embodiment, a bias table may be implemented in a stolen memory range of one or more GPU memories 1020, with or without a bias cache in a GPU 1010 (e.g., to cache frequently/recently used entries of a bias table). Alternatively, in at least one embodiment, an entire bias table may be maintained within a GPU.

In at least one embodiment, a bias table entry associated with each access to a GPU attached memory 1020 is accessed prior to actual access to a GPU memory, causing following operations. In at least one embodiment, local requests from a GPU 1010 that find their page in GPU bias are forwarded directly to a corresponding GPU memory 1020. In at least one embodiment, local requests from a GPU that find their page in host bias are forwarded to processor 1005 (e.g., over a high-speed link as described herein). In at least one embodiment, requests from processor 1005 that find a requested page in host processor bias complete a request like a normal memory read. Alternatively, requests directed to a GPU-biased page may be forwarded to a GPU 1010. In at least one embodiment, a GPU may then transition a page to a host processor bias if it is not currently using a page. In at least one embodiment, a bias state of a page can be changed either by a software-based mechanism, a hardware-assisted software-based mechanism, or, for a limited set of cases, a purely hardware-based mechanism.

In at least one embodiment, one mechanism for changing bias state employs an API call (e.g., OpenCL), which, in turn, calls a GPU's device driver which, in turn, sends a message (or enqueues a command descriptor) to a GPU directing it to change a bias state and, for some transitions, perform a cache flushing operation in a host. In at least one embodiment, a cache flushing operation is used for a transition from host processor 1005 bias to GPU bias, but is not for an opposite transition.

In at least one embodiment, cache coherency is maintained by temporarily rendering GPU-biased pages uncacheable by host processor 1005. In at least one embodiment, to access these pages, processor 1005 may request access from GPU 1010, which may or may not grant access right away. In at least one embodiment, thus, to reduce communication between processor 1005 and GPU 1010 it is beneficial to ensure that GPU-biased pages are those which are required by a GPU but not host processor 1005 and vice versa.

Hardware structure(s) 315 are used to perform one or more embodiments. Details regarding a hardware structure(s) 315 may be provided herein in conjunction with FIGS. 3A and/or 3B.

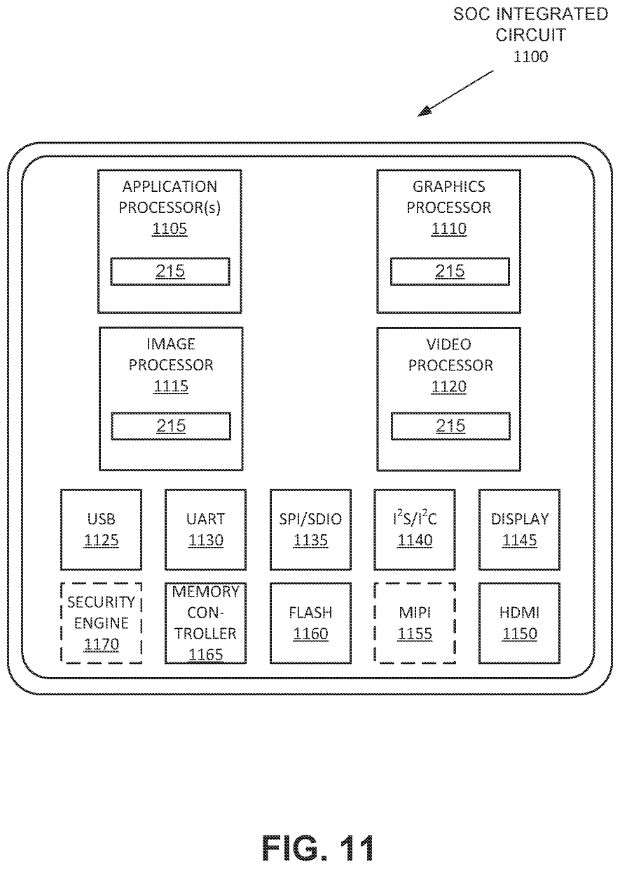

FIG. 11 illustrates exemplary integrated circuits and associated graphics processors that may be fabricated using one or more IP cores, according to various embodiments described herein. In addition to what is illustrated, other logic and circuits may be included in at least one embodiment, including additional graphics processors/cores, peripheral interface controllers, or general-purpose processor cores.

FIG. 11 is a block diagram illustrating an exemplary system on a chip integrated circuit 1100 that may be fabricated using one or more IP cores, according to at least one embodiment. In at least one embodiment, integrated circuit 1100 includes one or more application processor(s) 1105 (e.g., CPUs), at least one graphics processor 1110, and may additionally include an image processor 1115 and/or a video processor 1120, any of which may be a modular IP core. In at least one embodiment, integrated circuit 1100 includes peripheral or bus logic including a USB controller 1125, a UART controller 1130, an SPI/SDIO controller 1135, and an I²2S/I²2C controller 1140. In at least one embodiment, integrated circuit 1100 can include a display device 1145 coupled to one or more of a high-definition multimedia interface (HDMI) controller 1150 and a mobile industry processor interface (MIPI) display interface 1155. In at least one embodiment, storage may be provided by a flash memory subsystem 1160 including flash memory and a flash memory controller. In at least one embodiment, a memory interface may be provided via a memory controller 1165 for access to SDRAM or SRAM memory devices. In at least one embodiment, some integrated circuits additionally include an embedded security engine 1170.

Inference and/or training logic 315 are used to perform inferencing and/or training operations associated with one or more embodiments. Details regarding inference and/or training logic 315 are provided herein in conjunction with FIGS. 3A and/or 3B. In at least one embodiment, inference and/or training logic 315 may be used in integrated circuit 1100 for inferencing or predicting operations based, at least in part, on weight parameters calculated using neural network training operations, neural network functions and/or architectures, or neural network use cases described herein.

In at least one embodiment, one or more neural networks of an inference and/or training logic 315 may be used in conjunction with the system of FIG. 10 and may be configured to receive sensor inputs from multiple sensors and may be trained to infer a coolant requirement. In at least one embodiment, an inference and/or training logic 315 may be able to infer this using information from historical maintenance requirements and of historical sensor inputs. In at least one embodiment, an inference and/or training logic 315 may make an inference of a change in a maintenance requirement. In at least one embodiment, sensor inputs may be correlated to classes of different maintenance requirements of each of different sensor inputs. In at least one embodiment, a new sensor input classifying within a class of such different sensor inputs may indicate a maintenance requirement, or a change thereof.

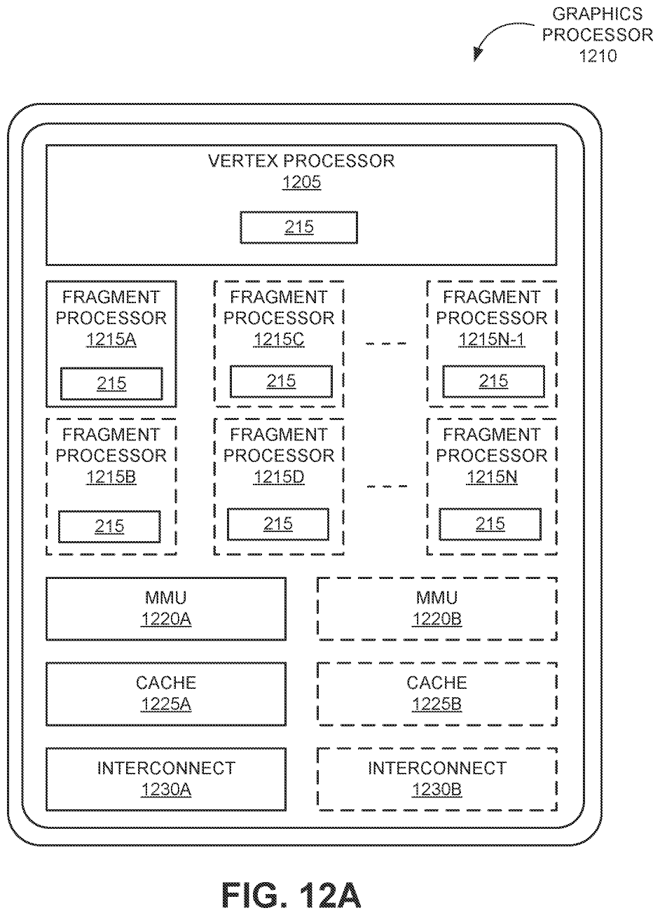

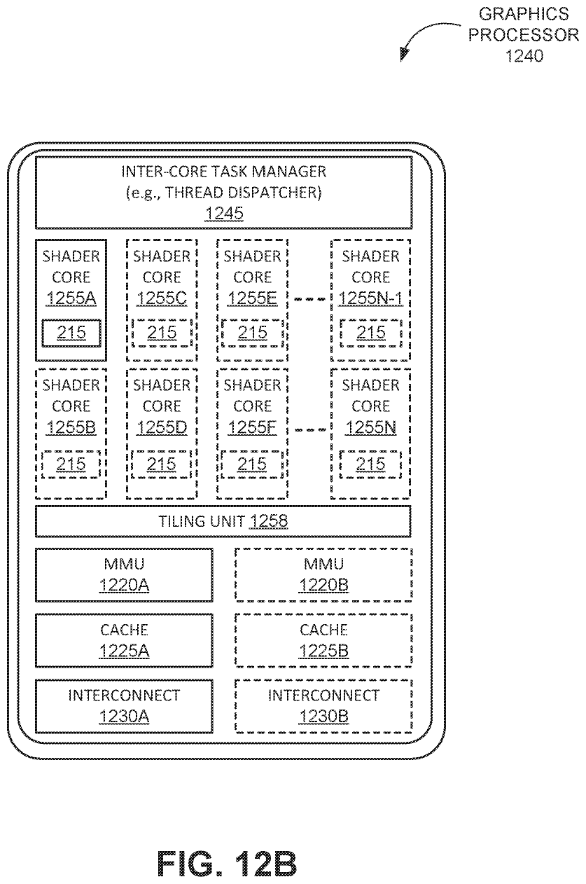

FIGS. 12A-12B illustrate exemplary integrated circuits and associated graphics processors that may be fabricated using one or more IP cores, according to various embodiments described herein. In addition to what is illustrated, other logic and circuits may be included in at least one embodiment, including additional graphics processors/cores, peripheral interface controllers, or general-purpose processor cores.

FIGS. 12A-12B are block diagrams illustrating exemplary graphics processors for use within an SoC, according to embodiments described herein. FIG. 12A illustrates an exemplary graphics processor 1210 of a system on a chip integrated circuit that may be fabricated using one or more IP cores, according to at least one embodiment. FIG. 12B illustrates an additional exemplary graphics processor 1240 of a system on a chip integrated circuit that may be fabricated using one or more IP cores, according to at least one embodiment. In at least one embodiment, graphics processor 1210 of FIG. 12A is a low power graphics processor core. In at least one embodiment, graphics processor 1240 of FIG. 12B is a higher performance graphics processor core. In at least one embodiment, each of graphics processors 1210, 1240 can be variants of graphics processor 1110 of FIG. 11.

In at least one embodiment, graphics processor 1210 includes a vertex processor 1205 and one or more fragment processor(s) 1215A-1215N (e.g., 1215A, 1215B, 1215C, 1215D, through 1215N−1, and 1215N). In at least one embodiment, graphics processor 1210 can execute different shader programs via separate logic, such that vertex processor 1205 is optimized to execute operations for vertex shader programs, while one or more fragment processor(s) 1215A-1215N execute fragment (e.g., pixel) shading operations for fragment or pixel shader programs. In at least one embodiment, vertex processor 1205 performs a vertex processing stage of a 3D graphics pipeline and generates primitives and vertex data. In at least one embodiment, fragment processor(s) 1215A-1215N use primitive and vertex data generated by vertex processor 1205 to produce a framebuffer that is displayed on a display device. In at least one embodiment, fragment processor(s) 1215A-1215N are optimized to execute fragment shader programs as provided for in an OpenGL API, which may be used to perform similar operations as a pixel shader program as provided for in a Direct 3D API.

In at least one embodiment, graphics processor 1210 additionally includes one or more memory management units (MMUs) 1220A-1220B, cache(s) 1225A-1225B, and circuit interconnect(s) 1230A-1230B. In at least one embodiment, one or more MMU(s) 1220A-1220B provide for virtual to physical address mapping for graphics processor 1210, including for vertex processor 1205 and/or fragment processor(s) 1215A-1215N, which may reference vertex or image/texture data stored in memory, in addition to vertex or image/texture data stored in one or more cache(s) 1225A-1225B. In at least one embodiment, one or more MMU(s) 1220A-1220B may be synchronized with other MMUs within a system, including one or more MMUs associated with one or more application processor(s) 1105, image processors 1115, and/or video processors 1120 of FIG. 11, such that each processor 1105-1120 can participate in a shared or unified virtual memory system. In at least one embodiment, one or more circuit interconnect(s) 1230A-1230B enable graphics processor 1210 to interface with other IP cores within SoC, either via an internal bus of SoC or via a direct connection.

In at least one embodiment, graphics processor 1240 includes one or more shader core(s) 1255A-1255N (e.g., 1255A, 1255B, 1255C, 1255D, 1255E, 1255F, through 1255N-1, and 1255N) as shown in FIG. 12B, which provides for a unified shader core architecture in which a single core or type or core can execute all types of programmable shader code, including shader program code to implement vertex shaders, fragment shaders, and/or compute shaders. In at least one embodiment, a number of shader cores can vary. In at least one embodiment, graphics processor 1240 includes an inter-core task manager 1245, which acts as a thread dispatcher to dispatch execution threads to one or more shader cores 1255A-1255N and a tiling unit 1258 to accelerate tiling operations for tile-based rendering, in which rendering operations for a scene are subdivided in image space, for example to exploit local spatial coherence within a scene or to optimize use of internal caches.

Inference and/or training logic 315 are used to perform inferencing and/or training operations associated with one or more embodiments. Details regarding inference and/or training logic 315 are provided herein in conjunction with FIGS. 3A and/or 3B. In at least one embodiment, inference and/or training logic 315 may be used in integrated circuit 12A and/or 12B for inferencing or predicting operations based, at least in part, on weight parameters calculated using neural network training operations, neural network functions and/or architectures, or neural network use cases described herein.

In at least one embodiment, one or more neural networks of an inference and/or training logic 315 may be used in conjunction with the system of FIG. 12 and may be configured to receive sensor inputs from multiple sensors and may be trained to infer a coolant requirement. In at least one embodiment, an inference and/or training logic 315 may be able to infer this using information from historical maintenance requirements and of historical sensor inputs. In at least one embodiment, an inference and/or training logic 315 may make an inference of a change in a maintenance requirement. In at least one embodiment, sensor inputs may be correlated to classes of different maintenance requirements of each of different sensor inputs. In at least one embodiment, a new sensor input classifying within a class of such different sensor inputs may indicate a maintenance requirement, or a change thereof.

FIGS. 13A-13B illustrate additional exemplary graphics processor logic according to embodiments described herein. FIG. 13A illustrates a graphics core 1300 that may be included within graphics processor 1110 of FIG. 11, in at least one embodiment, and may be a unified shader core 1255A-1255N as in FIG. 12B in at least one embodiment. FIG. 13B illustrates a highly-parallel general-purpose graphics processing unit (“GPGPU”) 1330 suitable for deployment on a multi-chip module in at least one embodiment.

In at least one embodiment, graphics core 1300 includes a shared instruction cache 1302, a texture unit 1318, and a cache/shared memory 1320 (e.g., including L1, L2, L3, last level cache, or other caches) that are common to execution resources within graphics core 1300. In at least one embodiment, graphics core 1300 can include multiple slices 1301A-1301N or a partition for each core, and a graphics processor can include multiple instances of graphics core 1300. In at least one embodiment, each slice 1301A-1301N refers to graphics core 1300. In at least one embodiment, slices 1301A-1301N have sub-slices, which are part of a slice 1301A-1301N. In at least one embodiment, slices 1301A-1301N are independent of other slices or dependent on other slices. In at least one embodiment, slices 1301A-1301N can include support logic including a local instruction cache 1304A-1304N, a thread scheduler (sequencer) 1306A-1306N, a thread dispatcher 1308A-1308N, and a set of registers 1310A-1310N. In at least one embodiment, slices 1301A-1301N can include a set of additional function units (AFUs 1312A-1312N), floating-point units (FPUs 1314A-1314N), integer arithmetic logic units (ALUs 1316A-1316N), address computational units (ACUs 1313A-1313N), double-precision floating-point units (DPFPUs 1315A-1315N), and matrix processing units (MPUs 1317A-1317N).

In at least one embodiment, each slice 1301A-1301N includes one or more engines for floating point and integer vector operations and one or more engines to accelerate convolution and matrix operations in AI, machine learning, or large dataset workloads. In at least one embodiment, one or more slices 1301A-1301N include one or more vector engines to compute a vector (e.g., compute mathematical operations for vectors). In at least one embodiment, a vector engine can compute a vector operation in 16-bit floating point (also referred to as “FP16”), 32-bit floating point (also referred to as “FP32”), or 64-bit floating point (also referred to as “FP64”). In at least one embodiment, one or more slices 1301A-1301N includes 16 vector engines that are paired with 16 matrix math units to compute matrix/tensor operations, where vector engines and math units are exposed via matrix extensions. In at least one embodiment, a slice a specified portion of processing resources of a processing unit, e.g., 16 cores and a ray tracing unit or 8 cores, a thread scheduler, a thread dispatcher, and additional functional units for a processor. In at least one embodiment, graphics core 1300 includes one or more matrix engines to compute matrix operations, e.g., when computing tensor operations.

In at least one embodiment, one or more slices 1301A-1301N includes one or more ray tracing units to compute ray tracing operations (e.g., 16 ray tracing units per slice slices 1301A-1301N). In at least one embodiment, a ray tracing unit computes ray traversal, triangle intersection, bounding box intersect, or other ray tracing operations.

In at least one embodiment, one or more slices 1301A-1301N includes a media slice that encodes, decodes, and/or transcodes data; scales and/or format converts data; and/or performs video quality operations on video data.

In at least one embodiment, one or more slices 1301A-1301N are linked to L2 cache and memory fabric, link connectors, high-bandwidth memory (HBM) (e.g., HBM2e, HDM3) stacks, and a media engine. In at least one embodiment, one or more slices 1301A-1301N include multiple cores (e.g., 16 cores) and multiple ray tracing units (e.g., 16) paired to each core. In at least one embodiment, one or more slices 1301A-1301N has one or more L1 caches. In at least one embodiment, one or more slices 1301A-1301N include one or more vector engines; one or more instruction caches to store instructions; one or more L1 caches to cache data; one or more shared local memories (SLMs) to store data, e.g., corresponding to instructions; one or more samplers to sample data; one or more ray tracing units to perform ray tracing operations; one or more geometries to perform operations in geometry pipelines and/or apply geometric transformations to vertices or polygons; one or more rasterizers to describe an image in vector graphics format (e.g., shape) and convert it into a raster image (e.g., a series of pixels, dots, or lines, which when displayed together, create an image that is represented by shapes); one or more a Hierarchical Depth Buffer (Hiz) to buffer data; and/or one or more pixel backends. In at least one embodiment, a slice 1301A-1301N includes a memory fabric, e.g., an L2 cache.

In at least one embodiment, FPUs 1314A-1314N can perform single-precision (32-bit) and half-precision (16-bit) floating point operations, while DPFPUs 1315A-1315N perform double precision (64-bit) floating point operations. In at least one embodiment, ALUs 1316A-1316N can perform variable precision integer operations at 8-bit, 16-bit, and 32-bit precision, and can be configured for mixed precision operations. In at least one embodiment, MPUs 1317A-1317N can also be configured for mixed precision matrix operations, including half-precision floating point and 8-bit integer operations. In at least one embodiment, MPUs 1317-1317N can perform a variety of matrix operations to accelerate machine learning application frameworks, including enabling support for accelerated general matrix to matrix multiplication (GEMM). In at least one embodiment, AFUs 1312A-1312N can perform additional logic operations not supported by floating-point or integer units, including trigonometric operations (e.g., sine, cosiInference and/or training logic 315 are used to perform inferencing and/or training operations associated with one or more embodiments. Details regarding inference and/or training logic 315 are provided herein in conjunction with FIGS. 3A and/or 3B. In at least one embodiment, inference and/or training logic 315 may be used in graphics core 1300 for inferencing or predicting operations based, at least in part, on weight parameters calculated using neural network training operations, neural network functions and/or architectures, or neural network use cases described herein.

In at least one embodiment, graphics core 1300 includes an interconnect and a link fabric sublayer that is attached to a switch and a GPU-GPU bridge that enables multiple graphics processors 1300 (e.g., 8) to be interlinked without glue to each other with load/store units (LSUs), data transfer units, and sync semantics across multiple graphics processors 1300. In at least one embodiment, interconnects include standardized interconnects (e.g., PCIe) or some combination thereof.

In at least one embodiment, graphics core 1300 includes multiple tiles. In at least one embodiment, a tile is an individual die or one or more dies, where individual dies can be connected with an interconnect (e.g., embedded multi-die interconnect bridge (EMIB)). In at least one embodiment, graphics core 1300 includes a compute tile, a memory tile (e.g., where a memory tile can be exclusively accessed by different tiles or different chipsets such as a Rambo tile), substrate tile, a base tile, a HMB tile, a link tile, and EMIB tile, where all tiles are packaged together in graphics core 1300 as part of a GPU. In at least one embodiment, graphics core 1300 can include multiple tiles in a single package (also referred to as a “multi tile package”). In at least one embodiment, a compute tile can have 8 graphics cores 1300, an L1 cache; and a base tile can have a host interface with PCIe 5.0, HBM2e, MDFI, and EMIB, a link tile with 8 links, 8 ports with an embedded switch. In at least one embodiment, tiles are connected with face-to-face (F2F) chip-on-chip bonding through fine-pitched, 36-micron, microbumps (e.g., copper pillars). In at least one embodiment, graphics core 1300 includes memory fabric, which includes memory, and is tile that is accessible by multiple tiles. In at least one embodiment, graphics core 1300 stores, accesses, or loads its own hardware contexts in memory, where a hardware context is a set of data loaded from registers before a process resumes, and where a hardware context can indicate a state of hardware (e.g., state of a GPU).

In at least one embodiment, graphics core 1300 includes serializer/deserializer (SERDES) circuitry that converts a serial data stream to a parallel data stream, or converts a parallel data stream to a serial data stream.

In at least one embodiment, graphics core 1300 includes a high speed coherent unified fabric (GPU to GPU), load/store units, bulk data transfer and sync semantics, and connected GPUs through an embedded switch, where a GPU-GPU bridge is controlled by a controller.

In at least one embodiment, graphics core 1300 performs an API, where said API abstracts hardware of graphics core 1300 and access libraries with instructions to perform math operations (e.g., math kernel library), deep neural network operations (e.g., deep neural network library), vector operations, collective communications, thread building blocks, video processing, data analytics library, and/or ray tracing operations.

In at least one embodiment, one or more neural networks of an inference and/or training logic 315 may be used in conjunction with the system of FIG. 12 and may be configured to receive sensor inputs from multiple sensors and may be trained to infer a coolant requirement. In at least one embodiment, an inference and/or training logic 315 may be able to infer this using information from historical maintenance requirements and of historical sensor inputs. In at least one embodiment, an inference and/or training logic 315 may make an inference of a change in a maintenance requirement. In at least one embodiment, sensor inputs may be correlated to classes of different maintenance requirements of each of different sensor inputs. In at least one embodiment, a new sensor input classifying within a class of such different sensor inputs may indicate a maintenance requirement, or a change thereof.

FIG. 13B illustrates a general-purpose processing unit (GPGPU) 1330 that can be configured to enable highly-parallel compute operations to be performed by an array of graphics processing units, in at least one embodiment. In at least one embodiment, GPGPU 1330 can be linked directly to other instances of GPGPU 1330 to create a multi-GPU cluster to improve training speed for deep neural networks. In at least one embodiment, GPGPU 1330 includes a host interface 1332 to enable a connection with a host processor. In at least one embodiment, host interface 1332 is a PCI Express interface. In at least one embodiment, host interface 1332 can be a vendor-specific communications interface or communications fabric. In at least one embodiment, GPGPU 1330 receives commands from a host processor and uses a global scheduler 1334 (which may be referred to as a thread sequencer and/or asynchronous compute engine) to distribute execution threads associated with those commands to a set of compute clusters 1336A-1336H. In at least one embodiment, compute clusters 1336A-1336H share a cache memory 1338. In at least one embodiment, cache memory 1338 can serve as a higher-level cache for cache memories within compute clusters 1336A-1336H.

In at least one embodiment, GPGPU 1330 includes memory 1344A-1344B coupled with compute clusters 1336A-1336H via a set of memory controllers 1342A-1342B (e.g., one or more controllers for HBM2e). In at least one embodiment, memory 1344A-1344B can include various types of memory devices including dynamic random access memory (DRAM) or graphics random access memory, such as synchronous graphics random access memory (SGRAM), including graphics double data rate (GDDR) memory.

In at least one embodiment, compute clusters 1336A-1336H each include a set of graphics cores, such as graphics core 1300 of FIG. 13A, which can include multiple types of integer and floating point logic units that can perform computational operations at a range of precisions including suited for machine learning computations. For example, in at least one embodiment, at least a subset of floating point units in each of compute clusters 1336A-1336H can be configured to perform 16-bit or 32-bit floating point operations, while a different subset of floating point units can be configured to perform 64-bit floating point operations.

In at least one embodiment, multiple instances of GPGPU 1330 can be configured to operate as a compute cluster. In at least one embodiment, communication used by compute clusters 1336A-1336H for synchronization and data exchange varies across embodiments. In at least one embodiment, multiple instances of GPGPU 1330 communicate over host interface 1332. In at least one embodiment, GPGPU 1330 includes an I/O hub 1339 that couples GPGPU 1330 with a GPU link 1340 that enables a direct connection to other instances of GPGPU 1330. In at least one embodiment, GPU link 1340 is coupled to a dedicated GPU-to-GPU bridge that enables communication and synchronization between multiple instances of GPGPU 1330. In at least one embodiment, GPU link 1340 couples with a high-speed interconnect to transmit and receive data to other GPGPUs or parallel processors. In at least one embodiment, multiple instances of GPGPU 1330 are located in separate data processing systems and communicate via a network device that is accessible via host interface 1332. In at least one embodiment GPU link 1340 can be configured to enable a connection to a host processor in addition to or as an alternative to host interface 1332.

In at least one embodiment, GPGPU 1330 can be configured to train neural networks. In at least one embodiment, GPGPU 1330 can be used within an inferencing platform. In at least one embodiment, in which GPGPU 1330 is used for inferencing, GPGPU 1330 may include fewer compute clusters 1336A-1336H relative to when GPGPU 1330 is used for training a neural network. In at least one embodiment, memory technology associated with memory 1344A-1344B may differ between inferencing and training configurations, with higher bandwidth memory technologies devoted to training configurations. In at least one embodiment, an inferencing configuration of GPGPU 1330 can support inferencing specific instructions. For example, in at least one embodiment, an inferencing configuration can provide support for one or more 8-bit integer dot product instructions, which may be used during inferencing operations for deployed neural networks.

Inference and/or training logic 315 are used to perform inferencing and/or training operations associated with one or more embodiments. Details regarding inference and/or training logic 315 are provided herein in conjunction with FIGS. 3A and/or 3B. In at least one embodiment, inference and/or training logic 315 may be used in GPGPU 1330 for inferencing or predicting operations based, at least in part, on weight parameters calculated using neural network training operations, neural network functions and/or architectures, or neural network use cases described herein.

In at least one embodiment, one or more neural networks of an inference and/or training logic 315 may be used in conjunction with the system of FIG. 13 and may be configured to receive sensor inputs from multiple sensors and may be trained to infer a coolant requirement. In at least one embodiment, an inference and/or training logic 315 may be able to infer this using information from historical maintenance requirements and of historical sensor inputs. In at least one embodiment, an inference and/or training logic 315 may make an inference of a change in a maintenance requirement. In at least one embodiment, sensor inputs may be correlated to classes of different maintenance requirements of each of different sensor inputs. In at least one embodiment, a new sensor input classifying within a class of such different sensor inputs may indicate a maintenance requirement, or a change thereof.

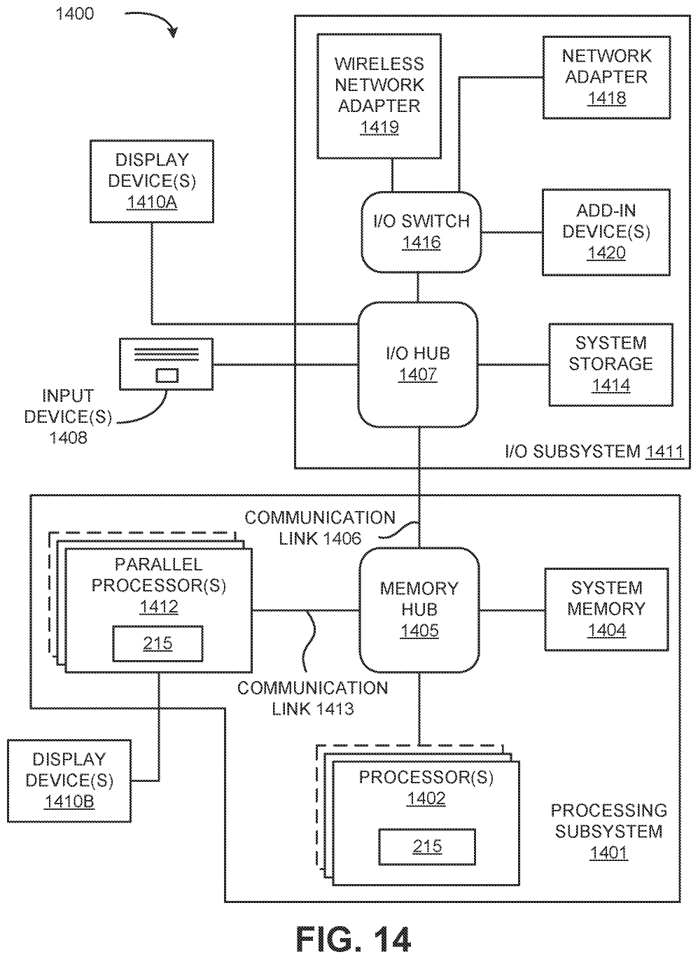

FIG. 14 is a block diagram illustrating a computing system 1400 according to at least one embodiment. In at least one embodiment, computing system 1400 includes a processing subsystem 1401 having one or more processor(s) 1402 and a system memory 1404 communicating via an interconnection path that may include a memory hub 1405. In at least one embodiment, memory hub 1405 may be a separate component within a chipset component or may be integrated within one or more processor(s) 1402. In at least one embodiment, memory hub 1405 couples with an I/O subsystem 1411 via a communication link 1406. In at least one embodiment, I/O subsystem 1411 includes an I/O hub 1407 that can enable computing system 1400 to receive input from one or more input device(s) 1408. In at least one embodiment, I/O hub 1407 can enable a display controller, which may be included in one or more processor(s) 1402, to provide outputs to one or more display device(s) 1410A. In at least one embodiment, one or more display device(s) 1410A coupled with I/O hub 1407 can include a local, internal, or embedded display device.

In at least one embodiment, processing subsystem 1401 includes one or more parallel processor(s) 1412 coupled to memory hub 1405 via a bus or other communication link 1413. In at least one embodiment, communication link 1413 may use one of any number of standards based communication link technologies or protocols, such as, but not limited to PCI Express, or may be a vendor-specific communications interface or communications fabric. In at least one embodiment, one or more parallel processor(s) 1412 form a computationally focused parallel or vector processing system that can include a large number of processing cores and/or processing clusters, such as a many-integrated core (MIC) processor. In at least one embodiment, some or all of parallel processor(s) 1412 form a graphics processing subsystem that can output pixels to one of one or more display device(s) 1410A coupled via I/O Hub 1407. In at least one embodiment, parallel processor(s) 1412 can also include a display controller and display interface (not shown) to enable a direct connection to one or more display device(s) 1410B. In at least one embodiment, parallel processor(s) 1412 include one or more cores, such as graphics cores 1300 discussed herein.

In at least one embodiment, a system storage unit 1414 can connect to I/O hub 1407 to provide a storage mechanism for computing system 1400. In at least one embodiment, an I/O switch 1416 can be used to provide an interface mechanism to enable connections between I/O hub 1407 and other components, such as a network adapter 1418 and/or a wireless network adapter 1419 that may be integrated into platform, and various other devices that can be added via one or more add-in device(s) 1420. In at least one embodiment, network adapter 1418 can be an Ethernet adapter or another wired network adapter. In at least one embodiment, wireless network adapter 1419 can include one or more of a Wi-Fi, Bluetooth, near field communication (NFC), or other network device that includes one or more wireless radios.

In at least one embodiment, computing system 1400 can include other components not explicitly shown, including USB or other port connections, optical storage drives, video capture devices, and like, may also be connected to I/O hub 1407. In at least one embodiment, communication paths interconnecting various components in FIG. 14 may be implemented using any suitable protocols, such as PCI (Peripheral Component Interconnect) based protocols (e.g., PCI-Express), or other bus or point-to-point communication interfaces and/or protocol(s), such as NV-Link high-speed interconnect, or interconnect protocols.

In at least one embodiment, parallel processor(s) 1412 incorporate circuitry optimized for graphics and video processing, including, for example, video output circuitry, and constitutes a graphics processing unit (GPU), e.g., parallel processor(s) 1412 includes graphics core 1300. In at least one embodiment, parallel processor(s) 1412 incorporate circuitry optimized for general purpose processing. In at least embodiment, components of computing system 1400 may be integrated with one or more other system elements on a single integrated circuit. For example, in at least one embodiment, parallel processor(s) 1412, memory hub 1405, processor(s) 1402, and I/O hub 1407 can be integrated into a system on chip (SoC) integrated circuit. In at least one embodiment, components of computing system 1400 can be integrated into a single package to form a system in package (SIP) configuration. In at least one embodiment, at least a portion of components of computing system 1400 can be integrated into a multi-chip module (MCM), which can be interconnected with other multi-chip modules into a modular computing system.

Inference and/or training logic 315 are used to perform inferencing and/or training operations associated with one or more embodiments. Details regarding inference and/or training logic 315 are provided herein in conjunction with FIGS. 3A and/or 3B. In at least one embodiment, inference and/or training logic 315 may be used in system FIG. 1400 for inferencing or predicting operations based, at least in part, on weight parameters calculated using neural network training operations, neural network functions and/or architectures, or neural network use cases described herein.

In at least one embodiment, one or more neural networks of an inference and/or training logic 315 may be used in conjunction with the system of FIG. 14 and may be configured to receive sensor inputs from multiple sensors and may be trained to infer a coolant requirement. In at least one embodiment, an inference and/or training logic 315 may be able to infer this using information from historical maintenance requirements and of historical sensor inputs. In at least one embodiment, an inference and/or training logic 315 may make an inference of a change in a maintenance requirement. In at least one embodiment, sensor inputs may be correlated to classes of different maintenance requirements of each of different sensor inputs. In at least one embodiment, a new sensor input classifying within a class of such different sensor inputs may indicate a maintenance requirement, or a change thereof.

### Processors

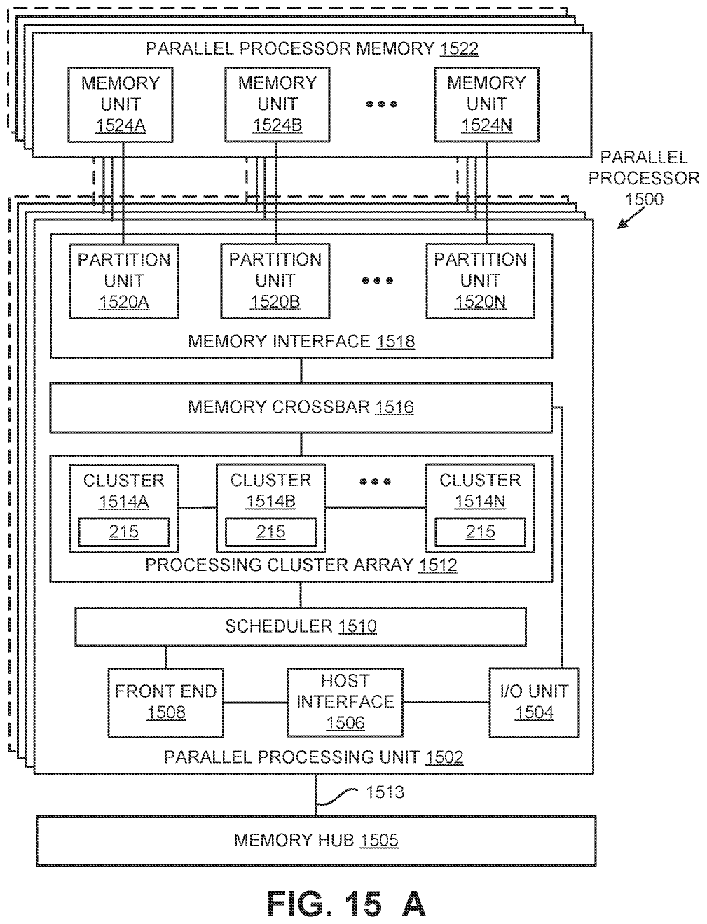

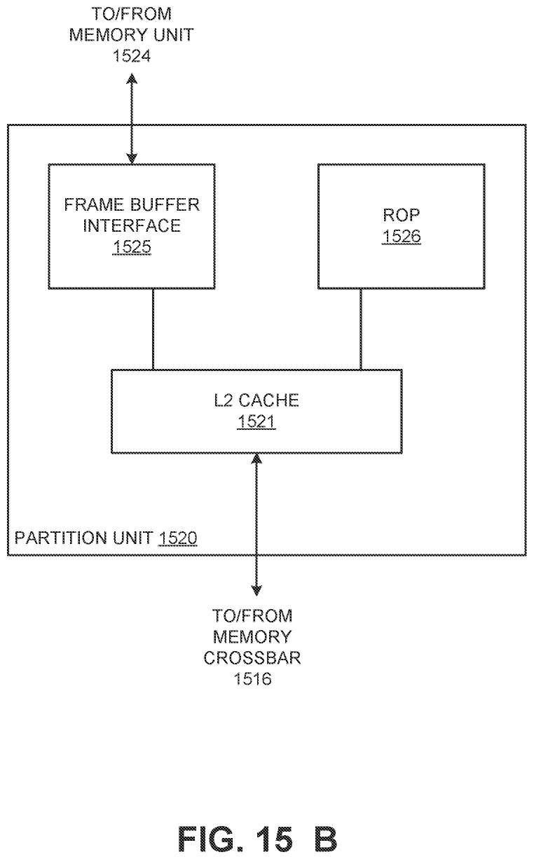

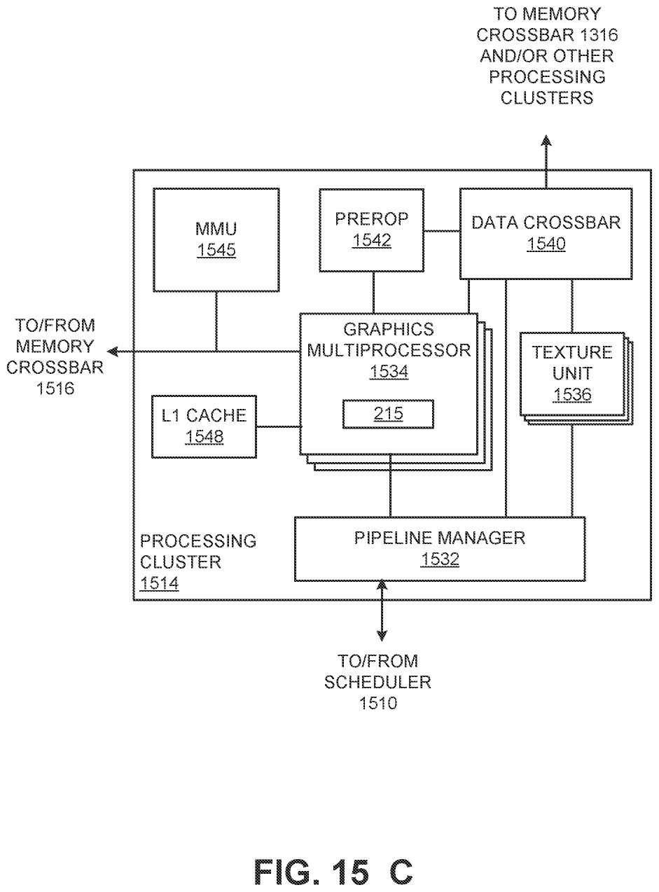

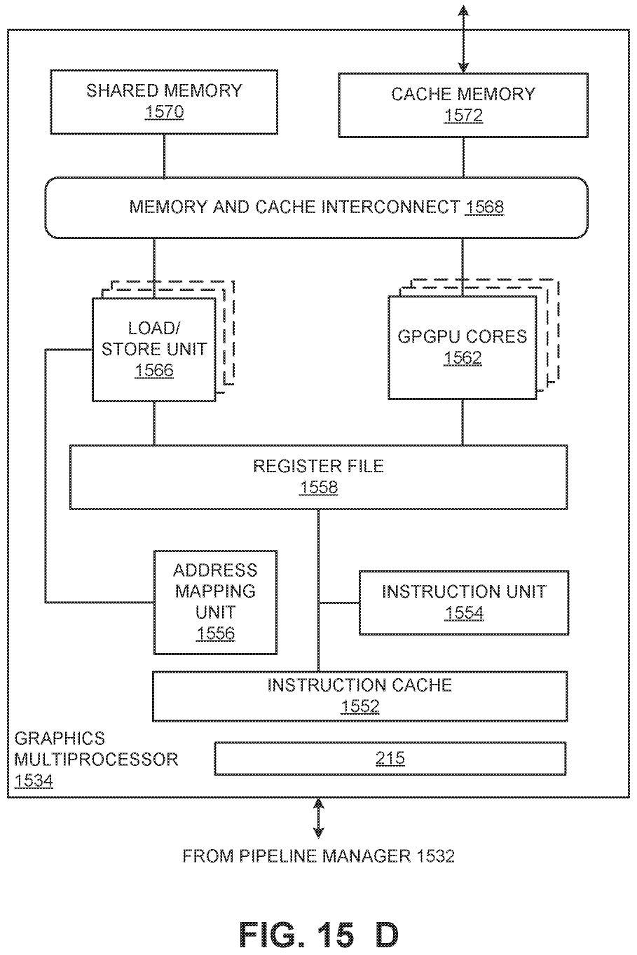

FIG. 15A illustrates a parallel processor 1500 according to at least one embodiment. In at least one embodiment, various components of parallel processor 1500 may be implemented using one or more integrated circuit devices, such as programmable processors, application specific integrated circuits (ASICs), or field programmable gate arrays (FPGA). In at least one embodiment, illustrated parallel processor 1500 is a variant of one or more parallel processor(s) 1412 shown in FIG. 14 according to an exemplary embodiment. In at least one embodiment, a parallel processor 1500 includes one or more graphics cores 1300.

In at least one embodiment, parallel processor 1500 includes a parallel processing unit 1502. In at least one embodiment, parallel processing unit 1502 includes an I/O unit 1504 that enables communication with other devices, including other instances of parallel processing unit 1502. In at least one embodiment, I/O unit 1504 may be directly connected to other devices. In at least one embodiment, I/O unit 1504 connects with other devices via use of a hub or switch interface, such as a memory hub 1505. In at least one embodiment, connections between memory hub 1505 and I/O unit 1504 form a communication link 1513. In at least one embodiment, I/O unit 1504 connects with a host interface 1506 and a memory crossbar 1516, where host interface 1506 receives commands directed to performing processing operations and memory crossbar 1516 receives commands directed to performing memory operations.

In at least one embodiment, when host interface 1506 receives a command buffer via I/O unit 1504, host interface 1506 can direct work operations to perform those commands to a front end 1508. In at least one embodiment, front end 1508 couples with a scheduler 1510 (which may be referred to as a sequencer), which is configured to distribute commands or other work items to a processing cluster array 1512. In at least one embodiment, scheduler 1510 ensures that processing cluster array 1512 is properly configured and in a valid state before tasks are distributed to a cluster of processing cluster array 1512. In at least one embodiment, scheduler 1510 is implemented via firmware logic executing on a microcontroller. In at least one embodiment, microcontroller implemented scheduler 1510 is configurable to perform complex scheduling and work distribution operations at coarse and fine granularity, enabling rapid preemption and context switching of threads executing on processing array 1512. In at least one embodiment, host software can prove workloads for scheduling on processing cluster array 1512 via one of multiple graphics processing paths. In at least one embodiment, workloads can then be automatically distributed across processing array cluster 1512 by scheduler 1510 logic within a microcontroller including scheduler 1510.

In at least one embodiment, processing cluster array 1512 can include up to “N” processing clusters (e.g., cluster 1514A, cluster 1514B, through cluster 1514N), where “N” represents a positive integer (which may be a different integer “N” than used in other figures). In at least one embodiment, each cluster 1514A-1514N of processing cluster array 1512 can execute a large number of concurrent threads. In at least one embodiment, scheduler 1510 can allocate work to clusters 1514A-1514N of processing cluster array 1512 using various scheduling and/or work distribution algorithms, which may vary depending on workload arising for each type of program or computation. In at least one embodiment, scheduling can be handled dynamically by scheduler 1510, or can be assisted in part by compiler logic during compilation of program logic configured for execution by processing cluster array 1512. In at least one embodiment, different clusters 1514A-1514N of processing cluster array 1512 can be allocated for processing different types of programs or for performing different types of computations.

In at least one embodiment, processing cluster array 1512 can be configured to perform various types of parallel processing operations. In at least one embodiment, processing cluster array 1512 is configured to perform general-purpose parallel compute operations. For example, in at least one embodiment, processing cluster array 1512 can include logic to execute processing tasks including filtering of video and/or audio data, performing modeling operations, including physics operations, and performing data transformations.

In at least one embodiment, processing cluster array 1512 is configured to perform parallel graphics processing operations. In at least one embodiment, processing cluster array 1512 can include additional logic to support execution of such graphics processing operations, including but not limited to, texture sampling logic to perform texture operations, as well as tessellation logic and other vertex processing logic. In at least one embodiment, processing cluster array 1512 can be configured to execute graphics processing related shader programs such as, but not limited to, vertex shaders, tessellation shaders, geometry shaders, and pixel shaders. In at least one embodiment, parallel processing unit 1502 can transfer data from system memory via I/O unit 1504 for processing. In at least one embodiment, during processing, transferred data can be stored to on-chip memory (e.g., parallel processor memory 1522) during processing, then written back to system memory.

In at least one embodiment, when parallel processing unit 1502 is used to perform graphics processing, scheduler 1510 can be configured to divide a processing workload into approximately equal sized tasks, to better enable distribution of graphics processing operations to multiple clusters 1514A-1514N of processing cluster array 1512. In at least one embodiment, portions of processing cluster array 1512 can be configured to perform different types of processing. For example, in at least one embodiment, a first portion may be configured to perform vertex shading and topology generation, a second portion may be configured to perform tessellation and geometry shading, and a third portion may be configured to perform pixel shading or other screen space operations, to produce a rendered image for display. In at least one embodiment, intermediate data produced by one or more of clusters 1514A-1514N may be stored in buffers to allow intermediate data to be transmitted between clusters 1514A-1514N for further processing.

In at least one embodiment, processing cluster array 1512 can receive processing tasks to be executed via scheduler 1510, which receives commands defining processing tasks from front end 1508. In at least one embodiment, processing tasks can include indices of data to be processed, e.g., surface (patch) data, primitive data, vertex data, and/or pixel data, as well as state parameters and commands defining how data is to be processed (e.g., what program is to be executed). In at least one embodiment, scheduler 1510 may be configured to fetch indices corresponding to tasks or may receive indices from front end 1508. In at least one embodiment, front end 1508 can be configured to ensure processing cluster array 1512 is configured to a valid state before a workload specified by incoming command buffers (e.g., batch-buffers, push buffers, etc.) is initiated.

In at least one embodiment, each of one or more instances of parallel processing unit 1502 can couple with a parallel processor memory 1522. In at least one embodiment, parallel processor memory 1522 can be accessed via memory crossbar 1516, which can receive memory requests from processing cluster array 1512 as well as I/O unit 1504. In at least one embodiment, memory crossbar 1516 can access parallel processor memory 1522 via a memory interface 1518. In at least one embodiment, memory interface 1518 can include multiple partition units (e.g., partition unit 1520A, partition unit 1520B, through partition unit 1520N) that can each couple to a portion (e.g., memory unit) of parallel processor memory 1522. In at least one embodiment, a number of partition units 1520A-1520N is configured to be equal to a number of memory units, such that a first partition unit 1520A has a corresponding first memory unit 1524A, a second partition unit 1520B has a corresponding memory unit 1524B, and an N-th partition unit 1520N has a corresponding N-th memory unit 1524N. In at least one embodiment, a number of partition units 1520A-1520N may not be equal to a number of memory units.

In at least one embodiment, memory units 1524A-1524N can include various types of memory devices, including dynamic random access memory (DRAM) or graphics random access memory, such as synchronous graphics random access memory (SGRAM), including graphics double data rate (GDDR) memory. In at least one embodiment, memory units 1524A-1524N may also include 3D stacked memory, including but not limited to high bandwidth memory (HBM), HBM2e, or HDM3. In at least one embodiment, render targets, such as frame buffers or texture maps may be stored across memory units 1524A-1524N, allowing partition units 1520A-1520N to write portions of each render target in parallel to efficiently use available bandwidth of parallel processor memory 1522. In at least one embodiment, a local instance of parallel processor memory 1522 may be excluded in favor of a unified memory design that utilizes system memory in conjunction with local cache memory.

In at least one embodiment, any one of clusters 1514A-1514N of processing cluster array 1512 can process data that will be written to any of memory units 1524A-1524N within parallel processor memory 1522. In at least one embodiment, memory crossbar 1516 can be configured to transfer an output of each cluster 1514A-1514N to any partition unit 1520A-1520N or to another cluster 1514A-1514N, which can perform additional processing operations on an output. In at least one embodiment, each cluster 1514A-1514N can communicate with memory interface 1518 through memory crossbar 1516 to read from or write to various external memory devices. In at least one embodiment, memory crossbar 1516 has a connection to memory interface 1518 to communicate with I/O unit 1504, as well as a connection to a local instance of parallel processor memory 1522, enabling processing units within different processing clusters 1514A-1514N to communicate with system memory or other memory that is not local to parallel processing unit 1502. In at least one embodiment, memory crossbar 1516 can use virtual channels to separate traffic streams between clusters 1514A-1514N and partition units 1520A-1520N.

In at least one embodiment, multiple instances of parallel processing unit 1502 can be provided on a single add-in card, or multiple add-in cards can be interconnected. In at least one embodiment, different instances of parallel processing unit 1502 can be configured to interoperate even if different instances have different numbers of processing cores, different amounts of local parallel processor memory, and/or other configuration differences. For example, in at least one embodiment, some instances of parallel processing unit 1502 can include higher precision floating point units relative to other instances. In at least one embodiment, systems incorporating one or more instances of parallel processing unit 1502 or parallel processor 1500 can be implemented in a variety of configurations and form factors, including but not limited to desktop, laptop, or handheld personal computers, servers, workstations, game consoles, and/or embedded systems.

FIG. 15B is a block diagram of a partition unit 1520 according to at least one embodiment. In at least one embodiment, partition unit 1520 is an instance of one of partition units 1520A-1520N of FIG. 15A. In at least one embodiment, partition unit 1520 includes an L2 cache 1521, a frame buffer interface 1525, and a ROP 1526 (raster operations unit). In at least one embodiment, L2 cache 1521 is a read/write cache that is configured to perform load and store operations received from memory crossbar 1516 and ROP 1526. In at least one embodiment, read misses and urgent write-back requests are output by L2 cache 1521 to frame buffer interface 1525 for processing. In at least one embodiment, updates can also be sent to a frame buffer via frame buffer interface 1525 for processing. In at least one embodiment, frame buffer interface 1525 interfaces with one of memory units in parallel processor memory, such as memory units 1524A-1524N of FIG. 15 (e.g., within parallel processor memory 1522).

In at least one embodiment, ROP 1526 is a processing unit that performs raster operations such as stencil, z test, blending, etc. In at least one embodiment, ROP 1526 then outputs processed graphics data that is stored in graphics memory. In at least one embodiment, ROP 1526 includes compression logic to compress depth or color data that is written to memory and decompress depth or color data that is read from memory. In at least one embodiment, compression logic can be lossless compression logic that makes use of one or more of multiple compression algorithms. In at least one embodiment, a type of compression that is performed by ROP 1526 can vary based on statistical characteristics of data to be compressed. For example, in at least one embodiment, delta color compression is performed on depth and color data on a per-tile basis.

In at least one embodiment, ROP 1526 is included within each processing cluster (e.g., cluster 1514A-1514N of FIG. 15A) instead of within partition unit 1520. In at least one embodiment, read and write requests for pixel data are transmitted over memory crossbar 1516 instead of pixel fragment data. In at least one embodiment, processed graphics data may be displayed on a display device, such as one of one or more display device(s) 1410 of FIG. 14, routed for further processing by processor(s) 1402, or routed for further processing by one of processing entities within parallel processor 1500 of FIG. 15A.

FIG. 15C is a block diagram of a processing cluster 1514 within a parallel processing unit according to at least one embodiment. In at least one embodiment, a processing cluster is an instance of one of processing clusters 1514A-1514N of FIG. 15A. In at least one embodiment, processing cluster 1514 can be configured to execute many threads in parallel, where “thread” refers to an instance of a particular program executing on a particular set of input data. In at least one embodiment, single-instruction, multiple-data (SIMD) instruction issue techniques are used to support parallel execution of a large number of threads without providing multiple independent instruction units. In at least one embodiment, single-instruction, multiple-thread (SIMT) techniques are used to support parallel execution of a large number of generally synchronized threads, using a common instruction unit configured to issue instructions to a set of processing engines within each one of processing clusters.

In at least one embodiment, operation of processing cluster 1514 can be controlled via a pipeline manager 1532 that distributes processing tasks to SIMT parallel processors. In at least one embodiment, pipeline manager 1532 receives instructions from scheduler 1510 of FIG. 15A and manages execution of those instructions via a graphics multiprocessor 1534 and/or a texture unit 1536. In at least one embodiment, graphics multiprocessor 1534 is an exemplary instance of a SIMT parallel processor. However, in at least one embodiment, various types of SIMT parallel processors of differing architectures may be included within processing cluster 1514. In at least one embodiment, one or more instances of graphics multiprocessor 1534 can be included within a processing cluster 1514. In at least one embodiment, graphics multiprocessor 1534 can process data and a data crossbar 1540 can be used to distribute processed data to one of multiple possible destinations, including other shader units. In at least one embodiment, pipeline manager 1532 can facilitate distribution of processed data by specifying destinations for processed data to be distributed via data crossbar 1540.

In at least one embodiment, each graphics multiprocessor 1534 within processing cluster 1514 can include an identical set of functional execution logic (e.g., arithmetic logic units, load-store units, etc.). In at least one embodiment, functional execution logic can be configured in a pipelined manner in which new instructions can be issued before previous instructions are complete. In at least one embodiment, functional execution logic supports a variety of operations including integer and floating point arithmetic, comparison operations, Boolean operations, bit-shifting, and computation of various algebraic functions. In at least one embodiment, same functional-unit hardware can be leveraged to perform different operations and any combination of functional units may be present.

In at least one embodiment, instructions transmitted to processing cluster 1514 constitute a thread. In at least one embodiment, a set of threads executing across a set of parallel processing engines is a thread group. In at least one embodiment, a thread group executes a common program on different input data. In at least one embodiment, each thread within a thread group can be assigned to a different processing engine within a graphics multiprocessor 1534. In at least one embodiment, a thread group may include fewer threads than a number of processing engines within graphics multiprocessor 1534. In at least one embodiment, when a thread group includes fewer threads than a number of processing engines, one or more of processing engines may be idle during cycles in which that thread group is being processed. In at least one embodiment, a thread group may also include more threads than a number of processing engines within graphics multiprocessor 1534. In at least one embodiment, when a thread group includes more threads than number of processing engines within graphics multiprocessor 1534, processing can be performed over consecutive clock cycles. In at least one embodiment, multiple thread groups can be executed concurrently on a graphics multiprocessor 1534.

In at least one embodiment, graphics multiprocessor 1534 includes an internal cache memory to perform load and store operations. In at least one embodiment, graphics multiprocessor 1534 can forego an internal cache and use a cache memory (e.g., L1 cache 1548) within processing cluster 1514. In at least one embodiment, each graphics multiprocessor 1534 also has access to L2 caches within partition units (e.g., partition units 1520A-1520N of FIG. that are shared among all processing clusters 1514 and may be used to transfer data between threads. In at least one embodiment, graphics multiprocessor 1534 may also access off-chip global memory, which can include one or more of local parallel processor memory and/or system memory. In at least one embodiment, any memory external to parallel processing unit 1502 may be used as global memory. In at least one embodiment, processing cluster 1514 includes multiple instances of graphics multiprocessor 1534 and can share common instructions and data, which may be stored in L1 cache 1548.

In at least one embodiment, each processing cluster 1514 may include an MMU 1545 (memory management unit) that is configured to map virtual addresses into physical addresses. In at least one embodiment, one or more instances of MMU 1545 may reside within memory interface 1518 of FIG. 15A. In at least one embodiment, MMU 1545 includes a set of page table entries (PTEs) used to map a virtual address to a physical address of a tile and optionally a cache line index. In at least one embodiment, MMU 1545 may include address translation lookaside buffers (TLB) or caches that may reside within graphics multiprocessor 1534 or L1 1548 cache or processing cluster 1514. In at least one embodiment, a physical address is processed to distribute surface data access locally to allow for efficient request interleaving among partition units. In at least one embodiment, a cache line index may be used to determine whether a request for a cache line is a hit or miss.

In at least one embodiment, a processing cluster 1514 may be configured such that each graphics multiprocessor 1534 is coupled to a texture unit 1536 for performing texture mapping operations, e.g., determining texture sample positions, reading texture data, and filtering texture data. In at least one embodiment, texture data is read from an internal texture L1 cache (not shown) or from an L1 cache within graphics multiprocessor 1534 and is fetched from an L2 cache, local parallel processor memory, or system memory, as needed. In at least one embodiment, each graphics multiprocessor 1534 outputs processed tasks to data crossbar 1540 to provide processed task to another processing cluster 1514 for further processing or to store processed task in an L2 cache, local parallel processor memory, or system memory via memory crossbar 1516. In at least one embodiment, a preROP 1542 (pre-raster operations unit) is configured to receive data from graphics multiprocessor 1534, and direct data to ROP units, which may be located with partition units as described herein (e.g., partition units 1520A-1520N of FIG. 15A). In at least one embodiment, preROP 1542 unit can perform optimizations for color blending, organizing pixel color data, and performing address translations.

Inference and/or training logic 315 are used to perform inferencing and/or training operations associated with one or more embodiments. Details regarding inference and/or training logic 315 are provided herein in conjunction with FIGS. 3A and/or 3B. In at least one embodiment, inference and/or training logic 315 may be used in graphics processing cluster 1514 for inferencing or predicting operations based, at least in part, on weight parameters calculated using neural network training operations, neural network functions and/or architectures, or neural network use cases described herein.

In at least one embodiment, one or more neural networks of an inference and/or training logic 315 may be used in conjunction with the system of FIG. 15C and may be configured to receive sensor inputs from multiple sensors and may be trained to infer a coolant requirement. In at least one embodiment, an inference and/or training logic 315 may be able to infer this using information from historical maintenance requirements and of historical sensor inputs. In at least one embodiment, an inference and/or training logic 315 may make an inference of a change in a maintenance requirement. In at least one embodiment, sensor inputs may be correlated to classes of different maintenance requirements of each of different sensor inputs. In at least one embodiment, a new sensor input classifying within a class of such different sensor inputs may indicate a maintenance requirement, or a change thereof.

FIG. 15D shows a graphics multiprocessor 1534 according to at least one embodiment. In at least one embodiment, graphics multiprocessor 1534 couples with pipeline manager 1532 of processing cluster 1514. In at least one embodiment, graphics multiprocessor 1534 has an execution pipeline including but not limited to an instruction cache 1552, an instruction unit 1554, an address mapping unit 1556, a register file 1558, one or more general purpose graphics processing unit (GPGPU) cores 1562, and one or more load/store units 1566, where one or more load/store units 1566 can perform load/store operations to load/store instructions corresponding to performing an operation. In at least one embodiment, GPGPU cores 1562 and load/store units 1566 are coupled with cache memory 1572 and shared memory 1570 via a memory and cache interconnect 1568.

In at least one embodiment, instruction cache 1552 receives a stream of instructions to execute from pipeline manager 1532. In at least one embodiment, instructions are cached in instruction cache 1552 and dispatched for execution by an instruction unit 1554. In at least one embodiment, instruction unit 1554 can dispatch instructions as thread groups (e.g., warps, wavefronts, waves), with each thread of thread group assigned to a different execution unit within GPGPU cores 1562. In at least one embodiment, an instruction can access any of a local, shared, or global address space by specifying an address within a unified address space. In at least one embodiment, address mapping unit 1556 can be used to translate addresses in a unified address space into a distinct memory address that can be accessed by load/store units 1566.

In at least one embodiment, register file 1558 provides a set of registers for functional units of graphics multiprocessor 1534. In at least one embodiment, register file 1558 provides temporary storage for operands connected to data paths of functional units (e.g., GPGPU cores 1562, load/store units 1566) of graphics multiprocessor 1534. In at least one embodiment, register file 1558 is divided between each of functional units such that each functional unit is allocated a dedicated portion of register file 1558. In at least one embodiment, register file 1558 is divided between different warps (which may be referred to as wavefronts and/or waves) being executed by graphics multiprocessor 1534.

In at least one embodiment, GPGPU cores 1562 can each include floating point units (FPUs) and/or integer arithmetic logic units (ALUs) that are used to execute instructions of graphics multiprocessor 1534. In at least one embodiment, GPGPU cores 1562 can be similar in architecture or can differ in architecture. In at least one embodiment, a first portion of GPGPU cores 1562 include a single precision FPU and an integer ALU while a second portion of GPGPU cores include a double precision FPU. In at least one embodiment, FPUs can implement IEEE 754-2008 standard floating point arithmetic or enable variable precision floating point arithmetic. In at least one embodiment, graphics multiprocessor 1534 can additionally include one or more fixed function or special function units to perform specific functions such as copy rectangle or pixel blending operations. In at least one embodiment, one or more of GPGPU cores 1562 can also include fixed or special function logic.

In at least one embodiment, GPGPU cores 1562 include SIMD logic capable of performing a single instruction on multiple sets of data. In at least one embodiment, GPGPU cores 1562 can physically execute SIMD4, SIMD8, and SIMD16 instructions and logically execute SIMD1, SIMD2, and SIMD32 instructions. In at least one embodiment, SIMD instructions for GPGPU cores can be generated at compile time by a shader compiler or automatically generated when executing programs written and compiled for single program multiple data (SPMD) or SIMT architectures. In at least one embodiment, multiple threads of a program configured for an SIMT execution model can executed via a single SIMD instruction. For example, in at least one embodiment, eight SIMT threads that perform same or similar operations can be executed in parallel via a single SIMD8 logic unit.

In at least one embodiment, memory and cache interconnect 1568 is an interconnect network that connects each functional unit of graphics multiprocessor 1534 to register file 1558 and to shared memory 1570. In at least one embodiment, memory and cache interconnect 1568 is a crossbar interconnect that allows load/store unit 1566 to implement load and store operations between shared memory 1570 and register file 1558. In at least one embodiment, register file 1558 can operate at a same frequency as GPGPU cores 1562, thus data transfer between GPGPU cores 1562 and register file 1558 can have very low latency. In at least one embodiment, shared memory 1570 can be used to enable communication between threads that execute on functional units within graphics multiprocessor 1534. In at least one embodiment, cache memory 1572 can be used as a data cache for example, to cache texture data communicated between functional units and texture unit 1536. In at least one embodiment, shared memory 1570 can also be used as a program managed cache. In at least one embodiment, threads executing on GPGPU cores 1562 can programmatically store data within shared memory in addition to automatically cached data that is stored within cache memory 1572.

In at least one embodiment, a parallel processor or GPGPU as described herein is communicatively coupled to host/processor cores to accelerate graphics operations, machine-learning operations, pattern analysis operations, and various general purpose GPU (GPGPU) functions. In at least one embodiment, a GPU may be communicatively coupled to host processor/cores over a bus or other interconnect (e.g., a high-speed interconnect such as PCIe or NVLink). In at least one embodiment, a GPU may be integrated on a package or chip as cores and communicatively coupled to cores over an internal processor bus/interconnect internal to a package or chip. In at least one embodiment, regardless a manner in which a GPU is connected, processor cores may allocate work to such GPU in a form of sequences of commands/instructions contained in a work descriptor. In at least one embodiment, that GPU then uses dedicated circuitry/logic for efficiently processing these commands/instructions.

Inference and/or training logic 315 are used to perform inferencing and/or training operations associated with one or more embodiments. Details regarding inference and/or training logic 315 are provided herein in conjunction with FIGS. 3A and/or 3B. In at least one embodiment, inference and/or training logic 315 may be used in graphics multiprocessor 1534 for inferencing or predicting operations based, at least in part, on weight parameters calculated using neural network training operations, neural network functions and/or architectures, or neural network use cases described herein.

In at least one embodiment, one or more neural networks of an inference and/or training logic 315 may be used in conjunction with the system of FIG. 15A and may be configured to receive sensor inputs from multiple sensors and may be trained to infer a coolant requirement. In at least one embodiment, an inference and/or training logic 315 may be able to infer this using information from historical maintenance requirements and of historical sensor inputs. In at least one embodiment, an inference and/or training logic 315 may make an inference of a change in a maintenance requirement. In at least one embodiment, sensor inputs may be correlated to classes of different maintenance requirements of each of different sensor inputs. In at least one embodiment, a new sensor input classifying within a class of such different sensor inputs may indicate a maintenance requirement, or a change thereof.

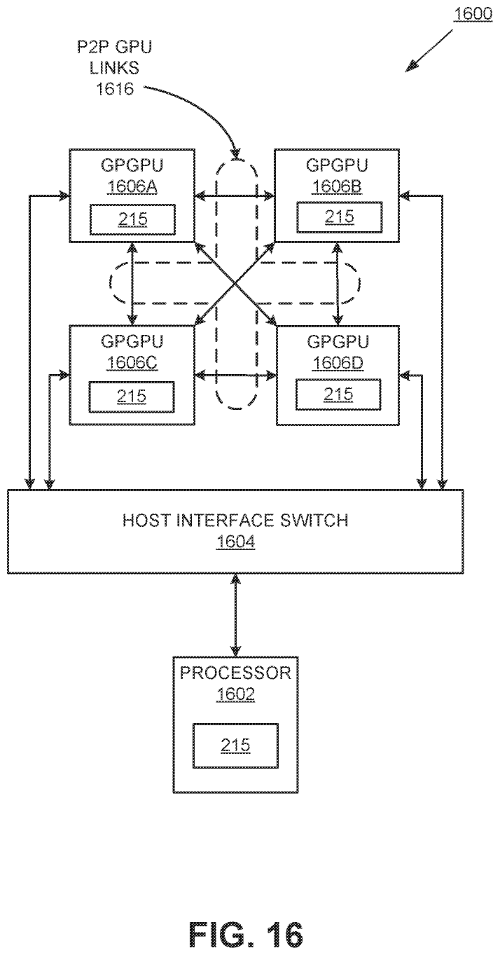

FIG. 16 illustrates a multi-GPU computing system 1600, according to at least one embodiment. In at least one embodiment, multi-GPU computing system 1600 can include a processor 1602 coupled to multiple general purpose graphics processing units (GPGPUs) 1606A-D via a host interface switch 1604. In at least one embodiment, host interface switch 1604 is a PCI express switch device that couples processor 1602 to a PCI express bus over which processor 1602 can communicate with GPGPUs 1606A-D. In at least one embodiment, GPGPUs 1606A-D can interconnect via a set of high-speed point-to-point GPU-to-GPU links 1616. In at least one embodiment, GPU-to-GPU links 1616 connect to each of GPGPUs 1606A-D via a dedicated GPU link. In at least one embodiment, P2P GPU links 1616 enable direct communication between each of GPGPUs 1606A-D without requiring communication over host interface bus 1604 to which processor 1602 is connected. In at least one embodiment, with GPU-to-GPU traffic directed to P2P GPU links 1616, host interface bus 1604 remains available for system memory access or to communicate with other instances of multi-GPU computing system 1600, for example, via one or more network devices. While in at least one embodiment GPGPUs 1606A-D connect to processor 1602 via host interface switch 1604, in at least one embodiment processor 1602 includes direct support for P2P GPU links 1616 and can connect directly to GPGPUs 1606A-D.

Inference and/or training logic 315 are used to perform inferencing and/or training operations associated with one or more embodiments. Details regarding inference and/or training logic 315 are provided herein in conjunction with FIGS. 3A and/or 3B. In at least one embodiment, inference and/or training logic 315 may be used in multi-GPU computing system 1600 for inferencing or predicting operations based, at least in part, on weight parameters calculated using neural network training operations, neural network functions and/or architectures, or neural network use cases described herein.

In at least one embodiment, multi-GPU computing system 1600 includes one or more graphics cores 1300.

In at least one embodiment, one or more neural networks of an inference and/or training logic 315 may be used in conjunction with the system of FIG. 16 and may be configured to receive sensor inputs from multiple sensors and may be trained to infer a coolant requirement. In at least one embodiment, an inference and/or training logic 315 may be able to infer this using information from historical maintenance requirements and of historical sensor inputs. In at least one embodiment, an inference and/or training logic 315 may make an inference of a change in a maintenance requirement. In at least one embodiment, sensor inputs may be correlated to classes of different maintenance requirements of each of different sensor inputs. In at least one embodiment, a new sensor input classifying within a class of such different sensor inputs may indicate a maintenance requirement, or a change thereof.

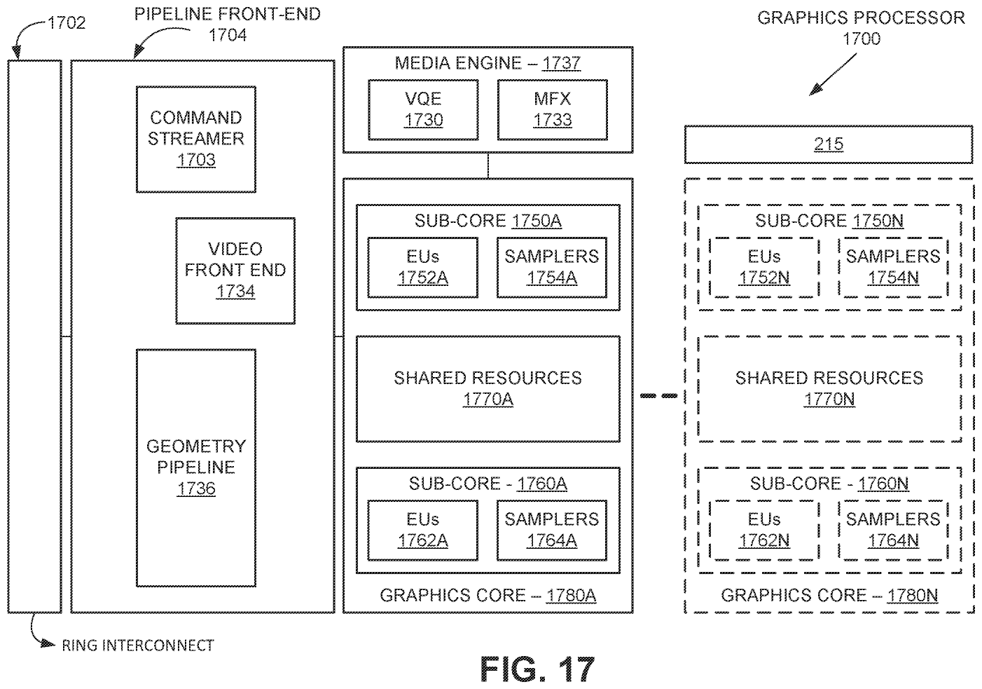

FIG. 17 is a block diagram of a graphics processor 1700, according to at least one embodiment. In at least one embodiment, graphics processor 1700 includes a ring interconnect 1702, a pipeline front-end 1704, a media engine 1737, and graphics cores 1780A-1780N. In at least one embodiment, ring interconnect 1702 couples graphics processor 1700 to other processing units, including other graphics processors or one or more general-purpose processor cores. In at least one embodiment, graphics processor 1700 is one of many processors integrated within a multi-core processing system. In at least one embodiment, graphics processor 1700 includes graphics core 1300.

In at least one embodiment, graphics processor 1700 receives batches of commands via ring interconnect 1702. In at least one embodiment, incoming commands are interpreted by a command streamer 1703 in pipeline front-end 1704. In at least one embodiment, graphics processor 1700 includes scalable execution logic to perform 3D geometry processing and media processing via graphics core(s) 1780A-1780N. In at least one embodiment, for 3D geometry processing commands, command streamer 1703 supplies commands to geometry pipeline 1736. In at least one embodiment, for at least some media processing commands, command streamer 1703 supplies commands to a video front end 1734, which couples with media engine 1737. In at least one embodiment, media engine 1737 includes a Video Quality Engine (VQE) 1730 for video and image post-processing and a multi-format encode/decode (MFX) 1733 engine to provide hardware-accelerated media data encoding and decoding. In at least one embodiment, geometry pipeline 1736 and media engine 1737 each generate execution threads for thread execution resources provided by at least one graphics core 1780.

In at least one embodiment, graphics processor 1700 includes scalable thread execution resources featuring graphics cores 1780A-1780N (which can be modular and are sometimes referred to as core slices), each having multiple sub-cores 1750A-50N, 1760A-1760N (sometimes referred to as core sub-slices). In at least one embodiment, graphics processor 1700 can have any number of graphics cores 1780A. In at least one embodiment, graphics processor 1700 includes a graphics core 1780A having at least a first sub-core 1750A and a second sub-core 1760A. In at least one embodiment, graphics processor 1700 is a low power processor with a single sub-core (e.g., 1750A). In at least one embodiment, graphics processor 1700 includes multiple graphics cores 1780A-1780N, each including a set of first sub-cores 1750A-1750N and a set of second sub-cores 1760A-1760N. In at least one embodiment, each sub-core in first sub-cores 1750A-1750N includes at least a first set of execution units 1752A-1752N and media/texture samplers 1754A-1754N. In at least one embodiment, each sub-core in second sub-cores 1760A-1760N includes at least a second set of execution units 1762A-1762N and samplers 1764A-1764N. In at least one embodiment, each sub-core 1750A-1750N, 1760A-1760N shares a set of shared resources 1770A-1770N. In at least one embodiment, shared resources include shared cache memory and pixel operation logic. In at least one embodiment, graphics processor 1700 includes load/store units in pipeline front-end 1704.

Inference and/or training logic 315 are used to perform inferencing and/or training operations associated with one or more embodiments. Details regarding inference and/or training logic 315 are provided herein in conjunction with FIGS. 3A and/or 3B. In at least one embodiment, inference and/or training logic 315 may be used in graphics processor 1700 for inferencing or predicting operations based, at least in part, on weight parameters calculated using neural network training operations, neural network functions and/or architectures, or neural network use cases described herein.

In at least one embodiment, one or more neural networks of an inference and/or training logic 315 may be used in conjunction with the system of FIG. 17 and may be configured to receive sensor inputs from multiple sensors and may be trained to infer a coolant requirement. In at least one embodiment, an inference and/or training logic 315 may be able to infer this using information from historical maintenance requirements and of historical sensor inputs. In at least one embodiment, an inference and/or training logic 315 may make an inference of a change in a maintenance requirement. In at least one embodiment, sensor inputs may be correlated to classes of different maintenance requirements of each of different sensor inputs. In at least one embodiment, a new sensor input classifying within a class of such different sensor inputs may indicate a maintenance requirement, or a change thereof.

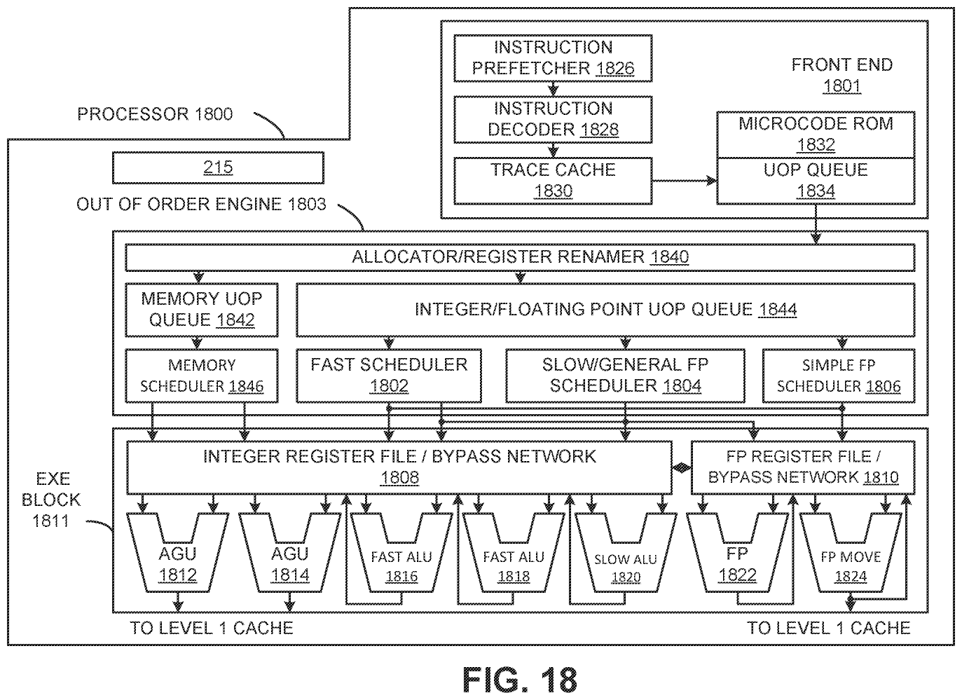

FIG. 18 is a block diagram illustrating micro-architecture for a processor 1800 that may include logic circuits to perform instructions, according to at least one embodiment. In at least one embodiment, processor 1800 may perform instructions, including x86 instructions, ARM instructions, specialized instructions for application-specific integrated circuits (ASICs), etc. In at least one embodiment, processor 1800 may include registers to store packed data, such as 64-bit wide MMX™ registers in microprocessors enabled with MMX technology from Intel Corporation of Santa Clara, Calif. In at least one embodiment, MMX registers, available in both integer and floating point forms, may operate with packed data elements that accompany single instruction, multiple data (“SIMD”) and streaming SIMD extensions (“SSE”) instructions. In at least one embodiment, 128-bit wide XMM registers relating to SSE2, SSE3, SSE4, AVX, or beyond (referred to generically as “SSEx”) technology may hold such packed data operands. In at least one embodiment, processor 1800 may perform instructions to accelerate machine learning or deep learning algorithms, training, or inferencing.

In at least one embodiment, processor 1800 includes an in-order front end (“front end”) 1801 to fetch instructions to be executed and prepare instructions to be used later in a processor pipeline. In at least one embodiment, front end 1801 may include several units. In at least one embodiment, an instruction prefetcher 1826 fetches instructions from memory and feeds instructions to an instruction decoder 1828 which in turn decodes or interprets instructions. For example, in at least one embodiment, instruction decoder 1828 decodes a received instruction into one or more operations called “micro-instructions” or “micro-operations” (also called “micro ops” or “uops” or “μ-ops”) that a machine may execute. In at least one embodiment, instruction decoder 1828 parses an instruction into an opcode and corresponding data and control fields that may be used by micro-architecture to perform operations in accordance with at least one embodiment. In at least one embodiment, a trace cache 1830 may assemble decoded uops into program ordered sequences or traces in a uop queue 1834 for execution. In at least one embodiment, when trace cache 1830 encounters a complex instruction, a microcode ROM 1832 provides uops needed to complete an operation.

In at least one embodiment, some instructions may be converted into a single micro-op, whereas others need several micro-ops to complete full operation. In at least one embodiment, if more than four micro-ops are needed to complete an instruction, instruction decoder 1828 may access microcode ROM 1832 to perform that instruction. In at least one embodiment, an instruction may be decoded into a small number of micro-ops for processing at instruction decoder 1828. In at least one embodiment, an instruction may be stored within microcode ROM 1832 should a number of micro-ops be needed to accomplish such operation. In at least one embodiment, trace cache 1830 refers to an entry point programmable logic array (“PLA”) to determine a correct micro-instruction pointer for reading microcode sequences to complete one or more instructions from microcode ROM 1832 in accordance with at least one embodiment. In at least one embodiment, after microcode ROM 1832 finishes sequencing micro-ops for an instruction, front end 1801 of a machine may resume fetching micro-ops from trace cache 1830.

In at least one embodiment, out-of-order execution engine (“out of order engine”) 1803 may prepare instructions for execution. In at least one embodiment, out-of-order execution logic has a number of buffers to smooth out and re-order flow of instructions to optimize performance as they go down a pipeline and get scheduled for execution. In at least one embodiment, out-of-order execution engine 1803 includes, without limitation, an allocator/register renamer 1840, a memory uop queue 1842, an integer/floating point uop queue 1844, a memory scheduler 1846, a fast scheduler 1802, a slow/general floating point scheduler (“slow/general FP scheduler”) 1804, and a simple floating point scheduler (“simple FP scheduler”) 1806. In at least one embodiment, fast schedule 1802, slow/general floating point scheduler 1804, and simple floating point scheduler 1806 are also collectively referred to herein as “uop schedulers 1802, 1804, 1806.” In at least one embodiment, allocator/register renamer 1840 allocates machine buffers and resources that each uop needs in order to execute. In at least one embodiment, allocator/register renamer 1840 renames logic registers onto entries in a register file. In at least one embodiment, allocator/register renamer 1840 also allocates an entry for each uop in one of two uop queues, memory uop queue 1842 for memory operations and integer/floating point uop queue 1844 for non-memory operations, in front of memory scheduler 1846 and uop schedulers 1802, 1804, 1806. In at least one embodiment, uop schedulers 1802, 1804, 1806, determine when a uop is ready to execute based on readiness of their dependent input register operand sources and availability of execution resources uops need to complete their operation. In at least one embodiment, fast scheduler 1802 may schedule on each half of a main clock cycle while slow/general floating point scheduler 1804 and simple floating point scheduler 1806 may schedule once per main processor clock cycle. In at least one embodiment, uop schedulers 1802, 1804, 1806 arbitrate for dispatch ports to schedule uops for execution.

In at least one embodiment, execution block 1811 includes, without limitation, an integer register file/bypass network 1808, a floating point register file/bypass network (“FP register file/bypass network”) 1810, address generation units (“AGUs”) 1812 and 1814, fast Arithmetic Logic Units (ALUs) (“fast ALUs”) 1816 and 1818, a slow Arithmetic Logic Unit (“slow ALU”) 1820, a floating point ALU (“FP”) 1822, and a floating point move unit (“FP move”) 1824. In at least one embodiment, integer register file/bypass network 1808 and floating point register file/bypass network 1810 are also referred to herein as “register files 1808, 1810.” In at least one embodiment, AGUSs 1812 and 1814, fast ALUs 1816 and 1818, slow ALU 1820, floating point ALU 1822, and floating point move unit 1824 are also referred to herein as “execution units 1812, 1814, 1816, 1818, 1820, 1822, and 1824.” In at least one embodiment, execution block 1811 may include, without limitation, any number (including zero) and type of register files, bypass networks, address generation units, and execution units, in any combination.

In at least one embodiment, register networks 1808, 1810 may be arranged between uop schedulers 1802, 1804, 1806, and execution units 1812, 1814, 1816, 1818, 1820, 1822, and 1824. In at least one embodiment, integer register file/bypass network 1808 performs integer operations. In at least one embodiment, floating point register file/bypass network 1810 performs floating point operations. In at least one embodiment, each of register networks 1808, 1810 may include, without limitation, a bypass network that may bypass or forward just completed results that have not yet been written into a register file to new dependent uops. In at least one embodiment, register networks 1808, 1810 may communicate data with each other. In at least one embodiment, integer register file/bypass network 1808 may include, without limitation, two separate register files, one register file for a low-order thirty-two bits of data and a second register file for a high order thirty-two bits of data. In at least one embodiment, floating point register file/bypass network 1810 may include, without limitation, 128-bit wide entries because floating point instructions typically have operands from 64 to 128 bits in width.

In at least one embodiment, execution units 1812, 1814, 1816, 1818, 1820, 1822, 1824 may execute instructions. In at least one embodiment, register networks 1808, 1810 store integer and floating point data operand values that micro-instructions need to execute. In at least one embodiment, processor 1800 may include, without limitation, any number and combination of execution units 1812, 1814, 1816, 1818, 1820, 1822, 1824. In at least one embodiment, floating point ALU 1822 and floating point move unit 1824, may execute floating point, MMX, SIMD, AVX and SSE, or other operations, including specialized machine learning instructions. In at least one embodiment, floating point ALU 1822 may include, without limitation, a 64-bit by 64-bit floating point divider to execute divide, square root, and remainder micro ops. In at least one embodiment, instructions involving a floating point value may be handled with floating point hardware. In at least one embodiment, ALU operations may be passed to fast ALUs 1816, 1818. In at least one embodiment, fast ALUS 1816, 1818 may execute fast operations with an effective latency of half a clock cycle. In at least one embodiment, most complex integer operations go to slow ALU 1820 as slow ALU 1820 may include, without limitation, integer execution hardware for long-latency type of operations, such as a multiplier, shifts, flag logic, and branch processing. In at least one embodiment, memory load/store operations may be executed by AGUs 1812, 1814. In at least one embodiment, fast ALU 1816, fast ALU 1818, and slow ALU 1820 may perform integer operations on 64-bit data operands. In at least one embodiment, fast ALU 1816, fast ALU 1818, and slow ALU 1820 may be implemented to support a variety of data bit sizes including sixteen, thirty-two, 128, 256, etc. In at least one embodiment, floating point ALU 1822 and floating point move unit 1824 may be implemented to support a range of operands having bits of various widths, such as 128-bit wide packed data operands in conjunction with SIMD and multimedia instructions.

In at least one embodiment, uop schedulers 1802, 1804, 1806 dispatch dependent operations before a parent load has finished executing. In at least one embodiment, as uops may be speculatively scheduled and executed in processor 1800, processor 1800 may also include logic to handle memory misses. In at least one embodiment, if a data load misses in a data cache, there may be dependent operations in flight in a pipeline that have left a scheduler with temporarily incorrect data. In at least one embodiment, a replay mechanism tracks and re-executes instructions that use incorrect data. In at least one embodiment, dependent operations might need to be replayed and independent ones may be allowed to complete. In at least one embodiment, schedulers and a replay mechanism of at least one embodiment of a processor may also be designed to catch instruction sequences for text string comparison operations.

In at least one embodiment, “registers” may refer to on-board processor storage locations that may be used as part of instructions to identify operands. In at least one embodiment, registers may be those that may be usable from outside of a processor (from a programmer's perspective). In at least one embodiment, registers might not be limited to a particular type of circuit. Rather, in at least one embodiment, a register may store data, provide data, and perform functions described herein. In at least one embodiment, registers described herein may be implemented by circuitry within a processor using any number of different techniques, such as dedicated physical registers, dynamically allocated physical registers using register renaming, combinations of dedicated and dynamically allocated physical registers, etc. In at least one embodiment, integer registers store 32-bit integer data. A register file of at least one embodiment also contains eight multimedia SIMD registers for packed data.

In at least one embodiment, processor 1800 or each core of processor 1800 includes one or more prefetchers, one or more fetchers, one or more pre-decoders, one or more decoders to decode data (e.g., instructions), one or more instruction queues to process instructions (e.g., corresponding to operations or API calls), one or more micro-operation (μOP) cache to store μOPs, one or more micro-operation (μOP) queues, an in-order execution engine, one or more load buffers, one or more store buffers, one or more reorder buffers, one or more fill buffers, an out-of-order execution engine, one or more ports, one or more shift and/or shifter units, one or more fused multiply accumulate (FMA) units, one or more load and store units (“LSUs”) to perform load of store operations corresponding to loading/storing data (e.g., instructions) to perform an operation (e.g., perform an API, an API call), one or more matrix multiply accumulate (MMA) units, and/or one or more shuffle units to perform any function further described herein with respect to said processor 1800. In at least one embodiment processor 1800 can access, use, perform, or execute instructions corresponding to calling an API.

In at least one embodiment, processor 1800 includes one or more ultra path interconnects (UPIs), e.g., that is a point-to-point processor interconnect; one or more PCIe's; one or more accelerators to accelerate computations or operations; and/or one or more memory controllers. In at least one embodiment, processor 1800 includes a shared last level cache (LLC) that is coupled to one or more memory controllers, which can enable shared memory access across processor cores.

In at least one embodiment, processor 1800 or a core of processor 1800 has a mesh architecture where processor cores, on-chip caches, memory controllers, and I/O controllers are organized in rows and columns, with wires and switches connecting them at each intersection to allow for turns. In at least one embodiment, processor 1800 has a one or more higher memory bandwidths (HMB s, e.g., HMBe) to store data or cache data, e.g., in Double Data Rate 5 Synchronous Dynamic Random-Access Memory (DDR5 SDRAM). In at least one embodiment, one or more components of processor 1800 are interconnected using compute express link (CXL) interconnects. In at least one embodiment, a memory controller uses a “least recently used” (LRU) approach to determine what gets stored in a cache. In at least one embodiment, processor 1800 includes one or more PCIe's (e.g., PCIe 5.0).

Inference and/or training logic 315 are used to perform inferencing and/or training operations associated with one or more embodiments. Details regarding inference and/or training logic 315 are provided herein in conjunction with FIGS. 3A and/or 3B. In at least one embodiment portions or all of inference and/or training logic 315 may be incorporated into execution block 1811 and other memory or registers shown or not shown. For example, in at least one embodiment, training and/or inferencing techniques described herein may use one or more of ALUs illustrated in execution block 1811. Moreover, weight parameters may be stored in on-chip or off-chip memory and/or registers (shown or not shown) that configure ALUs of execution block 1811 to perform one or more machine learning algorithms, neural network architectures, use cases, or training techniques described herein.

In at least one embodiment, one or more neural networks of an inference and/or training logic 315 may be used in conjunction with the system of FIG. 18 and may be configured to receive sensor inputs from multiple sensors and may be trained to infer a coolant requirement. In at least one embodiment, an inference and/or training logic 315 may be able to infer this using information from historical maintenance requirements and of historical sensor inputs. In at least one embodiment, an inference and/or training logic 315 may make an inference of a change in a maintenance requirement. In at least one embodiment, sensor inputs may be correlated to classes of different maintenance requirements of each of different sensor inputs. In at least one embodiment, a new sensor input classifying within a class of such different sensor inputs may indicate a maintenance requirement, or a change thereof.

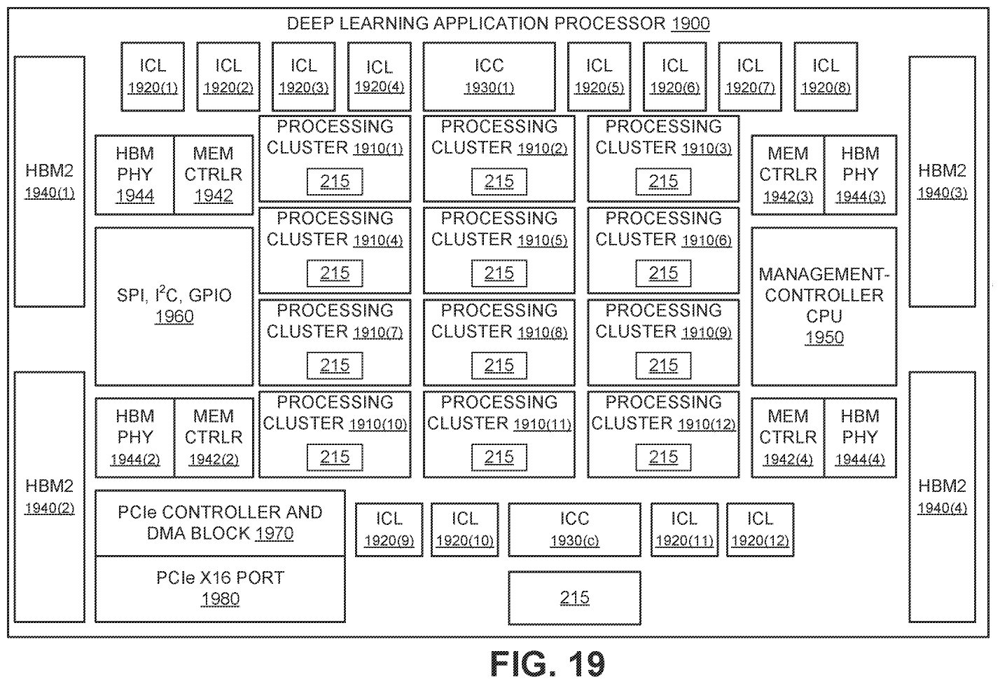

FIG. 19 illustrates a deep learning application processor 1900, according to at least one embodiment. In at least one embodiment, deep learning application processor 1900 uses instructions that, if executed by deep learning application processor 1900, cause deep learning application processor 1900 to perform some or all of processes and techniques described throughout this disclosure. In at least one embodiment, deep learning application processor 1900 is an application-specific integrated circuit (ASIC). In at least one embodiment, application processor 1900 performs matrix multiply operations either “hard-wired” into hardware as a result of performing one or more instructions or both. In at least one embodiment, deep learning application processor 1900 includes, without limitation, processing clusters 1910(1)-1910(12), Inter-Chip Links (“ICLs”) 1920(1)-1920(12), Inter-Chip Controllers (“ICCs”) 1930(1)-1930(2), high-bandwidth memory second generation (“HBM2”) 1940(1)-1940(4), memory controllers (“Mem Ctrlrs”) 1942(1)-1942(4), high bandwidth memory physical layer (“HBM PHY”) 1944(1)-1944(4), a management-controller central processing unit (“management-controller CPU”) 1950, a Serial Peripheral Interface, Inter-Integrated Circuit, and General Purpose Input/Output block (“SPI, I²C, GPIO”) 1960, a peripheral component interconnect express controller and direct memory access block (“PCIe Controller and DMA”) 1970, and a sixteen-lane peripheral component interconnect express port (“PCI Express×16”) 1980.

In at least one embodiment, processing clusters 1910 may perform deep learning operations, including inference or prediction operations based on weight parameters calculated one or more training techniques, including those described herein. In at least one embodiment, each processing cluster 1910 may include, without limitation, any number and type of processors. In at least one embodiment, deep learning application processor 1900 may include any number and type of processing clusters 1900. In at least one embodiment, Inter-Chip Links 1920 are bi-directional. In at least one embodiment, Inter-Chip Links 1920 and Inter-Chip Controllers 1930 enable multiple deep learning application processors 1900 to exchange information, including activation information resulting from performing one or more machine learning algorithms embodied in one or more neural networks. In at least one embodiment, deep learning application processor 1900 may include any number (including zero) and type of ICLs 1920 and ICCs 1930.

In at least one embodiment, HBM2s 1940 provide a total of 32 Gigabytes (GB) of memory. In at least one embodiment, HBM2 1940(i) is associated with both memory controller 1942(i) and HBM PHY 1944(i) where “i” is an arbitrary integer. In at least one embodiment, any number of HBM2s 1940 may provide any type and total amount of high bandwidth memory and may be associated with any number (including zero) and type of memory controllers 1942 and HBM PHYs 1944. In at least one embodiment, SPI, I²C, GPIO 1960, PCIe Controller and DMA 1970, and/or PCIe 1980 may be replaced with any number and type of blocks that enable any number and type of communication standards in any technically feasible fashion.

Inference and/or training logic 315 are used to perform inferencing and/or training operations associated with one or more embodiments. Details regarding inference and/or training logic 315 are provided herein in conjunction with FIGS. 3A and/or 3B. In at least one embodiment, deep learning application processor is used to train a machine learning model, such as a neural network, to predict or infer information provided to deep learning application processor 1900. In at least one embodiment, deep learning application processor 1900 is used to infer or predict information based on a trained machine learning model (e.g., neural network) that has been trained by another processor or system or by deep learning application processor 1900. In at least one embodiment, processor 1900 may be used to perform one or more neural network use cases described herein.

In at least one embodiment, one or more neural networks of an inference and/or training logic 315 may be used in conjunction with the system of FIG. 19 and may be configured to receive sensor inputs from multiple sensors and may be trained to infer a coolant requirement. In at least one embodiment, an inference and/or training logic 315 may be able to infer this using information from historical maintenance requirements and of historical sensor inputs. In at least one embodiment, an inference and/or training logic 315 may make an inference of a change in a maintenance requirement. In at least one embodiment, sensor inputs may be correlated to classes of different maintenance requirements of each of different sensor inputs. In at least one embodiment, a new sensor input classifying within a class of such different sensor inputs may indicate a maintenance requirement, or a change thereof.

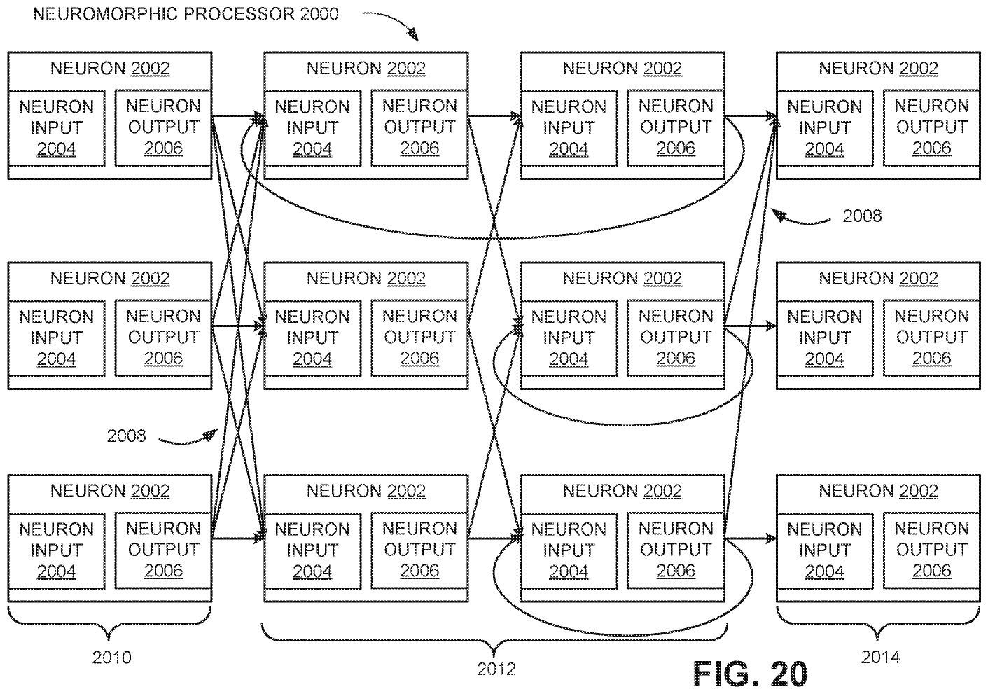

FIG. 20 is a block diagram of a neuromorphic processor 2000, according to at least one embodiment. In at least one embodiment, neuromorphic processor 2000 may receive one or more inputs from sources external to neuromorphic processor 2000. In at least one embodiment, these inputs may be transmitted to one or more neurons 2002 within neuromorphic processor 2000. In at least one embodiment, neurons 2002 and components thereof may be implemented using circuitry or logic, including one or more arithmetic logic units (ALUs). In at least one embodiment, neuromorphic processor 2000 may include, without limitation, thousands or millions of instances of neurons 2002, but any suitable number of neurons 2002 may be used. In at least one embodiment, each instance of neuron 2002 may include a neuron input 2004 and a neuron output 2006. In at least one embodiment, neurons 2002 may generate outputs that may be transmitted to inputs of other instances of neurons 2002. For example, in at least one embodiment, neuron inputs 2004 and neuron outputs 2006 may be interconnected via synapses 2008.

In at least one embodiment, neurons 2002 and synapses 2008 may be interconnected such that neuromorphic processor 2000 operates to process or analyze information received by neuromorphic processor 2000. In at least one embodiment, neurons 2002 may transmit an output pulse (or “fire” or “spike”) when inputs received through neuron input 2004 exceed a threshold. In at least one embodiment, neurons 2002 may sum or integrate signals received at neuron inputs 2004. For example, in at least one embodiment, neurons 2002 may be implemented as leaky integrate-and-fire neurons, wherein if a sum (referred to as a “membrane potential”) exceeds a threshold value, neuron 2002 may generate an output (or “fire”) using a transfer function such as a sigmoid or threshold function. In at least one embodiment, a leaky integrate-and-fire neuron may sum signals received at neuron inputs 2004 into a membrane potential and may also apply a decay factor (or leak) to reduce a membrane potential. In at least one embodiment, a leaky integrate-and-fire neuron may fire if multiple input signals are received at neuron inputs 2004 rapidly enough to exceed a threshold value (i.e., before a membrane potential decays too low to fire). In at least one embodiment, neurons 2002 may be implemented using circuits or logic that receive inputs, integrate inputs into a membrane potential, and decay a membrane potential. In at least one embodiment, inputs may be averaged, or any other suitable transfer function may be used. Furthermore, in at least one embodiment, neurons 2002 may include, without limitation, comparator circuits or logic that generate an output spike at neuron output 2006 when result of applying a transfer function to neuron input 2004 exceeds a threshold. In at least one embodiment, once neuron 2002 fires, it may disregard previously received input information by, for example, resetting a membrane potential to 0 or another suitable default value. In at least one embodiment, once membrane potential is reset to 0, neuron 2002 may resume normal operation after a suitable period of time (or refractory period).

In at least one embodiment, neurons 2002 may be interconnected through synapses 2008. In at least one embodiment, synapses 2008 may operate to transmit signals from an output of a first neuron 2002 to an input of a second neuron 2002. In at least one embodiment, neurons 2002 may transmit information over more than one instance of synapse 2008. In at least one embodiment, one or more instances of neuron output 2006 may be connected, via an instance of synapse 2008, to an instance of neuron input 2004 in same neuron 2002. In at least one embodiment, an instance of neuron 2002 generating an output to be transmitted over an instance of synapse 2008 may be referred to as a “pre-synaptic neuron” with respect to that instance of synapse 2008. In at least one embodiment, an instance of neuron 2002 receiving an input transmitted over an instance of synapse 2008 may be referred to as a “post-synaptic neuron” with respect to that instance of synapse 2008. Because an instance of neuron 2002 may receive inputs from one or more instances of synapse 2008, and may also transmit outputs over one or more instances of synapse 2008, a single instance of neuron 2002 may therefore be both a “pre-synaptic neuron” and “post-synaptic neuron,” with respect to various instances of synapses 2008, in at least one embodiment.

In at least one embodiment, neurons 2002 may be organized into one or more layers. In at least one embodiment, each instance of neuron 2002 may have one neuron output 2006 that may fan out through one or more synapses 2008 to one or more neuron inputs 2004. In at least one embodiment, neuron outputs 2006 of neurons 2002 in a first layer 2010 may be connected to neuron inputs 2004 of neurons 2002 in a second layer 2012. In at least one embodiment, layer 2010 may be referred to as a “feed-forward layer.” In at least one embodiment, each instance of neuron 2002 in an instance of first layer 2010 may fan out to each instance of neuron 2002 in second layer 2012. In at least one embodiment, first layer 2010 may be referred to as a “fully connected feed-forward layer.” In at least one embodiment, each instance of neuron 2002 in an instance of second layer 2012 may fan out to fewer than all instances of neuron 2002 in a third layer 2014. In at least one embodiment, second layer 2012 may be referred to as a “sparsely connected feed-forward layer.” In at least one embodiment, neurons 2002 in second layer 2012 may fan out to neurons 2002 in multiple other layers, including to neurons 2002 also in second layer 2012. In at least one embodiment, second layer 2012 may be referred to as a “recurrent layer.” In at least one embodiment, neuromorphic processor 2000 may include, without limitation, any suitable combination of recurrent layers and feed-forward layers, including, without limitation, both sparsely connected feed-forward layers and fully connected feed-forward layers.

In at least one embodiment, neuromorphic processor 2000 may include, without limitation, a reconfigurable interconnect architecture or dedicated hard-wired interconnects to connect synapse 2008 to neurons 2002. In at least one embodiment, neuromorphic processor 2000 may include, without limitation, circuitry or logic that allows synapses to be allocated to different neurons 2002 as needed based on neural network topology and neuron fan-in/out. For example, in at least one embodiment, synapses 2008 may be connected to neurons 2002 using an interconnect fabric, such as network-on-chip, or with dedicated connections. In at least one embodiment, synapse interconnections and components thereof may be implemented using circuitry or logic.

In at least one embodiment, one or more neural networks of an inference and/or training logic 315 may be used in conjunction with the system of FIG. 20 and may be configured to receive sensor inputs from multiple sensors and may be trained to infer a coolant requirement. In at least one embodiment, an inference and/or training logic 315 may be able to infer this using information from historical maintenance requirements and of historical sensor inputs. In at least one embodiment, an inference and/or training logic 315 may make an inference of a change in a maintenance requirement. In at least one embodiment, sensor inputs may be correlated to classes of different maintenance requirements of each of different sensor inputs. In at least one embodiment, a new sensor input classifying within a class of such different sensor inputs may indicate a maintenance requirement, or a change thereof.

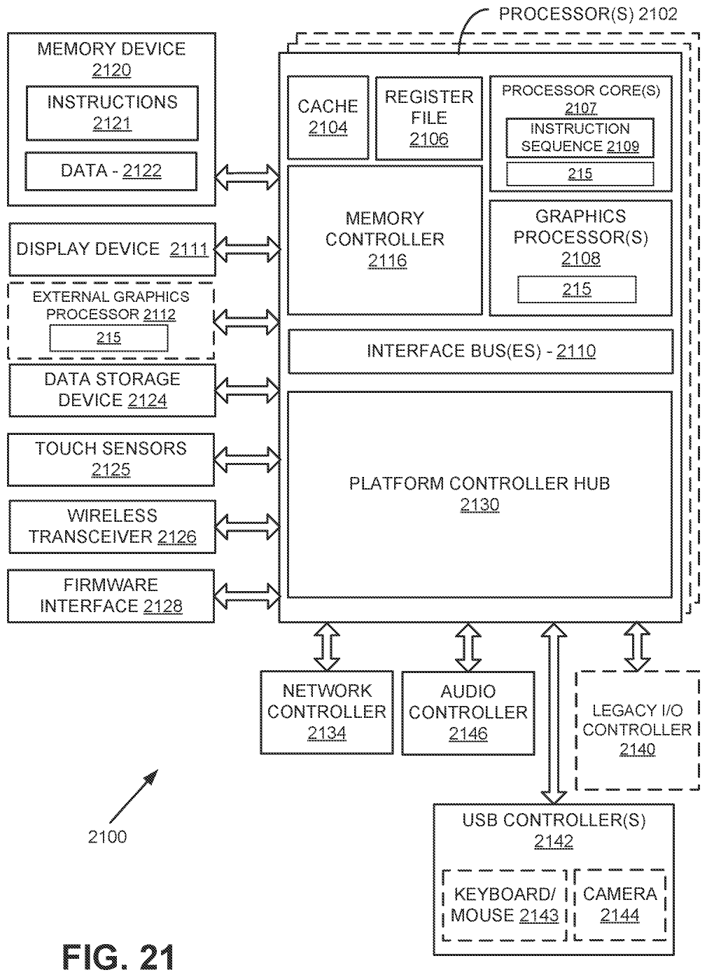

FIG. 21 is a block diagram of a processing system, according to at least one embodiment. In at least one embodiment, system 2100 includes one or more processors 2102 and one or more graphics processors 2108, and may be a single processor desktop system, a multiprocessor workstation system, or a server system having a large number of processors 2102 or processor cores 2107. In at least one embodiment, system 2100 is a processing platform incorporated within a system-on-a-chip (SoC) integrated circuit for use in mobile, handheld, or embedded devices. In at least one embodiment, one or more graphics processors 2108 include one or more graphics cores 1300.

In at least one embodiment, system 2100 can include, or be incorporated within a server-based gaming platform, a game console, including a game and media console, a mobile gaming console, a handheld game console, or an online game console. In at least one embodiment, system 2100 is a mobile phone, a smart phone, a tablet computing device or a mobile Internet device. In at least one embodiment, processing system 2100 can also include, couple with, or be integrated within a wearable device, such as a smart watch wearable device, a smart eyewear device, an augmented reality device, or a virtual reality device. In at least one embodiment, processing system 2100 is a television or set top box device having one or more processors 2102 and a graphical interface generated by one or more graphics processors 2108.

In at least one embodiment, one or more processors 2102 each include one or more processor cores 2107 to process instructions which, when executed, perform operations for system and user software. In at least one embodiment, each of one or more processor cores 2107 is configured to process a specific instruction sequence 2109. In at least one embodiment, instruction sequence 2109 may facilitate Complex Instruction Set Computing (CISC), Reduced Instruction Set Computing (RISC), or computing via a Very Long Instruction Word (VLIW). In at least one embodiment, processor cores 2107 may each process a different instruction sequence 2109, which may include instructions to facilitate emulation of other instruction sequences. In at least one embodiment, processor core 2107 may also include other processing devices, such a Digital Signal Processor (DSP).

In at least one embodiment, processor 2102 includes a cache memory 2104. In at least one embodiment, processor 2102 can have a single internal cache or multiple levels of internal cache. In at least one embodiment, cache memory is shared among various components of processor 2102. In at least one embodiment, processor 2102 also uses an external cache (e.g., a Level-3 (L3) cache or Last Level Cache (LLC)) (not shown), which may be shared among processor cores 2107 using known cache coherency techniques. In at least one embodiment, a register file 2106 is additionally included in processor 2102, which may include different types of registers for storing different types of data (e.g., integer registers, floating point registers, status registers, and an instruction pointer register). In at least one embodiment, register file 2106 may include general-purpose registers or other registers.

In at least one embodiment, one or more processor(s) 2102 are coupled with one or more interface bus(es) 2110 to transmit communication signals such as address, data, or control signals between processor 2102 and other components in system 2100. In at least one embodiment, interface bus 2110 can be a processor bus, such as a version of a Direct Media Interface (DMI) bus. In at least one embodiment, interface bus 2110 is not limited to a DMI bus, and may include one or more Peripheral Component Interconnect buses (e.g., PCI, PCI Express), memory busses, or other types of interface busses. In at least one embodiment processor(s) 2102 include an integrated memory controller 2116 and a platform controller hub 2130. In at least one embodiment, memory controller 2116 facilitates communication between a memory device and other components of system 2100, while platform controller hub (PCH) 2130 provides connections to I/O devices via a local I/O bus.

In at least one embodiment, a memory device 2120 can be a dynamic random access memory (DRAM) device, a static random access memory (SRAM) device, flash memory device, phase-change memory device, or some other memory device having suitable performance to serve as process memory. In at least one embodiment, memory device 2120 can operate as system memory for system 2100, to store data 2122 and instructions 2121 for use when one or more processors 2102 executes an application or process. In at least one embodiment, memory controller 2116 also couples with an optional external graphics processor 2112, which may communicate with one or more graphics processors 2108 in processors 2102 to perform graphics and media operations. In at least one embodiment, a display device 2111 can connect to processor(s) 2102. In at least one embodiment, display device 2111 can include one or more of an internal display device, as in a mobile electronic device or a laptop device, or an external display device attached via a display interface (e.g., DisplayPort, etc.). In at least one embodiment, display device 2111 can include a head mounted display (HMD) such as a stereoscopic display device for use in virtual reality (VR) applications or augmented reality (AR) applications.

In at least one embodiment, platform controller hub 2130 enables peripherals to connect to memory device 2120 and processor 2102 via a high-speed I/O bus. In at least one embodiment, I/O peripherals include, but are not limited to, an audio controller 2146, a network controller 2134, a firmware interface 2128, a wireless transceiver 2126, touch sensors 2125, a data storage device 2124 (e.g., hard disk drive, flash memory, etc.). In at least one embodiment, data storage device 2124 can connect via a storage interface (e.g., SATA) or via a peripheral bus, such as a Peripheral Component Interconnect bus (e.g., PCI, PCI Express). In at least one embodiment, touch sensors 2125 can include touch screen sensors, pressure sensors, or fingerprint sensors. In at least one embodiment, wireless transceiver 2126 can be a Wi-Fi transceiver, a Bluetooth transceiver, or a mobile network transceiver such as a 3G, 4G, or Long Term Evolution (LTE) transceiver. In at least one embodiment, firmware interface 2128 enables communication with system firmware, and can be, for example, a unified extensible firmware interface (UEFI). In at least one embodiment, network controller 2134 can enable a network connection to a wired network. In at least one embodiment, a high-performance network controller (not shown) couples with interface bus 2110. In at least one embodiment, audio controller 2146 is a multi-channel high definition audio controller. In at least one embodiment, system 2100 includes an optional legacy I/O controller 2140 for coupling legacy (e.g., Personal System 2 (PS/2)) devices to system 2100. In at least one embodiment, platform controller hub 2130 can also connect to one or more Universal Serial Bus (USB) controllers 2142 connect input devices, such as keyboard and mouse 2143 combinations, a camera 2144, or other USB input devices.

In at least one embodiment, an instance of memory controller 2116 and platform controller hub 2130 may be integrated into a discreet external graphics processor, such as external graphics processor 2112. In at least one embodiment, platform controller hub 2130 and/or memory controller 2116 may be external to one or more processor(s) 2102. For example, in at least one embodiment, system 2100 can include an external memory controller 2116 and platform controller hub 2130, which may be configured as a memory controller hub and peripheral controller hub within a system chipset that is in communication with processor(s) 2102.

Inference and/or training logic 315 are used to perform inferencing and/or training operations associated with one or more embodiments. Details regarding inference and/or training logic 315 are provided herein in conjunction with FIGS. 3A and/or 3B. In at least one embodiment portions or all of inference and/or training logic 315 may be incorporated into graphics processor 2108. For example, in at least one embodiment, training and/or inferencing techniques described herein may use one or more of ALUs embodied in a 3D pipeline. Moreover, in at least one embodiment, inferencing and/or training operations described herein may be done using logic other than logic illustrated in FIG. 3A or 3B. In at least one embodiment, weight parameters may be stored in on-chip or off-chip memory and/or registers (shown or not shown) that configure ALUs of graphics processor 2108 to perform one or more machine learning algorithms, neural network architectures, use cases, or training techniques described herein.

In at least one embodiment, one or more neural networks of an inference and/or training logic 315 may be used in conjunction with the system of FIG. 21 and may be configured to receive sensor inputs from multiple sensors and may be trained to infer a coolant requirement. In at least one embodiment, an inference and/or training logic 315 may be able to infer this using information from historical maintenance requirements and of historical sensor inputs. In at least one embodiment, an inference and/or training logic 315 may make an inference of a change in a maintenance requirement. In at least one embodiment, sensor inputs may be correlated to classes of different maintenance requirements of each of different sensor inputs. In at least one embodiment, a new sensor input classifying within a class of such different sensor inputs may indicate a maintenance requirement, or a change thereof.

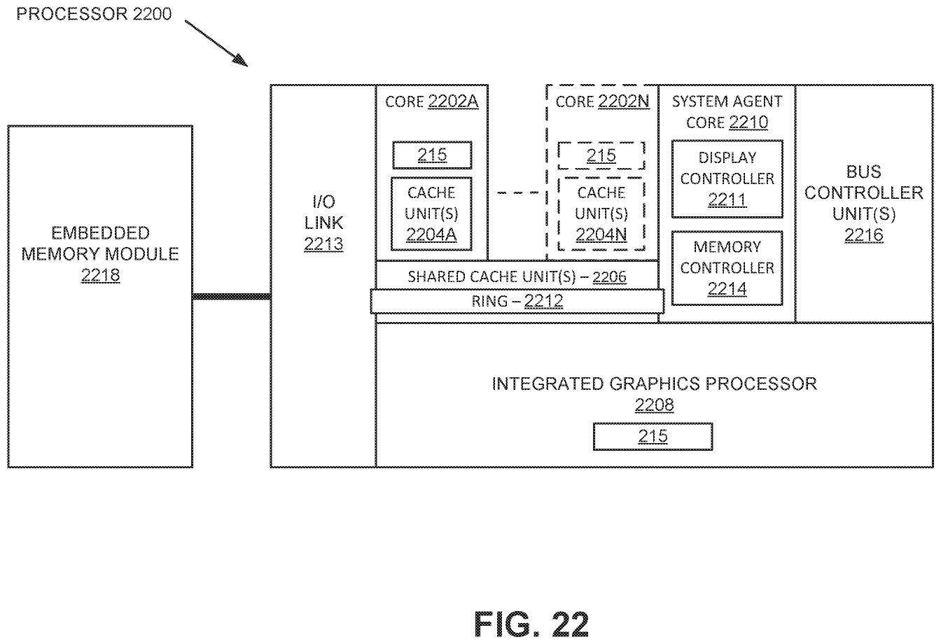

FIG. 22 is a block diagram of a processor 2200 having one or more processor cores 2202A-2202N, an integrated memory controller 2214, and an integrated graphics processor 2208, according to at least one embodiment. In at least one embodiment, processor 2200 can include additional cores up to and including additional core 2202N represented by dashed lined boxes. In at least one embodiment, each of processor cores 2202A-2202N includes one or more internal cache units 2204A-2204N. In at least one embodiment, each processor core also has access to one or more shared cached units 2206. In at least one embodiment, graphics processor 2208 includes one or more graphics cores 1300.

In at least one embodiment, internal cache units 2204A-2204N and shared cache units 2206 represent a cache memory hierarchy within processor 2200. In at least one embodiment, cache memory units 2204A-2204N may include at least one level of instruction and data cache within each processor core and one or more levels of shared mid-level cache, such as a Level 2 (L2), Level 3 (L3), Level 4 (L4), or other levels of cache, where a highest level of cache before external memory is classified as an LLC. In at least one embodiment, cache coherency logic maintains coherency between various cache units 2206 and 2204A-2204N.

In at least one embodiment, processor 2200 may also include a set of one or more bus controller units 2216 and a system agent core 2210. In at least one embodiment, bus controller units 2216 manage a set of peripheral buses, such as one or more PCI or PCI express busses. In at least one embodiment, system agent core 2210 provides management functionality for various processor components. In at least one embodiment, system agent core 2210 includes one or more integrated memory controllers 2214 to manage access to various external memory devices (not shown).

In at least one embodiment, one or more of processor cores 2202A-2202N include support for simultaneous multi-threading. In at least one embodiment, system agent core 2210 includes components for coordinating and operating cores 2202A-2202N during multi-threaded processing. In at least one embodiment, system agent core 2210 may additionally include a power control unit (PCU), which includes logic and components to regulate one or more power states of processor cores 2202A-2202N and graphics processor 2208.

In at least one embodiment, processor 2200 additionally includes graphics processor 2208 to execute graphics processing operations. In at least one embodiment, graphics processor 2208 couples with shared cache units 2206, and system agent core 2210, including one or more integrated memory controllers 2214. In at least one embodiment, system agent core 2210 also includes a display controller 2211 to drive graphics processor output to one or more coupled displays. In at least one embodiment, display controller 2211 may also be a separate module coupled with graphics processor 2208 via at least one interconnect, or may be integrated within graphics processor 2208.

In at least one embodiment, a ring-based interconnect unit 2212 is used to couple internal components of processor 2200. In at least one embodiment, an alternative interconnect unit may be used, such as a point-to-point interconnect, a switched interconnect, or other techniques. In at least one embodiment, graphics processor 2208 couples with ring interconnect 2212 via an I/O link 2213.

In at least one embodiment, I/O link 2213 represents at least one of multiple varieties of I/O interconnects, including an on package I/O interconnect which facilitates communication between various processor components and a high-performance embedded memory module 2218, such as an eDRAM module. In at least one embodiment, each of processor cores 2202A-2202N and graphics processor 2208 use embedded memory module 2218 as a shared Last Level Cache.

In at least one embodiment, processor cores 2202A-2202N are homogeneous cores executing a common instruction set architecture. In at least one embodiment, processor cores 2202A-2202N are heterogeneous in terms of instruction set architecture (ISA), where one or more of processor cores 2202A-2202N execute a common instruction set, while one or more other cores of processor cores 2202A-2202N executes a subset of a common instruction set or a different instruction set. In at least one embodiment, processor cores 2202A-2202N are heterogeneous in terms of microarchitecture, where one or more cores having a relatively higher power consumption couple with one or more power cores having a lower power consumption. In at least one embodiment, processor 2200 can be implemented on one or more chips or as an SoC integrated circuit.

Inference and/or training logic 315 are used to perform inferencing and/or training operations associated with one or more embodiments. Details regarding inference and/or training logic 315 are provided herein in conjunction with FIGS. 3A and/or 3B. In at least one embodiment portions or all of inference and/or training logic 315 may be incorporated into graphics processor 2208. For example, in at least one embodiment, training and/or inferencing techniques described herein may use one or more of ALUs embodied in a 3D pipeline, graphics core(s) 2202, shared function logic, or other logic in FIG. 22. Moreover, in at least one embodiment, inferencing and/or training operations described herein may be done using logic other than logic illustrated in FIG. 3A or 3B. In at least one embodiment, weight parameters may be stored in on-chip or off-chip memory and/or registers (shown or not shown) that configure ALUs of processor 2200 to perform one or more machine learning algorithms, neural network architectures, use cases, or training techniques described herein.

In at least one embodiment, one or more neural networks of an inference and/or training logic 315 may be used in conjunction with the system of FIG. 22 and may be configured to receive sensor inputs from multiple sensors and may be trained to infer a coolant requirement. In at least one embodiment, an inference and/or training logic 315 may be able to infer this using information from historical maintenance requirements and of historical sensor inputs. In at least one embodiment, an inference and/or training logic 315 may make an inference of a change in a maintenance requirement. In at least one embodiment, sensor inputs may be correlated to classes of different maintenance requirements of each of different sensor inputs. In at least one embodiment, a new sensor input classifying within a class of such different sensor inputs may indicate a maintenance requirement, or a change thereof.

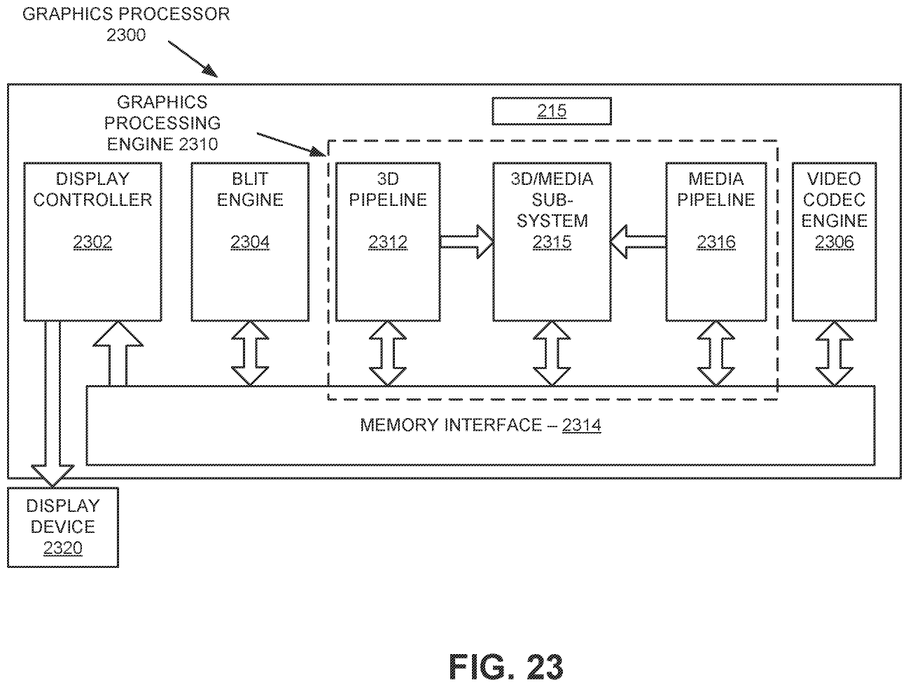

FIG. 23 is a block diagram of a graphics processor 2300, which may be a discrete graphics processing unit, or may be a graphics processor integrated with a plurality of processing cores. In at least one embodiment, graphics processor 2300 communicates via a memory mapped I/O interface to registers on graphics processor 2300 and with commands placed into memory. In at least one embodiment, graphics processor 2300 includes a memory interface 2314 to access memory. In at least one embodiment, memory interface 2314 is an interface to local memory, one or more internal caches, one or more shared external caches, and/or to system memory. In at least one embodiment, graphics processor 2300 includes graphics core 1300.

In at least one embodiment, graphics processor 2300 also includes a display controller 2302 to drive display output data to a display device 2320. In at least one embodiment, display controller 2302 includes hardware for one or more overlay planes for display device 2320 and composition of multiple layers of video or user interface elements. In at least one embodiment, display device 2320 can be an internal or external display device. In at least one embodiment, display device 2320 is a head mounted display device, such as a virtual reality (VR) display device or an augmented reality (AR) display device. In at least one embodiment, graphics processor 2300 includes a video codec engine 2306 to encode, decode, or transcode media to, from, or between one or more media encoding formats, including, but not limited to Moving Picture Experts Group (MPEG) formats such as MPEG-2, Advanced Video Coding (AVC) formats such as H.264/MPEG-4 AVC, as well as the Society of Motion Picture & Television Engineers (SMPTE) 421M/VC-1, and Joint Photographic Experts Group (JPEG) formats such as JPEG, and Motion JPEG (MJPEG) formats.

In at least one embodiment, graphics processor 2300 includes a block image transfer (BLIT) engine 2304 to perform two-dimensional (2D) rasterizer operations including, for example, bit-boundary block transfers. However, in at least one embodiment, 2D graphics operations are performed using one or more components of a graphics processing engine (GPE) 2310. In at least one embodiment, GPE 2310 is a compute engine for performing graphics operations, including three-dimensional (3D) graphics operations and media operations.

In at least one embodiment, GPE 2310 includes a 3D pipeline 2312 for performing 3D operations, such as rendering three-dimensional images and scenes using processing functions that act upon 3D primitive shapes (e.g., rectangle, triangle, etc.). In at least one embodiment, 3D pipeline 2312 includes programmable and fixed function elements that perform various tasks and/or spawn execution threads to a 3D/Media sub-system 2315. While 3D pipeline 2312 can be used to perform media operations, in at least one embodiment, GPE 2310 also includes a media pipeline 2316 that is used to perform media operations, such as video post-processing and image enhancement.

In at least one embodiment, media pipeline 2316 includes fixed function or programmable logic units to perform one or more specialized media operations, such as video decode acceleration, video de-interlacing, and video encode acceleration in place of, or on behalf of, video codec engine 2306. In at least one embodiment, media pipeline 2316 additionally includes a thread spawning unit to spawn threads for execution on 3D/Media sub-system 2315. In at least one embodiment, spawned threads perform computations for media operations on one or more graphics execution units included in 3D/Media sub-system 2315.

In at least one embodiment, 3D/Media subsystem 2315 includes logic for executing threads spawned by 3D pipeline 2312 and media pipeline 2316. In at least one embodiment, 3D pipeline 2312 and media pipeline 2316 send thread execution requests to 3D/Media subsystem 2315, which includes thread dispatch logic for arbitrating and dispatching various requests to available thread execution resources. In at least one embodiment, execution resources include an array of graphics execution units to process 3D and media threads. In at least one embodiment, 3D/Media subsystem 2315 includes one or more internal caches for thread instructions and data. In at least one embodiment, subsystem 2315 also includes shared memory, including registers and addressable memory, to share data between threads and to store output data.

Inference and/or training logic 315 are used to perform inferencing and/or training operations associated with one or more embodiments. Details regarding inference and/or training logic 315 are provided herein in conjunction with FIGS. 3A and/or 3B. In at least one embodiment portions or all of inference and/or training logic 315 may be incorporated into graphics processor 2300. For example, in at least one embodiment, training and/or inferencing techniques described herein may use one or more of ALUs embodied in 3D pipeline 2312. Moreover, in at least one embodiment, inferencing and/or training operations described herein may be done using logic other than logic illustrated in FIG. 3A or 3B. In at least one embodiment, weight parameters may be stored in on-chip or off-chip memory and/or registers (shown or not shown) that configure ALUs of graphics processor 2300 to perform one or more machine learning algorithms, neural network architectures, use cases, or training techniques described herein.

In at least one embodiment, one or more neural networks of an inference and/or training logic 315 may be used in conjunction with the system of FIG. 23 and may be configured to receive sensor inputs from multiple sensors and may be trained to infer a coolant requirement. In at least one embodiment, an inference and/or training logic 315 may be able to infer this using information from historical maintenance requirements and of historical sensor inputs. In at least one embodiment, an inference and/or training logic 315 may make an inference of a change in a maintenance requirement. In at least one embodiment, sensor inputs may be correlated to classes of different maintenance requirements of each of different sensor inputs. In at least one embodiment, a new sensor input classifying within a class of such different sensor inputs may indicate a maintenance requirement, or a change thereof.

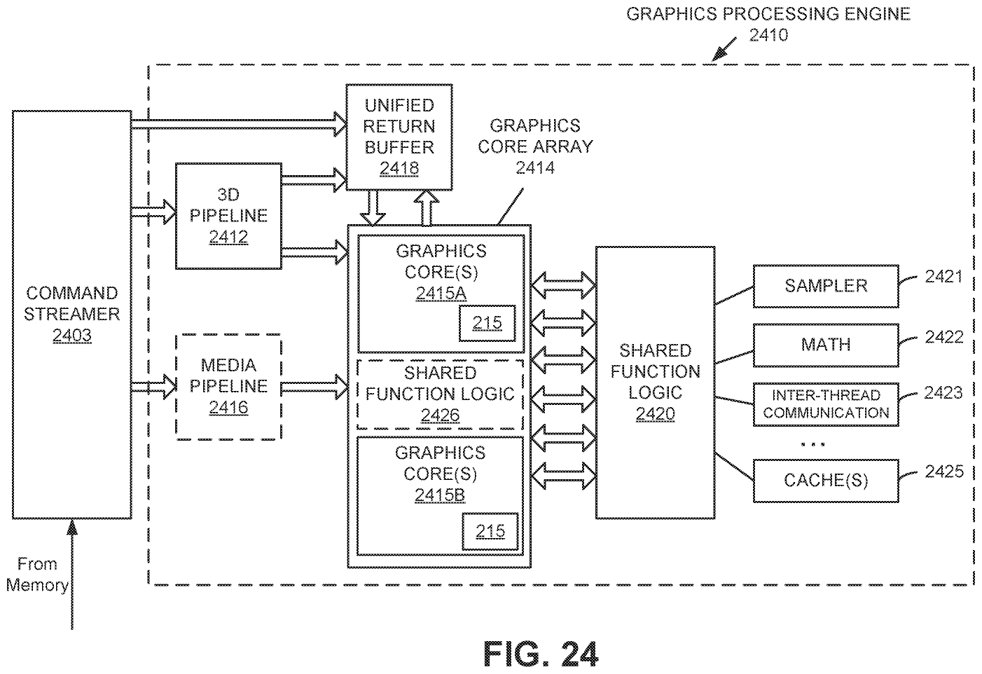

FIG. 24 is a block diagram of a graphics processing engine 2410 of a graphics processor in accordance with at least one embodiment. In at least one embodiment, graphics processing engine (GPE) 2410 is a version of GPE 2310 shown in FIG. 23. In at least one embodiment, a media pipeline 2416 is optional and may not be explicitly included within GPE 2410. In at least one embodiment, a separate media and/or image processor is coupled to GPE 2410.

In at least one embodiment, GPE 2410 is coupled to or includes a command streamer 2403, which provides a command stream to a 3D pipeline 2412 and/or media pipeline 2416. In at least one embodiment, command streamer 2403 is coupled to memory, which can be system memory, or one or more of internal cache memory and shared cache memory. In at least one embodiment, command streamer 2403 receives commands from memory and sends commands to 3D pipeline 2412 and/or media pipeline 2416. In at least one embodiment, commands are instructions, primitives, or micro-operations fetched from a ring buffer, which stores commands for 3D pipeline 2412 and media pipeline 2416. In at least one embodiment, a ring buffer can additionally include batch command buffers storing batches of multiple commands. In at least one embodiment, commands for 3D pipeline 2412 can also include references to data stored in memory, such as, but not limited to, vertex and geometry data for 3D pipeline 2412 and/or image data and memory objects for media pipeline 2416. In at least one embodiment, 3D pipeline 2412 and media pipeline 2416 process commands and data by performing operations or by dispatching one or more execution threads to a graphics core array 2414. In at least one embodiment, graphics core array 2414 includes one or more blocks of graphics cores (e.g., graphics core(s) 2415A, graphics core(s) 2415B), each block including one or more graphics cores. In at least one embodiment, graphics core(s) 2415A, 2415B may be referred to as execution units (“EUs”). In at least one embodiment, each graphics core includes a set of graphics execution resources that includes general-purpose and graphics specific execution logic to perform graphics and compute operations, as well as fixed function texture processing and/or machine learning and artificial intelligence acceleration logic, including inference and/or training logic 315 in FIG. 3A and FIG. 3B.

In at least one embodiment, 3D pipeline 2412 includes fixed function and programmable logic to process one or more shader programs, such as vertex shaders, geometry shaders, pixel shaders, fragment shaders, compute shaders, or other shader programs, by processing instructions and dispatching execution threads to graphics core array 2414. In at least one embodiment, graphics core array 2414 provides a unified block of execution resources for use in processing shader programs. In at least one embodiment, a multi-purpose execution logic (e.g., execution units) within graphics core(s) 2415A-2415B of graphic core array 2414 includes support for various 3D API shader languages and can execute multiple simultaneous execution threads associated with multiple shaders.

In at least one embodiment, graphics core array 2414 also includes execution logic to perform media functions, such as video and/or image processing. In at least one embodiment, execution units additionally include general-purpose logic that is programmable to perform parallel general-purpose computational operations, in addition to graphics processing operations.

In at least one embodiment, output data generated by threads executing on graphics core array 2414 can output data to memory in a unified return buffer (URB) 2418. In at least one embodiment, URB 2418 can store data for multiple threads. In at least one embodiment, URB 2418 may be used to send data between different threads executing on graphics core array 2414. In at least one embodiment, URB 2418 may additionally be used for synchronization between threads on graphics core array 2414 and fixed function logic within shared function logic 2420.

In at least one embodiment, graphics core array 2414 is scalable, such that graphics core array 2414 includes a variable number of graphics cores, each having a variable number of execution units based on a target power and performance level of GPE 2410. In at least one embodiment, execution resources are dynamically scalable, such that execution resources may be enabled or disabled as needed.

In at least one embodiment, graphics core array 2414 is coupled to shared function logic 2420 that includes multiple resources that are shared between graphics cores in graphics core array 2414. In at least one embodiment, shared functions performed by shared function logic 2420 are embodied in hardware logic units that provide specialized supplemental functionality to graphics core array 2414. In at least one embodiment, shared function logic 2420 includes but is not limited to a sampler unit 2421, a math unit 2422, and inter-thread communication (ITC) logic 2423. In at least one embodiment, one or more cache(s) 2425 are included in, or coupled to, shared function logic 2420.

In at least one embodiment, a shared function is used if demand for a specialized function is insufficient for inclusion within graphics core array 2414. In at least one embodiment, a single instantiation of a specialized function is used in shared function logic 2420 and shared among other execution resources within graphics core array 2414. In at least one embodiment, specific shared functions within shared function logic 2420 that are used extensively by graphics core array 2414 may be included within shared function logic 2426 within graphics core array 2414. In at least one embodiment, shared function logic 2426 within graphics core array 2414 can include some or all logic within shared function logic 2420. In at least one embodiment, all logic elements within shared function logic 2420 may be duplicated within shared function logic 2426 of graphics core array 2414. In at least one embodiment, shared function logic 2420 is excluded in favor of shared function logic 2426 within graphics core array 2414.

Inference and/or training logic 315 are used to perform inferencing and/or training operations associated with one or more embodiments. Details regarding inference and/or training logic 315 are provided herein in conjunction with FIGS. 3A and/or 3B. In at least one embodiment portions or all of inference and/or training logic 315 may be incorporated into graphics processor 2410. For example, in at least one embodiment, training and/or inferencing techniques described herein may use one or more of ALUs embodied in 3D pipeline 2412, graphics core(s) 2415, shared function logic 2426, shared function logic 2420, or other logic in FIG. 24. Moreover, in at least one embodiment, inferencing and/or training operations described herein may be done using logic other than logic illustrated in FIG. 3A or 3B. In at least one embodiment, weight parameters may be stored in on-chip or off-chip memory and/or registers (shown or not shown) that configure ALUs of graphics processor 2410 to perform one or more machine learning algorithms, neural network architectures, use cases, or training techniques described herein.

In at least one embodiment, one or more neural networks of an inference and/or training logic 315 may be used in conjunction with the system of FIG. 24 and may be configured to receive sensor inputs from multiple sensors and may be trained to infer a coolant requirement. In at least one embodiment, an inference and/or training logic 315 may be able to infer this using information from historical maintenance requirements and of historical sensor inputs. In at least one embodiment, an inference and/or training logic 315 may make an inference of a change in a maintenance requirement. In at least one embodiment, sensor inputs may be correlated to classes of different maintenance requirements of each of different sensor inputs. In at least one embodiment, a new sensor input classifying within a class of such different sensor inputs may indicate a maintenance requirement, or a change thereof.

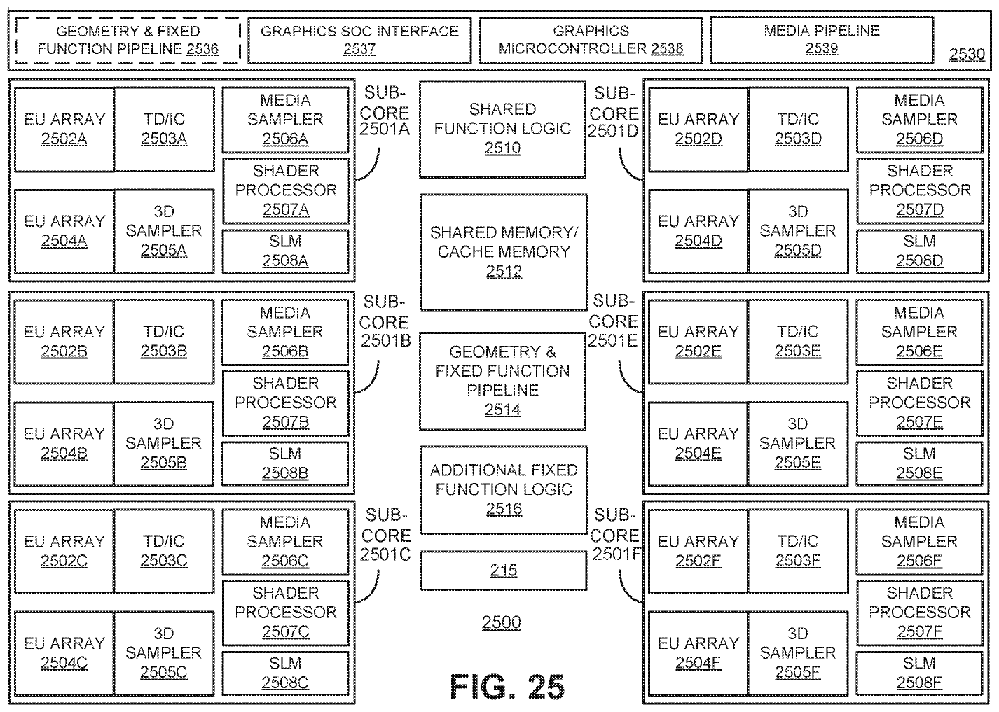

FIG. 25 is a block diagram of hardware logic of a graphics processor core 2500, according to at least one embodiment described herein. In at least one embodiment, graphics processor core 2500 includes graphics core 1300. In at least one embodiment, graphics processor core 2500 is included within a graphics core array. In at least one embodiment, graphics processor core 2500, sometimes referred to as a core slice, can be one or multiple graphics cores within a modular graphics processor. In at least one embodiment, graphics processor core 2500 is exemplary of one graphics core slice, and a graphics processor as described herein may include multiple graphics core slices based on target power and performance envelopes. In at least one embodiment, each graphics core 2500 can include a fixed function block 2530 coupled with multiple sub-cores 2501A-2501F, also referred to as sub-slices, that include modular blocks of general-purpose and fixed function logic.

In at least one embodiment, fixed function block 2530 includes a geometry and fixed function pipeline 2536 that can be shared by all sub-cores in graphics processor 2500, for example, in lower performance and/or lower power graphics processor implementations. In at least one embodiment, geometry and fixed function pipeline 2536 includes a 3D fixed function pipeline, a video front-end unit, a thread spawner and thread dispatcher, and a unified return buffer manager, which manages unified return buffers.

In at least one embodiment, fixed function block 2530 also includes a graphics SoC interface 2537, a graphics microcontroller 2538, and a media pipeline 2539. In at least one embodiment, graphics SoC interface 2537 provides an interface between graphics core 2500 and other processor cores within a system on a chip integrated circuit. In at least one embodiment, graphics microcontroller 2538 is a programmable sub-processor that is configurable to manage various functions of graphics processor 2500, including thread dispatch, scheduling, and pre-emption. In at least one embodiment, media pipeline 2539 includes logic to facilitate decoding, encoding, pre-processing, and/or post-processing of multimedia data, including image and video data. In at least one embodiment, media pipeline 2539 implements media operations via requests to compute or sampling logic within sub-cores 2501A-2501F.

In at least one embodiment, SoC interface 2537 enables graphics core 2500 to communicate with general-purpose application processor cores (e.g., CPUs) and/or other components within an SoC, including memory hierarchy elements such as a shared last level cache memory, system RAM, and/or embedded on-chip or on-package DRAM. In at least one embodiment, SoC interface 2537 can also enable communication with fixed function devices within an SoC, such as camera imaging pipelines, and enables use of and/or implements global memory atomics that may be shared between graphics core 2500 and CPUs within an SoC. In at least one embodiment, graphics SoC interface 2537 can also implement power management controls for graphics processor core 2500 and enable an interface between a clock domain of graphics processor core 2500 and other clock domains within an SoC. In at least one embodiment, SoC interface 2537 enables receipt of command buffers from a command streamer and global thread dispatcher that are configured to provide commands and instructions to each of one or more graphics cores within a graphics processor. In at least one embodiment, commands and instructions can be dispatched to media pipeline 2539, when media operations are to be performed, or a geometry and fixed function pipeline (e.g., geometry and fixed function pipeline 2536, and/or a geometry and fixed function pipeline 2514) when graphics processing operations are to be performed.

In at least one embodiment, graphics microcontroller 2538 can be configured to perform various scheduling and management tasks for graphics core 2500. In at least one embodiment, graphics microcontroller 2538 can perform graphics and/or compute workload scheduling on various graphics parallel engines within execution unit (EU) arrays 2502A-2502F, 2504A-2504F within sub-cores 2501A-2501F. In at least one embodiment, host software executing on a CPU core of an SoC including graphics core 2500 can submit workloads to one of multiple graphic processor paths, which invokes a scheduling operation on an appropriate graphics engine. In at least one embodiment, scheduling operations include determining which workload to run next, submitting a workload to a command streamer, pre-empting existing workloads running on an engine, monitoring progress of a workload, and notifying host software when a workload is complete. In at least one embodiment, graphics microcontroller 2538 can also facilitate low-power or idle states for graphics core 2500, providing graphics core 2500 with an ability to save and restore registers within graphics core 2500 across low-power state transitions independently from an operating system and/or graphics driver software on a system.

In at least one embodiment, graphics core 2500 may have greater than or fewer than illustrated sub-cores 2501A-2501F, up to N modular sub-cores. For each set of N sub-cores, in at least one embodiment, graphics core 2500 can also include shared function logic 2510, shared and/or cache memory 2512, geometry/fixed function pipeline 2514, as well as additional fixed function logic 2516 to accelerate various graphics and compute processing operations. In at least one embodiment, shared function logic 2510 can include logic units (e.g., sampler, math, and/or inter-thread communication logic) that can be shared by each N sub-cores within graphics core 2500. In at least one embodiment, shared and/or cache memory 2512 can be a last-level cache for N sub-cores 2501A-2501F within graphics core 2500 and can also serve as shared memory that is accessible by multiple sub-cores. In at least one embodiment, geometry/fixed function pipeline 2514 can be included instead of geometry/fixed function pipeline 2536 within fixed function block 2530 and can include similar logic units.

In at least one embodiment, graphics core 2500 includes additional fixed function logic 2516 that can include various fixed function acceleration logic for use by graphics core 2500. In at least one embodiment, additional fixed function logic 2516 includes an additional geometry pipeline for use in position-only shading. In position-only shading, at least two geometry pipelines exist, whereas in a full geometry pipeline within geometry and fixed function pipelines 2514, 2536, and a cull pipeline, which is an additional geometry pipeline that may be included within additional fixed function logic 2516. In at least one embodiment, a cull pipeline is a trimmed down version of a full geometry pipeline. In at least one embodiment, a full pipeline and a cull pipeline can execute different instances of an application, each instance having a separate context. In at least one embodiment, position only shading can hide long cull runs of discarded triangles, enabling shading to be completed earlier in some instances. For example, in at least one embodiment, cull pipeline logic within additional fixed function logic 2516 can execute position shaders in parallel with a main application and generally generates critical results faster than a full pipeline, as a cull pipeline fetches and shades position attributes of vertices, without performing rasterization and rendering of pixels to a frame buffer. In at least one embodiment, a cull pipeline can use generated critical results to compute visibility information for all triangles without regard to whether those triangles are culled. In at least one embodiment, a full pipeline (which in this instance may be referred to as a replay pipeline) can consume visibility information to skip culled triangles to shade only visible triangles that are finally passed to a rasterization phase.

In at least one embodiment, additional fixed function logic 2516 can also include machine-learning acceleration logic, such as fixed function matrix multiplication logic, for implementations including optimizations for machine learning training or inferencing.

In at least one embodiment, within each graphics sub-core 2501A-2501F includes a set of execution resources that may be used to perform graphics, media, and compute operations in response to requests by graphics pipeline, media pipeline, or shader programs. In at least one embodiment, graphics sub-cores 2501A-2501F include multiple EU arrays 2502A-2502F, 2504A-2504F, thread dispatch and inter-thread communication (TD/IC) logic 2503A-2503F, a 3D (e.g., texture) sampler 2505A-2505F, a media sampler 2506A-2506F, a shader processor 2507A-2507F, and shared local memory (SLM) 2508A-2508F. In at least one embodiment, EU arrays 2502A-2502F, 2504A-2504F each include multiple execution units, which are general-purpose graphics processing units capable of performing floating-point and integer/fixed-point logic operations in service of a graphics, media, or compute operation, including graphics, media, or compute shader programs. In at least one embodiment, TD/IC logic 2503A-2503F performs local thread dispatch and thread control operations for execution units within a sub-core and facilitates communication between threads executing on execution units of a sub-core. In at least one embodiment, 3D samplers 2505A-2505F can read texture or other 3D graphics related data into memory. In at least one embodiment, 3D samplers can read texture data differently based on a configured sample state and texture format associated with a given texture. In at least one embodiment, media samplers 2506A-2506F can perform similar read operations based on a type and format associated with media data. In at least one embodiment, each graphics sub-core 2501A-2501F can alternately include a unified 3D and media sampler. In at least one embodiment, threads executing on execution units within each of sub-cores 2501A-2501F can make use of shared local memory 2508A-2508F within each sub-core, to enable threads executing within a thread group to execute using a common pool of on-chip memory.

Inference and/or training logic 315 are used to perform inferencing and/or training operations associated with one or more embodiments. Details regarding inference and/or training logic 315 are provided herein in conjunction with FIGS. 3A and/or 3B. In at least one embodiment, portions or all of inference and/or training logic 315 may be incorporated into graphics processor 2500. For example, in at least one embodiment, training and/or inferencing techniques described herein may use one or more of ALUs embodied in a 3D pipeline, graphics microcontroller 2538, geometry and fixed function pipeline 2514 and 2536, or other logic in FIG. 25. Moreover, in at least one embodiment, inferencing and/or training operations described herein may be done using logic other than logic illustrated in FIG. 3A or 3B. In at least one embodiment, weight parameters may be stored in on-chip or off-chip memory and/or registers (shown or not shown) that configure ALUs of graphics processor 2500 to perform one or more machine learning algorithms, neural network architectures, use cases, or training techniques described herein.

In at least one embodiment, one or more neural networks of an inference and/or training logic 315 may be used in conjunction with the system of FIG. 25 and may be configured to receive sensor inputs from multiple sensors and may be trained to infer a coolant requirement. In at least one embodiment, an inference and/or training logic 315 may be able to infer this using information from historical maintenance requirements and of historical sensor inputs. In at least one embodiment, an inference and/or training logic 315 may make an inference of a change in a maintenance requirement. In at least one embodiment, sensor inputs may be correlated to classes of different maintenance requirements of each of different sensor inputs. In at least one embodiment, a new sensor input classifying within a class of such different sensor inputs may indicate a maintenance requirement, or a change thereof.

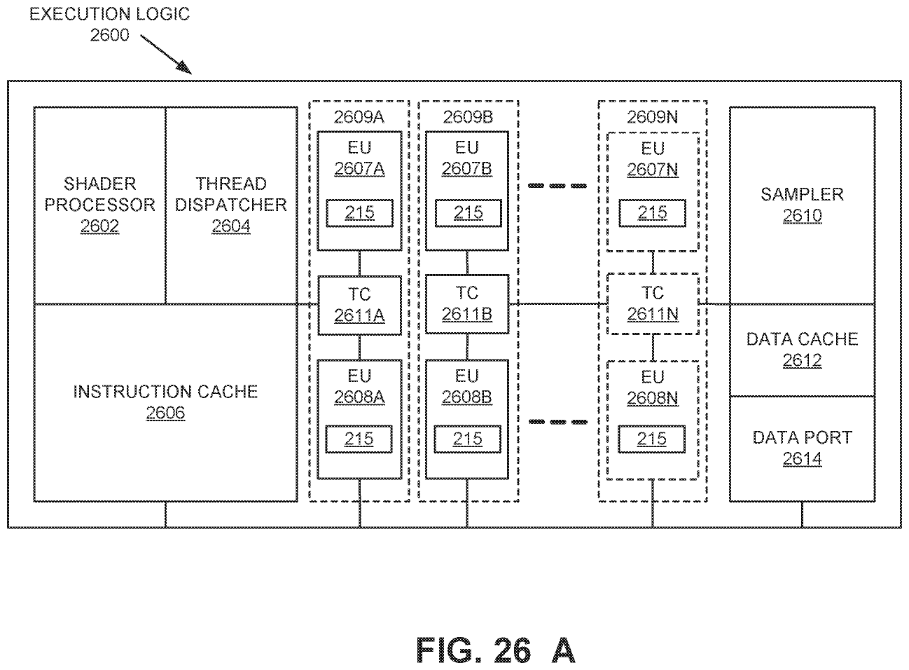

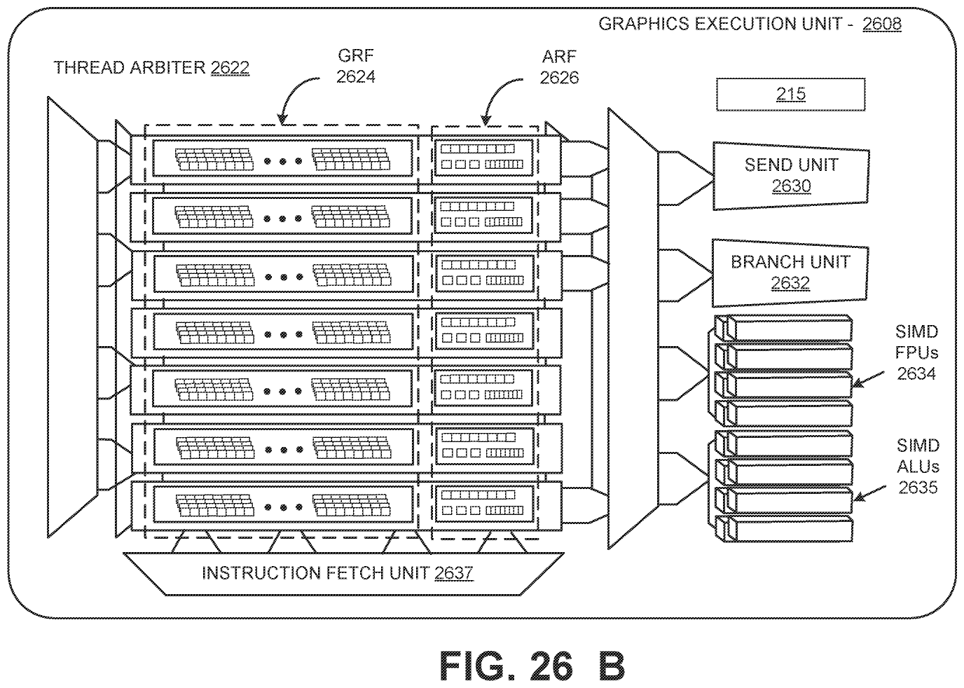

FIGS. 26A-26B illustrate thread execution logic 2600 including an array of processing elements of a graphics processor core according to at least one embodiment. FIG. 26A illustrates at least one embodiment, in which thread execution logic 2600 is used. FIG. 26B illustrates exemplary internal details of a graphics execution unit 2608, according to at least one embodiment.

As illustrated in FIG. 26A, in at least one embodiment, thread execution logic 2600 includes a shader processor 2602, a thread dispatcher 2604, an instruction cache 2606, a scalable execution unit array including a plurality of execution units 2607A-2607N and 2608A-2608N, a sampler 2610, a data cache 2612, and a data port 2614. In at least one embodiment, a scalable execution unit array can dynamically scale by enabling or disabling one or more execution units (e.g., any of execution unit 2608A-N or 2607A-N) based on computational requirements of a workload, for example. In at least one embodiment, scalable execution units are interconnected via an interconnect fabric that links to each execution unit. In at least one embodiment, thread execution logic 2600 includes one or more connections to memory, such as system memory or cache memory, through one or more of instruction cache 2606, data port 2614, sampler 2610, and execution units 2607 or 2608. In at least one embodiment, each execution unit (e.g., 2607A) is a stand-alone programmable general-purpose computational unit that is capable of executing multiple simultaneous hardware threads while processing multiple data elements in parallel for each thread. In at least one embodiment, array of execution units 2607 and/or 2608 is scalable to include any number individual execution units.

In at least one embodiment, execution units 2607 and/or 2608 are primarily used to execute shader programs. In at least one embodiment, shader processor 2602 can process various shader programs and dispatch execution threads associated with shader programs via a thread dispatcher 2604. In at least one embodiment, thread dispatcher 2604 includes logic to arbitrate thread initiation requests from graphics and media pipelines and instantiate requested threads on one or more execution units in execution units 2607 and/or 2608. For example, in at least one embodiment, a geometry pipeline can dispatch vertex, tessellation, or geometry shaders to thread execution logic for processing. In at least one embodiment, thread dispatcher 2604 can also process runtime thread spawning requests from executing shader programs.

In at least one embodiment, execution units 2607 and/or 2608 support an instruction set that includes native support for many standard 3D graphics shader instructions, such that shader programs from graphics libraries (e.g., Direct 3D and OpenGL) are executed with a minimal translation. In at least one embodiment, execution units support vertex and geometry processing (e.g., vertex programs, geometry programs, and/or vertex shaders), pixel processing (e.g., pixel shaders, fragment shaders) and general-purpose processing (e.g., compute and media shaders). In at least one embodiment, each of execution units 2607 and/or 2608, which include one or more arithmetic logic units (ALUs), is capable of multi-issue single instruction multiple data (SIMD) execution and multi-threaded operation enables an efficient execution environment despite higher latency memory accesses. In at least one embodiment, each hardware thread within each execution unit has a dedicated high-bandwidth register file and associated independent thread-state. In at least one embodiment, execution is multi-issue per clock to pipelines capable of integer, single and double precision floating point operations, SIMD branch capability, logical operations, transcendental operations, and other miscellaneous operations. In at least one embodiment, while waiting for data from memory or one of shared functions, dependency logic within execution units 2607 and/or 2608 causes a waiting thread to sleep until requested data has been returned. In at least one embodiment, while an awaiting thread is sleeping, hardware resources may be devoted to processing other threads. For example, in at least one embodiment, during a delay associated with a vertex shader operation, an execution unit can perform operations for a pixel shader, fragment shader, or another type of shader program, including a different vertex shader.

In at least one embodiment, each execution unit in execution units 2607 and/or 2608 operates on arrays of data elements. In at least one embodiment, a number of data elements is an “execution size,” or number of channels for an instruction. In at least one embodiment, an execution channel is a logical unit of execution for data element access, masking, and flow control within instructions. In at least one embodiment, a number of channels may be independent of a number of physical arithmetic logic units (ALUs) or floating point units (FPUs) for a particular graphics processor. In at least one embodiment, execution units 2607 and/or 2608 support integer and floating-point data types.

In at least one embodiment, an execution unit instruction set includes SIMD instructions. In at least one embodiment, various data elements can be stored as a packed data type in a register and execution unit will process various elements based on data size of elements. For example, in at least one embodiment, when operating on a 256-bit wide vector, 256 bits of a vector are stored in a register and an execution unit operates on a vector as four separate 64-bit packed data elements (Quad-Word (QW) size data elements), eight separate 32-bit packed data elements (Double Word (DW) size data elements), sixteen separate 16-bit packed data elements (Word (W) size data elements), or thirty-two separate 8-bit data elements (byte (B) size data elements). However, in at least one embodiment, different vector widths and register sizes are possible.

In at least one embodiment, one or more execution units can be combined into a fused execution unit 2609A-2609N having thread control logic (2611A-2611N) that is common to fused EUs such as execution unit 2607A fused with execution unit 2608A into fused execution unit 2609A. In at least one embodiment, multiple EUs can be fused into an EU group. In at least one embodiment, each EU in a fused EU group can be configured to execute a separate SIMD hardware thread, with a number of EUs in a fused EU group possibly varying according to various embodiments. In at least one embodiment, various SIMD widths can be performed per-EU, including but not limited to SIMD8, SIMD16, and SIMD32. In at least one embodiment, each fused graphics execution unit 2609A-2609N includes at least two execution units. For example, in at least one embodiment, fused execution unit 2609A includes a first EU 2607A, second EU 2608A, and thread control logic 2611A that is common to first EU 2607A and second EU 2608A. In at least one embodiment, thread control logic 2611A controls threads executed on fused graphics execution unit 2609A, allowing each EU within fused execution units 2609A-2609N to execute using a common instruction pointer register.

In at least one embodiment, one or more internal instruction caches (e.g., 2606) are included in thread execution logic 2600 to cache thread instructions for execution units. In at least one embodiment, one or more data caches (e.g., 2612) are included to cache thread data during thread execution. In at least one embodiment, sampler 2610 is included to provide texture sampling for 3D operations and media sampling for media operations. In at least one embodiment, sampler 2610 includes specialized texture or media sampling functionality to process texture or media data during sampling process before providing sampled data to an execution unit.

During execution, in at least one embodiment, graphics and media pipelines send thread initiation requests to thread execution logic 2600 via thread spawning and dispatch logic. In at least one embodiment, once a group of geometric objects has been processed and rasterized into pixel data, pixel processor logic (e.g., pixel shader logic, fragment shader logic, etc.) within shader processor 2602 is invoked to further compute output information and cause results to be written to output surfaces (e.g., color buffers, depth buffers, stencil buffers, etc.). In at least one embodiment, a pixel shader or a fragment shader calculates values of various vertex attributes that are to be interpolated across a rasterized object. In at least one embodiment, pixel processor logic within shader processor 2602 then executes an application programming interface (API)-supplied pixel or fragment shader program. In at least one embodiment, to execute a shader program, shader processor 2602 dispatches threads to an execution unit (e.g., 2608A) via thread dispatcher 2604. In at least one embodiment, shader processor 2602 uses texture sampling logic in sampler 2610 to access texture data in texture maps stored in memory. In at least one embodiment, arithmetic operations on texture data and input geometry data compute pixel color data for each geometric fragment, or discards one or more pixels from further processing.

In at least one embodiment, data port 2614 provides a memory access mechanism for thread execution logic 2600 to output processed data to memory for further processing on a graphics processor output pipeline. In at least one embodiment, data port 2614 includes or couples to one or more cache memories (e.g., data cache 2612) to cache data for memory access via a data port.

As illustrated in FIG. 26B, in at least one embodiment, a graphics execution unit 2608 can include an instruction fetch unit 2637, a general register file array (GRF) 2624, an architectural register file array (ARF) 2626, a thread arbiter 2622, a send unit 2630, a branch unit 2632, a set of SIMD floating point units (FPUs) 2634, and a set of dedicated integer SIMD ALUs 2635. In at least one embodiment, GRF 2624 and ARF 2626 includes a set of general register files and architecture register files associated with each simultaneous hardware thread that may be active in graphics execution unit 2608. In at least one embodiment, per thread architectural state is maintained in ARF 2626, while data used during thread execution is stored in GRF 2624. In at least one embodiment, execution state of each thread, including instruction pointers for each thread, can be held in thread-specific registers in ARF 2626.

In at least one embodiment, graphics execution unit 2608 has an architecture that is a combination of Simultaneous Multi-Threading (SMT) and fine-grained Interleaved Multi-Threading (IMT). In at least one embodiment, architecture has a modular configuration that can be fine-tuned at design time based on a target number of simultaneous threads and number of registers per execution unit, where execution unit resources are divided across logic used to execute multiple simultaneous threads.

In at least one embodiment, graphics execution unit 2608 can co-issue multiple instructions, which may each be different instructions. In at least one embodiment, thread arbiter 2622 of graphics execution unit thread 2608 can dispatch instructions to one of send unit 2630, branch unit 2632, or SIMD FPU(s) 2634 for execution. In at least one embodiment, each execution thread can access 128 general-purpose registers within GRF 2624, where each register can store 32 bytes, accessible as a SIMD 8-element vector of 32-bit data elements. In at least one embodiment, each execution unit thread has access to 4 kilobytes within GRF 2624, although embodiments are not so limited, and greater or fewer register resources may be provided in other embodiments. In at least one embodiment, up to seven threads can execute simultaneously, although a number of threads per execution unit can also vary according to embodiments. In at least one embodiment, in which seven threads may access 4 kilobytes, GRF 2624 can store a total of 28 kilobytes. In at least one embodiment, flexible addressing modes can permit registers to be addressed together to build effectively wider registers or to represent strided rectangular block data structures.

In at least one embodiment, memory operations, sampler operations, and other longer-latency system communications are dispatched via “send” instructions that are executed by message passing to send unit 2630. In at least one embodiment, branch instructions are dispatched to branch unit 2632 to facilitate SIMD divergence and eventual convergence.

In at least one embodiment, graphics execution unit 2608 includes one or more SIMD floating point units (FPU(s)) 2634 to perform floating-point operations. In at least one embodiment, FPU(s) 2634 also support integer computation. In at least one embodiment, FPU(s) 2634 can SIMD execute up to M number of 32-bit floating-point (or integer) operations, or SIMD execute up to 2M 16-bit integer or 16-bit floating-point operations. In at least one embodiment, at least one FPU provides extended math capability to support high-throughput transcendental math functions and double precision 64-bit floating-point. In at least one embodiment, a set of 8-bit integer SIMD ALUs 2635 are also present, and may be specifically optimized to perform operations associated with machine learning computations.

In at least one embodiment, arrays of multiple instances of graphics execution unit 2608 can be instantiated in a graphics sub-core grouping (e.g., a sub-slice). In at least one embodiment, execution unit 2608 can execute instructions across a plurality of execution channels. In at least one embodiment, each thread executed on graphics execution unit 2608 is executed on a different channel.

Inference and/or training logic 315 are used to perform inferencing and/or training operations associated with one or more embodiments. Details regarding inference and/or training logic 315 are provided herein in conjunction with FIGS. 3A and/or 3B. In at least one embodiment, portions or all of inference and/or training logic 315 may be incorporated into thread execution logic 2600. Moreover, in at least one embodiment, inferencing and/or training operations described herein may be done using logic other than logic illustrated in FIG. 3A or 3B. In at least one embodiment, weight parameters may be stored in on-chip or off-chip memory and/or registers (shown or not shown) that configure ALUs thread of execution logic 2600 to perform one or more machine learning algorithms, neural network architectures, use cases, or training techniques described herein.

In at least one embodiment, one or more neural networks of an inference and/or training logic 315 may be used in conjunction with the system of FIG. 26A-B and may be configured to receive sensor inputs from multiple sensors and may be trained to infer a coolant requirement. In at least one embodiment, an inference and/or training logic 315 may be able to infer this using information from historical maintenance requirements and of historical sensor inputs. In at least one embodiment, an inference and/or training logic 315 may make an inference of a change in a maintenance requirement. In at least one embodiment, sensor inputs may be correlated to classes of different maintenance requirements of each of different sensor inputs. In at least one embodiment, a new sensor input classifying within a class of such different sensor inputs may indicate a maintenance requirement, or a change thereof.

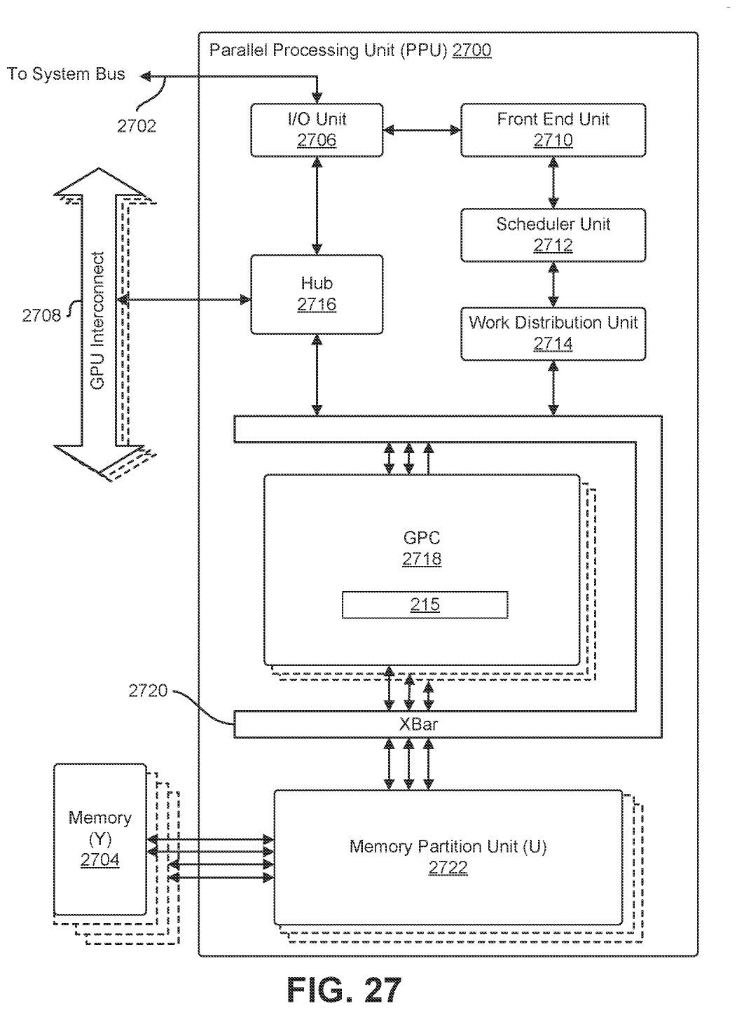

FIG. 27 illustrates a parallel processing unit (“PPU”) 2700, according to at least one embodiment. In at least one embodiment, PPU 2700 is configured with machine-readable code that, if executed by PPU 2700, causes PPU 2700 to perform some or all of processes and techniques described throughout this disclosure. In at least one embodiment, PPU 2700 is a multi-threaded processor that is implemented on one or more integrated circuit devices and that utilizes multithreading as a latency-hiding technique designed to process computer-readable instructions (also referred to as machine-readable instructions or simply instructions) on multiple threads in parallel. In at least one embodiment, PPU 2700 includes one or more graphics cores 1300 In at least one embodiment, a thread refers to a thread of execution and is an instantiation of a set of instructions configured to be executed by PPU 2700. In at least one embodiment, PPU 2700 is a graphics processing unit (“GPU”) configured to implement a graphics rendering pipeline for processing three-dimensional (“3D”) graphics data in order to generate two-dimensional (“2D”) image data for display on a display device such as a liquid crystal display (“LCD”) device. In at least one embodiment, PPU 2700 is utilized to perform computations such as linear algebra operations and machine-learning operations. FIG. 27 illustrates an example parallel processor for illustrative purposes only and should be construed as a non-limiting example of processor architectures contemplated within scope of this disclosure and that any suitable processor may be employed to supplement and/or substitute for same.

In at least one embodiment, one or more PPUs 2700 are configured to accelerate High Performance Computing (“HPC”), data center, and machine learning applications. In at least one embodiment, PPU 2700 is configured to accelerate deep learning systems and applications including following non-limiting examples: autonomous vehicle platforms, deep learning, high-accuracy speech, image, text recognition systems, intelligent video analytics, molecular simulations, drug discovery, disease diagnosis, weather forecasting, big data analytics, astronomy, molecular dynamics simulation, financial modeling, robotics, factory automation, real-time language translation, online search optimizations, and personalized user recommendations, and more.

In at least one embodiment, PPU 2700 includes, without limitation, an Input/Output (“I/O”) unit 2706, a front-end unit 2710, a scheduler (sequencer) unit 2712, a work distribution unit 2714, a hub 2716, a crossbar (“XBar”) 2720, one or more general processing clusters (“GPCs”) 2718, and one or more partition units (“memory partition units”) 2722. In at least one embodiment, PPU 2700 is connected to a host processor or other PPUs 2700 via one or more high-speed GPU interconnects (“GPU interconnects”) 2708. In at least one embodiment, PPU 2700 is connected to a host processor or other peripheral devices via a system bus 2702. In at least one embodiment, PPU 2700 is connected to a local memory comprising one or more memory devices (“memory”) 2704. In at least one embodiment, memory devices 2704 include, without limitation, one or more dynamic random access memory (“DRAM”) devices. In at least one embodiment, one or more DRAM devices are configured and/or configurable as high-bandwidth memory (“HBM”) subsystems, with multiple DRAM dies stacked within each device.

In at least one embodiment, high-speed GPU interconnect 2708 may refer to a wire-based multi-lane communications link that is used by systems to scale and include one or more PPUs 2700 combined with one or more central processing units (“CPUs”), supports cache coherence between PPUs 2700 and CPUs, and CPU mastering. In at least one embodiment, data and/or commands are transmitted by high-speed GPU interconnect 2708 through hub 2716 to/from other units of PPU 2700 such as one or more copy engines, video encoders, video decoders, power management units, and other components which may not be explicitly illustrated in FIG. 27.

In at least one embodiment, I/O unit 2706 is configured to transmit and receive communications (e.g., commands, data) from a host processor (not illustrated in FIG. 27) over system bus 2702. In at least one embodiment, I/O unit 2706 communicates with host processor directly via system bus 2702 or through one or more intermediate devices such as a memory bridge. In at least one embodiment, I/O unit 2706 may communicate with one or more other processors, such as one or more of PPUs 2700 via system bus 2702. In at least one embodiment, I/O unit 2706 implements a Peripheral Component Interconnect Express (“PCIe”) interface for communications over a PCIe bus. In at least one embodiment, I/O unit 2706 implements interfaces for communicating with external devices.

In at least one embodiment, I/O unit 2706 decodes packets received via system bus 2702. In at least one embodiment, at least some packets represent commands configured to cause PPU 2700 to perform various operations. In at least one embodiment, I/O unit 2706 transmits decoded commands to various other units of PPU 2700 as specified by commands. In at least one embodiment, commands are transmitted to front-end unit 2710 and/or transmitted to hub 2716 or other units of PPU 2700 such as one or more copy engines, a video encoder, a video decoder, a power management unit, etc. (not explicitly illustrated in FIG. 27). In at least one embodiment, I/O unit 2706 is configured to route communications between and among various logical units of PPU 2700.

In at least one embodiment, a program executed by host processor encodes a command stream in a buffer that provides workloads to PPU 2700 for processing. In at least one embodiment, a workload comprises instructions and data to be processed by those instructions. In at least one embodiment, a buffer is a region in a memory that is accessible (e.g., read/write) by both a host processor and PPU 2700—a host interface unit may be configured to access that buffer in a system memory connected to system bus 2702 via memory requests transmitted over system bus 2702 by I/O unit 2706. In at least one embodiment, a host processor writes a command stream to a buffer and then transmits a pointer to a start of a command stream to PPU 2700 such that front-end unit 2710 receives pointers to one or more command streams and manages one or more command streams, reading commands from command streams and forwarding commands to various units of PPU 2700.

In at least one embodiment, front-end unit 2710 is coupled to scheduler unit 2712 (which may be referred to as a sequencer unit, a thread sequencer, and/or an asynchronous compute engine) that configures various GPCs 2718 to process tasks defined by one or more command streams. In at least one embodiment, scheduler unit 2712 is configured to track state information related to various tasks managed by scheduler unit 2712 where state information may indicate which of GPCs 2718 a task is assigned to, whether task is active or inactive, a priority level associated with task, and so forth. In at least one embodiment, scheduler unit 2712 manages execution of a plurality of tasks on one or more of GPCs 2718.

In at least one embodiment, scheduler unit 2712 is coupled to work distribution unit 2714 that is configured to dispatch tasks for execution on GPCs 2718. In at least one embodiment, work distribution unit 2714 tracks a number of scheduled tasks received from scheduler unit 2712 and work distribution unit 2714 manages a pending task pool and an active task pool for each of GPCs 2718. In at least one embodiment, pending task pool comprises a number of slots (e.g., 32 slots) that contain tasks assigned to be processed by a particular GPC 2718; an active task pool may comprise a number of slots (e.g., 4 slots) for tasks that are actively being processed by GPCs 2718 such that as one of GPCs 2718 completes execution of a task, that task is evicted from that active task pool for GPC 2718 and another task from a pending task pool is selected and scheduled for execution on GPC 2718. In at least one embodiment, if an active task is idle on GPC 2718, such as while waiting for a data dependency to be resolved, then that active task is evicted from GPC 2718 and returned to that pending task pool while another task in that pending task pool is selected and scheduled for execution on GPC 2718.

In at least one embodiment, work distribution unit 2714 communicates with one or more GPCs 2718 via XBar 2720. In at least one embodiment, XBar 2720 is an interconnect network that couples many of units of PPU 2700 to other units of PPU 2700 and can be configured to couple work distribution unit 2714 to a particular GPC 2718. In at least one embodiment, one or more other units of PPU 2700 may also be connected to XBar 2720 via hub 2716.

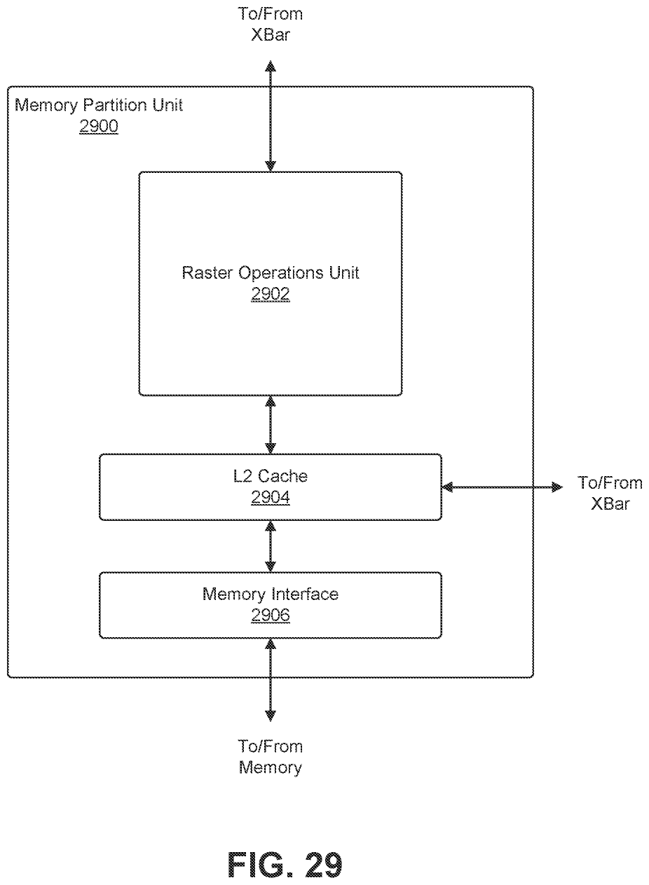

In at least one embodiment, tasks are managed by scheduler unit 2712 and dispatched to one of GPCs 2718 by work distribution unit 2714. In at least one embodiment, GPC 2718 is configured to process task and generate results. In at least one embodiment, results may be consumed by other tasks within GPC 2718, routed to a different GPC 2718 via XBar 2720, or stored in memory 2704. In at least one embodiment, results can be written to memory 2704 via partition units 2722, which implement a memory interface for reading and writing data to/from memory 2704. In at least one embodiment, results can be transmitted to another PPU or CPU via high-speed GPU interconnect 2708. In at least one embodiment, PPU 2700 includes, without limitation, a number U of partition units 2722 that is equal to a number of separate and distinct memory devices 2704 coupled to PPU 2700, as described in more detail herein in conjunction with FIG. 29.

In at least one embodiment, a host processor executes a driver kernel that implements an application programming interface (“API”) that enables one or more applications executing on a host processor to schedule operations for execution on PPU 2700. In at least one embodiment, multiple compute applications are simultaneously executed by PPU 2700 and PPU 2700 provides isolation, quality of service (“QoS”), and independent address spaces for multiple compute applications. In at least one embodiment, an application generates instructions (e.g., in form of API calls) that cause a driver kernel to generate one or more tasks for execution by PPU 2700 and that driver kernel outputs tasks to one or more streams being processed by PPU 2700. In at least one embodiment, each task comprises one or more groups of related threads, which may be referred to as a warp, wavefront, and/or wave. In at least one embodiment, a warp, wavefront, and/or wave comprises a plurality of related threads (e.g., 32 threads) that can be executed in parallel. In at least one embodiment, cooperating threads can refer to a plurality of threads including instructions to perform task and that exchange data through shared memory. In at least one embodiment, threads and cooperating threads are described in more detail in conjunction with FIG. 29.

Inference and/or training logic 315 are used to perform inferencing and/or training operations associated with one or more embodiments. Details regarding inference and/or training logic 315 are provided herein in conjunction with FIGS. 3A and/or 3B. In at least one embodiment, deep learning application processor is used to train a machine learning model, such as a neural network, to predict or infer information provided to PPU 2700. In at least one embodiment, deep learning application processor is used to infer or predict information based on a trained machine learning model (e.g., neural network) that has been trained by another processor or system or by PPU 2700. In at least one embodiment, PPU 2700 may be used to perform one or more neural network use cases described herein.

In at least one embodiment, one or more neural networks of an inference and/or training logic 315 may be used in conjunction with the system of FIG. 27 and may be configured to receive sensor inputs from multiple sensors and may be trained to infer a coolant requirement. In at least one embodiment, an inference and/or training logic 315 may be able to infer this using information from historical maintenance requirements and of historical sensor inputs. In at least one embodiment, an inference and/or training logic 315 may make an inference of a change in a maintenance requirement. In at least one embodiment, sensor inputs may be correlated to classes of different maintenance requirements of each of different sensor inputs. In at least one embodiment, a new sensor input classifying within a class of such different sensor inputs may indicate a maintenance requirement, or a change thereof.

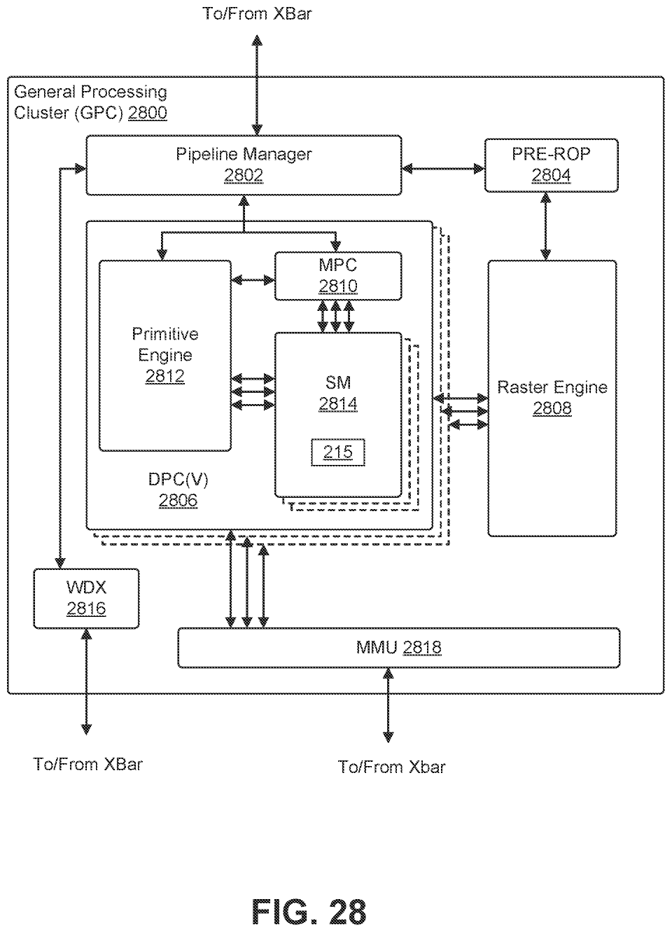

FIG. 28 illustrates a general processing cluster (“GPC”) 2800, according to at least one embodiment. In at least one embodiment, GPC 2800 is GPC 2718 of FIG. 27. In at least one embodiment, each GPC 2800 includes, without limitation, a number of hardware units for processing tasks and each GPC 2800 includes, without limitation, a pipeline manager 2802, a pre-raster operations unit (“preROP”) 2804, a raster engine 2808, a work distribution crossbar (“WDX”) 2816, a memory management unit (“MMU”) 2818, one or more Data Processing Clusters (“DPCs”) 2806, and any suitable combination of parts.

In at least one embodiment, operation of GPC 2800 is controlled by pipeline manager 2802. In at least one embodiment, pipeline manager 2802 manages configuration of one or more DPCs 2806 for processing tasks allocated to GPC 2800. In at least one embodiment, pipeline manager 2802 configures at least one of one or more DPCs 2806 to implement at least a portion of a graphics rendering pipeline. In at least one embodiment, DPC 2806 is configured to execute a vertex shader program on a programmable streaming multi-processor (“SM”) 2814. In at least one embodiment, pipeline manager 2802 is configured to route packets received from a work distribution unit to appropriate logical units within GPC 2800, in at least one embodiment, and some packets may be routed to fixed function hardware units in preROP 2804 and/or raster engine 2808 while other packets may be routed to DPCs 2806 for processing by a primitive engine 2812 or SM 2814. In at least one embodiment, pipeline manager 2802 configures at least one of DPCs 2806 to implement a neural network model and/or a computing pipeline.

In at least one embodiment, preROP unit 2804 is configured, in at least one embodiment, to route data generated by raster engine 2808 and DPCs 2806 to a Raster Operations (“ROP”) unit in partition unit 2722, described in more detail above in conjunction with FIG. 27. In at least one embodiment, preROP unit 2804 is configured to perform optimizations for color blending, organize pixel data, perform address translations, and more. In at least one embodiment, raster engine 2808 includes, without limitation, a number of fixed function hardware units configured to perform various raster operations, in at least one embodiment, and raster engine 2808 includes, without limitation, a setup engine, a coarse raster engine, a culling engine, a clipping engine, a fine raster engine, a tile coalescing engine, and any suitable combination thereof. In at least one embodiment, setup engine receives transformed vertices and generates plane equations associated with geometric primitive defined by vertices; plane equations are transmitted to a coarse raster engine to generate coverage information (e.g., an x, y coverage mask for a tile) for primitive; output of a coarse raster engine is transmitted to a culling engine where fragments associated with a primitive that fail a z-test are culled, and transmitted to a clipping engine where fragments lying outside a viewing frustum are clipped. In at least one embodiment, fragments that survive clipping and culling are passed to a fine raster engine to generate attributes for pixel fragments based on plane equations generated by a setup engine. In at least one embodiment, an output of raster engine 2808 comprises fragments to be processed by any suitable entity, such as by a fragment shader implemented within DPC 2806.

In at least one embodiment, each DPC 2806 included in GPC 2800 comprises, without limitation, an M-Pipe Controller (“MPC”) 2810; primitive engine 2812; one or more SMs 2814; and any suitable combination thereof. In at least one embodiment, MPC 2810 controls operation of DPC 2806, routing packets received from pipeline manager 2802 to appropriate units in DPC 2806. In at least one embodiment, packets associated with a vertex are routed to primitive engine 2812, which is configured to fetch vertex attributes associated with a vertex from memory; in contrast, packets associated with a shader program may be transmitted to SM 2814.

In at least one embodiment, SM 2814 comprises, without limitation, a programmable streaming processor that is configured to process tasks represented by a number of threads. In at least one embodiment, SM 2814 is multi-threaded and configured to execute a plurality of threads (e.g., 32 threads) from a particular group of threads concurrently and implements a Single-Instruction, Multiple-Data (“SIMD”) architecture where each thread in a group of threads (e.g., a warp, wavefront, wave) is configured to process a different set of data based on same set of instructions. In at least one embodiment, all threads in group of threads execute a common set of instructions. In at least one embodiment, SM 2814 implements a Single-Instruction, Multiple Thread (“SIMT”) architecture wherein each thread in a group of threads is configured to process a different set of data based on that common set of instructions, but where individual threads in a group of threads are allowed to diverge during execution. In at least one embodiment, a program counter, call stack, and execution state is maintained for each warp (which may be referred to as wavefronts and/or waves), enabling concurrency between warps and serial execution within warps when threads within a warp diverge. In another embodiment, a program counter, call stack, and execution state is maintained for each individual thread, enabling equal concurrency between all threads, within and between warps. In at least one embodiment, execution state is maintained for each individual thread and threads executing common instructions may be converged and executed in parallel for better efficiency. At least one embodiment of SM 2814 is described in more detail herein.

In at least one embodiment, MMU 2818 provides an interface between GPC 2800 and a memory partition unit (e.g., partition unit 2722 of FIG. 27) and MMU 2818 provides translation of virtual addresses into physical addresses, memory protection, and arbitration of memory requests. In at least one embodiment, MMU 2818 provides one or more translation lookaside buffers (“TLBs”) for performing translation of virtual addresses into physical addresses in memory.

Inference and/or training logic 315 are used to perform inferencing and/or training operations associated with one or more embodiments. Details regarding inference and/or training logic 315 are provided herein in conjunction with FIGS. 3A and/or 3B. In at least one embodiment, deep learning application processor is used to train a machine learning model, such as a neural network, to predict or infer information provided to GPC 2800. In at least one embodiment, GPC 2800 is used to infer or predict information based on a trained machine learning model (e.g., neural network) that has been trained by another processor or system or by GPC 2800. In at least one embodiment, GPC 2800 may be used to perform one or more neural network use cases described herein.

In at least one embodiment, one or more neural networks of an inference and/or training logic 315 may be used in conjunction with the system of FIG. 28 and may be configured to receive sensor inputs from multiple sensors and may be trained to infer a coolant requirement. In at least one embodiment, an inference and/or training logic 315 may be able to infer this using information from historical maintenance requirements and of historical sensor inputs. In at least one embodiment, an inference and/or training logic 315 may make an inference of a change in a maintenance requirement. In at least one embodiment, sensor inputs may be correlated to classes of different maintenance requirements of each of different sensor inputs. In at least one embodiment, a new sensor input classifying within a class of such different sensor inputs may indicate a maintenance requirement, or a change thereof.

FIG. 29 illustrates a memory partition unit 2900 of a parallel processing unit (“PPU”), in accordance with at least one embodiment. In at least one embodiment, memory partition unit 2900 includes, without limitation, a Raster Operations (“ROP”) unit 2902, a level two (“L2”) cache 2904, a memory interface 2906, and any suitable combination thereof. In at least one embodiment, memory interface 2906 is coupled to memory. In at least one embodiment, memory interface 2906 may implement 32, 64, 128, 1024-bit data buses, or like, for high-speed data transfer. In at least one embodiment, PPU incorporates U memory interfaces 2906 where U is a positive integer, with one memory interface 2906 per pair of partition units 2900, where each pair of partition units 2900 is connected to a corresponding memory device. For example, in at least one embodiment, PPU may be connected to up to Y memory devices, such as high bandwidth memory stacks or graphics double-data-rate, version 5, synchronous dynamic random access memory (“GDDR5 SDRAM”).

In at least one embodiment, memory interface 2906 implements a high bandwidth memory second generation (“HBM2”) memory interface and Y equals half of U. In at least one embodiment, HBM2 memory stacks are located on a physical package with a PPU, providing substantial power and area savings compared with conventional GDDR5 SDRAM systems. In at least one embodiment, each HBM2 stack includes, without limitation, four memory dies with Y=4, with each HBM2 stack including two 128-bit channels per die for a total of 8 channels and a data bus width of 1024 bits. In at least one embodiment, that memory supports Single-Error Correcting Double-Error Detecting (“SECDED”) Error Correction Code (“ECC”) to protect data. In at least one embodiment, ECC can provide higher reliability for compute applications that are sensitive to data corruption.

In at least one embodiment, PPU implements a multi-level memory hierarchy. In at least one embodiment, memory partition unit 2900 supports a unified memory to provide a single unified virtual address space for central processing unit (“CPU”) and PPU memory, enabling data sharing between virtual memory systems. In at least one embodiment frequency of accesses by a PPU to a memory located on other processors is traced to ensure that memory pages are moved to physical memory of PPU that is accessing pages more frequently. In at least one embodiment, high-speed GPU interconnect 2708 supports address translation services allowing PPU to directly access a CPU's page tables and providing full access to CPU memory by a PPU.

In at least one embodiment, copy engines transfer data between multiple PPUs or between PPUs and CPUs. In at least one embodiment, copy engines can generate page faults for addresses that are not mapped into page tables and memory partition unit 2900 then services page faults, mapping addresses into page table, after which copy engine performs a transfer. In at least one embodiment, memory is pinned (i.e., non-pageable) for multiple copy engine operations between multiple processors, substantially reducing available memory. In at least one embodiment, with hardware page faulting, addresses can be passed to copy engines without regard as to whether memory pages are resident, and a copy process is transparent.

Data from memory 2704 of FIG. 27 or other system memory is fetched by memory partition unit 2900 and stored in L2 cache 2904, which is located on-chip and is shared between various GPCs, in accordance with at least one embodiment. Each memory partition unit 2900, in at least one embodiment, includes, without limitation, at least a portion of L2 cache associated with a corresponding memory device. In at least one embodiment, lower level caches are implemented in various units within GPCs. In at least one embodiment, each of SMs 2814 in FIG. 28 may implement a Level 1 (“L1”) cache wherein that L1 cache is private memory that is dedicated to a particular SM 2814 and data from L2 cache 2904 is fetched and stored in each L1 cache for processing in functional units of SMs 2814. In at least one embodiment, L2 cache 2904 is coupled to memory interface 2906 and XBar 2720 shown in FIG. 27.

ROP unit 2902 performs graphics raster operations related to pixel color, such as color compression, pixel blending, and more, in at least one embodiment. ROP unit 2902, in at least one embodiment, implements depth testing in conjunction with raster engine 2808, receiving a depth for a sample location associated with a pixel fragment from a culling engine of raster engine 2808. In at least one embodiment, depth is tested against a corresponding depth in a depth buffer for a sample location associated with a fragment. In at least one embodiment, if that fragment passes that depth test for that sample location, then ROP unit 2902 updates depth buffer and transmits a result of that depth test to raster engine 2808. It will be appreciated that a number of partition units 2900 may be different than a number of GPCs and, therefore, each ROP unit 2902 can, in at least one embodiment, be coupled to each GPC. In at least one embodiment, ROP unit 2902 tracks packets received from different GPCs and determines whether a result generated by ROP unit 2902 is to be routed to through XBar 2720.

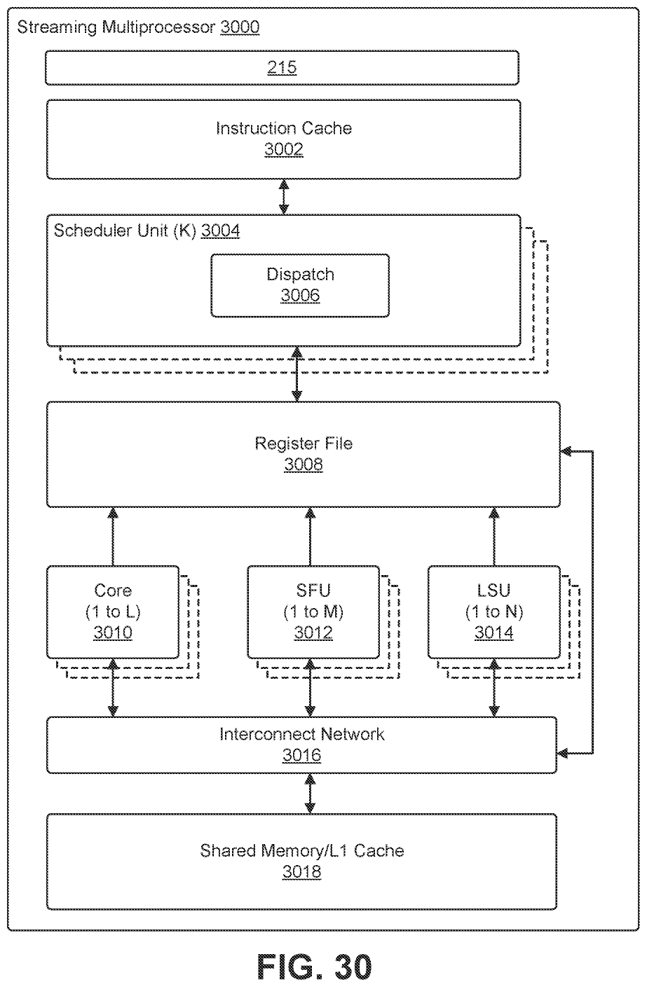

FIG. 30 illustrates a streaming multi-processor (“SM”) 3000, according to at least one embodiment. In at least one embodiment, SM 3000 is SM of FIG. 28. In at least one embodiment, SM 3000 includes, without limitation, an instruction cache 3002, one or more scheduler units 3004 (which may be referred to as sequencer units), a register file 3008, one or more processing cores (“cores”) 3010, one or more special function units (“SFUs”) 3012, one or more load/store units (“LSUs”) 3014, an interconnect network 3016, a shared memory/level one (“L1”) cache 3018, and/or any suitable combination thereof. In at least one embodiment, LSUs 3014 perform load of store operations corresponding to loading/storing data (e.g., instructions) to perform an operation (e.g., perform an API, an API call).

In at least one embodiment, a work distribution unit dispatches tasks for execution on general processing clusters (“GPCs”) of parallel processing units (“PPUs”) and each task is allocated to a particular Data Processing Cluster (“DPC”) within a GPC and, if a task is associated with a shader program, that task is allocated to one of SMs 3000 (which may be referred to as CUs and/or slices). In at least one embodiment, scheduler unit 3004 (which may be referred to as a sequencer and/or asynchronous compute engine) receives tasks from a work distribution unit and manages instruction scheduling for one or more thread blocks assigned to SM 3000. In at least one embodiment, scheduler unit 3004 schedules thread blocks for execution as warps (which may be referred to as wavefronts and/or waves) of parallel threads, wherein each thread block is allocated at least one warp. In at least one embodiment, each warp executes threads. In at least one embodiment, scheduler unit 3004 manages a plurality of different thread blocks, allocating warps to different thread blocks and then dispatching instructions from plurality of different cooperative groups to various functional units (e.g., processing cores 3010, SFUs 3012, and LSUs 3014) during each clock cycle.

In at least one embodiment, Cooperative Groups (which may also be referred to as wavefronts and/or waves) may refer to a programming model for organizing groups of communicating threads that allows developers to express granularity at which threads are communicating, enabling expression of richer, more efficient parallel decompositions. In at least one embodiment, cooperative launch APIs support synchronization amongst thread blocks for execution of parallel algorithms. In at least one embodiment, applications of conventional programming models provide a single, simple construct for synchronizing cooperating threads: a barrier across all threads of a thread block (e.g., syncthreads( ) function). However, in at least one embodiment, programmers may define groups of threads at smaller than thread block granularities and synchronize within defined groups to enable greater performance, design flexibility, and software reuse in form of collective group-wide function interfaces. In at least one embodiment, Cooperative Groups enables programmers to define groups of threads explicitly at sub-block (i.e., as small as a single thread) and multi-block granularities, and to perform collective operations such as synchronization on threads in a cooperative group. In at least one embodiment, that programming model supports clean composition across software boundaries, so that libraries and utility functions can synchronize safely within their local context without having to make assumptions about convergence. In at least one embodiment, Cooperative Groups primitives enable new patterns of cooperative parallelism, including, without limitation, producer-consumer parallelism, opportunistic parallelism, and global synchronization across an entire grid of thread blocks.

In at least one embodiment, a dispatch unit 3006 is configured to transmit instructions to one or more functional units and scheduler unit 3004 and includes, without limitation, two dispatch units 3006 that enable two different instructions from a common warp to be dispatched during each clock cycle. In at least one embodiment, each scheduler unit 3004 includes a single dispatch unit 3006 or additional dispatch units 3006.

In at least one embodiment, each SM 3000 (which may be referred to as a CU and/or slice), in at least one embodiment, includes, without limitation, register file 3008 that provides a set of registers for functional units of SM 3000. In at least one embodiment, register file 3008 is divided between each functional unit such that each functional unit is allocated a dedicated portion of register file 3008. In at least one embodiment, register file 3008 is divided between different warps being executed by SM 3000 and register file 3008 provides temporary storage for operands connected to data paths of functional units. In at least one embodiment, each SM 3000 comprises, without limitation, a plurality of L processing cores 3010, where L is a positive integer. In at least one embodiment, SM 3000 includes, without limitation, a large number (e.g., 128 or more) of distinct processing cores 3010. In at least one embodiment, each processing core 3010 includes, without limitation, a fully-pipelined, single-precision, double-precision, and/or mixed precision processing unit that includes, without limitation, a floating point arithmetic logic unit and an integer arithmetic logic unit. In at least one embodiment, floating point arithmetic logic units implement IEEE 754-2008 standard for floating point arithmetic. In at least one embodiment, processing cores 3010 include, without limitation, 64 single-precision (32-bit) floating point cores, 64 integer cores, 32 double-precision (64-bit) floating point cores, and 8 tensor cores.

Tensor cores are configured to perform matrix operations in accordance with at least one embodiment. In at least one embodiment, one or more tensor cores are included in processing cores 3010. In at least one embodiment, tensor cores are configured to perform deep learning matrix arithmetic, such as convolution operations for neural network training and inferencing. In at least one embodiment, each tensor core operates on a 4×4 matrix and performs a matrix multiply and accumulate operation, D=A×B+C, where A, B, C, and D are 4×4 matrices.

In at least one embodiment, matrix multiply inputs A and B are 16-bit floating point matrices and accumulation matrices C and D are 16-bit floating point or 32-bit floating point matrices. In at least one embodiment, tensor cores operate on 16-bit floating point input data with 32-bit floating point accumulation. In at least one embodiment, 16-bit floating point multiply uses 64 operations and results in a full precision product that is then accumulated using 32-bit floating point addition with other intermediate products for a 4×4×4 matrix multiply. Tensor cores are used to perform much larger two-dimensional or higher dimensional matrix operations, built up from these smaller elements, in at least one embodiment. In at least one embodiment, an API, such as a CUDA 9 C++ API, exposes specialized matrix load, matrix multiply and accumulate, and matrix store operations to efficiently use tensor cores from a CUDA-C++ program. In at least one embodiment, at a CUDA level, a warp-level interface assumes 16×16 size matrices spanning all 32 threads of warp (which may be referred to as a wavefront and/or wave).

In at least one embodiment, each SM 3000 comprises, without limitation, M SFUs 3012 that perform special functions (e.g., attribute evaluation, reciprocal square root, and like). In at least one embodiment, SFUs 3012 include, without limitation, a tree traversal unit configured to traverse a hierarchical tree data structure. In at least one embodiment, SFUs 3012 include, without limitation, a texture unit configured to perform texture map filtering operations. In at least one embodiment, texture units are configured to load texture maps (e.g., a 2D array of texels) from memory and sample texture maps to produce sampled texture values for use in shader programs executed by SM 3000. In at least one embodiment, texture maps are stored in shared memory/L1 cache 3018. In at least one embodiment, texture units implement texture operations such as filtering operations using mip-maps (e.g., texture maps of varying levels of detail), in accordance with at least one embodiment. In at least one embodiment, each SM 3000 includes, without limitation, two texture units.

Each SM 3000 comprises, without limitation, N LSUs 3014 that implement load and store operations between shared memory/L1 cache 3018 and register file 3008, in at least one embodiment. Interconnect network 3016 connects each functional unit to register file 3008 and LSU 3014 to register file 3008 and shared memory/L1 cache 3018 in at least one embodiment. In at least one embodiment, interconnect network 3016 is a crossbar that can be configured to connect any functional units to any registers in register file 3008 and connect LSUs 3014 to register file 3008 and memory locations in shared memory/L1 cache 3018.

In at least one embodiment, shared memory/L1 cache 3018 is an array of on-chip memory that allows for data storage and communication between SM 3000 and primitive engine and between threads in SM 3000, in at least one embodiment. In at least one embodiment, shared memory/L1 cache 3018 comprises, without limitation, 128 KB of storage capacity and is in a path from SM 3000 to a partition unit. In at least one embodiment, shared memory/L1 cache 3018, in at least one embodiment, is used to cache reads and writes. In at least one embodiment, one or more of shared memory/L1 cache 3018, L2 cache, and memory are backing stores.

Combining data cache and shared memory functionality into a single memory block provides improved performance for both types of memory accesses, in at least one embodiment. In at least one embodiment, capacity is used or is usable as a cache by programs that do not use shared memory, such as if shared memory is configured to use half of a capacity, and texture and load/store operations can use remaining capacity. Integration within shared memory/L1 cache 3018 enables shared memory/L1 cache 3018 to function as a high-throughput conduit for streaming data while simultaneously providing high-bandwidth and low-latency access to frequently reused data, in accordance with at least one embodiment. In at least one embodiment, when configured for general purpose parallel computation, a simpler configuration can be used compared with graphics processing. In at least one embodiment, fixed function graphics processing units are bypassed, creating a much simpler programming model. In a general purpose parallel computation configuration, a work distribution unit assigns and distributes blocks of threads directly to DPCs, in at least one embodiment. In at least one embodiment, threads in a block execute a common program, using a unique thread ID in calculation to ensure each thread generates unique results, using SM 3000 to execute program and perform calculations, shared memory/L1 cache 3018 to communicate between threads, and LSU 3014 to read and write global memory through shared memory/L1 cache 3018 and memory partition unit. In at least one embodiment, when configured for general purpose parallel computation, SM 3000 writes commands that scheduler unit 3004 can use to launch new work on DPCs.

In at least one embodiment, a PPU is included in or coupled to a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, and more. In at least one embodiment, a PPU is embodied on a single semiconductor substrate. In at least one embodiment, a PPU is included in a system-on-a-chip (“SoC”) along with one or more other devices such as additional PPUs, memory, a reduced instruction set computer (“RISC”) CPU, a memory management unit (“MMU”), a digital-to-analog converter (“DAC”), and like.

In at least one embodiment, a PPU may be included on a graphics card that includes one or more memory devices. In at least one embodiment, that graphics card may be configured to interface with a PCIe slot on a motherboard of a desktop computer. In at least one embodiment, that PPU may be an integrated graphics processing unit (“iGPU”) included in chipset of a motherboard.

Inference and/or training logic 315 are used to perform inferencing and/or training operations associated with one or more embodiments. Details regarding inference and/or training logic 315 are provided herein in conjunction with FIGS. 3A and/or 3B. In at least one embodiment, deep learning application processor is used to train a machine learning model, such as a neural network, to predict or infer information provided to SM 3000. In at least one embodiment, SM 3000 is used to infer or predict information based on a trained machine learning model (e.g., neural network) that has been trained by another processor or system or by SM 3000. In at least one embodiment, SM 3000 may be used to perform one or more neural network use cases described herein.

In at least one embodiment, one or more neural networks of an inference and/or training logic 315 may be used in conjunction with the system of FIG. 30 and may be configured to receive sensor inputs from multiple sensors and may be trained to infer a coolant requirement. In at least one embodiment, an inference and/or training logic 315 may be able to infer this using information from historical maintenance requirements and of historical sensor inputs. In at least one embodiment, an inference and/or training logic 315 may make an inference of a change in a maintenance requirement. In at least one embodiment, sensor inputs may be correlated to classes of different maintenance requirements of each of different sensor inputs. In at least one embodiment, a new sensor input classifying within a class of such different sensor inputs may indicate a maintenance requirement, or a change thereof.

Embodiments are disclosed related a virtualized computing platform for advanced computing, such as image inferencing and image processing in medical applications. Without limitation, embodiments may include radiography, magnetic resonance imaging (MRI), nuclear medicine, ultrasound, sonography, elastography, photoacoustic imaging, tomography, echocardiography, functional near-infrared spectroscopy, and magnetic particle imaging, or a combination thereof. In at least one embodiment, a virtualized computing platform and associated processes described herein may additionally or alternatively be used, without limitation, in forensic science analysis, sub-surface detection and imaging (e.g., oil exploration, archaeology, paleontology, etc.), topography, oceanography, geology, osteology, meteorology, intelligent area or object tracking and monitoring, sensor data processing (e.g., RADAR, SONAR, LIDAR, etc.), and/or genomics and gene sequencing.

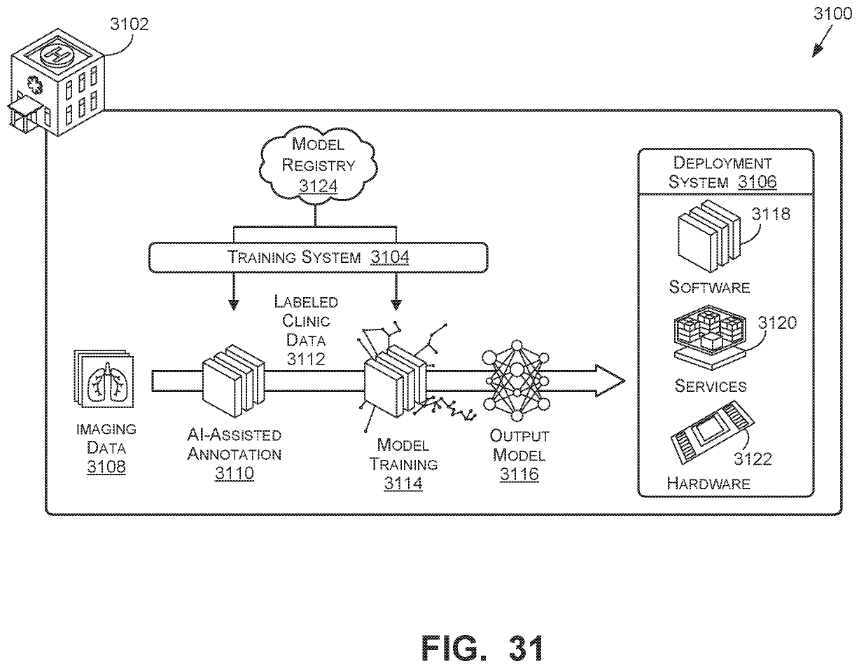

With reference to FIG. 31, FIG. 31 is an example data flow diagram for a process 3100 of generating and deploying an image processing and inferencing pipeline, in accordance with at least one embodiment. In at least one embodiment, process 3100 may be deployed for use with imaging devices, processing devices, genomics devices, gene sequencing devices, radiology devices, and/or other device types at one or more facilities 3102, such as medical facilities, hospitals, healthcare institutes, clinics, research or diagnostic labs, etc. In at least one embodiment, process 3100 may be deployed to perform genomics analysis and inferencing on sequencing data. Examples of genomic analyses that may be performed using systems and processes described herein include, without limitation, variant calling, mutation detection, and gene expression quantification.

In at least one embodiment, process 3100 may be executed within a training system 3104 and/or a deployment system 3106. In at least one embodiment, training system 3104 may be used to perform training, deployment, and implementation of machine learning models (e.g., neural networks, object detection algorithms, computer vision algorithms, etc.) for use in deployment system 3106. In at least one embodiment, deployment system 3106 may be configured to offload processing and compute resources among a distributed computing environment to reduce infrastructure requirements at facility 3102. In at least one embodiment, deployment system 3106 may provide a streamlined platform for selecting, customizing, and implementing virtual instruments for use with imaging devices (e.g., Mill, CT Scan, X-Ray, Ultrasound, etc.) or sequencing devices at facility 3102. In at least one embodiment, virtual instruments may include software-defined applications for performing one or more processing operations with respect to imaging data generated by imaging devices, sequencing devices, radiology devices, and/or other device types. In at least one embodiment, one or more applications in a pipeline may use or call upon services (e.g., inference, visualization, compute, AI, etc.) of deployment system 3106 during execution of applications.

In at least one embodiment, some of applications used in advanced processing and inferencing pipelines may use machine learning models or other AI to perform one or more processing steps. In at least one embodiment, machine learning models may be trained at facility 3102 using data 3108 (such as imaging data) generated at facility 3102 (and stored on one or more picture archiving and communication system (PACS) servers at facility 3102), may be trained using imaging or sequencing data 3108 from another facility or facilities (e.g., a different hospital, lab, clinic, etc.), or a combination thereof. In at least one embodiment, training system 3104 may be used to provide applications, services, and/or other resources for generating working, deployable machine learning models for deployment system 3106.

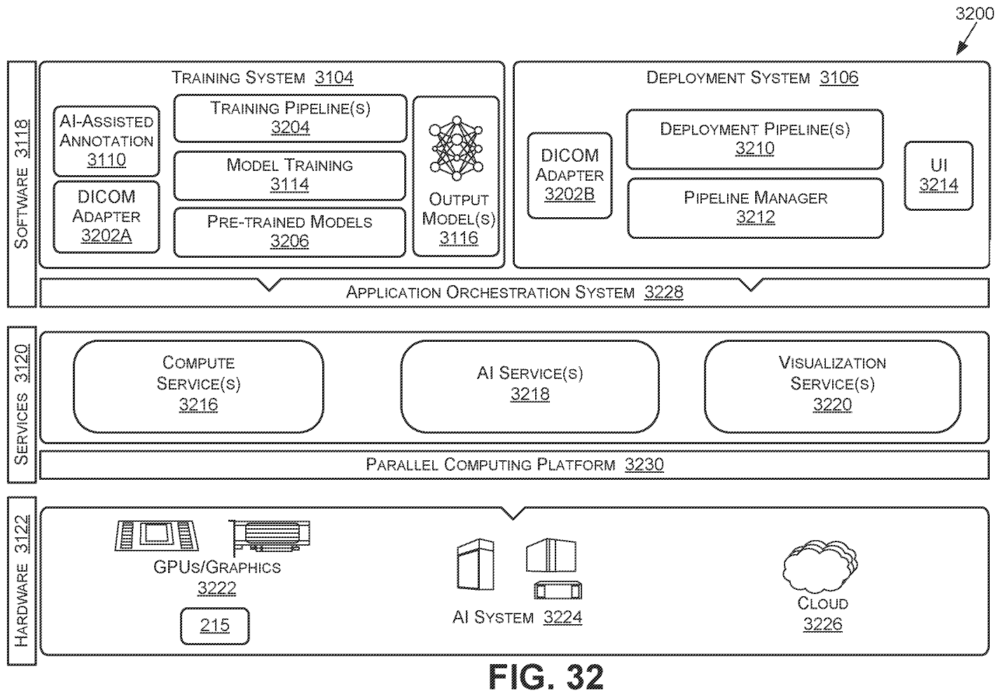

In at least one embodiment, a model registry 3124 may be backed by object storage that may support versioning and object metadata. In at least one embodiment, object storage may be accessible through, for example, a cloud storage (e.g., a cloud 3226 of FIG. 32) compatible application programming interface (API) from within a cloud platform. In at least one embodiment, machine learning models within model registry 3124 may uploaded, listed, modified, or deleted by developers or partners of a system interacting with an API. In at least one embodiment, an API may provide access to methods that allow users with appropriate credentials to associate models with applications, such that models may be executed as part of execution of containerized instantiations of applications.

In at least one embodiment, a training pipeline 3204 (FIG. 32) may include a scenario where facility 3102 is training their own machine learning model, or has an existing machine learning model that needs to be optimized or updated. In at least one embodiment, imaging data 3108 generated by imaging device(s), sequencing devices, and/or other device types may be received. In at least one embodiment, once imaging data 3108 is received, AI-assisted annotation 3110 may be used to aid in generating annotations corresponding to imaging data 3108 to be used as ground truth data for a machine learning model. In at least one embodiment, AI-assisted annotation 3110 may include one or more machine learning models (e.g., convolutional neural networks (CNNs)) that may be trained to generate annotations corresponding to certain types of imaging data 3108 (e.g., from certain devices) and/or certain types of anomalies in imaging data 3108. In at least one embodiment, AI-assisted annotations 3110 may then be used directly, or may be adjusted or fine-tuned using an annotation tool (e.g., by a researcher, a clinician, a doctor, a scientist, etc.), to generate ground truth data. In at least one embodiment, in some examples, labeled clinic data 3112 (e.g., annotations provided by a clinician, doctor, scientist, technician, etc.) may be used as ground truth data for training a machine learning model. In at least one embodiment, AI-assisted annotations 3110, labeled clinic data 3112, or a combination thereof may be used as ground truth data for training a machine learning model. In at least one embodiment, a trained machine learning model may be referred to as an output model 3116, and may be used by deployment system 3106, as described herein.

In at least one embodiment, training pipeline 3204 (FIG. 32) may include a scenario where facility 3102 needs a machine learning model for use in performing one or more processing tasks for one or more applications in deployment system 3106, but facility 3102 may not currently have such a machine learning model (or may not have a model that is optimized, efficient, or effective for such purposes). In at least one embodiment, an existing machine learning model may be selected from model registry 3124. In at least one embodiment, model registry 3124 may include machine learning models trained to perform a variety of different inference tasks on imaging data. In at least one embodiment, machine learning models in model registry 3124 may have been trained on imaging data from different facilities than facility 3102 (e.g., facilities remotely located). In at least one embodiment, machine learning models may have been trained on imaging data from one location, two locations, or any number of locations. In at least one embodiment, when being trained on imaging data from a specific location, training may take place at that location, or at least in a manner that protects confidentiality of imaging data or restricts imaging data from being transferred off-premises (e.g., to comply with HIPAA regulations, privacy regulations, etc.). In at least one embodiment, once a model is trained—or partially trained—at one location, a machine learning model may be added to model registry 3124. In at least one embodiment, a machine learning model may then be retrained, or updated, at any number of other facilities, and a retrained or updated model may be made available in model registry 3124. In at least one embodiment, a machine learning model may then be selected from model registry 3124— and referred to as output model 3116— and may be used in deployment system 3106 to perform one or more processing tasks for one or more applications of a deployment system.

In at least one embodiment, training pipeline 3204 (FIG. 32) may be used in a scenario that includes facility 3102 requiring a machine learning model for use in performing one or more processing tasks for one or more applications in deployment system 3106, but facility 3102 may not currently have such a machine learning model (or may not have a model that is optimized, efficient, or effective for such purposes). In at least one embodiment, a machine learning model selected from model registry 3124 might not be fine-tuned or optimized for imaging data 3108 generated at facility 3102 because of differences in populations, genetic variations, robustness of training data used to train a machine learning model, diversity in anomalies of training data, and/or other issues with training data. In at least one embodiment, AI-assisted annotation 3110 may be used to aid in generating annotations corresponding to imaging data 3108 to be used as ground truth data for retraining or updating a machine learning model. In at least one embodiment, labeled clinic data 3112 (e.g., annotations provided by a clinician, doctor, scientist, etc.) may be used as ground truth data for training a machine learning model. In at least one embodiment, retraining or updating a machine learning model may be referred to as model training 3114. In at least one embodiment, model training 3114—e.g., AI-assisted annotations 3110, labeled clinic data 3112, or a combination thereof—may be used as ground truth data for retraining or updating a machine learning model.

In at least one embodiment, deployment system 3106 may include software 3118, services 3120, hardware 3122, and/or other components, features, and functionality. In at least one embodiment, deployment system 3106 may include a software “stack,” such that software 3118 may be built on top of services 3120 and may use services 3120 to perform some or all of processing tasks, and services 3120 and software 3118 may be built on top of hardware 3122 and use hardware 3122 to execute processing, storage, and/or other compute tasks of deployment system 3106.

In at least one embodiment, software 3118 may include any number of different containers, where each container may execute an instantiation of an application. In at least one embodiment, each application may perform one or more processing tasks in an advanced processing and inferencing pipeline (e.g., inferencing, object detection, feature detection, segmentation, image enhancement, calibration, etc.). In at least one embodiment, for each type of imaging device (e.g., CT, MM, X-Ray, ultrasound, sonography, echocardiography, etc.), sequencing device, radiology device, genomics device, etc., there may be any number of containers that may perform a data processing task with respect to imaging data 3108 (or other data types, such as those described herein) generated by a device. In at least one embodiment, an advanced processing and inferencing pipeline may be defined based on selections of different containers that are desired or required for processing imaging data 3108, in addition to containers that receive and configure imaging data for use by each container and/or for use by facility 3102 after processing through a pipeline (e.g., to convert outputs back to a usable data type, such as digital imaging and communications in medicine (DICOM) data, radiology information system (RIS) data, clinical information system (CIS) data, remote procedure call (RPC) data, data substantially compliant with a representation state transfer (REST) interface, data substantially compliant with a file-based interface, and/or raw data, for storage and display at facility 3102). In at least one embodiment, a combination of containers within software 3118 (e.g., that make up a pipeline) may be referred to as a virtual instrument (as described in more detail herein), and a virtual instrument may leverage services 3120 and hardware 3122 to execute some or all processing tasks of applications instantiated in containers.

In at least one embodiment, a data processing pipeline may receive input data (e.g., imaging data 3108) in a DICOM, RIS, CIS, REST compliant, RPC, raw, and/or other format in response to an inference request (e.g., a request from a user of deployment system 3106, such as a clinician, a doctor, a radiologist, etc.). In at least one embodiment, input data may be representative of one or more images, video, and/or other data representations generated by one or more imaging devices, sequencing devices, radiology devices, genomics devices, and/or other device types. In at least one embodiment, data may undergo pre-processing as part of data processing pipeline to prepare data for processing by one or more applications. In at least one embodiment, post-processing may be performed on an output of one or more inferencing tasks or other processing tasks of a pipeline to prepare an output data for a next application and/or to prepare output data for transmission and/or use by a user (e.g., as a response to an inference request). In at least one embodiment, inferencing tasks may be performed by one or more machine learning models, such as trained or deployed neural networks, which may include output models 3116 of training system 3104.

In at least one embodiment, tasks of data processing pipeline may be encapsulated in a container(s) that each represent a discrete, fully functional instantiation of an application and virtualized computing environment that is able to reference machine learning models. In at least one embodiment, containers or applications may be published into a private (e.g., limited access) area of a container registry (described in more detail herein), and trained or deployed models may be stored in model registry 3124 and associated with one or more applications. In at least one embodiment, images of applications (e.g., container images) may be available in a container registry, and once selected by a user from a container registry for deployment in a pipeline, an image may be used to generate a container for an instantiation of an application for use by a user's system.

In at least one embodiment, developers (e.g., software developers, clinicians, doctors, etc.) may develop, publish, and store applications (e.g., as containers) for performing image processing and/or inferencing on supplied data. In at least one embodiment, development, publishing, and/or storing may be performed using a software development kit (SDK) associated with a system (e.g., to ensure that an application and/or container developed is compliant with or compatible with a system). In at least one embodiment, an application that is developed may be tested locally (e.g., at a first facility, on data from a first facility) with an SDK which may support at least some of services 3120 as a system (e.g., system 3200 of FIG. 32). In at least one embodiment, because DICOM objects may contain anywhere from one to hundreds of images or other data types, and due to a variation in data, a developer may be responsible for managing (e.g., setting constructs for, building pre-processing into an application, etc.) extraction and preparation of incoming DICOM data. In at least one embodiment, once validated by system 3200 (e.g., for accuracy, safety, patient privacy, etc.), an application may be available in a container registry for selection and/or implementation by a user (e.g., a hospital, clinic, lab, healthcare provider, etc.) to perform one or more processing tasks with respect to data at a facility (e.g., a second facility) of a user.

In at least one embodiment, developers may then share applications or containers through a network for access and use by users of a system (e.g., system 3200 of FIG. 32). In at least one embodiment, completed and validated applications or containers may be stored in a container registry and associated machine learning models may be stored in model registry 3124. In at least one embodiment, a requesting entity (e.g., a user at a medical facility)—who provides an inference or image processing request—may browse a container registry and/or model registry 3124 for an application, container, dataset, machine learning model, etc., select a desired combination of elements for inclusion in data processing pipeline, and submit an imaging processing request. In at least one embodiment, a request may include input data (and associated patient data, in some examples) that is necessary to perform a request, and/or may include a selection of application(s) and/or machine learning models to be executed in processing a request. In at least one embodiment, a request may then be passed to one or more components of deployment system 3106 (e.g., a cloud) to perform processing of data processing pipeline. In at least one embodiment, processing by deployment system 3106 may include referencing selected elements (e.g., applications, containers, models, etc.) from a container registry and/or model registry 3124. In at least one embodiment, once results are generated by a pipeline, results may be returned to a user for reference (e.g., for viewing in a viewing application suite executing on a local, on-premises workstation or terminal). In at least one embodiment, a radiologist may receive results from an data processing pipeline including any number of application and/or containers, where results may include anomaly detection in X-rays, CT scans, MRIs, etc.

In at least one embodiment, to aid in processing or execution of applications or containers in pipelines, services 3120 may be leveraged. In at least one embodiment, services 3120 may include compute services, artificial intelligence (AI) services, visualization services, and/or other service types. In at least one embodiment, services 3120 may provide functionality that is common to one or more applications in software 3118, so functionality may be abstracted to a service that may be called upon or leveraged by applications. In at least one embodiment, functionality provided by services 3120 may run dynamically and more efficiently, while also scaling well by allowing applications to process data in parallel (e.g., using a parallel computing platform 3230 (FIG. 32)). In at least one embodiment, rather than each application that shares a same functionality offered by a service 3120 being required to have a respective instance of service 3120, service 3120 may be shared between and among various applications. In at least one embodiment, services may include an inference server or engine that may be used for executing detection or segmentation tasks, as non-limiting examples. In at least one embodiment, a model training service may be included that may provide machine learning model training and/or retraining capabilities. In at least one embodiment, a data augmentation service may further be included that may provide GPU accelerated data (e.g., DICOM, RIS, CIS, REST compliant, RPC, raw, etc.) extraction, resizing, scaling, and/or other augmentation. In at least one embodiment, a visualization service may be used that may add image rendering effects—such as ray-tracing, rasterization, denoising, sharpening, etc. —to add realism to two-dimensional (2D) and/or three-dimensional (3D) models. In at least one embodiment, virtual instrument services may be included that provide for beam-forming, segmentation, inferencing, imaging, and/or support for other applications within pipelines of virtual instruments.

In at least one embodiment, where a service 3120 includes an AI service (e.g., an inference service), one or more machine learning models associated with an application for anomaly detection (e.g., tumors, growth abnormalities, scarring, etc.) may be executed by calling upon (e.g., as an API call) an inference service (e.g., an inference server) to execute machine learning model(s), or processing thereof, as part of application execution. In at least one embodiment, where another application includes one or more machine learning models for segmentation tasks, an application may call upon an inference service to execute machine learning models for performing one or more of processing operations associated with segmentation tasks. In at least one embodiment, software 3118 implementing advanced processing and inferencing pipeline that includes segmentation application and anomaly detection application may be streamlined because each application may call upon a same inference service to perform one or more inferencing tasks.

In at least one embodiment, hardware 3122 may include GPUs, CPUs, graphics cards, an AI/deep learning system (e.g., an AI supercomputer, such as NVIDIA's DGX supercomputer system), a cloud platform, or a combination thereof. In at least one embodiment, different types of hardware 3122 may be used to provide efficient, purpose-built support for software 3118 and services 3120 in deployment system 3106. In at least one embodiment, use of GPU processing may be implemented for processing locally (e.g., at facility 3102), within an AI/deep learning system, in a cloud system, and/or in other processing components of deployment system 3106 to improve efficiency, accuracy, and efficacy of image processing, image reconstruction, segmentation, MM exams, stroke or heart attack detection (e.g., in real-time), image quality in rendering, etc. In at least one embodiment, a facility may include imaging devices, genomics devices, sequencing devices, and/or other device types on-premises that may leverage GPUs to generate imaging data representative of a subject's anatomy.

In at least one embodiment, software 3118 and/or services 3120 may be optimized for GPU processing with respect to deep learning, machine learning, and/or high-performance computing, as non-limiting examples. In at least one embodiment, at least some of computing environment of deployment system 3106 and/or training system 3104 may be executed in a datacenter one or more supercomputers or high performance computing systems, with GPU optimized software (e.g., hardware and software combination of NVIDIA's DGX system). In at least one embodiment, datacenters may be compliant with provisions of HIPAA, such that receipt, processing, and transmission of imaging data and/or other patient data is securely handled with respect to privacy of patient data. In at least one embodiment, hardware 3122 may include any number of GPUs that may be called upon to perform processing of data in parallel, as described herein. In at least one embodiment, cloud platform may further include GPU processing for GPU-optimized execution of deep learning tasks, machine learning tasks, or other computing tasks. In at least one embodiment, cloud platform (e.g., NVIDIA's NGC) may be executed using an AI/deep learning supercomputer(s) and/or GPU-optimized software (e.g., as provided on NVIDIA's DGX systems) as a hardware abstraction and scaling platform. In at least one embodiment, cloud platform may integrate an application container clustering system or orchestration system (e.g., KUBERNETES) on multiple GPUs to enable seamless scaling and load balancing.

In at least one embodiment, one or more neural networks of an inference and/or training logic 315 may be used in conjunction with the system of FIG. 31 and may be configured to receive sensor inputs from multiple sensors and may be trained to infer a coolant requirement. In at least one embodiment, an inference and/or training logic 315 may be able to infer this using information from historical maintenance requirements and of historical sensor inputs. In at least one embodiment, an inference and/or training logic 315 may make an inference of a change in a maintenance requirement. In at least one embodiment, sensor inputs may be correlated to classes of different maintenance requirements of each of different sensor inputs. In at least one embodiment, a new sensor input classifying within a class of such different sensor inputs may indicate a maintenance requirement, or a change thereof.

FIG. 32 is a system diagram for an example system 3200 for generating and deploying an imaging deployment pipeline, in accordance with at least one embodiment. In at least one embodiment, system 3200 may be used to implement process 3100 of FIG. 31 and/or other processes including advanced processing and inferencing pipelines. In at least one embodiment, system 3200 may include training system 3104 and deployment system 3106. In at least one embodiment, training system 3104 and deployment system 3106 may be implemented using software 3118, services 3120, and/or hardware 3122, as described herein.

In at least one embodiment, system 3200 (e.g., training system 3104 and/or deployment system 3106) may implemented in a cloud computing environment (e.g., using cloud 3226). In at least one embodiment, system 3200 may be implemented locally with respect to a healthcare services facility, or as a combination of both cloud and local computing resources. In at least one embodiment, in embodiments where cloud computing is implemented, patient data may be separated from, or unprocessed by, by one or more components of system 3200 that would render processing non-compliant with HIPAA and/or other data handling and privacy regulations or laws. In at least one embodiment, access to APIs in cloud 3226 may be restricted to authorized users through enacted security measures or protocols. In at least one embodiment, a security protocol may include web tokens that may be signed by an authentication (e.g., AuthN, AuthZ, Gluecon, etc.) service and may carry appropriate authorization. In at least one embodiment, APIs of virtual instruments (described herein), or other instantiations of system 3200, may be restricted to a set of public IPs that have been vetted or authorized for interaction.

In at least one embodiment, various components of system 3200 may communicate between and among one another using any of a variety of different network types, including but not limited to local area networks (LANs) and/or wide area networks (WANs) via wired and/or wireless communication protocols. In at least one embodiment, communication between facilities and components of system 3200 (e.g., for transmitting inference requests, for receiving results of inference requests, etc.) may be communicated over a data bus or data busses, wireless data protocols (Wi-Fi), wired data protocols (e.g., Ethernet), etc.

In at least one embodiment, training system 3104 may execute training pipelines 3204, similar to those described herein with respect to FIG. 31. In at least one embodiment, where one or more machine learning models are to be used in deployment pipelines 3210 by deployment system 3106, training pipelines 3204 may be used to train or retrain one or more (e.g., pre-trained) models, and/or implement one or more of pre-trained models 3206 (e.g., without a need for retraining or updating). In at least one embodiment, as a result of training pipelines 3204, output model(s) 3116 may be generated. In at least one embodiment, training pipelines 3204 may include any number of processing steps, such as but not limited to imaging data (or other input data) conversion or adaption (e.g., using DICOM adapter 3202A to convert DICOM images to another format suitable for processing by respective machine learning models, such as Neuroimaging Informatics Technology Initiative (NIfTI) format), AI-assisted annotation 3110, labeling or annotating of imaging data 3108 to generate labeled clinic data 3112, model selection from a model registry, model training 3114, training, retraining, or updating models, and/or other processing steps. In at least one embodiment, for different machine learning models used by deployment system 3106, different training pipelines 3204 may be used. In at least one embodiment, training pipeline 3204 similar to a first example described with respect to FIG. 31 may be used for a first machine learning model, training pipeline 3204 similar to a second example described with respect to FIG. 31 may be used for a second machine learning model, and training pipeline 3204 similar to a third example described with respect to FIG. 31 may be used for a third machine learning model. In at least one embodiment, any combination of tasks within training system 3104 may be used depending on what is required for each respective machine learning model. In at least one embodiment, one or more of machine learning models may already be trained and ready for deployment so machine learning models may not undergo any processing by training system 3104, and may be implemented by deployment system 3106.

In at least one embodiment, output model(s) 3116 and/or pre-trained model(s) 3206 may include any types of machine learning models depending on implementation or embodiment. In at least one embodiment, and without limitation, machine learning models used by system 3200 may include machine learning model(s) using linear regression, logistic regression, decision trees, support vector machines (SVM), Naïve Bayes, k-nearest neighbor (Knn), K means clustering, random forest, dimensionality reduction algorithms, gradient boosting algorithms, neural networks (e.g., auto-encoders, convolutional, recurrent, perceptrons, Long/Short Term Memory (LSTM), Hopfield, Boltzmann, deep belief, deconvolutional, generative adversarial, liquid state machine, etc.), and/or other types of machine learning models.

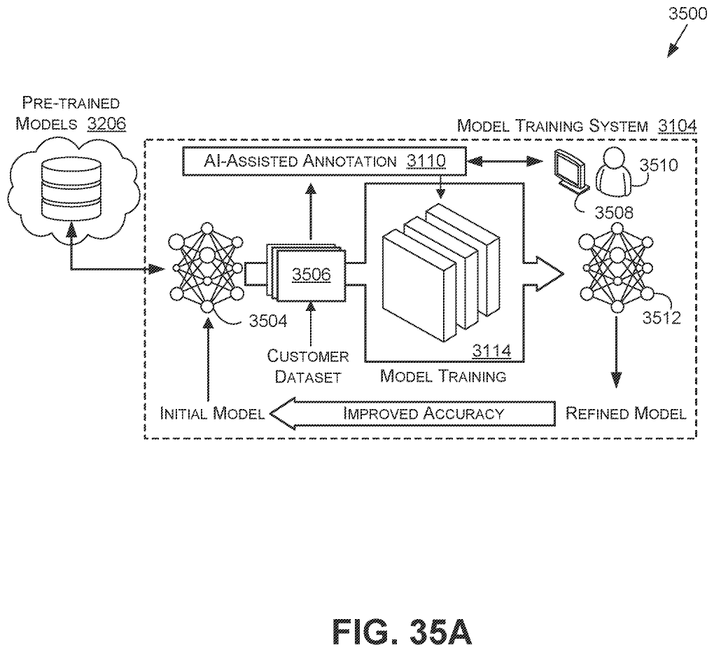

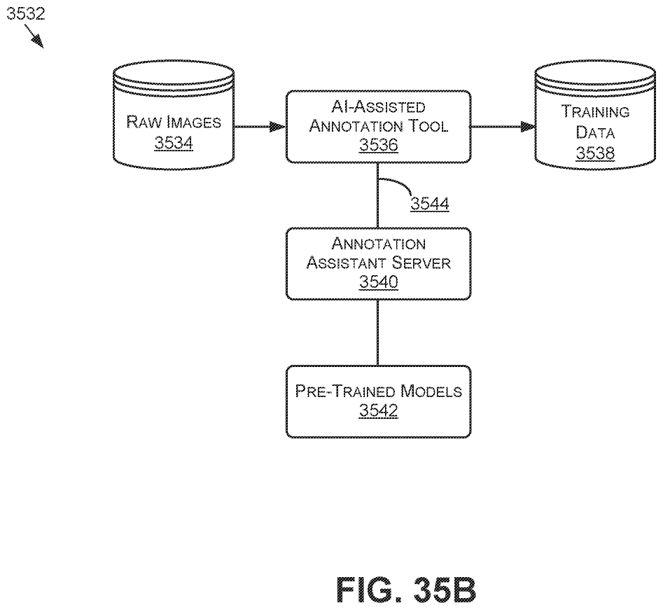

In at least one embodiment, training pipelines 3204 may include AI-assisted annotation, as described in more detail herein with respect to at least FIG. 35B. In at least one embodiment, labeled clinic data 3112 (e.g., traditional annotation) may be generated by any number of techniques. In at least one embodiment, labels or other annotations may be generated within a drawing program (e.g., an annotation program), a computer aided design (CAD) program, a labeling program, another type of program suitable for generating annotations or labels for ground truth, and/or may be hand drawn, in some examples. In at least one embodiment, ground truth data may be synthetically produced (e.g., generated from computer models or renderings), real produced (e.g., designed and produced from real-world data), machine-automated (e.g., using feature analysis and learning to extract features from data and then generate labels), human annotated (e.g., labeler, or annotation expert, defines location of labels), and/or a combination thereof. In at least one embodiment, for each instance of imaging data 3108 (or other data type used by machine learning models), there may be corresponding ground truth data generated by training system 3104. In at least one embodiment, AI-assisted annotation may be performed as part of deployment pipelines 3210; either in addition to, or in lieu of AI-assisted annotation included in training pipelines 3204. In at least one embodiment, system 3200 may include a multi-layer platform that may include a software layer (e.g., software 3118) of diagnostic applications (or other application types) that may perform one or more medical imaging and diagnostic functions. In at least one embodiment, system 3200 may be communicatively coupled to (e.g., via encrypted links) PACS server networks of one or more facilities. In at least one embodiment, system 3200 may be configured to access and referenced data (e.g., DICOM data, RIS data, raw data, CIS data, REST compliant data, RPC data, raw data, etc.) from PACS servers (e.g., via a DICOM adapter 3202, or another data type adapter such as RIS, CIS, REST compliant, RPC, raw, etc.) to perform operations, such as training machine learning models, deploying machine learning models, image processing, inferencing, and/or other operations.

In at least one embodiment, a software layer may be implemented as a secure, encrypted, and/or authenticated API through which applications or containers may be invoked (e.g., called) from an external environment(s) (e.g., facility 3102). In at least one embodiment, applications may then call or execute one or more services 3120 for performing compute, AI, or visualization tasks associated with respective applications, and software 3118 and/or services 3120 may leverage hardware 3122 to perform processing tasks in an effective and efficient manner.

In at least one embodiment, deployment system 3106 may execute deployment pipelines 3210. In at least one embodiment, deployment pipelines 3210 may include any number of applications that may be sequentially, non-sequentially, or otherwise applied to imaging data (and/or other data types) generated by imaging devices, sequencing devices, genomics devices, etc. —including AI-assisted annotation, as described above. In at least one embodiment, as described herein, a deployment pipeline 3210 for an individual device may be referred to as a virtual instrument for a device (e.g., a virtual ultrasound instrument, a virtual CT scan instrument, a virtual sequencing instrument, etc.). In at least one embodiment, for a single device, there may be more than one deployment pipeline 3210 depending on information desired from data generated by a device. In at least one embodiment, where detections of anomalies are desired from an MRI machine, there may be a first deployment pipeline 3210, and where image enhancement is desired from output of an Mill machine, there may be a second deployment pipeline 3210.

In at least one embodiment, applications available for deployment pipelines 3210 may include any application that may be used for performing processing tasks on imaging data or other data from devices. In at least one embodiment, different applications may be responsible for image enhancement, segmentation, reconstruction, anomaly detection, object detection, feature detection, treatment planning, dosimetry, beam planning (or other radiation treatment procedures), and/or other analysis, image processing, or inferencing tasks. In at least one embodiment, deployment system 3106 may define constructs for each of applications, such that users of deployment system 3106 (e.g., medical facilities, labs, clinics, etc.) may understand constructs and adapt applications for implementation within their respective facility. In at least one embodiment, an application for image reconstruction may be selected for inclusion in deployment pipeline 3210, but data type generated by an imaging device may be different from a data type used within an application. In at least one embodiment, DICOM adapter 3202B (and/or a DICOM reader) or another data type adapter or reader (e.g., RIS, CIS, REST compliant, RPC, raw, etc.) may be used within deployment pipeline 3210 to convert data to a form useable by an application within deployment system 3106. In at least one embodiment, access to DICOM, RIS, CIS, REST compliant, RPC, raw, and/or other data type libraries may be accumulated and pre-processed, including decoding, extracting, and/or performing any convolutions, color corrections, sharpness, gamma, and/or other augmentations to data. In at least one embodiment, DICOM, RIS, CIS, REST compliant, RPC, and/or raw data may be unordered and a pre-pass may be executed to organize or sort collected data. In at least one embodiment, because various applications may share common image operations, in some embodiments, a data augmentation library (e.g., as one of services 3120) may be used to accelerate these operations. In at least one embodiment, to avoid bottlenecks of conventional processing approaches that rely on CPU processing, parallel computing platform 3230 may be used for GPU acceleration of these processing tasks.

In at least one embodiment, an image reconstruction application may include a processing task that includes use of a machine learning model. In at least one embodiment, a user may desire to use their own machine learning model, or to select a machine learning model from model registry 3124. In at least one embodiment, a user may implement their own machine learning model or select a machine learning model for inclusion in an application for performing a processing task. In at least one embodiment, applications may be selectable and customizable, and by defining constructs of applications, deployment and implementation of applications for a particular user are presented as a more seamless user experience. In at least one embodiment, by leveraging other features of system 3200— such as services 3120 and hardware 3122— deployment pipelines 3210 may be even more user friendly, provide for easier integration, and produce more accurate, efficient, and timely results.

In at least one embodiment, deployment system 3106 may include a user interface 3214 (e.g., a graphical user interface, a web interface, etc.) that may be used to select applications for inclusion in deployment pipeline(s) 3210, arrange applications, modify or change applications or parameters or constructs thereof, use and interact with deployment pipeline(s) 3210 during set-up and/or deployment, and/or to otherwise interact with deployment system 3106. In at least one embodiment, although not illustrated with respect to training system 3104, user interface 3214 (or a different user interface) may be used for selecting models for use in deployment system 3106, for selecting models for training, or retraining, in training system 3104, and/or for otherwise interacting with training system 3104.

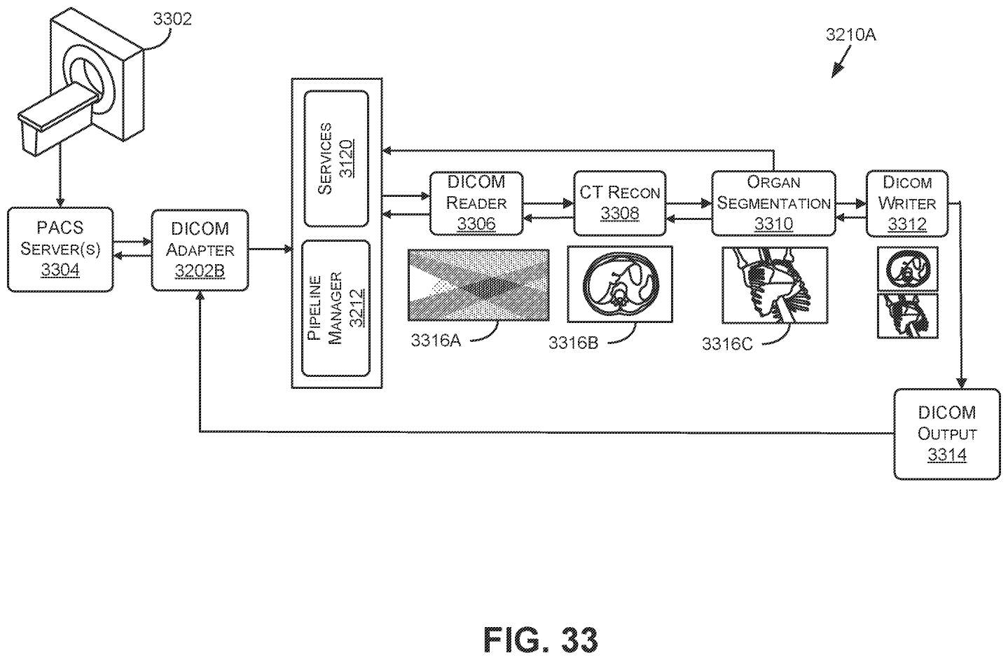

In at least one embodiment, pipeline manager 3212 may be used, in addition to an application orchestration system 3228, to manage interaction between applications or containers of deployment pipeline(s) 3210 and services 3120 and/or hardware 3122. In at least one embodiment, pipeline manager 3212 may be configured to facilitate interactions from application to application, from application to service 3120, and/or from application or service to hardware 3122. In at least one embodiment, although illustrated as included in software 3118, this is not intended to be limiting, and in some examples (e.g., as illustrated in FIG. 33) pipeline manager 3212 may be included in services 3120. In at least one embodiment, application orchestration system 3228 (e.g., Kubernetes, DOCKER, etc.) may include a container orchestration system that may group applications into containers as logical units for coordination, management, scaling, and deployment. In at least one embodiment, by associating applications from deployment pipeline(s) 3210 (e.g., a reconstruction application, a segmentation application, etc.) with individual containers, each application may execute in a self-contained environment (e.g., at a kernel level) to increase speed and efficiency.

In at least one embodiment, each application and/or container (or image thereof) may be individually developed, modified, and deployed (e.g., a first user or developer may develop, modify, and deploy a first application and a second user or developer may develop, modify, and deploy a second application separate from a first user or developer), which may allow for focus on, and attention to, a task of a single application and/or container(s) without being hindered by tasks of another application(s) or container(s). In at least one embodiment, communication, and cooperation between different containers or applications may be aided by pipeline manager 3212 and application orchestration system 3228. In at least one embodiment, so long as an expected input and/or output of each container or application is known by a system (e.g., based on constructs of applications or containers), application orchestration system 3228 and/or pipeline manager 3212 may facilitate communication among and between, and sharing of resources among and between, each of applications or containers. In at least one embodiment, because one or more of applications or containers in deployment pipeline(s) 3210 may share same services and resources, application orchestration system 3228 may orchestrate, load balance, and determine sharing of services or resources between and among various applications or containers. In at least one embodiment, a scheduler may be used to track resource requirements of applications or containers, current usage or planned usage of these resources, and resource availability. In at least one embodiment, a scheduler may thus allocate resources to different applications and distribute resources between and among applications in view of requirements and availability of a system. In some examples, a scheduler (and/or other component of application orchestration system 3228 such as a sequencer and/or asynchronous compute engine) may determine resource availability and distribution based on constraints imposed on a system (e.g., user constraints), such as quality of service (QoS), urgency of need for data outputs (e.g., to determine whether to execute real-time processing or delayed processing), etc.

In at least one embodiment, services 3120 leveraged by and shared by applications or containers in deployment system 3106 may include compute services 3216, AI services 3218, visualization services 3220, and/or other service types. In at least one embodiment, applications may call (e.g., execute) one or more of services 3120 to perform processing operations for an application. In at least one embodiment, compute services 3216 may be leveraged by applications to perform super-computing or other high-performance computing (HPC) tasks. In at least one embodiment, compute service(s) 3216 may be leveraged to perform parallel processing (e.g., using a parallel computing platform 3230) for processing data through one or more of applications and/or one or more tasks of a single application, substantially simultaneously. In at least one embodiment, parallel computing platform 3230 (e.g., NVIDIA's CUDA) may enable general purpose computing on GPUs (GPGPU) (e.g., GPUs 3222). In at least one embodiment, a software layer of parallel computing platform 3230 may provide access to virtual instruction sets and parallel computational elements of GPUs, for execution of compute kernels. In at least one embodiment, parallel computing platform 3230 may include memory and, in some embodiments, a memory may be shared between and among multiple containers, and/or between and among different processing tasks within a single container. In at least one embodiment, inter-process communication (IPC) calls may be generated for multiple containers and/or for multiple processes within a container to use same data from a shared segment of memory of parallel computing platform 3230 (e.g., where multiple different stages of an application or multiple applications are processing same information). In at least one embodiment, rather than making a copy of data and moving data to different locations in memory (e.g., a read/write operation), same data in same location of a memory may be used for any number of processing tasks (e.g., at a same time, at different times, etc.). In at least one embodiment, as data is used to generate new data as a result of processing, this information of a new location of data may be stored and shared between various applications. In at least one embodiment, location of data and a location of updated or modified data may be part of a definition of how a payload is understood within containers.

In at least one embodiment, AI services 3218 may be leveraged to perform inferencing services for executing machine learning model(s) associated with applications (e.g., tasked with performing one or more processing tasks of an application). In at least one embodiment, AI services 3218 may leverage AI system 3224 to execute machine learning model(s) (e.g., neural networks, such as CNNs) for segmentation, reconstruction, object detection, feature detection, classification, and/or other inferencing tasks. In at least one embodiment, applications of deployment pipeline(s) 3210 may use one or more of output models 3116 from training system 3104 and/or other models of applications to perform inferencing on imaging data (e.g., DICOM data, RIS data, CIS data, REST compliant data, RPC data, raw data, etc.). In at least one embodiment, two or more examples of inferencing using application orchestration system 3228 (e.g., a scheduler, sequencer, and/or asynchronous compute engine) may be available. In at least one embodiment, a first category may include a high priority/low latency path that may achieve higher service level agreements, such as for performing inference on urgent requests during an emergency, or for a radiologist during diagnosis. In at least one embodiment, a second category may include a standard priority path that may be used for requests that may be non-urgent or where analysis may be performed at a later time. In at least one embodiment, application orchestration system 3228 may distribute resources (e.g., services 3120 and/or hardware 3122) based on priority paths for different inferencing tasks of AI services 3218.

In at least one embodiment, shared storage may be mounted to AI services 3218 within system 3200. In at least one embodiment, shared storage may operate as a cache (or other storage device type) and may be used to process inference requests from applications. In at least one embodiment, when an inference request is submitted, a request may be received by a set of API instances of deployment system 3106, and one or more instances may be selected (e.g., for best fit, for load balancing, etc.) to process a request. In at least one embodiment, to process a request, a request may be entered into a database, a machine learning model may be located from model registry 3124 if not already in a cache, a validation step may ensure appropriate machine learning model is loaded into a cache (e.g., shared storage), and/or a copy of a model may be saved to a cache. In at least one embodiment, a scheduler (e.g., of pipeline manager 3212) may be used to launch an application that is referenced in a request if an application is not already running or if there are not enough instances of an application. In at least one embodiment, if an inference server is not already launched to execute a model, an inference server may be launched. In at least one embodiment, any number of inference servers may be launched per model. In at least one embodiment, in a pull model, in which inference servers are clustered, models may be cached whenever load balancing is advantageous. In at least one embodiment, inference servers may be statically loaded in corresponding, distributed servers.

In at least one embodiment, inferencing may be performed using an inference server that runs in a container. In at least one embodiment, an instance of an inference server may be associated with a model (and optionally a plurality of versions of a model). In at least one embodiment, if an instance of an inference server does not exist when a request to perform inferencing on a model is received, a new instance may be loaded. In at least one embodiment, when starting an inference server, a model may be passed to an inference server such that a same container may be used to serve different models so long as inference server is running as a different instance.

In at least one embodiment, during application execution, an inference request for a given application may be received, and a container (e.g., hosting an instance of an inference server) may be loaded (if not already), and a start procedure may be called. In at least one embodiment, pre-processing logic in a container may load, decode, and/or perform any additional pre-processing on incoming data (e.g., using a CPU(s) and/or GPU(s)). In at least one embodiment, once data is prepared for inference, a container may perform inferencing as necessary on data. In at least one embodiment, this may include a single inference call on one image (e.g., a hand X-ray), or may require inference on hundreds of images (e.g., a chest CT). In at least one embodiment, an application may summarize results before completing, which may include, without limitation, a single confidence score, pixel level-segmentation, voxel-level segmentation, generating a visualization, or generating text to summarize findings. In at least one embodiment, different models or applications may be assigned different priorities. For example, some models may have a real-time (TAT less than one minute) priority while others may have lower priority (e.g., TAT less than 10 minutes). In at least one embodiment, model execution times may be measured from requesting institution or entity and may include partner network traversal time, as well as execution on an inference service.

In at least one embodiment, transfer of requests between services 3120 and inference applications may be hidden behind a software development kit (SDK), and robust transport may be provide through a queue. In at least one embodiment, a request will be placed in a queue via an API for an individual application/tenant ID combination and an SDK will pull a request from a queue and give a request to an application. In at least one embodiment, a name of a queue may be provided in an environment from where an SDK will pick it up. In at least one embodiment, asynchronous communication through a queue may be useful as it may allow any instance of an application to pick up work as it becomes available. In at least one embodiment, results may be transferred back through a queue, to ensure no data is lost. In at least one embodiment, queues may also provide an ability to segment work, as highest priority work may go to a queue with most instances of an application connected to it, while lowest priority work may go to a queue with a single instance connected to it that processes tasks in an order received. In at least one embodiment, an application may run on a GPU-accelerated instance generated in cloud 3226, and an inference service may perform inferencing on a GPU.

In at least one embodiment, visualization services 3220 may be leveraged to generate visualizations for viewing outputs of applications and/or deployment pipeline(s) 3210. In at least one embodiment, GPUs 3222 may be leveraged by visualization services 3220 to generate visualizations. In at least one embodiment, rendering effects, such as ray-tracing, may be implemented by visualization services 3220 to generate higher quality visualizations. In at least one embodiment, visualizations may include, without limitation, 2D image renderings, 3D volume renderings, 3D volume reconstruction, 2D tomographic slices, virtual reality displays, augmented reality displays, etc. In at least one embodiment, virtualized environments may be used to generate a virtual interactive display or environment (e.g., a virtual environment) for interaction by users of a system (e.g., doctors, nurses, radiologists, etc.). In at least one embodiment, visualization services 3220 may include an internal visualizer, cinematics, and/or other rendering or image processing capabilities or functionality (e.g., ray tracing, rasterization, internal optics, etc.).

In at least one embodiment, hardware 3122 may include GPUs 3222, AI system 3224, cloud 3226, and/or any other hardware used for executing training system 3104 and/or deployment system 3106. In at least one embodiment, GPUs 3222 (e.g., NVIDIA's TESLA and/or QUADRO GPUs) may include any number of GPUs that may be used for executing processing tasks of compute services 3216, AI services 3218, visualization services 3220, other services, and/or any of features or functionality of software 3118. For example, with respect to AI services 3218, GPUs 3222 may be used to perform pre-processing on imaging data (or other data types used by machine learning models), post-processing on outputs of machine learning models, and/or to perform inferencing (e.g., to execute machine learning models). In at least one embodiment, cloud 3226, AI system 3224, and/or other components of system 3200 may use GPUs 3222. In at least one embodiment, cloud 3226 may include a GPU-optimized platform for deep learning tasks. In at least one embodiment, AI system 3224 may use GPUs, and cloud 3226— or at least a portion tasked with deep learning or inferencing—may be executed using one or more AI systems 3224. As such, although hardware 3122 is illustrated as discrete components, this is not intended to be limiting, and any components of hardware 3122 may be combined with, or leveraged by, any other components of hardware 3122.

In at least one embodiment, AI system 3224 may include a purpose-built computing system (e.g., a super-computer or an HPC) configured for inferencing, deep learning, machine learning, and/or other artificial intelligence tasks. In at least one embodiment, AI system 3224 (e.g., NVIDIA's DGX) may include GPU-optimized software (e.g., a software stack) that may be executed using a plurality of GPUs 3222, in addition to CPUs, RAM, storage, and/or other components, features, or functionality. In at least one embodiment, one or more AI systems 3224 may be implemented in cloud 3226 (e.g., in a data center) for performing some or all of AI-based processing tasks of system 3200.

In at least one embodiment, cloud 3226 may include a GPU-accelerated infrastructure (e.g., NVIDIA's NGC) that may provide a GPU-optimized platform for executing processing tasks of system 3200. In at least one embodiment, cloud 3226 may include an AI system(s) 3224 for performing one or more of AI-based tasks of system 3200 (e.g., as a hardware abstraction and scaling platform). In at least one embodiment, cloud 3226 may integrate with application orchestration system 3228 leveraging multiple GPUs to enable seamless scaling and load balancing between and among applications and services 3120. In at least one embodiment, cloud 3226 may tasked with executing at least some of services 3120 of system 3200, including compute services 3216, AI services 3218, and/or visualization services 3220, as described herein. In at least one embodiment, cloud 3226 may perform small and large batch inference (e.g., executing NVIDIA's TENSOR RT), provide an accelerated parallel computing API and platform 3230 (e.g., NVIDIA's CUDA), execute application orchestration system 3228 (e.g., KUBERNETES), provide a graphics rendering API and platform (e.g., for ray-tracing, 2D graphics, 3D graphics, and/or other rendering techniques to produce higher quality cinematics), and/or may provide other functionality for system 3200.

In at least one embodiment, in an effort to preserve patient confidentiality (e.g., where patient data or records are to be used off-premises), cloud 3226 may include a registry—such as a deep learning container registry. In at least one embodiment, a registry may store containers for instantiations of applications that may perform pre-processing, post-processing, or other processing tasks on patient data. In at least one embodiment, cloud 3226 may receive data that includes patient data as well as sensor data in containers, perform requested processing for just sensor data in those containers, and then forward a resultant output and/or visualizations to appropriate parties and/or devices (e.g., on-premises medical devices used for visualization or diagnoses), all without having to extract, store, or otherwise access patient data. In at least one embodiment, confidentiality of patient data is preserved in compliance with HIPAA and/or other data regulations.

In at least one embodiment, one or more neural networks of an inference and/or training logic 315 may be used in conjunction with the system of FIG. 32 and may be configured to receive sensor inputs from multiple sensors and may be trained to infer a coolant requirement. In at least one embodiment, an inference and/or training logic 315 may be able to infer this using information from historical maintenance requirements and of historical sensor inputs. In at least one embodiment, an inference and/or training logic 315 may make an inference of a change in a maintenance requirement. In at least one embodiment, sensor inputs may be correlated to classes of different maintenance requirements of each of different sensor inputs. In at least one embodiment, a new sensor input classifying within a class of such different sensor inputs may indicate a maintenance requirement, or a change thereof.

FIG. 33 includes an example illustration of a deployment pipeline 3210A for processing imaging data, in accordance with at least one embodiment. In at least one embodiment, system 3200— and specifically deployment system 3106— may be used to customize, update, and/or integrate deployment pipeline(s) 3210A into one or more production environments. In at least one embodiment, deployment pipeline 3210A of FIG. 33 includes a non-limiting example of a deployment pipeline 3210A that may be custom defined by a particular user (or team of users) at a facility (e.g., at a hospital, clinic, lab, research environment, etc.). In at least one embodiment, to define deployment pipelines 3210A for a CT scanner 3302, a user may select—from a container registry, for example—one or more applications that perform specific functions or tasks with respect to imaging data generated by CT scanner 3302. In at least one embodiment, applications may be applied to deployment pipeline 3210A as containers that may leverage services 3120 and/or hardware 3122 of system 3200. In addition, deployment pipeline 3210A may include additional processing tasks or applications that may be implemented to prepare data for use by applications (e.g., DICOM adapter 3202B and DICOM reader 3306 may be used in deployment pipeline 3210A to prepare data for use by CT reconstruction 3308, organ segmentation 3310, etc.). In at least one embodiment, deployment pipeline 3210A may be customized or selected for consistent deployment, one time use, or for another frequency or interval. In at least one embodiment, a user may desire to have CT reconstruction 3308 and organ segmentation 3310 for several subjects over a specific interval, and thus may deploy pipeline 3210A for that period of time. In at least one embodiment, a user may select, for each request from system 3200, applications that a user wants to perform processing on that data for that request. In at least one embodiment, deployment pipeline 3210A may be adjusted at any interval and, because of adaptability and scalability of a container structure within system 3200, this may be a seamless process.

In at least one embodiment, deployment pipeline 3210A of FIG. 33 may include CT scanner 3302 generating imaging data of a patient or subject. In at least one embodiment, imaging data from CT scanner 3302 may be stored on a PACS server(s) 3304 associated with a facility housing CT scanner 3302. In at least one embodiment, PACS server(s) 3304 may include software and/or hardware components that may directly interface with imaging modalities (e.g., CT scanner 3302) at a facility. In at least one embodiment, DICOM adapter 3202B may enable sending and receipt of DICOM objects using DICOM protocols. In at least one embodiment, DICOM adapter 3202B may aid in preparation or configuration of DICOM data from PACS server(s) 3304 for use by deployment pipeline 3210A. In at least one embodiment, once DICOM data is processed through DICOM adapter 3202B, pipeline manager 3212 may route data through to deployment pipeline 3210A. In at least one embodiment, DICOM reader 3306 may extract image files and any associated metadata from DICOM data (e.g., raw sinogram data, as illustrated in visualization 3316A). In at least one embodiment, working files that are extracted may be stored in a cache for faster processing by other applications in deployment pipeline 3210A. In at least one embodiment, once DICOM reader 3306 has finished extracting and/or storing data, a signal of completion may be communicated to pipeline manager 3212. In at least one embodiment, pipeline manager 3212 may then initiate or call upon one or more other applications or containers in deployment pipeline 3210A.

In at least one embodiment, CT reconstruction 3308 application and/or container may be executed once data (e.g., raw sinogram data) is available for processing by CT reconstruction 3308 application. In at least one embodiment, CT reconstruction 3308 may read raw sinogram data from a cache, reconstruct an image file out of raw sinogram data (e.g., as illustrated in visualization 3316B), and store resulting image file in a cache. In at least one embodiment, at completion of reconstruction, pipeline manager 3212 may be signaled that reconstruction task is complete. In at least one embodiment, once reconstruction is complete, and a reconstructed image file may be stored in a cache (or other storage device), organ segmentation 3310 application and/or container may be triggered by pipeline manager 3212. In at least one embodiment, organ segmentation 3310 application and/or container may read an image file from a cache, normalize or convert an image file to format suitable for inference (e.g., convert an image file to an input resolution of a machine learning model), and run inference against a normalized image. In at least one embodiment, to run inference on a normalized image, organ segmentation 3310 application and/or container may rely on services 3120, and pipeline manager 3212 and/or application orchestration system 3228 may facilitate use of services 3120 by organ segmentation 3310 application and/or container. In at least one embodiment, for example, organ segmentation 3310 application and/or container may leverage AI services 3218 to perform inferencing on a normalized image, and AI services 3218 may leverage hardware 3122 (e.g., AI system 3224) to execute AI services 3218. In at least one embodiment, a result of an inference may be a mask file (e.g., as illustrated in visualization 3316C) that may be stored in a cache (or other storage device).

In at least one embodiment, once applications that process DICOM data and/or data extracted from DICOM data have completed processing, a signal may be generated for pipeline manager 3212. In at least one embodiment, pipeline manager 3212 may then execute DICOM writer 3312 to read results from a cache (or other storage device), package results into a DICOM format (e.g., as DICOM output 3314) for use by users at a facility who generated a request. In at least one embodiment, DICOM output 3314 may then be transmitted to DICOM adapter 3202B to prepare DICOM output 3314 for storage on PACS server(s) 3304 (e.g., for viewing by a DICOM viewer at a facility). In at least one embodiment, in response to a request for reconstruction and segmentation, visualizations 3316B and 3316C may be generated and available to a user for diagnoses, research, and/or for other purposes.

Although illustrated as consecutive application in deployment pipeline 3210A, CT reconstruction 3308 and organ segmentation 3310 applications may be processed in parallel in at least one embodiment. In at least one embodiment, where applications do not have dependencies on one another, and data is available for each application (e.g., after DICOM reader 3306 extracts data), applications may be executed at a same time, substantially at a same time, or with some overlap. In at least one embodiment, where two or more applications require similar services 3120, a scheduler of system 3200 may be used to load balance and distribute compute or processing resources between and among various applications. In at least one embodiment, in some embodiments, parallel computing platform 3230 may be used to perform parallel processing for applications to decrease run-time of deployment pipeline 3210A to provide real-time results.

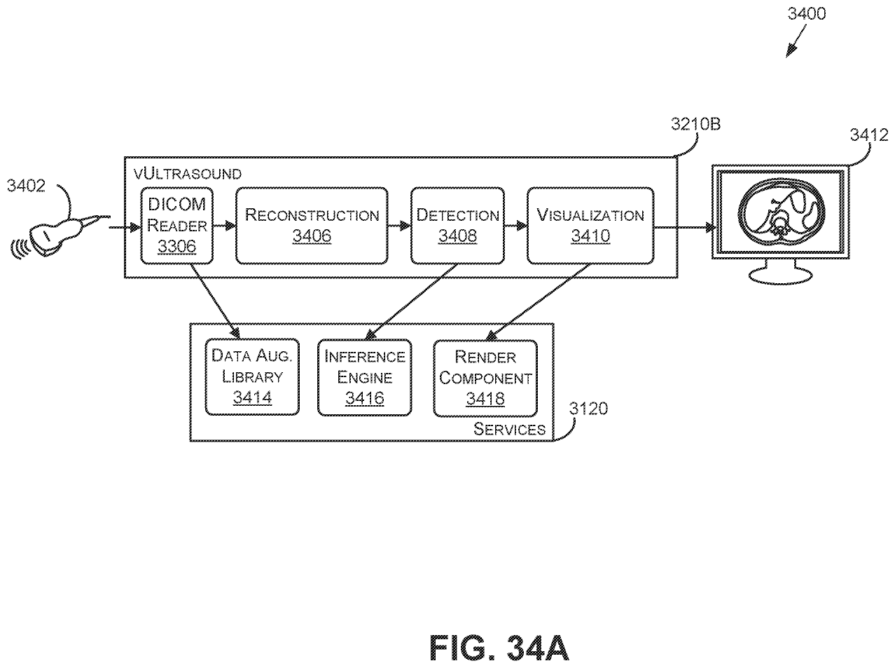

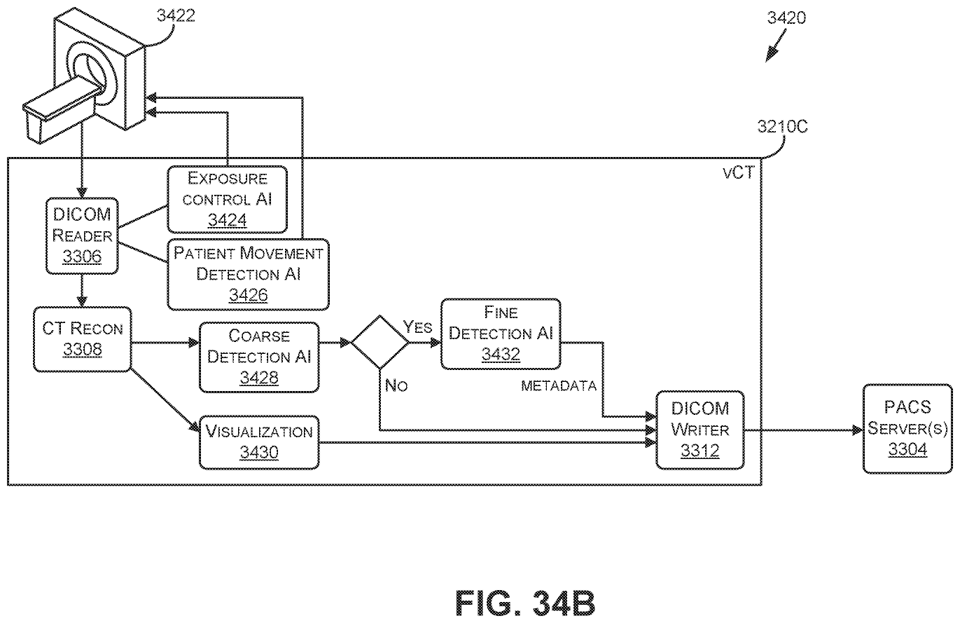

In at least one embodiment, and with reference to FIGS. 34A-34B, deployment system 3106 may be implemented as one or more virtual instruments to perform different functionalities—such as image processing, segmentation, enhancement, AI, visualization, and inferencing—with imaging devices (e.g., CT scanners, X-ray machines, MRI machines, etc.), sequencing devices, genomics devices, and/or other device types. In at least one embodiment, system 3200 may allow for creation and provision of virtual instruments that may include a software-defined deployment pipeline 3210 that may receive raw/unprocessed input data generated by a device(s) and output processed/reconstructed data. In at least one embodiment, deployment pipelines 3210 (e.g., 3210A and 3210B) that represent virtual instruments may implement intelligence into a pipeline, such as by leveraging machine learning models, to provide containerized inference support to a system. In at least one embodiment, virtual instruments may execute any number of containers each including instantiations of applications. In at least one embodiment, such as where real-time processing is desired, deployment pipelines 3210 representing virtual instruments may be static (e.g., containers and/or applications may be set), while in other examples, container and/or applications for virtual instruments may be selected (e.g., on a per-request basis) from a pool of applications or resources (e.g., within a container registry).

In at least one embodiment, system 3200 may be instantiated or executed as one or more virtual instruments on-premise at a facility in, for example, a computing system deployed next to or otherwise in communication with a radiology machine, an imaging device, and/or another device type at a facility. In at least one embodiment, however, an on-premise installation may be instantiated or executed within a computing system of a device itself (e.g., a computing system integral to an imaging device), in a local datacenter (e.g., a datacenter on-premise), and/or in a cloud-environment (e.g., in cloud 3226). In at least one embodiment, deployment system 3106, operating as a virtual instrument, may be instantiated by a supercomputer or other HPC system in some examples. In at least one embodiment, on-premise installation may allow for high-bandwidth uses (via, for example, higher throughput local communication interfaces, such as RF over Ethernet) for real-time processing. In at least one embodiment, real-time or near real-time processing may be particularly useful where a virtual instrument supports an ultrasound device or other imaging modality where immediate visualizations are expected or required for accurate diagnoses and analyses. In at least one embodiment, a cloud-computing architecture may be capable of dynamic bursting to a cloud computing service provider, or other compute cluster, when local demand exceeds on-premise capacity or capability. In at least one embodiment, a cloud architecture, when implemented, may be tuned for training neural networks or other machine learning models, as described herein with respect to training system 3104. In at least one embodiment, with training pipelines in place, machine learning models may be continuously learn and improve as they process additional data from devices they support. In at least one embodiment, virtual instruments may be continually improved using additional data, new data, existing machine learning models, and/or new or updated machine learning models.

In at least one embodiment, a computing system may include some or all of hardware 3122 described herein, and hardware 3122 may be distributed in any of a number of ways including within a device, as part of a computing device coupled to and located proximate a device, in a local datacenter at a facility, and/or in cloud 3226. In at least one embodiment, because deployment system 3106 and associated applications or containers are created in software (e.g., as discrete containerized instantiations of applications), behavior, operation, and configuration of virtual instruments, as well as outputs generated by virtual instruments, may be modified or customized as desired, without having to change or alter raw output of a device that a virtual instrument supports.

In at least one embodiment, one or more neural networks of an inference and/or training logic 315 may be used in conjunction with the system of FIG. 33 and may be configured to receive sensor inputs from multiple sensors and may be trained to infer a coolant requirement. In at least one embodiment, an inference and/or training logic 315 may be able to infer this using information from historical maintenance requirements and of historical sensor inputs. In at least one embodiment, an inference and/or training logic 315 may make an inference of a change in a maintenance requirement. In at least one embodiment, sensor inputs may be correlated to classes of different maintenance requirements of each of different sensor inputs. In at least one embodiment, a new sensor input classifying within a class of such different sensor inputs may indicate a maintenance requirement, or a change thereof.

FIG. 34A includes an example data flow diagram of a virtual instrument supporting an ultrasound device, in accordance with at least one embodiment. In at least one embodiment, deployment pipeline 3210B may leverage one or more of services 3120 of system 3200. In at least one embodiment, deployment pipeline 3210B and services 3120 may leverage hardware 3122 of a system either locally or in cloud 3226. In at least one embodiment, although not illustrated, process 3400 may be facilitated by pipeline manager 3212, application orchestration system 3228, and/or parallel computing platform 3230.

In at least one embodiment, process 3400 may include receipt of imaging data from an ultrasound device 3402. In at least one embodiment, imaging data may be stored on PACS server(s) in a DICOM format (or other format, such as RIS, CIS, REST compliant, RPC, raw, etc.), and may be received by system 3200 for processing through deployment pipeline 3210 selected or customized as a virtual instrument (e.g., a virtual ultrasound) for ultrasound device 3402. In at least one embodiment, imaging data may be received directly from an imaging device (e.g., ultrasound device 3402) and processed by a virtual instrument. In at least one embodiment, a transducer or other signal converter communicatively coupled between an imaging device and a virtual instrument may convert signal data generated by an imaging device to image data that may be processed by a virtual instrument. In at least one embodiment, raw data and/or image data may be applied to DICOM reader 3306 to extract data for use by applications or containers of deployment pipeline 3210B. In at least one embodiment, DICOM reader 3306 may leverage data augmentation library 3414 (e.g., NVIDIA's DALI) as a service 3120 (e.g., as one of compute service(s) 3216) for extracting, resizing, rescaling, and/or otherwise preparing data for use by applications or containers.

In at least one embodiment, once data is prepared, a reconstruction 3406 application and/or container may be executed to reconstruct data from ultrasound device 3402 into an image file. In at least one embodiment, after reconstruction 3406, or at a same time as reconstruction 3406, a detection 3408 application and/or container may be executed for anomaly detection, object detection, feature detection, and/or other detection tasks related to data. In at least one embodiment, an image file generated during reconstruction 3406 may be used during detection 3408 to identify anomalies, objects, features, etc. In at least one embodiment, detection 3408 application may leverage an inference engine 3416 (e.g., as one of AI service(s) 3218) to perform inferencing on data to generate detections. In at least one embodiment, one or more machine learning models (e.g., from training system 3104) may be executed or called by detection 3408 application.

In at least one embodiment, once reconstruction 3406 and/or detection 3408 is/are complete, data output from these application and/or containers may be used to generate visualizations 3410, such as visualization 3412 (e.g., a grayscale output) displayed on a workstation or display terminal. In at least one embodiment, visualization may allow a technician or other user to visualize results of deployment pipeline 3210B with respect to ultrasound device 3402. In at least one embodiment, visualization 3410 may be executed by leveraging a render component 3418 of system 3200 (e.g., one of visualization service(s) 3220). In at least one embodiment, render component 3418 may execute a 2D, OpenGL, or ray-tracing service to generate visualization 3412.

In at least one embodiment, one or more neural networks of an inference and/or training logic 315 may be used in conjunction with the system of FIG. 34A and may be configured to receive sensor inputs from multiple sensors and may be trained to infer a coolant requirement. In at least one embodiment, an inference and/or training logic 315 may be able to infer this using information from historical maintenance requirements and of historical sensor inputs. In at least one embodiment, an inference and/or training logic 315 may make an inference of a change in a maintenance requirement. In at least one embodiment, sensor inputs may be correlated to classes of different maintenance requirements of each of different sensor inputs. In at least one embodiment, a new sensor input classifying within a class of such different sensor inputs may indicate a maintenance requirement, or a change thereof.

FIG. 34B includes an example data flow diagram of a virtual instrument supporting a CT scanner, in accordance with at least one embodiment. In at least one embodiment, deployment pipeline 3210C may leverage one or more of services 3120 of system 3200. In at least one embodiment, deployment pipeline 3210C and services 3120 may leverage hardware 3122 of a system either locally or in cloud 3226. In at least one embodiment, although not illustrated, process 3420 may be facilitated by pipeline manager 3212, application orchestration system 3228, and/or parallel computing platform 3230.

In at least one embodiment, process 3420 may include CT scanner 3422 generating raw data that may be received by DICOM reader 3306 (e.g., directly, via a PACS server 3304, after processing, etc.). In at least one embodiment, a Virtual CT (instantiated by deployment pipeline 3210C) may include a first, real-time pipeline for monitoring a patient (e.g., patient movement detection AI 3426) and/or for adjusting or optimizing exposure of CT scanner 3422 (e.g., using exposure control AI 3424). In at least one embodiment, one or more of applications (e.g., 3424 and 3426) may leverage a service 3120, such as AI service(s) 3218. In at least one embodiment, outputs of exposure control AI 3424 application (or container) and/or patient movement detection AI 3426 application (or container) may be used as feedback to CT scanner 3422 and/or a technician for adjusting exposure (or other settings of CT scanner 3422) and/or informing a patient to move less.

In at least one embodiment, deployment pipeline 3210C may include a non-real-time pipeline for analyzing data generated by CT scanner 3422. In at least one embodiment, a second pipeline may include CT reconstruction 3308 application and/or container, a coarse detection AI 3428 application and/or container, a fine detection AI 3432 application and/or container (e.g., where certain results are detected by coarse detection AI 3428), a visualization 3430 application and/or container, and a DICOM writer 3312 (and/or other data type writer, such as RIS, CIS, REST compliant, RPC, raw, etc.) application and/or container. In at least one embodiment, raw data generated by CT scanner 3422 may be passed through pipelines of deployment pipeline 3210C (instantiated as a virtual CT instrument) to generate results. In at least one embodiment, results from DICOM writer 3312 may be transmitted for display and/or may be stored on PACS server(s) 3304 for later retrieval, analysis, or display by a technician, practitioner, or other user.

In at least one embodiment, one or more neural networks of an inference and/or training logic 315 may be used in conjunction with the features of FIG. 34 and may be configured to receive sensor inputs from multiple sensors and may be trained to infer a maintenance requirement. In at least one embodiment, an inference and/or training logic 315 may be able to infer this using information from historical maintenance requirements and of historical sensor inputs. In at least one embodiment, an inference and/or training logic 315 may make an inference of a change in a maintenance requirement. In at least one embodiment, sensor inputs may be correlated to classes of different maintenance requirements of each of different sensor inputs. In at least one embodiment, a new sensor input classifying within a class of such different sensor inputs may indicate a maintenance requirement, or a change thereof.

FIG. 35A illustrates a data flow diagram for a process 3500 to train, retrain, or update a machine learning model, in accordance with at least one embodiment. In at least one embodiment, process 3500 may be executed using, as a non-limiting example, system 3200 of FIG. 32. In at least one embodiment, process 3500 may leverage services 3120 and/or hardware 3122 of system 3200, as described herein. In at least one embodiment, refined models 3512 generated by process 3500 may be executed by deployment system 3106 for one or more containerized applications in deployment pipelines 3210.

In at least one embodiment, model training 3114 may include retraining or updating an initial model 3504 (e.g., a pre-trained model) using new training data (e.g., new input data, such as customer dataset 3506, and/or new ground truth data associated with input data). In at least one embodiment, to retrain, or update, initial model 3504, output or loss layer(s) of initial model 3504 may be reset, or deleted, and/or replaced with an updated or new output or loss layer(s). In at least one embodiment, initial model 3504 may have previously fine-tuned parameters (e.g., weights and/or biases) that remain from prior training, so training or retraining 3114 may not take as long or require as much processing as training a model from scratch. In at least one embodiment, during model training 3114, by having reset or replaced output or loss layer(s) of initial model 3504, parameters may be updated and re-tuned for a new data set based on loss calculations associated with accuracy of output or loss layer(s) at generating predictions on new, customer dataset 3506 (e.g., image data 3108 of FIG. 31).

In at least one embodiment, pre-trained models 3206 may be stored in a data store, or registry (e.g., model registry 3124 of FIG. 31). In at least one embodiment, pre-trained models 3206 may have been trained, at least in part, at one or more facilities other than a facility executing process 3500. In at least one embodiment, to protect privacy and rights of patients, subjects, or clients of different facilities, pre-trained models 3206 may have been trained, on-premise, using customer or patient data generated on-premise. In at least one embodiment, pre-trained models 3206 may be trained using cloud 3226 and/or other hardware 3122, but confidential, privacy protected patient data may not be transferred to, used by, or accessible to any components of cloud 3226 (or other off premise hardware). In at least one embodiment, where a pre-trained model 3206 is trained at using patient data from more than one facility, pre-trained model 3206 may have been individually trained for each facility prior to being trained on patient or customer data from another facility. In at least one embodiment, such as where a customer or patient data has been released of privacy concerns (e.g., by waiver, for experimental use, etc.), or where a customer or patient data is included in a public data set, a customer or patient data from any number of facilities may be used to train pre-trained model 3206 on-premise and/or off premise, such as in a datacenter or other cloud computing infrastructure.

In at least one embodiment, when selecting applications for use in deployment pipelines 3210, a user may also select machine learning models to be used for specific applications. In at least one embodiment, a user may not have a model for use, so a user may select a pre-trained model 3206 to use with an application. In at least one embodiment, pre-trained model 3206 may not be optimized for generating accurate results on customer dataset 3506 of a facility of a user (e.g., based on patient diversity, demographics, types of medical imaging devices used, etc.). In at least one embodiment, prior to deploying pre-trained model 3206 into deployment pipeline 3210 for use with an application(s), pre-trained model 3206 may be updated, retrained, and/or fine-tuned for use at a respective facility.

In at least one embodiment, a user may select pre-trained model 3206 that is to be updated, retrained, and/or fine-tuned, and pre-trained model 3206 may be referred to as initial model 3504 for training system 3104 within process 3500. In at least one embodiment, customer dataset 3506 (e.g., imaging data, genomics data, sequencing data, or other data types generated by devices at a facility) may be used to perform model training 3114 (which may include, without limitation, transfer learning) on initial model 3504 to generate refined model 3512. In at least one embodiment, ground truth data corresponding to customer dataset 3506 may be generated by training system 3104. In at least one embodiment, ground truth data may be generated, at least in part, by clinicians, scientists, doctors, practitioners, at a facility (e.g., as labeled clinic data 3112 of FIG. 31).

In at least one embodiment, AI-assisted annotation 3110 may be used in some examples to generate ground truth data. In at least one embodiment, AI-assisted annotation 3110 (e.g., implemented using an AI-assisted annotation SDK) may leverage machine learning models (e.g., neural networks) to generate suggested or predicted ground truth data for a customer dataset. In at least one embodiment, user 3510 may use annotation tools within a user interface (a graphical user interface (GUI)) on computing device 3508.

In at least one embodiment, user 3510 may interact with a GUI via computing device 3508 to edit or fine-tune annotations or auto-annotations. In at least one embodiment, a polygon editing feature may be used to move vertices of a polygon to more accurate or fine-tuned locations.

In at least one embodiment, once customer dataset 3506 has associated ground truth data, ground truth data (e.g., from AI-assisted annotation, manual labeling, etc.) may be used by during model training 3114 to generate refined model 3512. In at least one embodiment, customer dataset 3506 may be applied to initial model 3504 any number of times, and ground truth data may be used to update parameters of initial model 3504 until an acceptable level of accuracy is attained for refined model 3512. In at least one embodiment, once refined model 3512 is generated, refined model 3512 may be deployed within one or more deployment pipelines 3210 at a facility for performing one or more processing tasks with respect to medical imaging data.

In at least one embodiment, refined model 3512 may be uploaded to pre-trained models 3206 in model registry 3124 to be selected by another facility. In at least one embodiment, his process may be completed at any number of facilities such that refined model 3512 may be further refined on new datasets any number of times to generate a more universal model.

In at least one embodiment, one or more neural networks of an inference and/or training logic 315 may be used in conjunction with the features of FIG. 35A and may be configured to receive sensor inputs from multiple sensors and may be trained to infer a maintenance requirement. In at least one embodiment, an inference and/or training logic 315 may be able to infer this using information from historical maintenance requirements and of historical sensor inputs. In at least one embodiment, an inference and/or training logic 315 may make an inference of a change in maintenance requirements. In at least one embodiment, sensor inputs may be correlated to classes of different maintenance requirements of each of different sensor inputs. In at least one embodiment, a new sensor input classifying within a class of such different sensor inputs may indicate a maintenance requirement, or a change thereof.

FIG. 35B is an example illustration of a client-server architecture 3532 to enhance annotation tools with pre-trained annotation models, in accordance with at least one embodiment. In at least one embodiment, AI-assisted annotation tools 3536 may be instantiated based on a client-server architecture 3532. In at least one embodiment, annotation tools 3536 in imaging applications may aid radiologists, for example, identify organs and abnormalities. In at least one embodiment, imaging applications may include software tools that help user 3510 to identify, as a non-limiting example, a few extreme points on a particular organ of interest in raw images 3534 (e.g., in a 3D MRI or CT scan) and receive auto-annotated results for all 2D slices of a particular organ. In at least one embodiment, results may be stored in a data store as training data 3538 and used as (for example and without limitation) ground truth data for training. In at least one embodiment, when computing device 3508 sends extreme points for AI-assisted annotation 3110, a deep learning model, for example, may receive this data as input and return inference results of a segmented organ or abnormality. In at least one embodiment, pre-instantiated annotation tools, such as AI-Assisted Annotation Tool 3536B in FIG. 35B, may be enhanced by making API calls (e.g., API Call 3544) to a server, such as an Annotation Assistant Server 3540 that may include a set of pre-trained models 3542 stored in an annotation model registry, for example. In at least one embodiment, an annotation model registry may store pre-trained models 3542 (e.g., machine learning models, such as deep learning models) that are pre-trained to perform AI-assisted annotation on a particular organ or abnormality. In at least one embodiment, these models may be further updated by using training pipelines 3204. In at least one embodiment, pre-installed annotation tools may be improved over time as new labeled clinic data 3112 is added.

Inference and/or training logic 315 are used to perform inferencing and/or training operations associated with one or more embodiments. Details regarding inference and/or training logic 315 are provided herein in conjunction with FIGS. 3A and/or 3B.

In at least one embodiment, one or more neural networks of an inference and/or training logic 315 may be used in conjunction with the features of FIG. 35B and may be configured to receive sensor inputs from multiple sensors and may be trained to infer health data related to data transmission components. In at least one embodiment, an inference and/or training logic 315 may be able to infer this using information from physical sensors related to the data transmission components. In at least one embodiment, an inference and/or training logic 315 may make an inference of maintenance that may be required in the future. In at least one embodiment, sensor inputs may be correlated to maintenance needs for one or more similar data transmission components. In at least one embodiment, sensor inputs may be correlated to classes of different maintenance requirements of each of different sensor inputs. In at least one embodiment, a new sensor input classifying within a class of such different sensor inputs may indicate a maintenance requirement, or a change thereof.

At least one embodiment of the disclosure can be described in view of the following clauses:

1. A computer-implemented method, comprising:
monitoring health data collected from one or more monitored cables, wherein individual cables of the one or more monitored cables having one or more known characteristics;
analyzing the health data in order to determine health metrics of the one or more monitored cables;
generating, using the analyzed health metrics, profiles for the individual cables; and
predicting, using the generated profiles for the individual cables, future health metrics of one or more related cables that share the one or more known characteristics with at least one individual cable.

2. The computer-implemented method of claim 1, further comprising:
collecting the health data using one or more physical sensors that provide physical condition of the one or more monitored cables.

3. The computer-implemented method of claim 1, wherein monitoring the health data occurs continuously during operation of the one or more monitored cables.

4. The computer-implemented method of claim 1, wherein the one or more monitored cables transmit data in a data center.

5. The computer-implemented method of claim 1, wherein the one or more monitored cables connect to an interface panel.

6. The computer-implemented method of claim 1, wherein the health metrics include one or more types of cable failures.

7 The computer-implemented method of claim 1, further comprising:
determining a relative location of the one or more monitored cables based on the analyzed health metrics.

8. The computer-implemented method of claim 1, wherein predicting the future health metrics utilizes machine learning.

9. The computer-implemented method of claim 1, wherein predicting the future health metrics applies cross-correlation of the generated profiles.

10. The computer-implemented method of claim 1, further comprising:
sending instructions for servicing of the one or more related cables in response to the predicted future health metric.

11. A system, comprising:
one or more processors; and
memory including instructions that, when executed by the one or more processors, cause the system to:
   analyze physical condition data monitored from one or more data transmission components to determine one or more anomalies;
   categorize the analyzed physical condition data and the one or more anomalies for individual data transmission components of the one or more data transmission components to determine corresponding individual health profiles;
   create, using the individual health profiles, one or more component clusters to group the individual data transmission components with similar profiles, wherein the individual health profiled are associated with individual component clusters of the one or more component clusters; and
   predict, based on the individual health profiles associated with the individual component clusters, maintenance schedules for the individual data transmission components.

12. The system of claim 11, wherein the maintenance schedules are predicted utilizing machine learning at least in part.

13. The system of claim 11, wherein the maintenance schedules are predicted utilizing cross-correlation of the individual health profiles.

14. The system of claim 11, wherein the one or more anomalies include one or more types of failures, each of the known failures being associated with specific physical condition data values.

15. A processor, comprising:
one or more circuits to provide maintenance recommendations for one or more data transmission components monitored in one or more logical clusters including the one or more data transmission components profiles based, at least in part, on characteristic data monitored over time from the one or more data transmission components.

16. The processor of claim 15, wherein the characteristic data includes one or more physical metrics taken from one or more physical sensors that collect data related to the one or more data transmission components.

17. The processor of claim 15, wherein the characteristic data includes the location of the one or more data transmission component data.

18. The processor of claim 15, wherein the characteristic data is monitored continuously during operation of the one or more data transmission components.

19. The processor of claim 15, wherein the maintenance recommendations include preventative maintenance for an individual data transmission component of the one or more data transmission components based on the monitored characteristic data of an individual logical cluster of the one or more logical clusters.

20. The processor of claim 15, wherein the one or more logical clusters are visualized.

In at least one embodiment, a single semiconductor platform may refer to a sole unitary semiconductor-based integrated circuit or chip. In at least one embodiment, multi-chip modules may be used with increased connectivity which simulate on-chip operation, and make substantial improvements over utilizing a conventional central processing unit (“CPU”) and bus implementation. In at least one embodiment, various modules may also be situated separately or in various combinations of semiconductor platforms per desires of user.

In at least one embodiment, referring back to FIG. 8, computer programs in form of machine-readable executable code or computer control logic algorithms are stored in main memory 804 and/or secondary storage. Computer programs, if executed by one or more processors, enable system 800 to perform various functions in accordance with at least one embodiment. In at least one embodiment, memory 804, storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, architecture and/or functionality of various previous figures are implemented in context of CPU 802, parallel processing system 812, an integrated circuit capable of at least a portion of capabilities of both CPU 802, parallel processing system 812, a chipset (e.g., a group of integrated circuits designed to work and sold as a unit for performing related functions, etc.), and/or any suitable combination of integrated circuit(s).

In at least one embodiment, architecture and/or functionality of various previous figures are implemented in context of a general computer system, a circuit board system, a game console system dedicated for entertainment purposes, an application-specific system, and more. In at least one embodiment, computer system 800 may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

In at least one embodiment, parallel processing system 812 includes, without limitation, a plurality of parallel processing units (“PPUs”) 814 and associated memories 816. In at least one embodiment, PPUs 814 are connected to a host processor or other peripheral devices via an interconnect 818 and a switch 820 or multiplexer. In at least one embodiment, parallel processing system 812 distributes computational tasks across PPUs 814 which can be parallelizable—for example, as part of distribution of computational tasks across multiple graphics processing unit (“GPU”) thread blocks. In at least one embodiment, memory is shared and accessible (e.g., for read and/or write access) across some or all of PPUs 814, although such shared memory may incur performance penalties relative to use of local memory and registers resident to a PPU 814. In at least one embodiment, operation of PPUs 814 is synchronized through use of a command such as syncthreads( ) wherein all threads in a block (e.g., executed across multiple PPUs 814) to reach a certain point of execution of code before proceeding.

In at least one embodiment, one or more techniques described herein utilize a oneAPI programming model. In at least one embodiment, a oneAPI programming model refers to a programming model for interacting with various compute accelerator architectures. In at least one embodiment, oneAPI refers to an application programming interface (API) designed to interact with various compute accelerator architectures. In at least one embodiment, a oneAPI programming model utilizes a DPC++ programming language. In at least one embodiment, a DPC++ programming language refers to a high-level language for data parallel programming productivity. In at least one embodiment, a DPC++ programming language is based at least in part on C and/or C++ programming languages. In at least one embodiment, a oneAPI programming model is a programming model such as those developed by Intel Corporation of Santa Clara, CA.

In at least one embodiment, oneAPI and/or oneAPI programming model is utilized to interact with various accelerator, GPU, processor, and/or variations thereof, architectures. In at least one embodiment, oneAPI includes a set of libraries that implement various functionalities. In at least one embodiment, oneAPI includes at least a oneAPI DPC++ library, a oneAPI math kernel library, a oneAPI data analytics library, a oneAPI deep neural network library, a oneAPI collective communications library, a oneAPI threading building blocks library, a oneAPI video processing library, and/or variations thereof.

In at least one embodiment, a oneAPI DPC++ library, also referred to as oneDPL, is a library that implements algorithms and functions to accelerate DPC++ kernel programming. In at least one embodiment, oneDPL implements one or more standard template library (STL) functions. In at least one embodiment, oneDPL implements one or more parallel STL functions. In at least one embodiment, oneDPL provides a set of library classes and functions such as parallel algorithms, iterators, function object classes, range-based API, and/or variations thereof. In at least one embodiment, oneDPL implements one or more classes and/or functions of a C++ standard library. In at least one embodiment, oneDPL implements one or more random number generator functions.

In at least one embodiment, a oneAPI math kernel library, also referred to as oneMKL, is a library that implements various optimized and parallelized routines for various mathematical functions and/or operations. In at least one embodiment, oneMKL implements one or more basic linear algebra subprograms (BLAS) and/or linear algebra package (LAPACK) dense linear algebra routines. In at least one embodiment, oneMKL implements one or more sparse BLAS linear algebra routines. In at least one embodiment, oneMKL implements one or more random number generators (RNGs). In at least one embodiment, oneMKL implements one or more vector mathematics (VM) routines for mathematical operations on vectors. In at least one embodiment, oneMKL implements one or more Fast Fourier Transform (FFT) functions.

In at least one embodiment, a oneAPI data analytics library, also referred to as oneDAL, is a library that implements various data analysis applications and distributed computations. In at least one embodiment, oneDAL implements various algorithms for preprocessing, transformation, analysis, modeling, validation, and decision making for data analytics, in batch, online, and distributed processing modes of computation. In at least one embodiment, oneDAL implements various C++ and/or Java APIs and various connectors to one or more data sources. In at least one embodiment, oneDAL implements DPC++ API extensions to a traditional C++ interface and enables GPU usage for various algorithms.

In at least one embodiment, a oneAPI deep neural network library, also referred to as oneDNN, is a library that implements various deep learning functions. In at least one embodiment, oneDNN implements various neural network, machine learning, and deep learning functions, algorithms, and/or variations thereof.

In at least one embodiment, a oneAPI collective communications library, also referred to as oneCCL, is a library that implements various applications for deep learning and machine learning workloads. In at least one embodiment, oneCCL is built upon lower-level communication middleware, such as message passing interface (MPI) and libfabrics. In at least one embodiment, oneCCL enables a set of deep learning specific optimizations, such as prioritization, persistent operations, out of order executions, and/or variations thereof. In at least one embodiment, oneCCL implements various CPU and GPU functions.

In at least one embodiment, a oneAPI threading building blocks library, also referred to as oneTBB, is a library that implements various parallelized processes for various applications. In at least one embodiment, oneTBB is utilized for task-based, shared parallel programming on a host. In at least one embodiment, oneTBB implements generic parallel algorithms. In at least one embodiment, oneTBB implements concurrent containers. In at least one embodiment, oneTBB implements a scalable memory allocator. In at least one embodiment, oneTBB implements a work-stealing task scheduler. In at least one embodiment, oneTBB implements low-level synchronization primitives. In at least one embodiment, oneTBB is compiler-independent and usable on various processors, such as GPUs, PPUs, CPUs, and/or variations thereof.

In at least one embodiment, a oneAPI video processing library, also referred to as oneVPL, is a library that is utilized for accelerating video processing in one or more applications. In at least one embodiment, oneVPL implements various video decoding, encoding, and processing functions. In at least one embodiment, oneVPL implements various functions for media pipelines on CPUs, GPUs, and other accelerators. In at least one embodiment, oneVPL implements device discovery and selection in media centric and video analytics workloads. In at least one embodiment, oneVPL implements API primitives for zero-copy buffer sharing.

In at least one embodiment, a oneAPI programming model utilizes a DPC++ programming language. In at least one embodiment, a DPC++ programming language is a programming language that includes, without limitation, functionally similar versions of CUDA mechanisms to define device code and distinguish between device code and host code. In at least one embodiment, a DPC++ programming language may include a subset of functionality of a CUDA programming language. In at least one embodiment, one or more CUDA programming model operations are performed using a oneAPI programming model using a DPC++ programming language.

In at least one embodiment, any application programming interface (API) described herein is compiled into one or more instructions, operations, or any other signal by a compiler, interpreter, or other software tool. In at least one embodiment, compilation comprises generating one or more machine-executable instructions, operations, or other signals from source code. In at least one embodiment, an API compiled into one or more instructions, operations, or other signals, when performed, causes one or more processors such as graphics processors 2300, graphics cores 1300, parallel processor 1500, processor 1800, processor core 1800, or any other logic circuit further described herein to perform one or more computing operations.

It should be noted that, while example embodiments described herein may relate to a CUDA programming model, techniques described herein can be utilized with any suitable programming model, such HIP, oneAPI, and/or variations thereof.

Other variations are within spirit of present disclosure. Thus, while disclosed techniques are susceptible to various modifications and alternative constructions, certain illustrated embodiments thereof are shown in drawings and have been described above in detail. It should be understood, however, that there is no intention to limit disclosure to specific form or forms disclosed, but on contrary, intention is to cover all modifications, alternative constructions, and equivalents falling within spirit and scope of disclosure, as defined in appended claims.

Use of terms “a” and “an” and “the” and similar referents in context of describing disclosed embodiments (especially in context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. “Connected,” when unmodified and referring to physical connections, is to be construed as partly or wholly contained within, attached to, or joined together, even if there is something intervening. Recitation of ranges of values herein are merely intended to serve as a shorthand method of referring individually to each separate value falling within range, unless otherwise indicated herein and each separate value is incorporated into specification as if it were individually recited herein. In at least one embodiment, use of term “set” (e.g., “a set of items”) or “subset” unless otherwise noted or contradicted by context, is to be construed as a nonempty collection comprising one or more members. Further, unless otherwise noted or contradicted by context, term “subset” of a corresponding set does not necessarily denote a proper subset of corresponding set, but subset and corresponding set may be equal.

Conjunctive language, such as phrases of form “at least one of A, B, and C,” or “at least one of A, B and C,” unless specifically stated otherwise or otherwise clearly contradicted by context, is otherwise understood with context as used in general to present that an item, term, etc., may be either A or B or C, or any nonempty subset of set of A and B and C. For instance, in illustrative example of a set having three members, conjunctive phrases “at least one of A, B, and C” and “at least one of A, B and C” refer to any of following sets: {A}, {B}, {C}, {A, B}, {A, C}, {B, C}, {A, B, C}. Thus, such conjunctive language is not generally intended to imply that certain embodiments require at least one of A, at least one of B and at least one of C each to be present. In addition, unless otherwise noted or contradicted by context, term “plurality” indicates a state of being plural (e.g., “a plurality of items” indicates multiple items). In at least one embodiment, number of items in a plurality is at least two, but can be more when so indicated either explicitly or by context. Further, unless stated otherwise or otherwise clear from context, phrase “based on” means “based at least in part on” and not “based solely on.”

Operations of processes described herein can be performed in any suitable order unless otherwise indicated herein or otherwise clearly contradicted by context. In at least one embodiment, a process such as those processes described herein (or variations and/or combinations thereof) is performed under control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in form of a computer program comprising a plurality of instructions executable by one or more processors. In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause computer system to perform operations described herein. In at least one embodiment, set of non-transitory computer-readable storage media comprises multiple non-transitory computer-readable storage media and one or more of individual non-transitory storage media of multiple non-transitory computer-readable storage media lack all of code while multiple non-transitory computer-readable storage media collectively store all of code. In at least one embodiment, executable instructions are executed such that different instructions are executed by different processors—for example, a non-transitory computer-readable storage medium store instructions and a main central processing unit (“CPU”) executes some of instructions while a graphics processing unit (“GPU”) executes other instructions. In at least one embodiment, different components of a computer system have separate processors and different processors execute different subsets of instructions.

In at least one embodiment, an arithmetic logic unit is a set of combinational logic circuitry that takes one or more inputs to produce a result. In at least one embodiment, an arithmetic logic unit is used by a processor to implement mathematical operation such as addition, subtraction, or multiplication. In at least one embodiment, an arithmetic logic unit is used to implement logical operations such as logical AND/OR or XOR. In at least one embodiment, an arithmetic logic unit is stateless, and made from physical switching components such as semiconductor transistors arranged to form logical gates. In at least one embodiment, an arithmetic logic unit may operate internally as a stateful logic circuit with an associated clock. In at least one embodiment, an arithmetic logic unit may be constructed as an asynchronous logic circuit with an internal state not maintained in an associated register set. In at least one embodiment, an arithmetic logic unit is used by a processor to combine operands stored in one or more registers of the processor and produce an output that can be stored by the processor in another register or a memory location.

In at least one embodiment, as a result of processing an instruction retrieved by the processor, the processor presents one or more inputs or operands to an arithmetic logic unit, causing the arithmetic logic unit to produce a result based at least in part on an instruction code provided to inputs of the arithmetic logic unit. In at least one embodiment, the instruction codes provided by the processor to the ALU are based at least in part on the instruction executed by the processor. In at least one embodiment combinational logic in the ALU processes the inputs and produces an output which is placed on a bus within the processor. In at least one embodiment, the processor selects a destination register, memory location, output device, or output storage location on the output bus so that clocking the processor causes the results produced by the ALU to be sent to the desired location.

In the scope of this application, the term arithmetic logic unit, or ALU, is used to refer to any computational logic circuit that processes operands to produce a result. For example, in the present document, the term ALU can refer to a floating point unit, a DSP, a tensor core, a shader core, a coprocessor, or a CPU.

Accordingly, in at least one embodiment, computer systems are configured to implement one or more services that singly or collectively perform operations of processes described herein and such computer systems are configured with applicable hardware and/or software that enable performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples, or exemplary language (e.g., “such as”) provided herein, is intended merely to better illuminate embodiments of disclosure and does not pose a limitation on scope of disclosure unless otherwise claimed. No language in specification should be construed as indicating any non-claimed element as essential to practice of disclosure.

All references, including publications, patent applications, and patents, cited herein are hereby incorporated by reference to same extent as if each reference were individually and specifically indicated to be incorporated by reference and were set forth in its entirety herein.

In description and claims, terms “coupled” and “connected,” along with their derivatives, may be used. It should be understood that these terms may be not intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other, but yet still co-operate or interact with each other.

Unless specifically stated otherwise, it may be appreciated that throughout specification terms such as “processing,” “computing,” “calculating,” “determining,” or like, refer to action and/or processes of a computer or computing system, or similar electronic computing device, that manipulate and/or transform data represented as physical, such as electronic, quantities within computing system's registers and/or memories into other data similarly represented as physical quantities within computing system's memories, registers or other such information storage, transmission or display devices.

In a similar manner, term “processor” may refer to any device or portion of a device that processes electronic data from registers and/or memory and transform that electronic data into other electronic data that may be stored in registers and/or memory. As non-limiting examples, “processor” may be a CPU or a GPU. A “computing platform” may comprise one or more processors. As used herein, “software” processes may include, for example, software and/or hardware entities that perform work over time, such as tasks, threads, and intelligent agents. Also, each process may refer to multiple processes, for carrying out instructions in sequence or in parallel, continuously or intermittently. In at least one embodiment, terms “system” and “method” are used herein interchangeably insofar as system may embody one or more methods and methods may be considered a system.

In present document, references may be made to obtaining, acquiring, receiving, or inputting analog or digital data into a subsystem, computer system, or computer-implemented machine. In at least one embodiment, process of obtaining, acquiring, receiving, or inputting analog and digital data can be accomplished in a variety of ways such as by receiving data as a parameter of a function call or a call to an application programming interface. In at least one embodiment, processes of obtaining, acquiring, receiving, or inputting analog or digital data can be accomplished by transferring data via a serial or parallel interface. In at least one embodiment, processes of obtaining, acquiring, receiving, or inputting analog or digital data can be accomplished by transferring data via a computer network from providing entity to acquiring entity. In at least one embodiment, references may also be made to providing, outputting, transmitting, sending, or presenting analog or digital data. In various examples, processes of providing, outputting, transmitting, sending, or presenting analog or digital data can be accomplished by transferring data as an input or output parameter of a function call, a parameter of an application programming interface or interprocess communication mechanism.

Although descriptions herein set forth example implementations of described techniques, other architectures may be used to implement described functionality, and are intended to be within scope of this disclosure. Furthermore, although specific distributions of responsibilities may be defined above for purposes of description, various functions and responsibilities might be distributed and divided in different ways, depending on circumstances.

Furthermore, although subject matter has been described in language specific to structural features and/or methodological acts, it is to be understood that subject matter claimed in appended claims is not necessarily limited to specific features or acts described. Rather, specific features and acts are disclosed as exemplary forms of implementing the claims.

What is claimed is:

1. A computer-implemented method, comprising:
monitoring health data collected from one or more monitored cables, wherein individual cables of the one or more monitored cables having one or more known characteristics;
analyzing the health data in order to determine health metrics of the one or more monitored cables;
generating, using the analyzed health metrics, profiles for the individual cables; and
predicting, using the generated profiles for the individual cables, future health metrics of one or more related cables that share the one or more known characteristics with at least one individual cable.

2. The computer-implemented method of claim 1, further comprising:
collecting the health data using one or more physical sensors that provide physical condition of the one or more monitored cables.

3. The computer-implemented method of claim 1, wherein monitoring the health data occurs continuously during operation of the one or more monitored cables.

4. The computer-implemented method of claim 1, wherein the one or more monitored cables transmit data in a data center.

5. The computer-implemented method of claim 1, wherein the one or more monitored cables connect to an interface panel.

6. The computer-implemented method of claim 1, wherein the health metrics include one or more types of cable failures.

7. The computer-implemented method of claim 1, further comprising:
determining a relative location of the one or more monitored cables based on the analyzed health metrics.

8. The computer-implemented method of claim 1, wherein predicting the future health metrics utilizes machine learning.

9. The computer-implemented method of claim 1, wherein predicting the future health metrics applies cross-correlation of the generated profiles.

10. The computer-implemented method of claim 1, further comprising:
sending instructions for servicing of the one or more related cables in response to the predicted future health metric.

11. A system, comprising:
one or more processors; and
memory including instructions that, when executed by the one or more processors, cause the system to:
analyze physical condition data monitored from one or more data transmission components to determine one or more anomalies;
categorize the analyzed physical condition data and the one or more anomalies for individual data transmission components of the one or more data transmission components to determine corresponding individual health profiles;
create, using the individual health profiles, one or more component clusters to group the individual data transmission components with similar profiles, wherein the individual health profiled are associated with individual component clusters of the one or more component clusters; and
predict, based on the individual health profiles associated with the individual component clusters, maintenance schedules for the individual data transmission components.

12. The system of claim 11, wherein the maintenance schedules are predicted utilizing machine learning at least in part.

13. The system of claim 11, wherein the maintenance schedules are predicted utilizing cross-correlation of the individual health profiles.

14. The system of claim 11, wherein the one or more anomalies include one or more types of failures, each of the known failures being associated with specific physical condition data values.

15. A processor, comprising:
one or more circuits to provide maintenance recommendations for one or more data transmission components monitored in one or more logical clusters including the one or more data transmission components profiles based, at least in part, on characteristic data monitored over time from the one or more data transmission components.

16. The processor of claim 15, wherein the characteristic data includes one or more physical metrics taken from one or more physical sensors that collect data related to the one or more data transmission components.

17. The processor of claim 15, wherein the characteristic data includes the location of the one or more data transmission component data.

18. The processor of claim 15, wherein the characteristic data is monitored continuously during operation of the one or more data transmission components.

19. The processor of claim 15, wherein the maintenance recommendations include preventative maintenance for an individual data transmission component of the one or more data transmission components based on the monitored characteristic data of an individual logical cluster of the one or more logical clusters.

20. The processor of claim 15, wherein the one or more logical clusters are visualized.
